(19) United States
(12) Patent Application Publication
(10) Pub. No.: US 2024/0392184 A1
(43) Pub. Date: Nov. 28, 2024

(54) ORGANOMETALLIC COMPOUND AND ORGANIC LIGHT-EMITTING DIODE INCLUDING THE SAME

(71) Applicants: LG Display Co., Ltd., Seoul (KR); DuPont Specialty Materials Korea Ltd., Cheonan-si (KR)

(72) Inventors: Yoojeong Jeong, Seoul (KR); Misang Yoo, Seoul (KR); Hansol Park, Goyang-si (KR); Kusun Choung, Seoul (KR); Soonjae Hwang, Seoul (KR); Kyoung-Jin PARK, Hwaseong-si (KR); Hyun Kim, Hwaseong-si (KR); Soo-Yong LEE, Cheonan-si (KR); Samuel KIM, Cheonan-si (KR)

(73) Assignees: LG Display Co., Ltd., Seoul (KR); DuPont Specialty Materials Korea Ltd., Cheonan-si (KR)

(21) Appl. No.: 18/663,891

(22) Filed: May 14, 2024

(30) Foreign Application Priority Data
May 15, 2023 (KR) 10-2023-0062550

(51) Int. Cl. C09K 11/06; H10K 50/12; H10K 50/15; H10K 50/16; H10K 85/30

(52) U.S. Cl. CPC C09K 11/06; H10K 50/12; H10K 50/15; H10K 50/16; H10K 85/342; C09K 2211/185

(57) ABSTRACT

An organometallic compound represented by Chemical Formula 1, Ir(L_{A})ₘ(L_{B})ₙ, and an organic light-emitting diode including the same. The organometallic compound may act as a dopant of a light-emitting layer of the organic light-emitting diode. An operation voltage of the device may be lowered, and luminous efficiency and a lifespan thereof may be improved.

### CROSS-REFERENCE TO RELATED APPLICATION

This application claims the benefit of and the priority to Korean Patent Application No. 10-2023-0062550 filed on May 15, 2023 in the Korean Intellectual Property Office, the disclosure of which is hereby incorporated by reference in its entirety.

### BACKGROUND

### 1. Technical Field

The present disclosure relates to an organometallic compound, and more particularly, to an organometallic compound having phosphorescent properties and an organic light-emitting diode including the same.

### 2. Description of the Related Art

Display devices are ubiquitous, and interest in such devices is increasing. One of the display devices is an organic light-emitting display device including an organic light-emitting diode (OLED) which is rapidly developing.

In the organic light-emitting diode, when electric charges are injected into a light-emitting layer formed or disposed between a positive electrode and a negative electrode, an electron and a hole may be recombined with each other in the light-emitting layer to form an exciton. The energy of the exciton may be converted to light that will be emitted by the organic light-emitting diode. Compared to conventional display devices, the organic light-emitting diode may operate at a lower voltage, consume relatively little power, render excellent colors, and may be used in a variety of ways when the organic light-emitting diode includes a flexible substrate. Further, a size of the organic light-emitting diode may be adjustable.

### SUMMARY

The organic light-emitting diode (OLED) may have superior viewing angle and contrast ratio compared to a liquid crystal display (LCD), and may be lightweight and ultra-thin because the OLED may not require a backlight. The organic light-emitting diode may include a plurality of organic layers between a negative electrode (electron injection electrode; cathode) and a positive electrode (hole injection electrode; anode). The plurality of organic layers may include a hole injection layer, a hole transport layer, a hole transport auxiliary layer, an electron blocking layer, and a light-emitting layer, an electron transport layer, etc.

In this organic light-emitting diode structure, when a voltage is applied across the two electrodes, electrons and holes are injected from the negative and positive electrodes, respectively, into the light-emitting layer. Excitons are generated in the light-emitting layer and then fall to a ground state to emit light.

Organic materials used in the organic light-emitting diode may be largely classified into light-emitting materials and charge-transporting materials. The light-emitting material may be an important factor in determining luminous efficiency of the organic light-emitting diode. The luminescent material may have high quantum efficiency, excellent electron and hole mobility, and may exist uniformly and stably in the light-emitting layer. The light-emitting materials may be classified into light-emitting materials emitting blue, red, and green colors based on colors of the light. A color-generating material may include a host and dopants to increase the color purity and luminous efficiency through energy transfer.

When a fluorescent material is used, singlets which make up about 25% of excitons generated in the light-emitting layer, are used to emit light, while most of triplets which make up 75% of the excitons generated in the light-emitting layer, are dissipated as heat. However, when a phosphorescent material is used, both singlets and triplets may emit light.

An organometallic compound may be used as the phosphorescent material in the organic light-emitting diode. The performance of an organic light-emitting diode may be improved by deriving a high-efficiency phosphorescent dopant material and applying a host material that may have optimal or desirable photophysical properties. The diode efficiency and lifetime may be improved as compared to an organic light-emitting diode in the related art.

Accordingly, an object of the present disclosure is to provide an organometallic compound capable of lowering operation voltage, and improving efficiency, and lifespan, and an organic light-emitting diode including an organic light-emitting layer containing the same.

Objects of the present disclosure are not limited to the above-mentioned objects. Other objects and advantages of the present disclosure that are not mentioned may be understood based on following description, and may be more clearly understood based on aspects of the present disclosure. Further, it may be easily understood that the objects and advantages of the present disclosure may be realized using means shown in the claims and combinations thereof.

To achieve these and other advantages and in accordance with objects of the disclosure, as embodied and broadly described herein, an organometallic compound has a structure represented by Chemical Formula 1:

Ir(L_{A})ₘ(L_{B})ₙ Chemical Formula 1
in Chemical Formula 1,
Ir represents iridium,
m is an integer from 1 to 3, n is an integer from 0 to 2, and a sum of m and n is 3,
L_{A} is represented by one selected from Chemical Formula 2 to Chemical Formula 4, and L_{B} is represented by Chemical Formula 5:

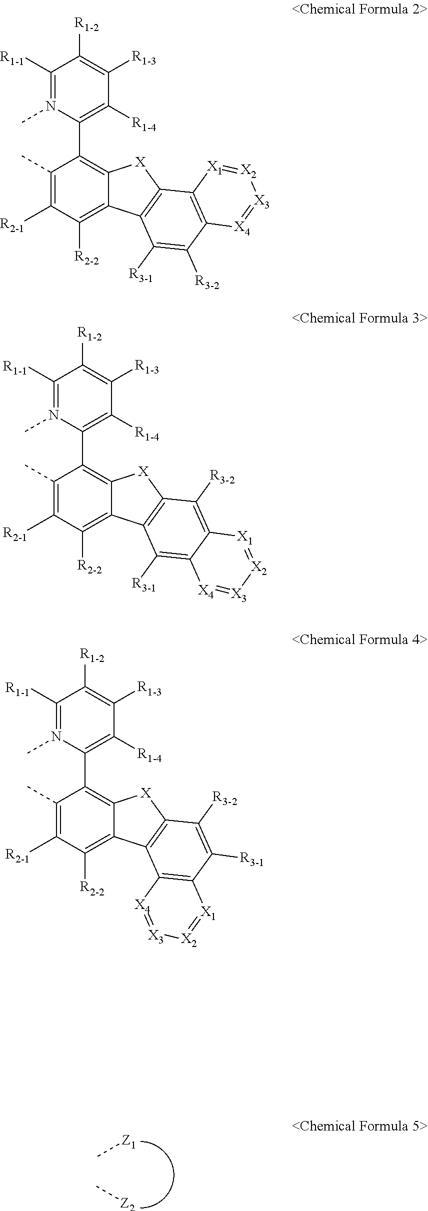

in Chemical Formula 2 to Chemical Formula 4,
X is one selected from C(Rx)₂, NRx, oxygen (O), sulfur (S), and selenium (Se),
X₁, X₂, X₃, and X₄ each independently represents one selected from C(Rx) and N; at least one of X₁, X₂, X₃, and X₄ is N; each Rx independently represents one selected from hydrogen, C1 to C20 linear alkyl, and C3 to C20 branched alkyl; and optionally, C1 to C20 linear alkyl, and C3 to C20 branched alkyl is each independently substituted with at least one substituent selected from deuterium and halogen,
R₁₋₁, R₁₋₂, R₁₋₃, R₁₋₄, R₂₋₁, R₂₋₂, R₃₋₁, and R₃₋₂ each independently represents one selected from the group consisting of hydrogen, deuterium, halogen, C1 to C20 linear alkyl, C3 to C20 branched alkyl, C3 to C20 cycloalkyl, C3 to C20 heteroalkyl, C7 to C30 arylalkyl, C1 to C10 alkoxy, C6 to C20 aryloxy, amino, silyl, C2 to C20 alkenyl, C3 to C20 cycloalkenyl, C2 to C20 heteroalkenyl, C2 to C20 alkynyl, C6 to C30 aryl, C2 to C30 heteroaryl, and acyl, and optionally, C1 to C20 linear alkyl, C3 to C20 branched alkyl, C3 to C20 cycloalkyl, C3 to C20 heteroalkyl, C7 to C30 arylalkyl, C1 to C10 alkoxy, C6 to C20 aryloxy, amino, silyl, C2 to C20 alkenyl, C3 to C20 cycloalkenyl, C2 to C20 heteroalkenyl, C2 to C20 alkynyl, C6 to C30 aryl, C2 to C30 heteroaryl, and acyl are each independently substituted with at least one substituent selected from deuterium and halogen, and
optionally, two adjacent groups among R₁₋₁, R₁₋₂, R₁₋₃, and R₁₋₄ bind to each other to form a ring structure; optionally, R₂₋₁ and R₂₋₂ bind to each other to form a ring structure; and optionally, R₃₋₁ and R₃₋₂ bind to each other to form a ring structure; and

Chemical Formula 5 represents a bidentate ligand.

In some example embodiments of the present application, R₁₋₁, R₁₋₂, R₁₋₃, and R₁₋₄ each independently represents one selected from the group consisting of hydrogen, C1 to C5 linear alkyl, C3 to C10 branched alkyl, C6 to C30 aryl, and C2 to C30 heteroaryl, and optionally, C1 to C5 linear alkyl, C3 to C10 branched alkyl, C6 to C30 aryl, and C2 to C30 heteroaryl are each independently substituted with deuterium.

In some example embodiments of the present application, R₂₋₁ and R₂₋₂ each represents hydrogen.

In some example embodiments of the present application, R₃₋₁ and R₃₋₂ each represents hydrogen.

In some example embodiments of the present application, L_{B} includes a compound represented by one selected from the group consisting of Chemical Formula 6 and Chemical Formula 7. In Chemical Formula 6 and Chemical Formula 7, R₅₋₁, R₅₋₂, R₅₋₃, R₅₋₄, R₆₋₁, R₆₋₂, R₆₋₃, and R₆₄ each independently represents one selected from the group consisting of hydrogen, deuterium, C1 to C5 linear alkyl, C3 to C5 branched alkyl, C6 to C10 aryl, and C7 to C30 arylalkyl, and optionally, C1 to C5 linear alkyl, C3 to C5 branched alkyl, and C7 to C30 arylalkyl is each independently substituted with at least one substituent selected from deuterium and halogen, and optionally, two adjacent groups among R₅₋₁, R₅₋₂, R₅₋₃, and R₅₋₄ bind to each other to form a ring structure; and optionally, two adjacent groups among R₆₋₁, R₆₋₂, R₆₋₃, and R₆₋₄ bind to each other to form a ring structure; and R₇, R₈, and R₉ each independently represents one selected from the group consisting of hydrogen, deuterium, C1 to C5 linear alkyl, and C3 to C5 branched alkyl, and optionally, C1 to C5 linear alkyl, or C3 to C5 branched alkyl as at least one selected from R₇, R₈, and R₉ is each independently substituted with at least one substituent selected from deuterium and halogen, and optionally, two adjacent groups among R₇, R₈, and R₉ bind to each other to form a ring structure.

In some example embodiments of the present application, m is 1 and n is 2.

In some example embodiments of the present application, m is 2 and n is 1.

In some example embodiments of the present application, m is 3 and n is 0.

In some example embodiments of the present application, the organometallic compound represented by Chemical Formula 1 includes one selected from the group consisting of following compounds 1 to 549.

In some example embodiments of the present application, the organometallic compound represented by Chemical Formula 1 may be a green phosphorescent material.

According to another aspect of the present disclosure, an organic light-emitting diode may include: a first electrode; a second electrode facing the first electrode; and an organic layer disposed between the first electrode and the second electrode, the organic layer including a light-emitting layer that includes a dopant material including the organometallic compound according to an aspect of the present disclosure.

In some example embodiments of the present disclosure, the light-emitting layer may be a green phosphorescent light-emitting layer.

In some example embodiments of the present disclosure, the organic layer may further include at least one selected from the group consisting of a hole injection layer, a hole transport layer, an electron transport layer, and an electron injection layer.

According to another aspect of the present disclosure, an organic light-emitting diode may include: a first electrode; a second electrode facing the first electrode; a first light-emitting stack; and a second light-emitting stack, wherein the first light-emitting stack and the second light-emitting stack may be positioned between the first electrode and the second electrode, wherein each of the first light-emitting stack and the second light-emitting stack may include at least one light-emitting layer, and wherein at least one of the light-emitting layers may include a green phosphorescent light-emitting layer that includes a dopant material including the organometallic compound according to an aspect of the present disclosure.

According to another aspect of the present disclosure, an organic light-emitting diode may include: a first electrode; a second electrode facing the first electrode; and a first light-emitting stack; a second light-emitting stack; and a third light-emitting stack, wherein the first light-emitting stack, the second light-emitting stack, and the third light-emitting stack may be positioned between the first electrode and the second electrode, wherein each of the first light-emitting stack, the second light-emitting stack, and the third light-emitting stack may include at least one light-emitting layer, and wherein at least one of the light-emitting layers may include a green phosphorescent light-emitting layer that includes a dopant material including the organometallic compound according to an aspect of the present disclosure.

According to another aspect of the present disclosure, an organic light-emitting display device may include: a substrate; a driving element positioned on the substrate; and an organic light-emitting element disposed on the substrate and connected to the driving element, the organic light-emitting element including the organic light-emitting diode according to an aspect of the present disclosure.

According to another aspect of the present disclosure, An organometallic compound represented by Chemical Formula 1:

Ir(L_{A})ₘ(L_{B})ₙ Chemical Formula 1
in Chemical Formula 1,
Ir represents iridium,
m is an integer from 1 to 3, n is an integer from 0 to 2, and a sum of m and n is 3,
L_{A} is represented by Chemical Formula, and L_{B} is represented by Chemical Formula 5:

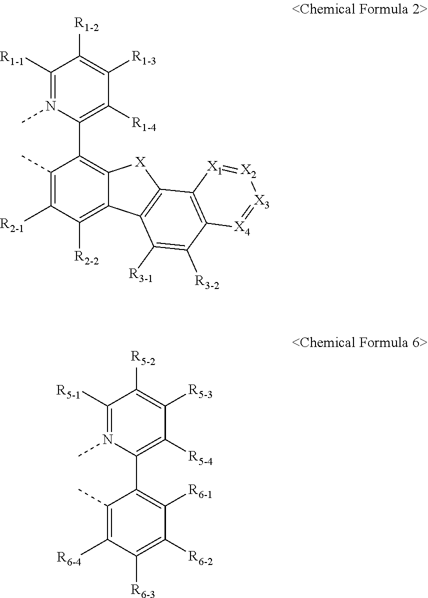

in Chemical Formula 2,
X is one selected from C(Rx)₂, NRx, oxygen (O), sulfur (S), and selenium (Se),
X₁, X₂, X₃, and X₄ each independently represents one selected from C(Rx) and N; at least one of X₁, X₂, X₃, and X₄ is N; each Rx independently represents one selected from hydrogen, C1 to C20 linear alkyl, and C3 to C20 branched alkyl; and optionally, C1 to C20 linear alkyl, and C3 to C20 branched alkyl is each independently substituted with at least one substituent selected from deuterium and halogen,
R₁₋₁, R₁₋₂, R₁₋₃, R₁₋₄, R₂₋₁, R₂₋₂, R₃₋₁, and R₃₋₂ each independently represents one selected from the group consisting of hydrogen, deuterium, halogen, C1 to C20 linear alkyl, C3 to C20 branched alkyl, C3 to C20 cycloalkyl, C3 to C20 heteroalkyl, C7 to C30 arylalkyl, C1 to C10 alkoxy, C6 to C20 aryloxy, amino, silyl, C2 to C20 alkenyl, C3 to C20 cycloalkenyl, C2 to C20 heteroalkenyl, C2 to C20 alkynyl, C6 to C30 aryl, C2 to C30 heteroaryl, and acyl, and optionally, C1 to C20 linear alkyl, C3 to C20 branched alkyl, C3 to C20 cycloalkyl, C3 to C20 heteroalkyl, C7 to C30 arylalkyl, C1 to C10 alkoxy, C6 to C20 aryloxy, amino, silyl, C2 to C20 alkenyl, C3 to C20 cycloalkenyl, C2 to C20 heteroalkenyl, C2 to C20 alkynyl, C6 to C30 aryl, C2 to C30 heteroaryl, and acyl are each independently substituted with at least one substituent selected from deuterium and halogen, and
optionally, two adjacent groups among R₁₋₁, R₁₋₂, R₁₋₃, and R₁₋₄ bind to each other to form a ring structure; optionally, R₂₋₁ and R₂₋₂ bind to each other to form a ring structure; and optionally, R₃₋₁ and R₃₋₂ bind to each other to form a ring structure; and
in Chemical Formula 6,
R₅₋₁, R₅₋₂, R₅₋₃, R₅₋₄, R₆₋₁, R₆₋₂, R₆₋₃, and R₆₋₄ each independently represents one selected from the group consisting of hydrogen, deuterium, C1 to C5 linear alkyl, C3 to C5 branched alkyl, C6 to C10 aryl, and C7 to C30 arylalkyl, and optionally, C1 to C5 linear alkyl, C3 to C5 branched alkyl, and C7 to C30 arylalkyl is each independently substituted with at least one substituent selected from deuterium and halogen, and
optionally, two adjacent groups among R₅₋₁, R₅₋₂, R₅₋₃, and R₅₋₄ bind to each other to form a ring structure; and optionally, two adjacent groups among R₆₋₁, R₆₋₂, R₆₋₃, and R₆₋₄ bind to each other to form a ring structure.

In some example embodiments of the present application, R₅₋₂, R₅₋₃, and R₆₋₃ in Chemical Formula 6 are each independently an unsubstituted or deuterium-substituted methyl group.

In some example embodiments of the present application, X is O.

In some example embodiments of the present application, the organometallic compound represented by Chemical Formula 1 includes one selected from compounds 97, 101, 109, 121, 145, 157, 169, 137, 185, and 329.

The organometallic compound according to example embodiments of the present disclosure may be used as the dopant of the phosphorescent light-emitting layer of the organic light-emitting diode. The operation voltage of the organic light-emitting diode may be lowered, and the efficiency and lifespan characteristics of the organic light-emitting diode may be improved.

Effects of the present disclosure are not limited to the above-mentioned effects, and other effects not mentioned may be clearly understood by those skilled in the art from following description.

It is to be understood that both the foregoing general description and the following detailed description of the present disclosure are merely by way of example and are intended to provide further explanation of the inventive concepts as claimed.

### BRIEF DESCRIPTION OF DRAWINGS

The accompanying drawings, which are included to provide a further understanding of the disclosure and are incorporated in and constitute a part of this application, illustrate embodiments of the disclosure and together with the description serve to explain principles of the disclosure.

FIG. 1 is a cross-sectional view schematically illustrating an organic light-emitting diode in which a light-emitting layer contains an organometallic compound according to an example embodiment of the present disclosure.

FIG. 2 is a cross-sectional view schematically illustrating an organic light-emitting diode having a tandem structure having two light-emitting stacks and containing an organometallic compound represented by Chemical Formula 1 according to an example embodiment of the present disclosure.

FIG. 3 is a cross-sectional view schematically illustrating an organic light-emitting diode having a tandem structure having three light-emitting stacks and containing an organometallic compound represented by Chemical Formula 1 according to an example embodiment of the present disclosure.

FIG. 4 is a cross-sectional view schematically illustrating an organic light-emitting display device including an organic light-emitting diode according to an example embodiment of the present disclosure.

### DETAILED DESCRIPTION

Reference will now be made in detail to some of the examples and embodiments of the disclosure illustrated in the accompanying drawings. Wherever possible, the same reference numbers will be used throughout the drawings to refer to the same or like parts.

Advantages and features of the present disclosure, and a method of achieving the advantages and features will become apparent with reference to the example embodiments described herein in detail together with the accompanying drawings. The present disclosure should not be construed as limited to the example embodiments as disclosed below, and may be embodied in various different forms. Thus, these example embodiments are set forth to make the present disclosure sufficiently complete, and to assist those skilled in the art to fully understand the scope of the present disclosure. The protected scope of the present disclosure is defined by claims and their equivalents.

For convenience of description, a scale in which each of elements is illustrated in the accompanying drawings may differ from an actual scale. Thus, the illustrated elements are not limited to the specific scale in which they are illustrated in the drawings. The same reference numbers in different drawings represent the same or similar elements, which may perform similar functionality.

The shapes, sizes, ratios, angles, numbers, and the like, which are illustrated in the drawings to describe various example embodiments of the present disclosure, are merely given by way of example. Therefore, the present disclosure is not limited to the illustrations in the drawings. The same or similar elements are designated by the same reference numerals throughout the specification unless otherwise specified. Further, where the detailed description of the relevant known steps and elements may obscure an important point of the present disclosure, a detailed description of such known steps and elements may be omitted. Furthermore, in the following detailed description of the present disclosure, numerous specific details are set forth to provide a sufficiently thorough understanding of the present disclosure. However, it will be understood that the present disclosure may be practiced without these specific details. In other instances, known methods, procedures, components, and circuits have not been described in detail so as not to unnecessarily obscure aspects of the present disclosure.

Although example embodiments of the present disclosure are described in detail with reference to the accompanying drawings, the present disclosure is not limited thereto.

Therefore, example embodiments of the present disclosure are provided for illustrative purposes only and are not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In the present specification, where the terms “comprise”, “have”, “include”, and the like are used, one or more other elements may be added unless the term, such as “only” is used. As used herein, the term “and/or” includes a single associated listed item and any and all of the combinations of two or more of the associated listed items. An expression such as “at least one of” when preceding a list of elements may modify the entire list of elements and may not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

In construing an element or numerical value, the element or the numerical value is to be construed as including an error or tolerance range even where no explicit description of such an error or tolerance range is provided.

It will be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “coupled to” another element or layer, it may be directly connected to or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present. In the description of the various embodiments of the present disclosure, where positional relationships are described, for example, where the positional relationship between two parts is described using “on”, “over”, “under”, “above”, “below”, “beside”, “next”, or the like, one or more other parts may be located between the two parts unless a more limiting term, such as “immediate(ly)”, “direct(ly)”, or “close(ly)” is used.

Further, as used herein, when a layer, film, region, plate, or the like may be disposed “on” or “on a top” of another layer, film, region, plate, or the like, the former may directly contact the latter or another layer, film, region, plate, or the like may be disposed between the former and the latter. As used herein, when a layer, film, region, plate, or the like is directly disposed “on” or “on a top” of another layer, film, region, plate, or the like, the former directly contacts the latter and another layer, film, region, plate, or the like is not disposed between the former and the latter. Further, as used herein, when a layer, film, region, plate, or the like may be disposed “below” or “under” another layer, film, region, plate, or the like, the former may directly contact the latter or another layer, film, region, plate, or the like may be disposed between the former and the latter. As used herein, when a layer, film, region, plate, or the like is directly disposed “below” or “under” another layer, film, region, plate, or the like, the former directly contacts the latter and another layer, film, region, plate, or the like is not disposed between the former and the latter.

In descriptions of temporal relationships, for example, temporal precedent relationships between two events such as “after”, “subsequent to”, “before”, “next”, etc., another event may occur therebetween unless a more limiting term, “just”, “immediate(ly)”, or “direct(ly)” (“directly after”, “directly subsequent”, “directly before”) is indicated.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

The features of the various embodiments of the present disclosure may be partially or overall combined with each other, and may be variously inter-operated with each other and driven technically as those skilled in the art can sufficiently understand. The embodiments may be implemented independently of each other and may be implemented together in a co-dependent relationship.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects,” and the like should not be construed such that any aspect or design as described is superior to or advantageous over other aspects or designs.

Further, the term “or” means “inclusive or” rather than “exclusive or”. That is, unless otherwise stated or clear from the context, the expression that “x uses a or b” means any one of natural inclusive permutations.

The terms used in the description below may be general and universal in the relevant art. However, there may be other terms depending on the development and/or change of technology, convention, preference of technicians, etc. Therefore, the terms used in the description below should not be understood as limiting the disclosure, and should be understood as examples of the terms for describing embodiments.

Further, in some example embodiments, a term may be arbitrarily selected by the applicant, and in this case, the detailed meaning thereof will be described in a corresponding description section. Therefore, such terms used in the description below may be understood based on the name of the terms, and the meaning of the terms and the contents throughout the Detailed Description.

As used herein, the term “halo” or “halogen” includes fluorine, chlorine, bromine and iodine.

As used herein, the term “alkyl group” refers to both linear alkyl radicals and branched alkyl radicals. Unless otherwise specified, the alkyl group contains 1 to 20 carbon atoms, and includes methyl, ethyl, propyl, isopropyl, butyl, isobutyl, tert-butyl, etc. Further, the alkyl group may be optionally substituted.

As used herein, the term “cycloalkyl group” refers to a cyclic alkyl radical. Unless otherwise specified, the cycloalkyl group contains 3 to 20 carbon atoms, and includes cyclopropyl, cyclopentyl, cyclohexyl, and the like. Further, the cycloalkyl group may be optionally substituted.

As used herein, the term “alkenyl group” refers to both linear alkenyl radicals and branched alkenyl radicals. Unless otherwise specified, the alkenyl group contains 2 to 20 carbon atoms. Additionally, the alkenyl group may be optionally substituted.

As used herein, the term “cycloalkenyl group” refers to a cyclic alkenyl radical. Unless otherwise specified, the cycloalkenyl group contains 3 to 20 carbon atoms. Further, the cycloalkenyl group may be optionally substituted.

As used herein, the term “alkynyl group” refers to both linear alkynyl radicals and branched alkynyl radicals. Unless otherwise specified, the alkynyl group contains 2 to 20 carbon atoms. Additionally, the alkynyl group may be optionally substituted.

As used herein, the term “cycloalkynyl group” refers to a cyclic alkynyl radical. Unless otherwise specified, the cycloalkynyl group contains 3 to 20 carbon atoms or 8 to 20 carbons. Further, the cycloalkynyl group may be optionally substituted.

The terms “aralkyl group” and “arylalkyl group” as used herein are used interchangeably with each other and refer to an alkyl group having an aromatic group as a substituent. Unless otherwise specified, the aralkyl group (arylalkyl group) contains 2 to 60 or 7 to 60 carbon atoms. Further, the aralkyl group (arylalkyl group) may be optionally substituted.

The terms “aryl group” and “aromatic group” as used herein are used in the same meaning. The aryl group includes both a monocyclic group and a polycyclic group. The polycyclic group may include a “fused ring” in which two or more rings are fused with each other such that two carbons are common to two adjacent rings. Unless otherwise specified, the aryl group contains 5 to 60 or 6 to 60 carbon atoms. Further, the aryl group may be optionally substituted.

The term “heterocyclic group” as used herein means that at least one of carbon atoms constituting an aryl group, a cycloalkyl group, a cycloalkenyl group, a cycloalkynyl group, an aralkyl group (arylalkyl group), or an arylamino group is substituted with a heteroatom such as oxygen (O), nitrogen (N), sulfur (S), etc. Based on this definition, the heterocyclic group includes a heteroaryl group, a heterocycloalkyl group, a heterocycloalkenyl group, a heterocycloalkynyl group, a heteroaralkyl group (heteroarylalkyl group), a heteroarylamino group, etc. The heterocyclic group contains 2 to 60 carbon atoms or 3 to 60 carbons. Further, the heterocyclic group may be optionally substituted.

The term “carbocyclic ring” as used herein may be used as a term including both (i) “cycloalkyl group”, “cycloalkenyl group” and “cycloalkynyl group” as an alicyclic group and (ii) “aryl group” as an aromatic group, unless otherwise specified. Further, the carbocyclic ring may be optionally substituted.

The term“heteroalkyl group”, “heteroalkenyl group”, “heteroalkynyl group”, or “heteroaralkyl group (heteroarylalkyl group)” as used herein means that at least one of carbon atoms constituting the alkyl group, the alkenyl group, the alkynyl group, or the aralkyl is substituted with a heteroatom such as oxygen (O), nitrogen (N), or sulfur (S). In addition, the heteroalkyl group, the heteroalkenyl group, the heteroalkynyl group, or the heteroaralkyl group (heteroarylalkyl group) may be optionally substituted.

As used herein, the term “alkylamino group”, “aralkylamino group”, “arylamino group”, or “heteroarylamino group” refers to an alkyl group, an aralkyl group, an aryl group, or a heteroaryl group as a heterocyclic group in which an amine group is attached. In this regard, the amine group may include all of primary, secondary, and tertiary amines. Further, the alkylamino group, the aralkylamino group, the arylamino group, and the heteroarylamino group may be optionally substituted.

As used herein, the term “alkylsilyl group”, “alkoxy group”, or “alkylthio group” refers to an alkyl group in which a silyl group (e.g., —SiR₃, where R may be a substituted or unsubstituted C1 to C20 alkyl group), an oxy group, or a thio group, respectively, is attached. As used herein, the term “arylsilyl group”, “aryloxy group”, or “arylthio group” refers to an aryl group in which a silyl group, an oxy group, or a thio group, respectively, is attached. Additionally, the alkylsilyl group, the arylsilyl group, the alkoxy group, the aryloxy group, the alkylthio group, and the arylthio group may be optionally substituted.

As used herein, the term “amino” refers to a functional group represented by —NR₂, where each R is independently hydrogen, deuterium, an alkyl group, or an aryl group.

As used herein, the term “acyl” refers to a functional group represented by RC(═O)—, where each R is independently hydrogen, deuterium, an alkyl group, or an aryl group.

As used herein, the term “substituted” means that a substituent other than hydrogen (H) binds to corresponding carbon. When there are a plurality of substituents, the substituents may be the same as or different from each other.

As used herein, unless otherwise specified, a substituent may be selected from the group consisting of deuterium, halide, alkyl, cycloalkyl, heteroalkyl, arylalkyl, alkoxy, aryloxy, amino, silyl, alkenyl, cycloalkenyl, heteroalkenyl, alkynyl, aryl, heteroaryl, acyl, carbonyl, carboxylic acid, ester, nitrile, isonitrile, sulfanyl, sulfinyl, sulfonyl, phosphino, and combinations thereof.

Unless otherwise specified, a position at which the substitution occurs is not particularly limited as long as a hydrogen atom can be substituted with a substituent at the position. When two or more substituents, that is, the plurality of substituents are present, the substituents may be identical to or different from each other.

Subjects and substituents as defined in the present disclosure may be the same as or different from each other unless otherwise specified.

Hereinafter, example embodiments of an organometallic compound according to the present disclosure and of an organic light-emitting diode including the same will be described.

An organometallic compound may be used as a dopant in the phosphorescent light-emitting layer. For example, 2-phenylpyridine, 2-phenylquinoline, etc. may be the main ligand structure of the organometallic compound. However, the light-emitting dopant may have limitations in improving the efficiency and lifespan of the organic light-emitting diode. Thus, it may be beneficial to develop new light-emitting dopant materials. Accordingly, the inventors of the present disclosure have derived a light-emitting dopant material that may further improve the efficiency and lifespan of the organic light-emitting diode. Thus, the present disclosure has been completed.

An organometallic compound according to example embodiments of the present disclosure may be represented by Chemical Formula 1. Chemical Formula 2 as a main ligand of Chemical Formula 1 is characterized by having a structure in which 2-phenylpyridine binds to iridium (Ir) as a central coordination metal, and a 6-membered-5-membered-6-membered-6 membered fused aromatic polycyclic structure containing X binds to phenyl moiety containing carbon (C) in the 2-phenylpyridine.

The inventors of the present disclosure have experimentally identified that when a dopant material of a phosphorescent light-emitting layer of the organic light emitting diode includes the organometallic compound represented by Chemical Formula 1, effects of increasing the luminous efficiency and the lifespan of the organic light emitting diode and lowering the operation voltage thereof may be achieved. Thus, the present disclosure has been completed.

The organometallic compound according to the present disclosure having the above characteristics may be represented by Chemical Formula 1:

Ir(L_{A})ₘ(L_{B})ₙ Chemical Formula 1
in Chemical Formula 1,
Ir represents iridium,
L_{A} is represented by one selected from Chemical Formula 2 to Chemical Formula 4, and L_{B} is represented by Chemical Formula 5:

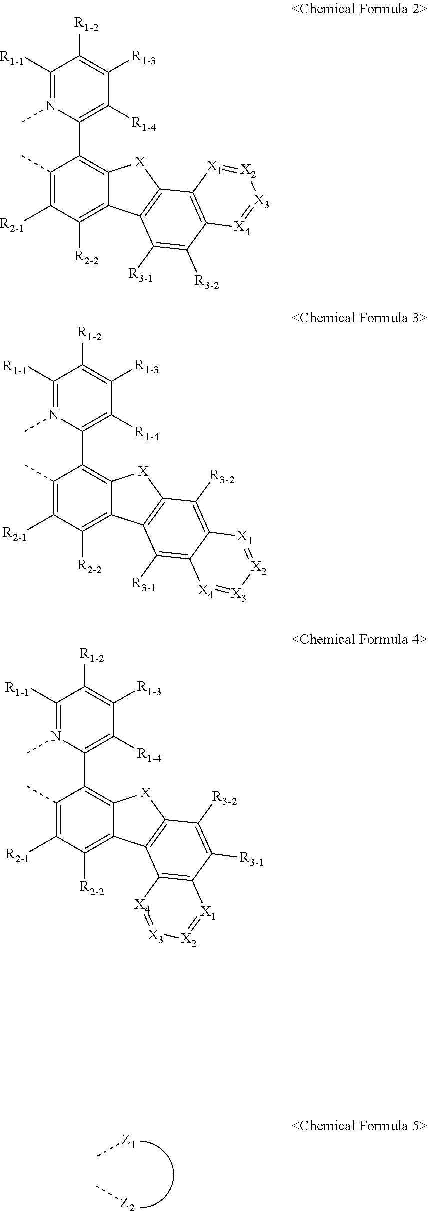

in Chemical Formula 2 to Chemical Formula 4,
   X is one selected from C(Rx)₂, NRx, oxygen (O), sulfur (S), and selenium (Se),
   X₁, X₂, X₃, and X₄ each independently represents one selected from C(Rx) and N; at least one of X₁, X₂, X₃, and X₄ is N; each Rx independently represents one selected from hydrogen, C1 to C20 linear alkyl, and C3 to C20 branched alkyl; and optionally, C1 to C20 linear alkyl, and C3 to C20 branched alkyl may each be independently substituted with at least one substituent selected from deuterium and halogen,
   R₁₋₁, R₁₋₂, R₁₋₃, R₁₋₄, R₂₋₁, R₂₋₂, R₃₋₁, and R₃₋₂ each independently represents one selected from the group consisting of hydrogen, deuterium, halogen, C1 to C20 linear alkyl, C3 to C20 branched alkyl, C3 to C20 cycloalkyl, C3 to C20 heteroalkyl, C7 to C30 arylalkyl, C1 to C10 alkoxy, C6 to C20 aryloxy, amino, silyl, C2 to C20 alkenyl, C3 to C20 cycloalkenyl, C2 to C20 heteroalkenyl, C2 to C20 alkynyl, C6 to C30 aryl, C2 to C30 heteroaryl, and acyl, and optionally, R₁₋₁, R₁₋₂, R₁₋₃, R₁₋₄, R₂₋₁, R₂₋₂, R₃₋₁ and R₃₋₂ may each be independently substituted with at least one substituent selected from deuterium and halogen, or optionally, C1 to C20 linear alkyl, C3 to C20 branched alkyl, C3 to C20 cycloalkyl, C3 to C20 heteroalkyl, C7 to C30 arylalkyl, C1 to C10 alkoxy, C6 to C20 aryloxy, amino, silyl, C2 to C20 alkenyl, C3 to C20 cycloalkenyl, C2 to C20 heteroalkenyl, C2 to C20 alkynyl, C6 to C30 aryl, C2 to C30 heteroaryl, and acyl may each be independently substituted with at least one substituent selected from deuterium and halogen, and
optionally, two adjacent groups among R₁₋₁, R₁₋₂, R₁₋₃, and R₁₋₄ may bind to each other to form a ring structure; optionally, R₂₋₁ and R₂₋₂ may bind to each other to form a ring structure; and optionally, R₃₋₁ and R₃₋₂ may bind to each other to form a ring structure;
Chemical Formula 5 represents a bidentate ligand, and
m is an integer from 1 to 3, n is an integer from 0 to 2, and a sum of m and n is 3.

According to some example embodiments of the present disclosure, R₁₋₁, R₁₋₂, R₁₋₃, and R₁₋₄ each independently represents one selected from the group consisting of hydrogen, C1 to C5 linear alkyl, C3 to C10 branched alkyl, C6 to C30 aryl, and C2 to C30 heteroaryl, and optionally, R₁₋₄, R₁₋₂, R₁₋₃, and R₁₋₄ may each be independently substituted with deuterium, or optionally, C1 to C5 linear alkyl, C3 to C10 branched alkyl, C6 to C30 aryl, and C2 to C30 heteroaryl may each be independently substituted with deuterium.

According to some example embodiments of the present disclosure, R₂₋₁ and R₂₋₂ each represent hydrogen.

According to some example embodiments of the present disclosure, R₃₋₁ and R₃₋₂ each represent hydrogen.

In the organometallic compound according to example embodiments of the present disclosure, an auxiliary ligand connected the central coordination metal may include L_{B}, which is the bidentate ligand

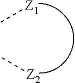

represented by Chemical Formula 5. The bidentate ligand represented by Chemical Formula 5 according to the present disclosure includes an electron donor. The electron donor auxiliary ligand acts to increase the electron density of the central coordination metal, thereby reducing the energy of MLCT (metal to ligand charge transfer) and increasing a contribution ratio of ³MLCT to the T₁ state. As a result, the organic light-emitting diode including the organic compound of the present disclosure may achieve improved light-emitting properties such as high luminous efficiency and high external quantum efficiency.

According to example embodiments of the present disclosure, L_{B} may include a compound represented by one selected from the group consisting of Chemical Formula 6 and Chemical Formula 7:

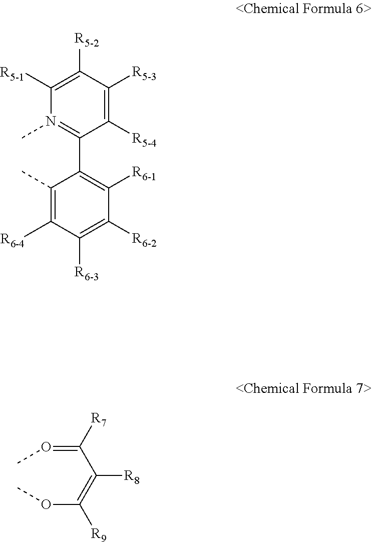

in Chemical Formula 6 and Chemical Formula 7,
   R₅₋₁, R₅₋₂, R₅₋₃, R₅₋₄, R₆₋₁, R₆₋₂, R₆₋₃, and R₆₋₄ each independently represents one selected from the group consisting of hydrogen, deuterium, C1 to C5 linear alkyl, C3 to C5 branched alkyl, C6 to C10 aryl, C7 to C30 alkylaryl, and C7 to C30 arylalkyl, and optionally, C1 to C5 linear alkyl or C3 to C5 branched alkyl as R₅₋₁, R₅₋₂, R₅₋₃, R₅₋₄, R₆₋₁, R₆₋₂, R₆₋₃, and R₆₋₄ may each independently be substituted with at least one substituent selected from deuterium and halogen, or C1 to C5 linear alkyl, C3 to C5 branched alkyl, and C7 to C30 arylalkyl may each be independently substituted with at least one substituent selected from deuterium and halogen, and
   optionally, two adjacent groups among R₅₋₁, R₅₋₂, R₅₋₃, and R₅₋₄ may bind to each other to form a ring structure; and optionally, two adjacent groups among R₆₋₁, R₆₋₂, R₆₋₃, and R₆₋₄ may bind to each other to form a ring structure; and
   R₇, R₈, and R₉ each independently represents one selected from the group consisting of hydrogen, deuterium, C1 to C5 linear alkyl, and C3 to C5 branched alkyl, and optionally, C1 to C5 linear alkyl, or C3 to C5 branched alkyl as R₇, R₈, and R₉ may each independently be substituted with at least one substituent selected from deuterium and halogen, and
optionally, two adjacent groups among R₇, R₈, and R₉ may bind to each other to form a ring structure.

The organometallic compound according to some example embodiments of the present disclosure may have a heteroleptic or homoleptic structure.

For example, the organometallic compound according to some example embodiments of the present disclosure may have a heteroleptic structure in which in Chemical Formula 1, m is 1 and n is 2; or a heteroleptic structure where m is 2 and n is 1; or a homoleptic structure where m is 3 and n is 0.

An example embodiment of the compound represented by Chemical Formula 1 of the present disclosure may include one selected from the group consisting of compounds 1 to 549. However, example embodiments of the compound represented by Chemical Formula 1 of the present disclosure is not limited thereto as long as it meets the above definition of Chemical Formula 1:

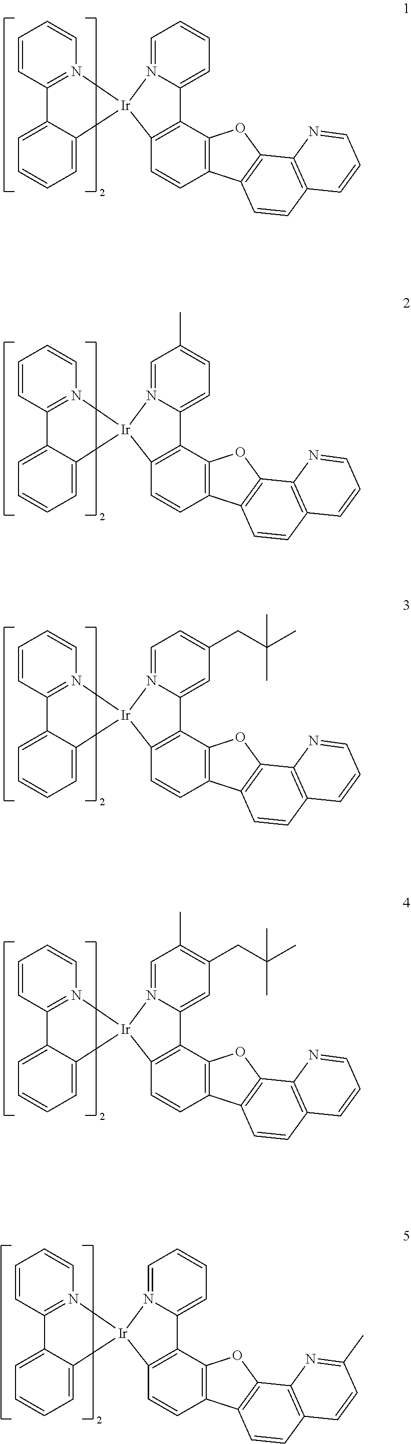

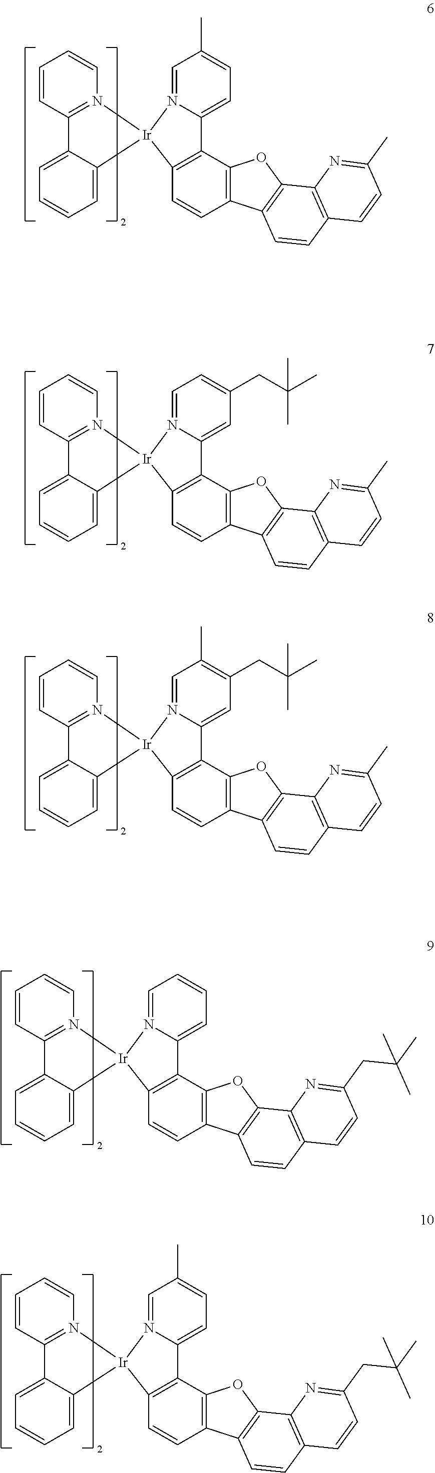

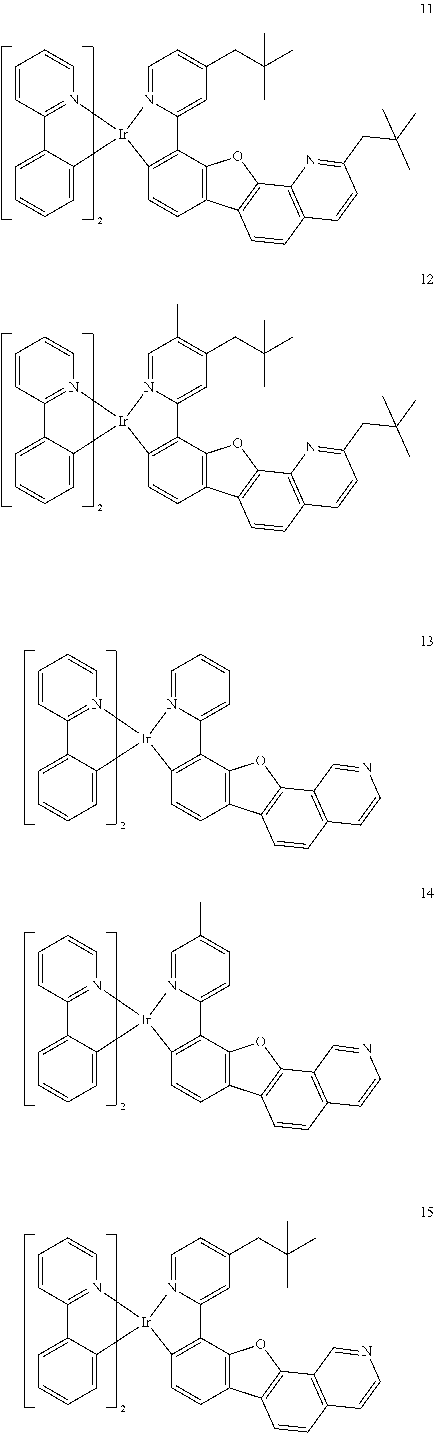

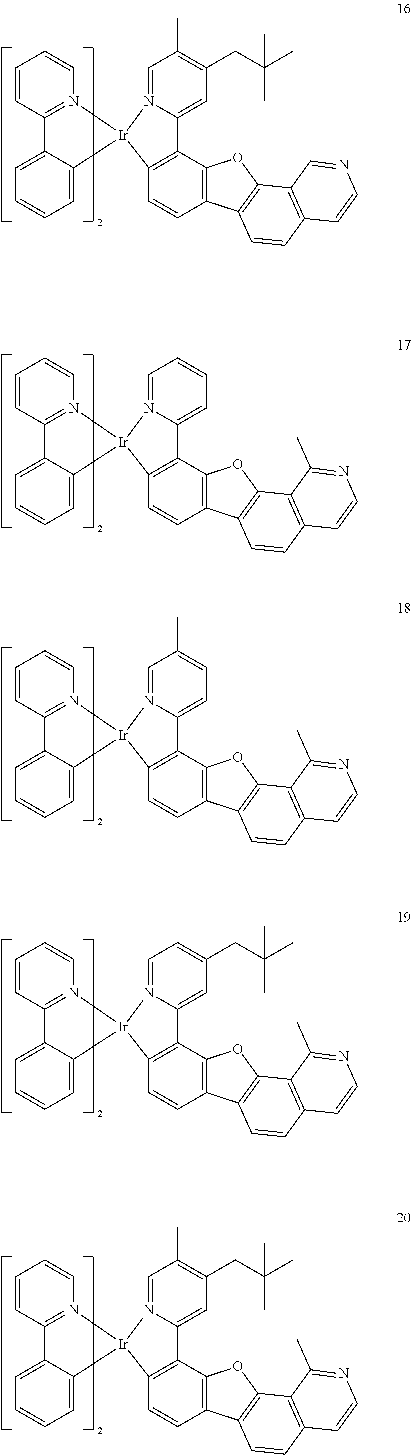

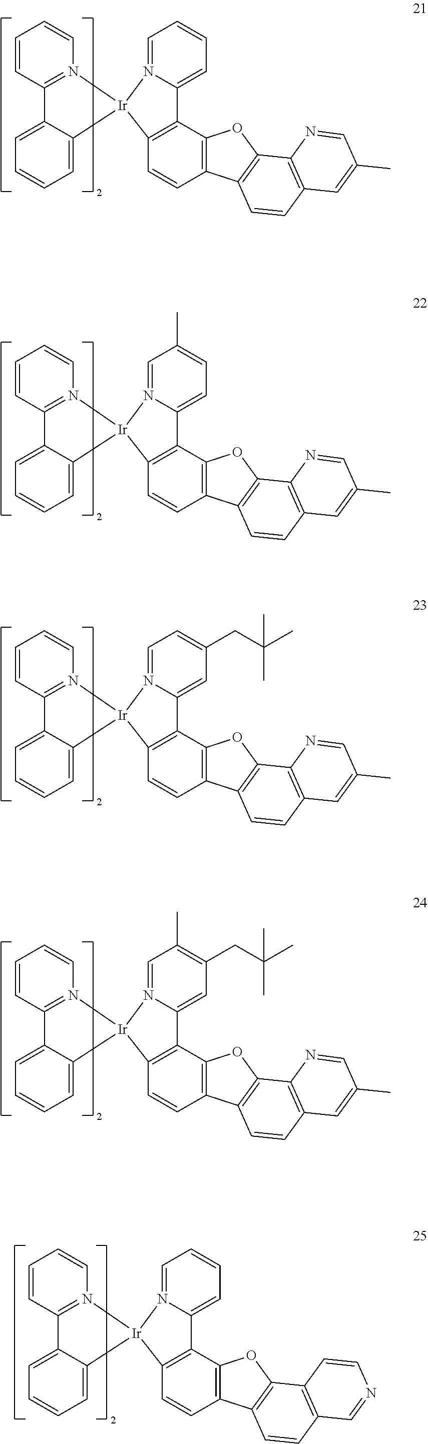

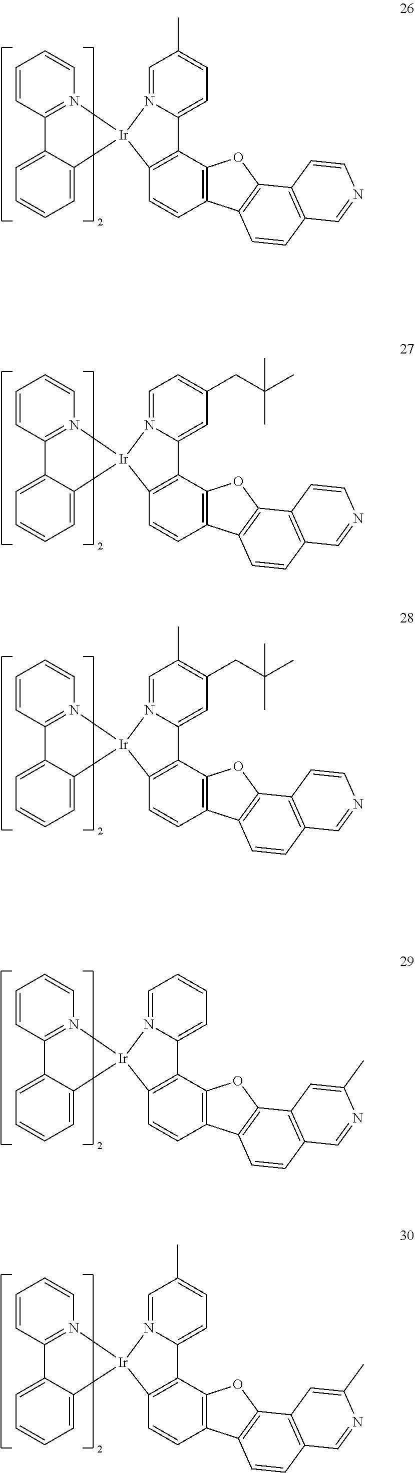

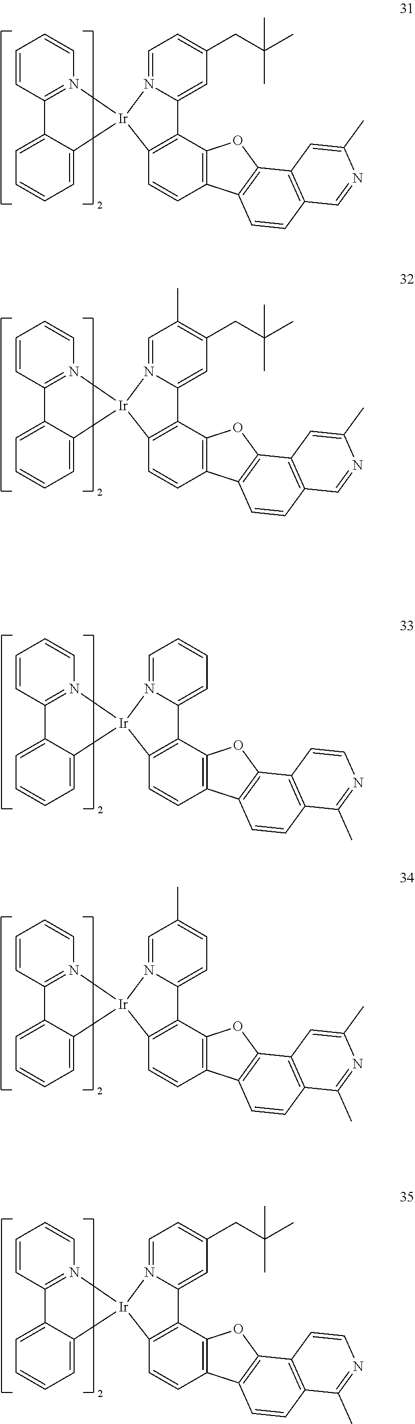

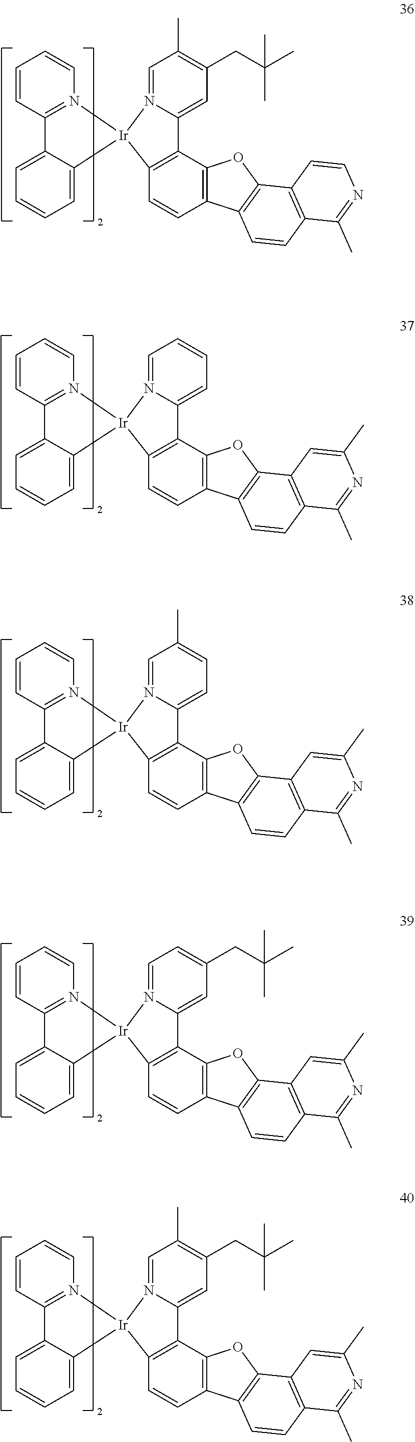

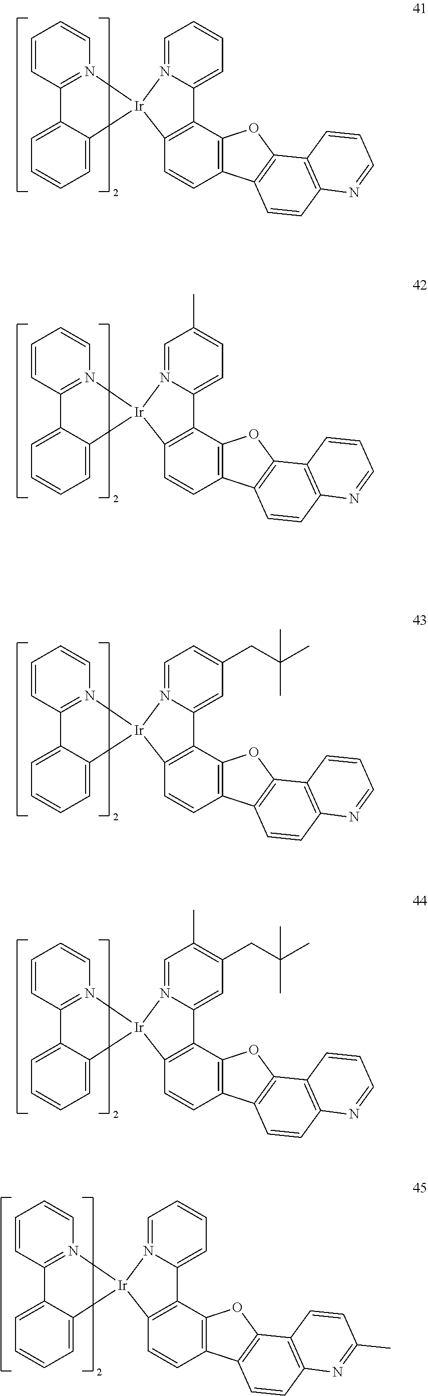

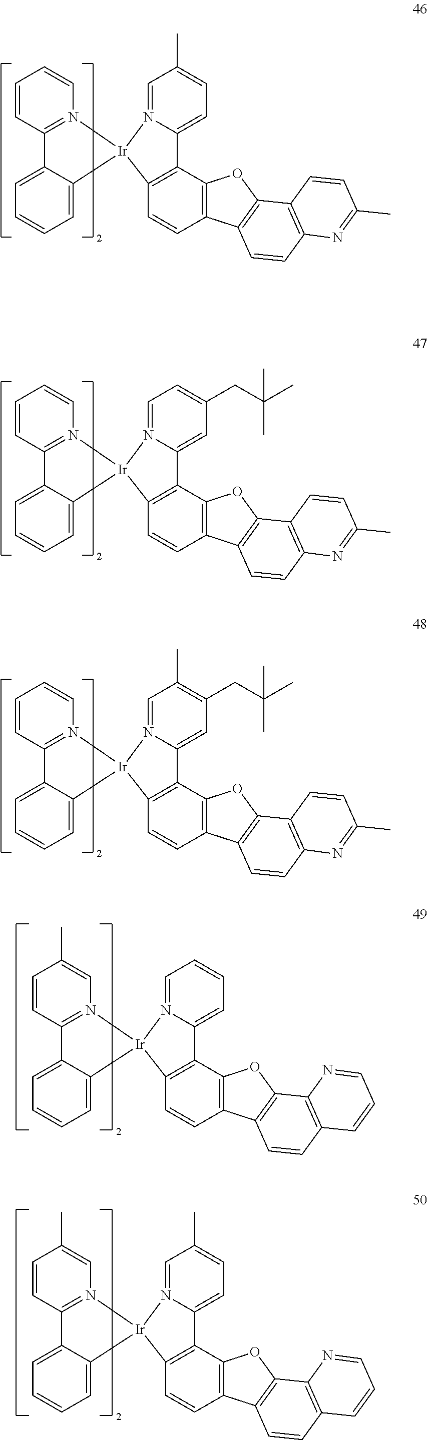

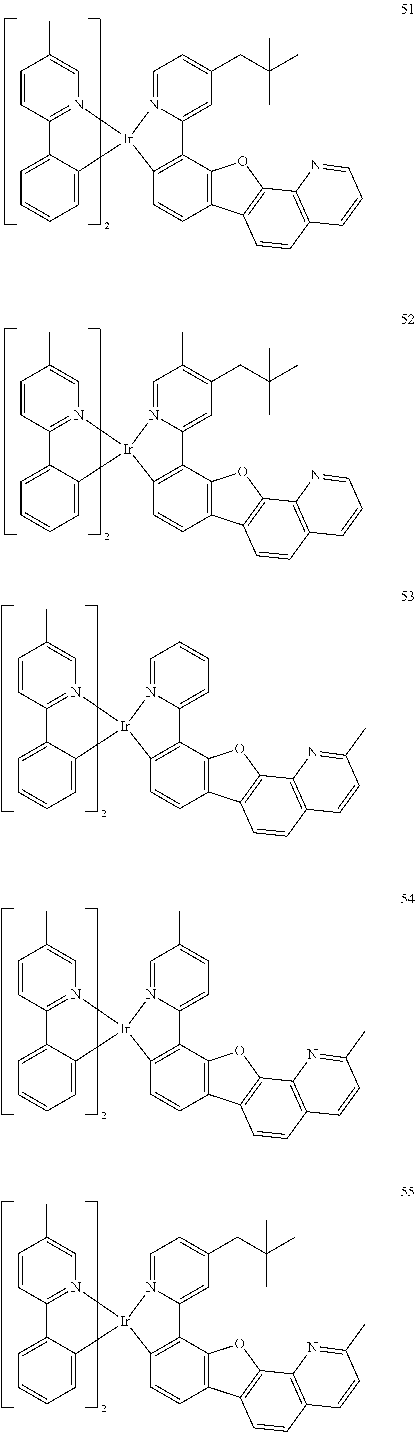

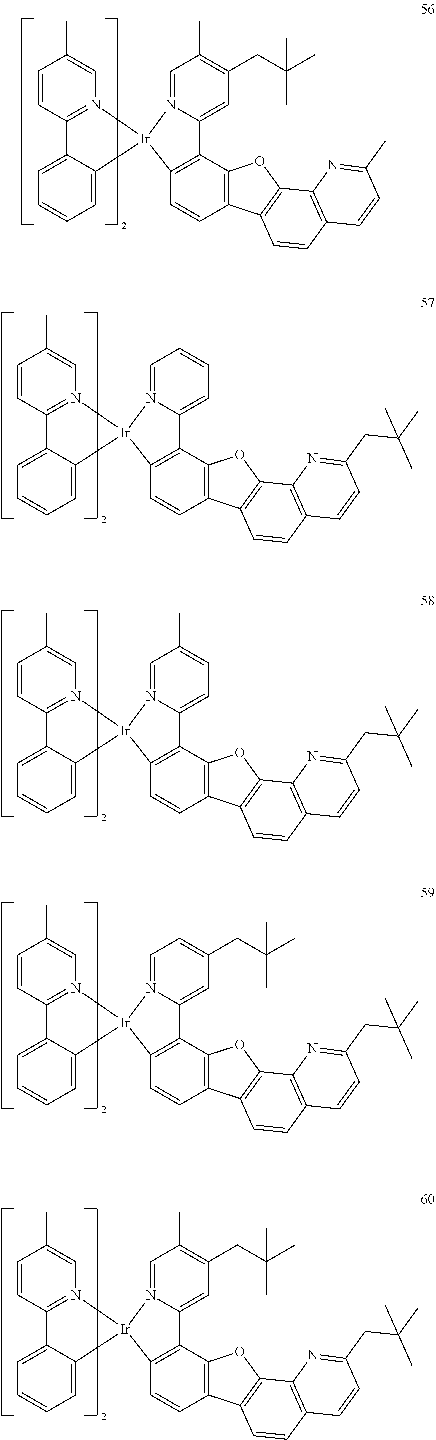

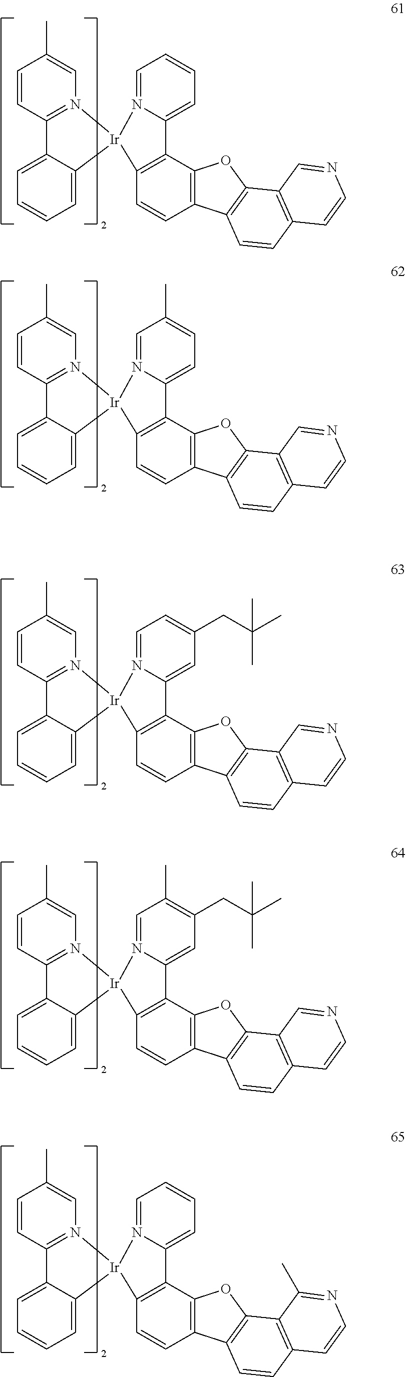

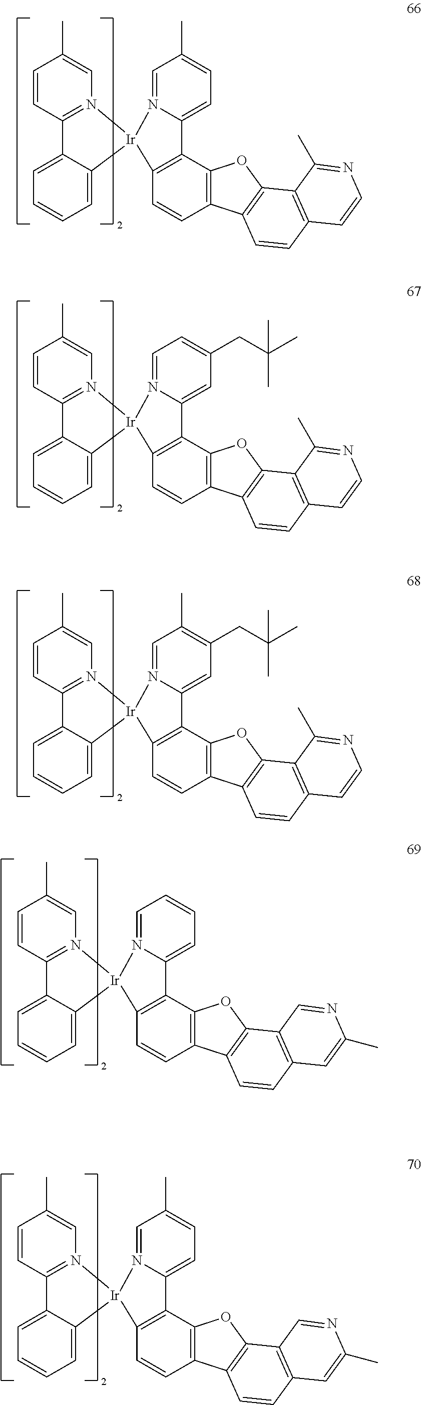

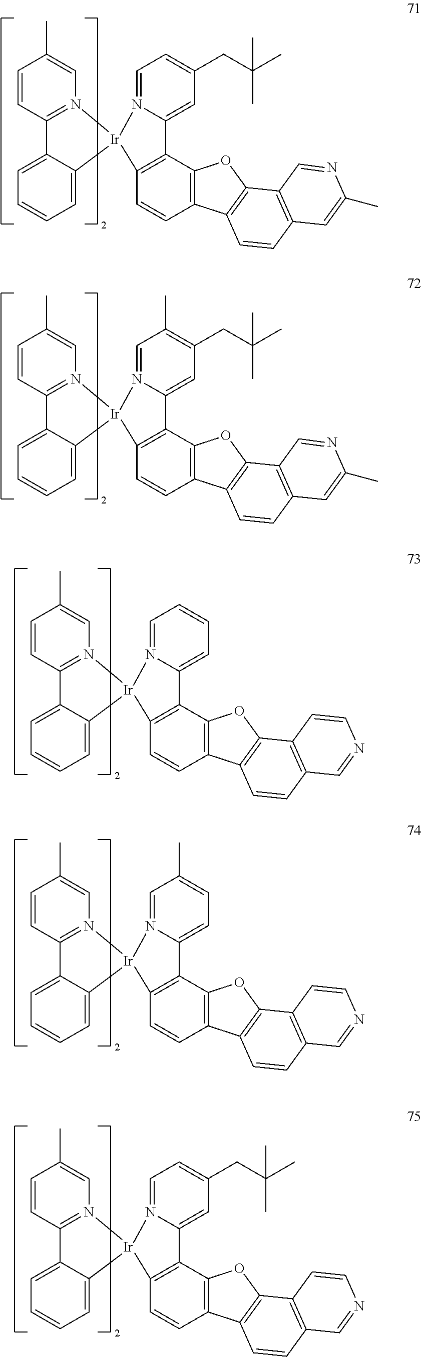

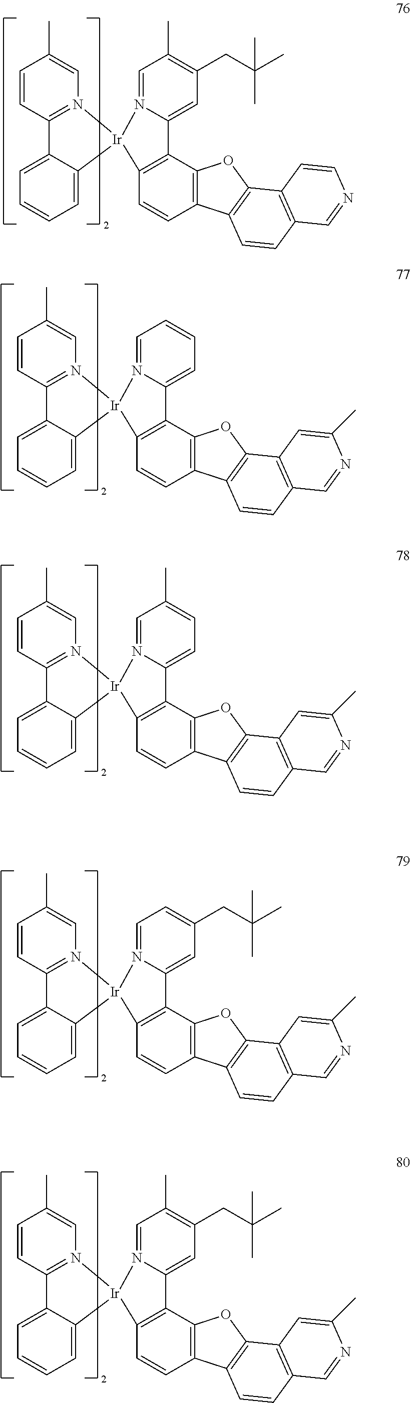

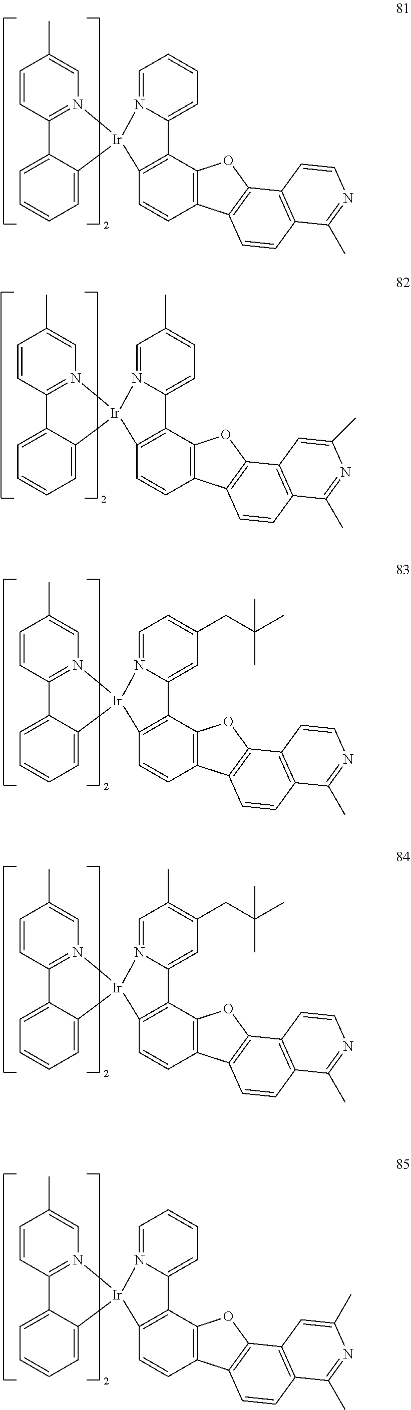

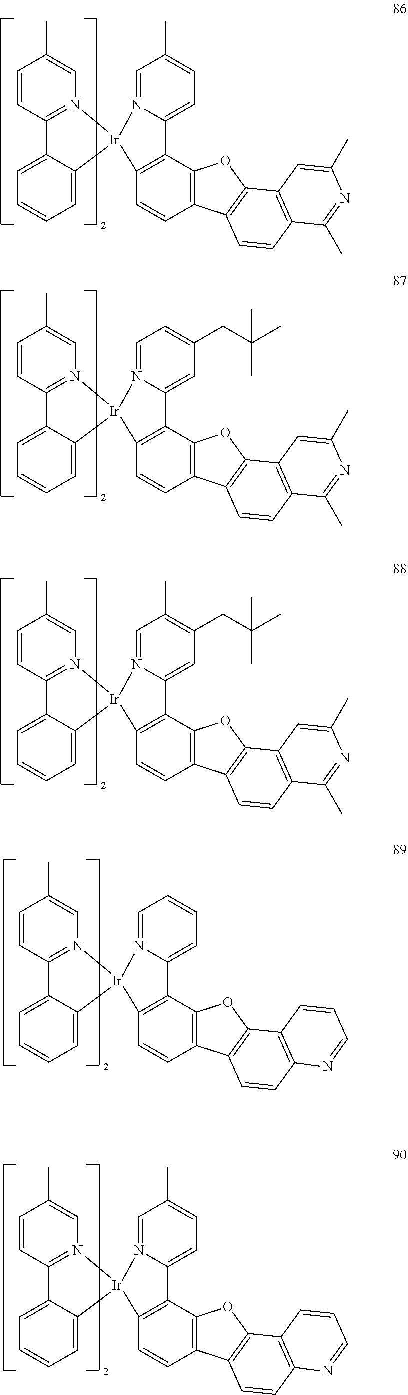

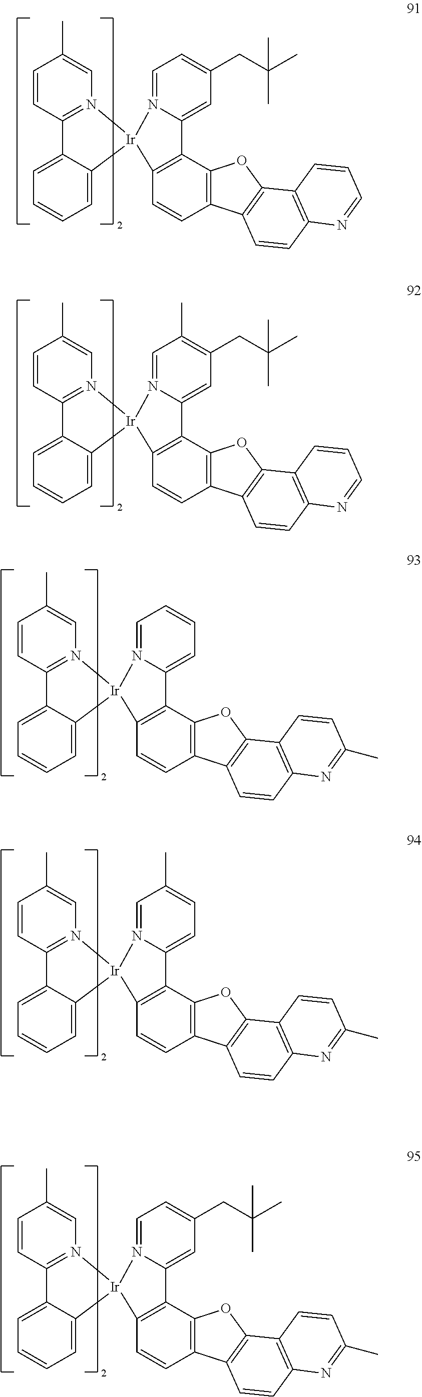

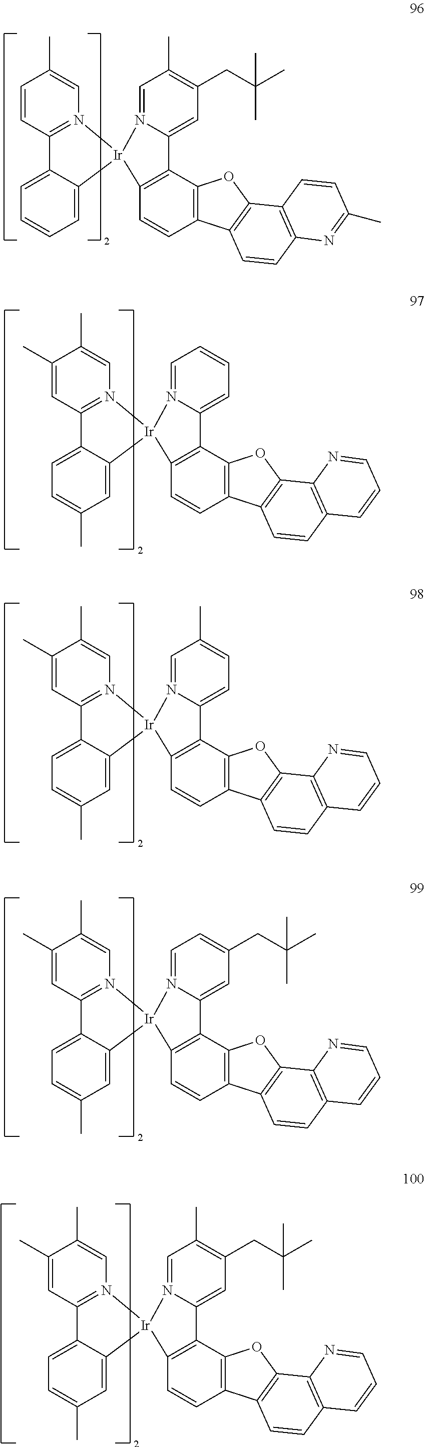

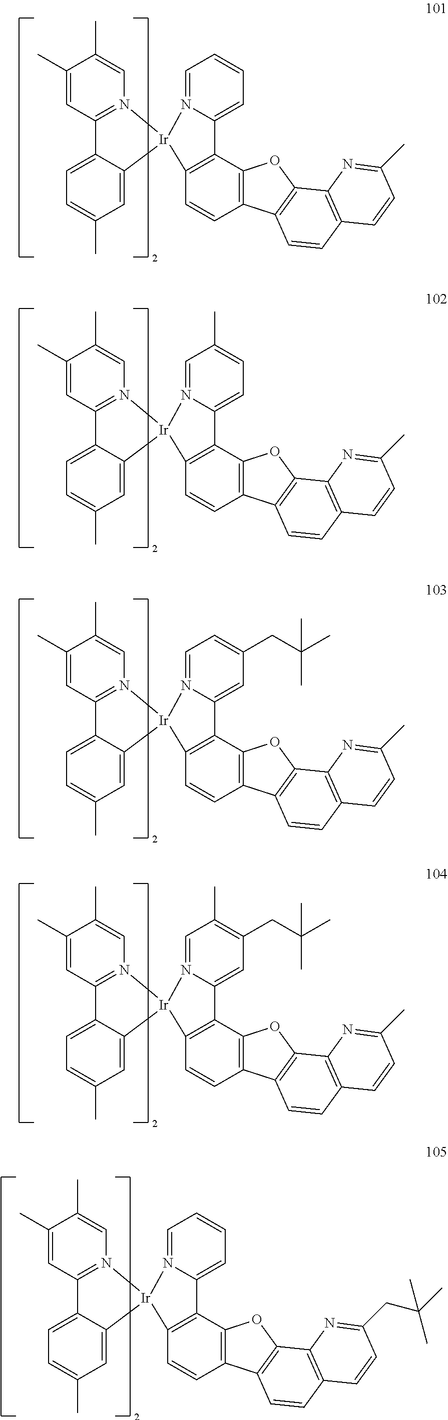

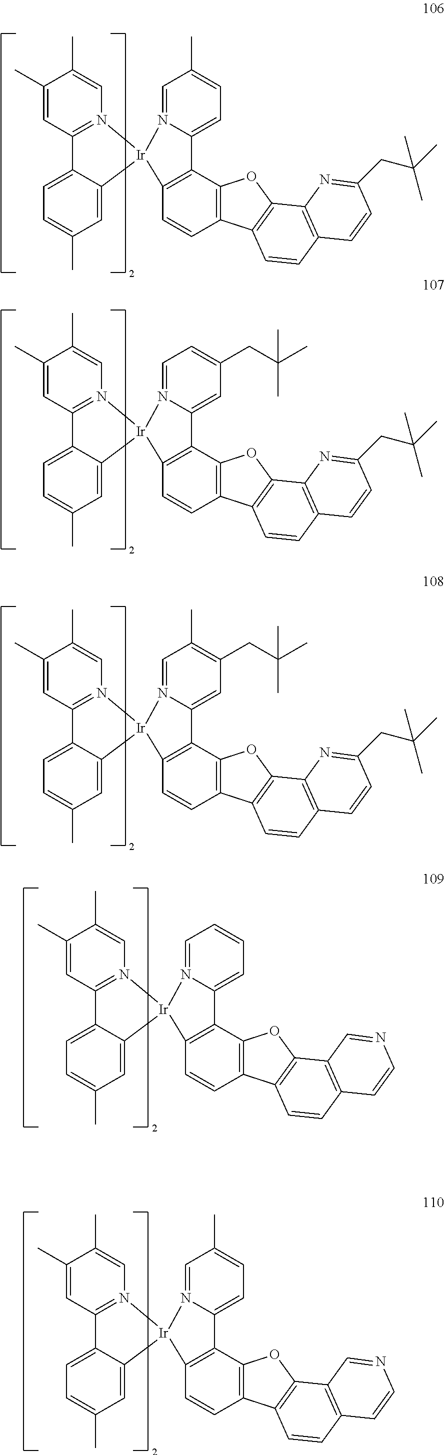

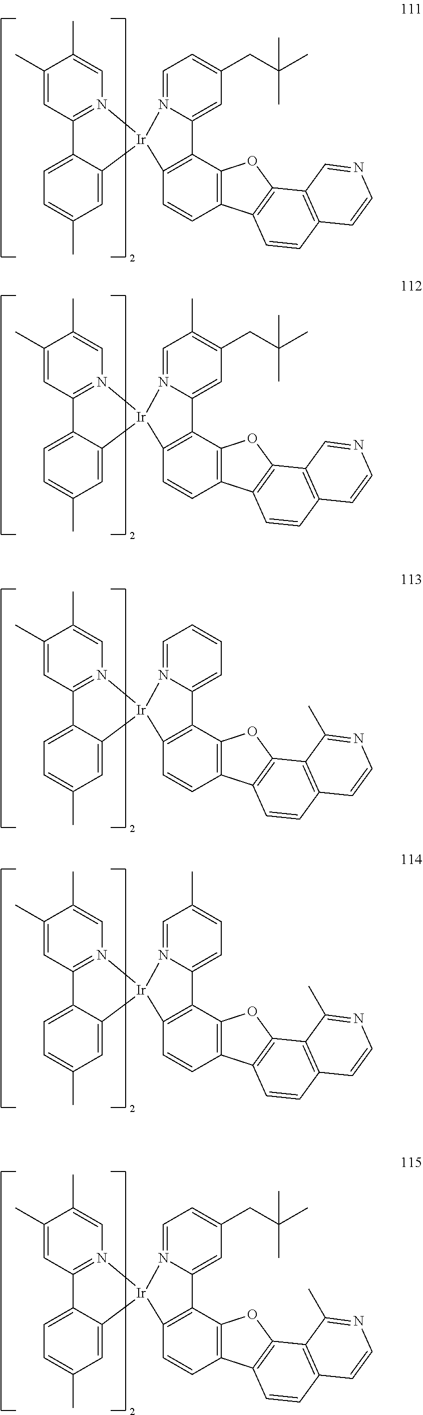

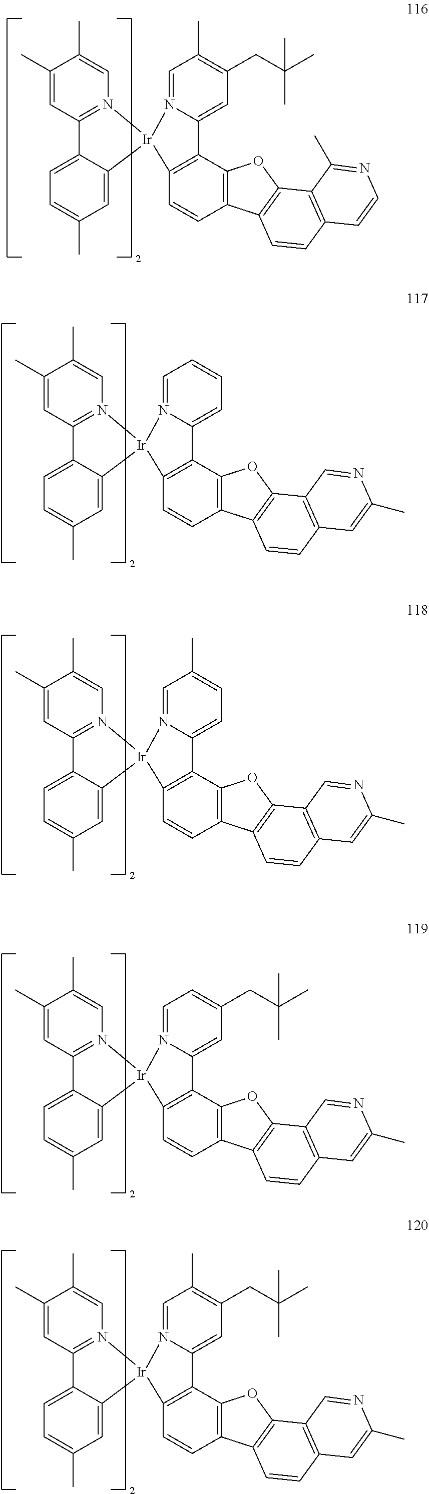

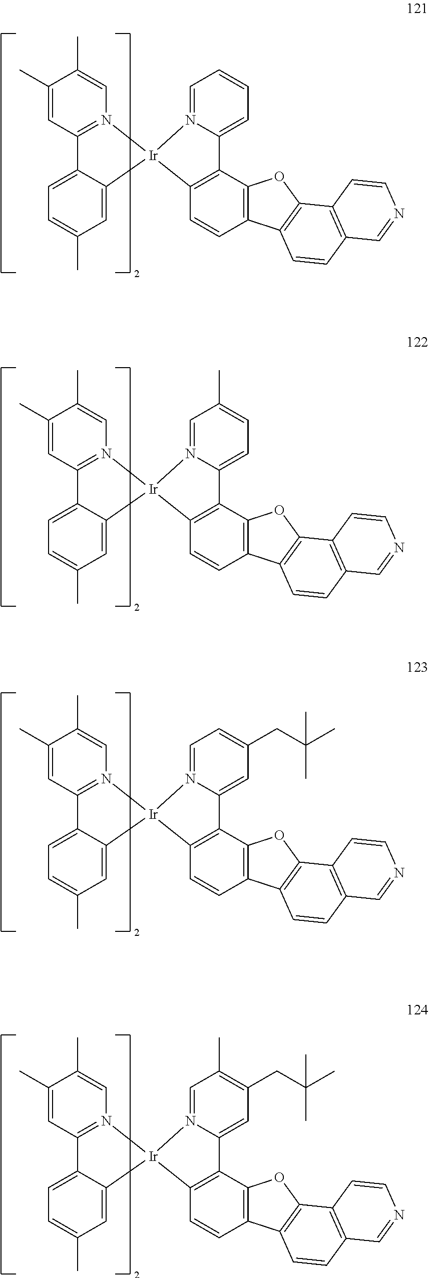

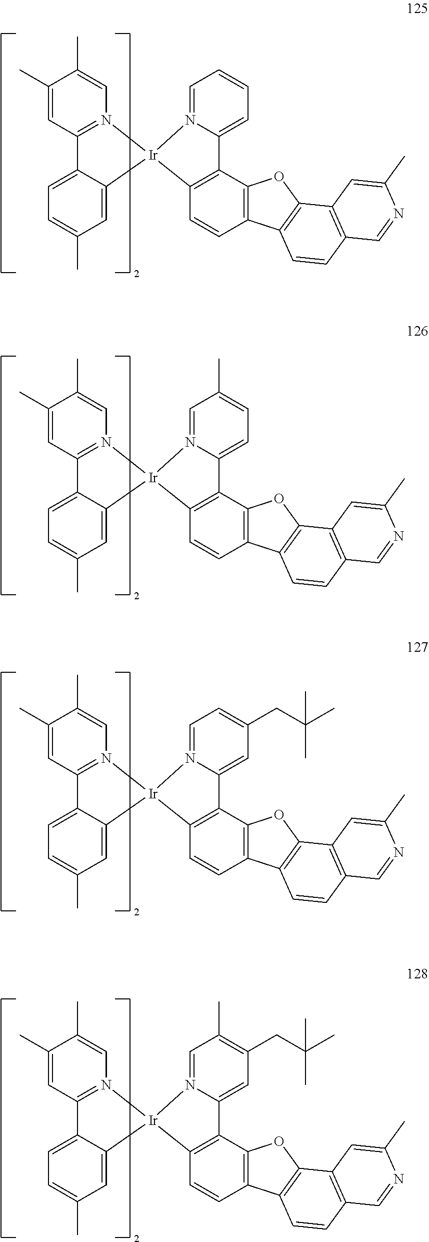

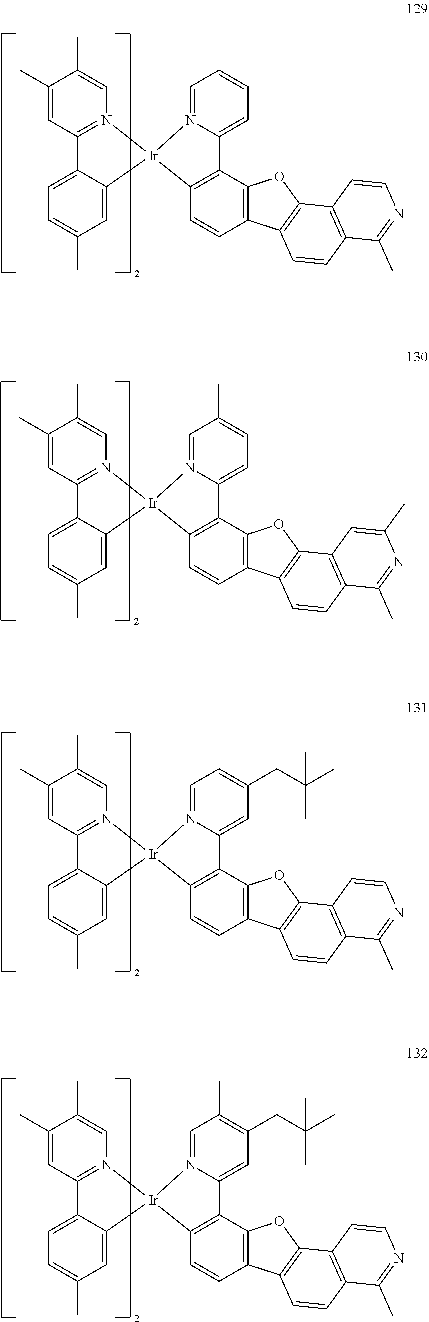

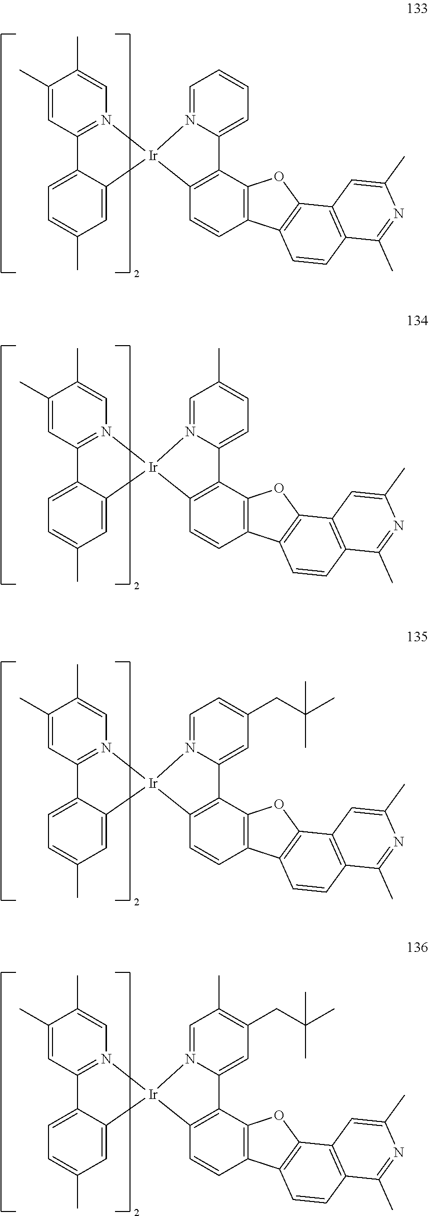

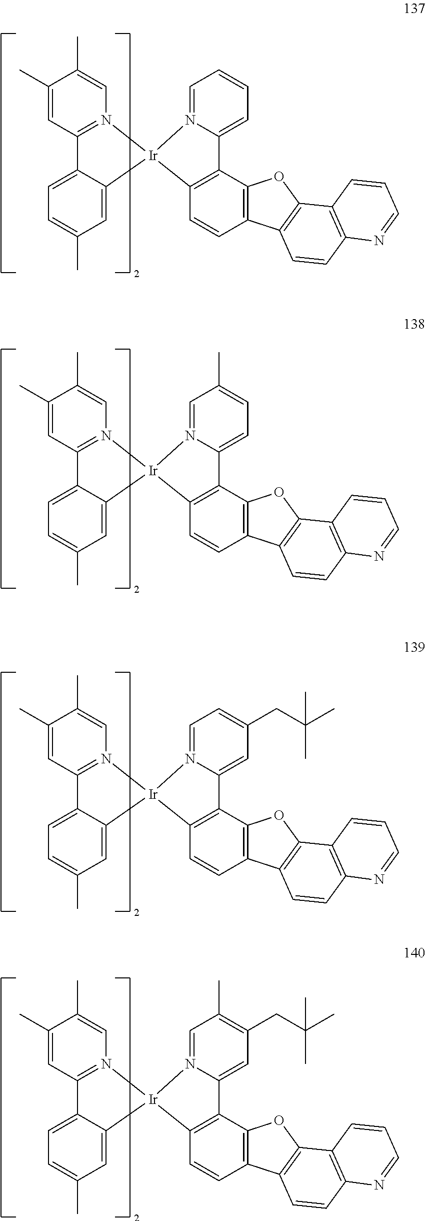

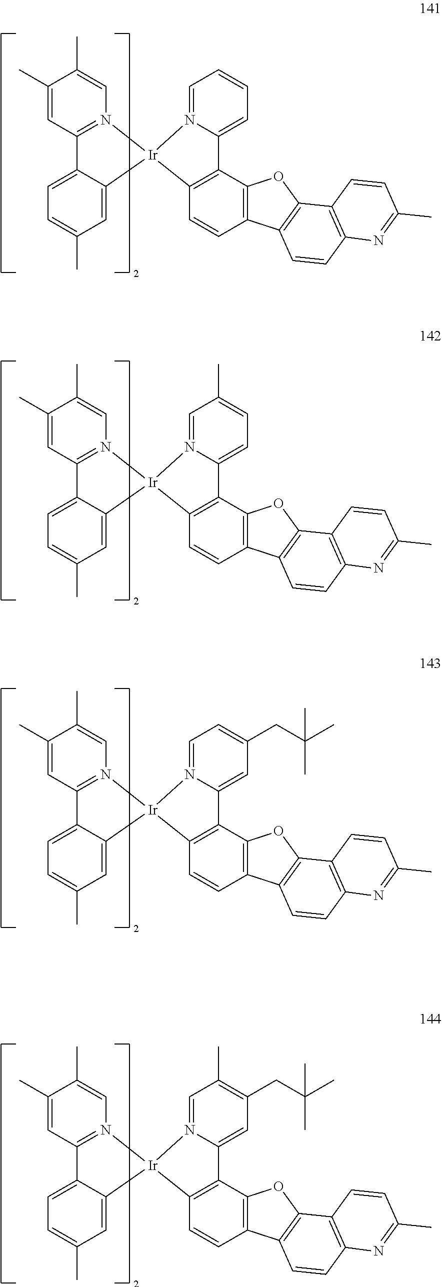

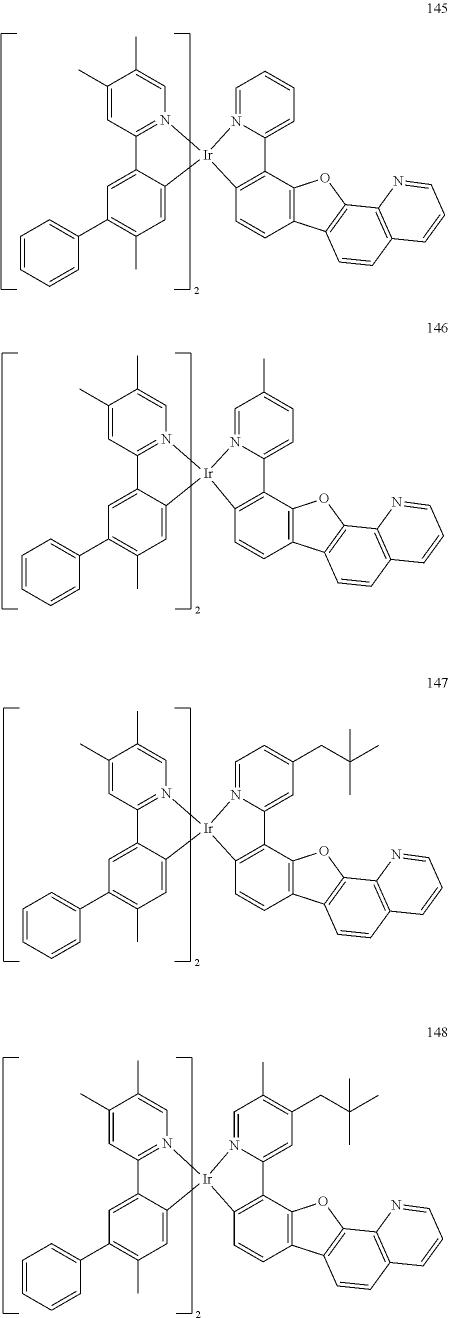

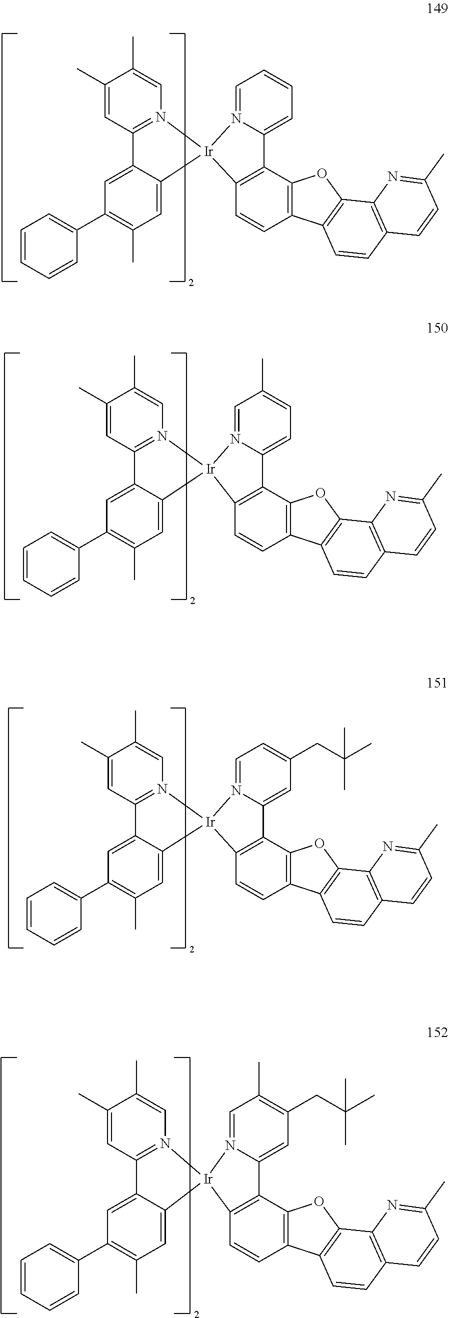

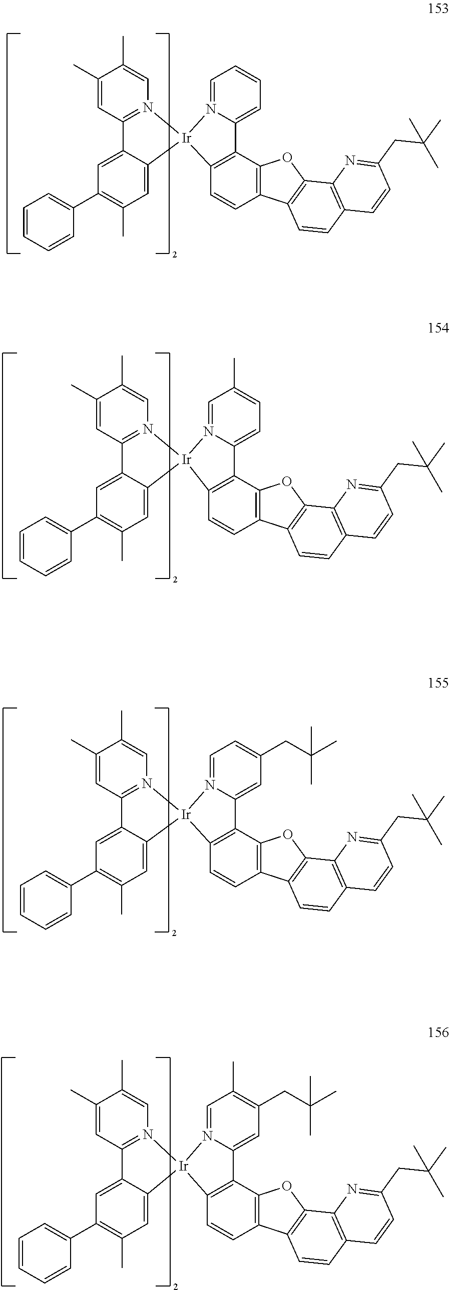

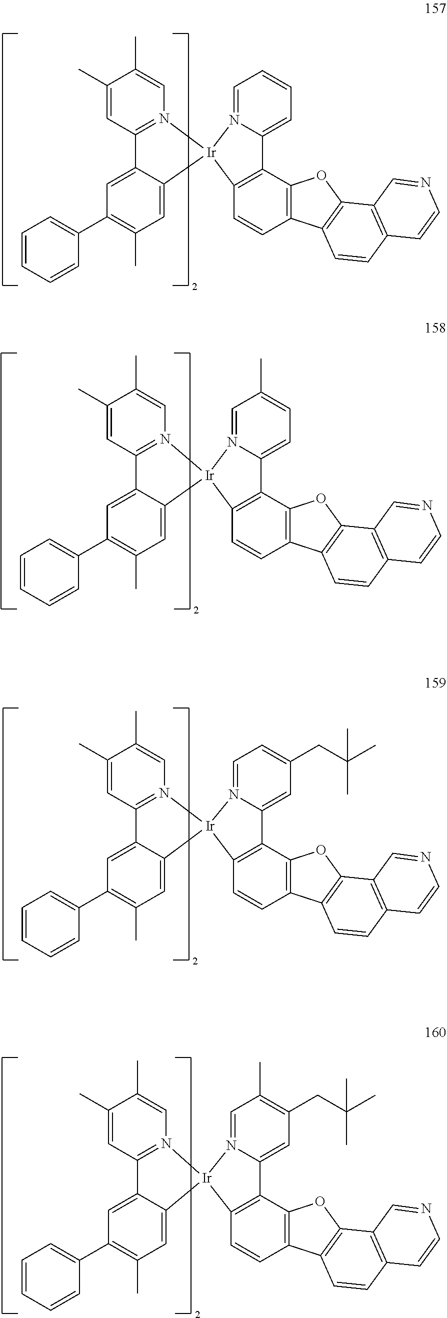

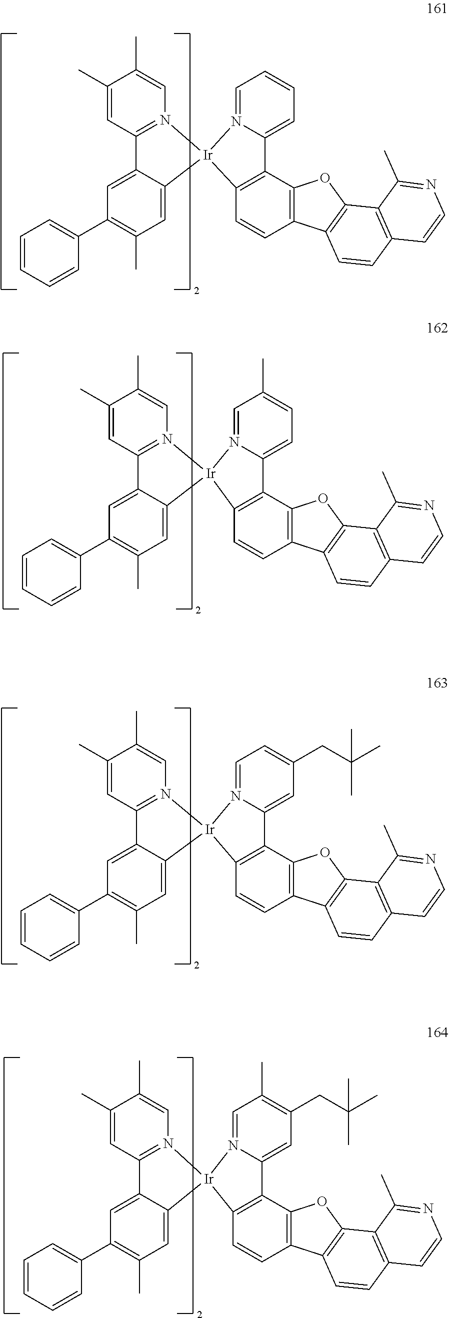

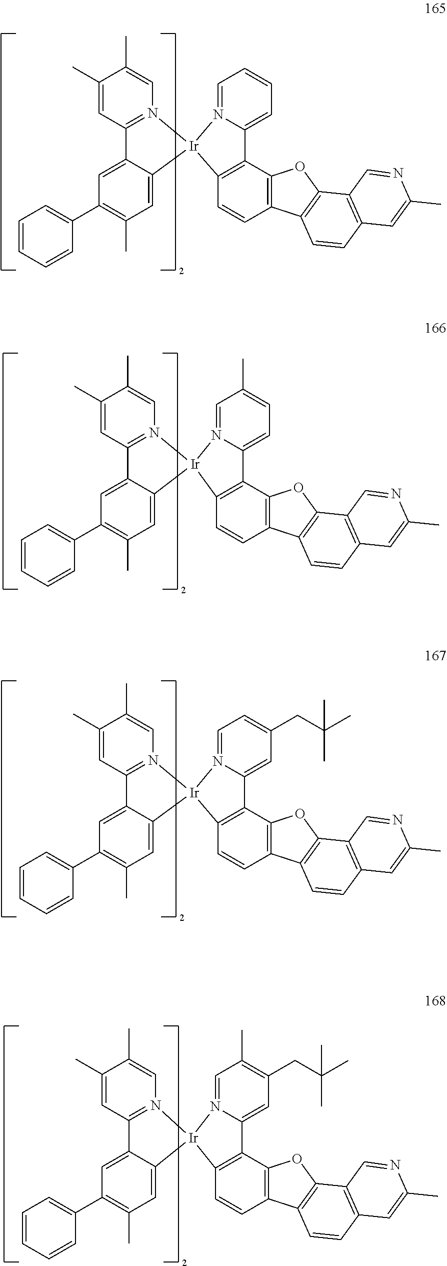

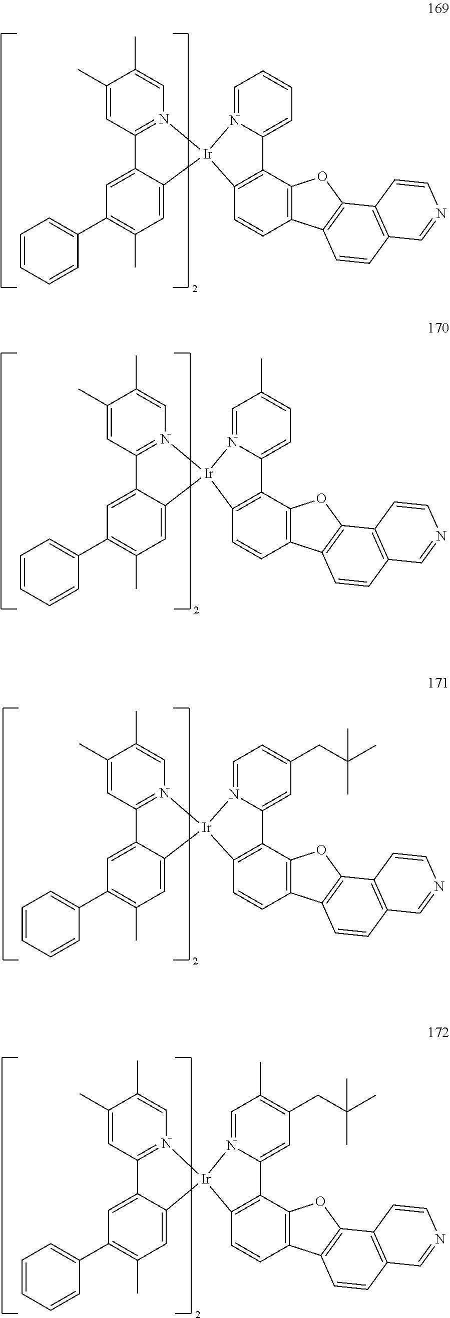

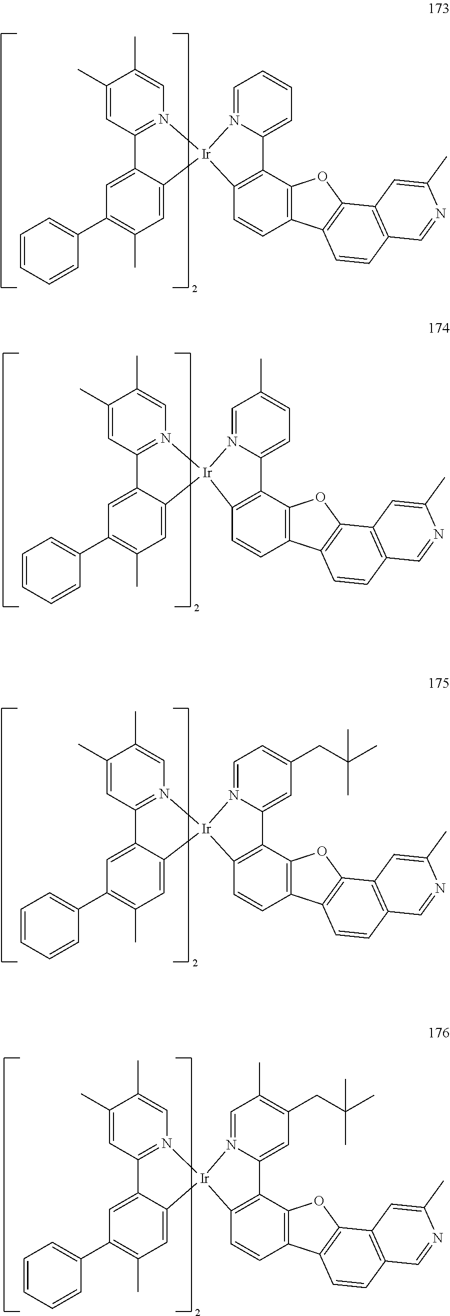

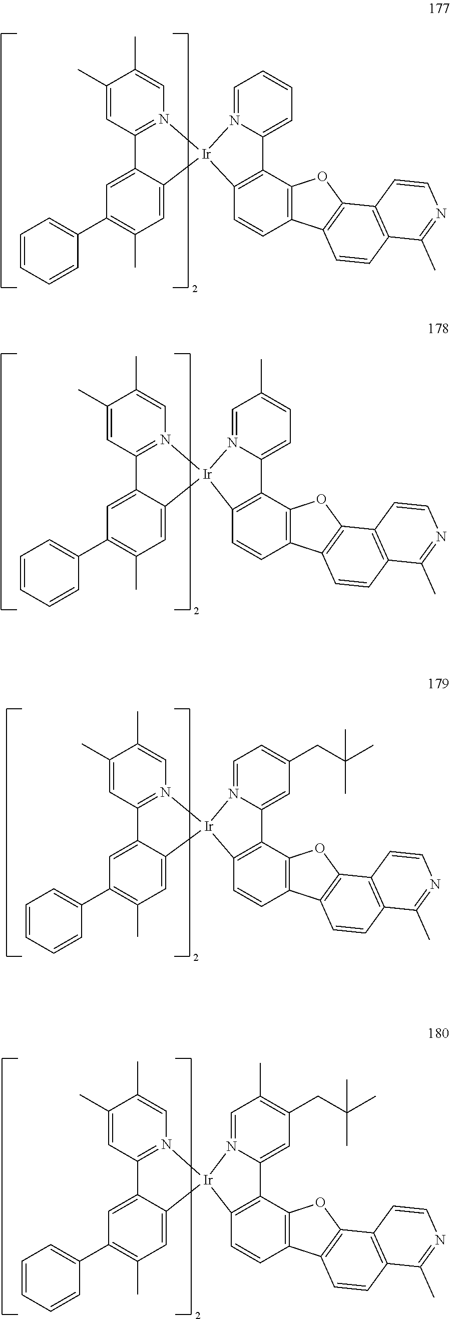

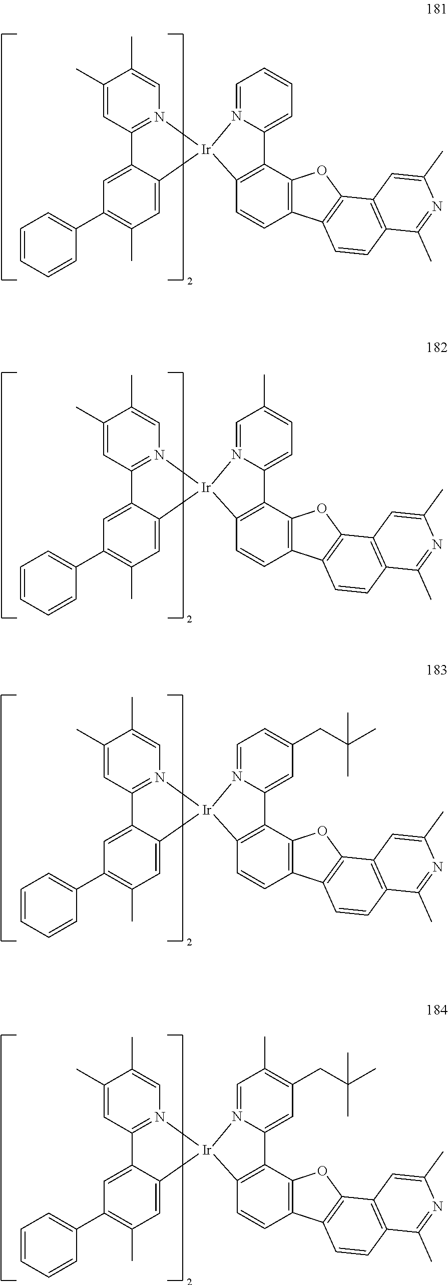

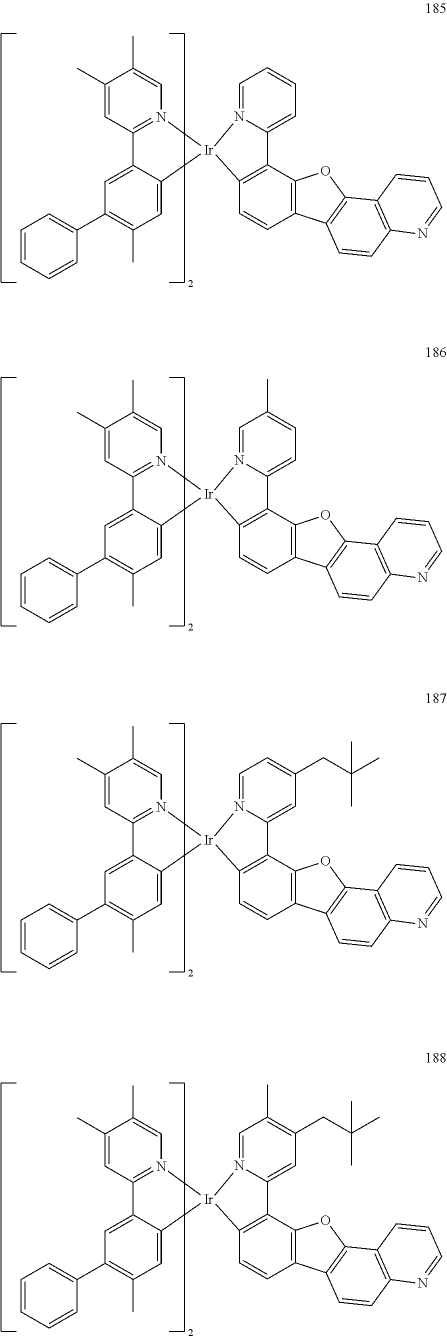

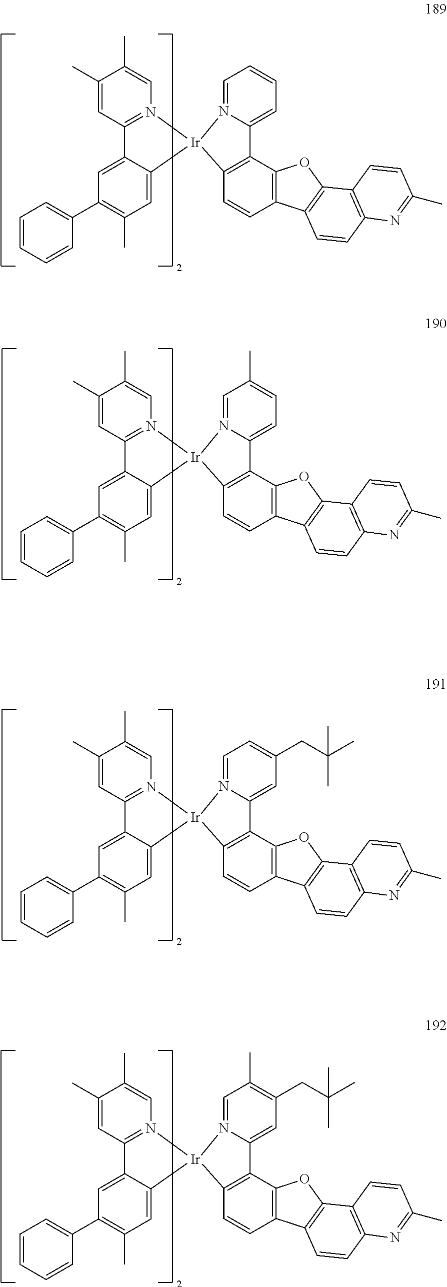

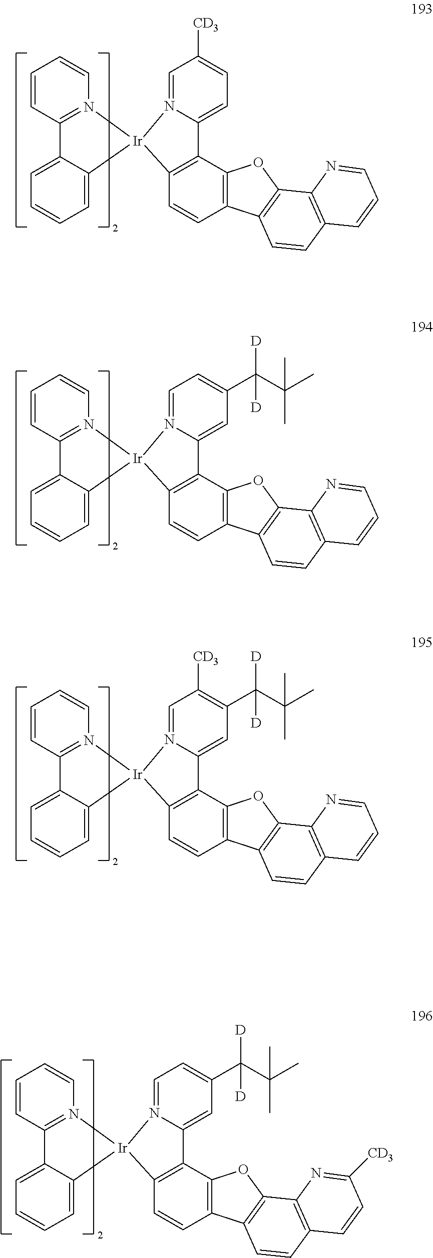

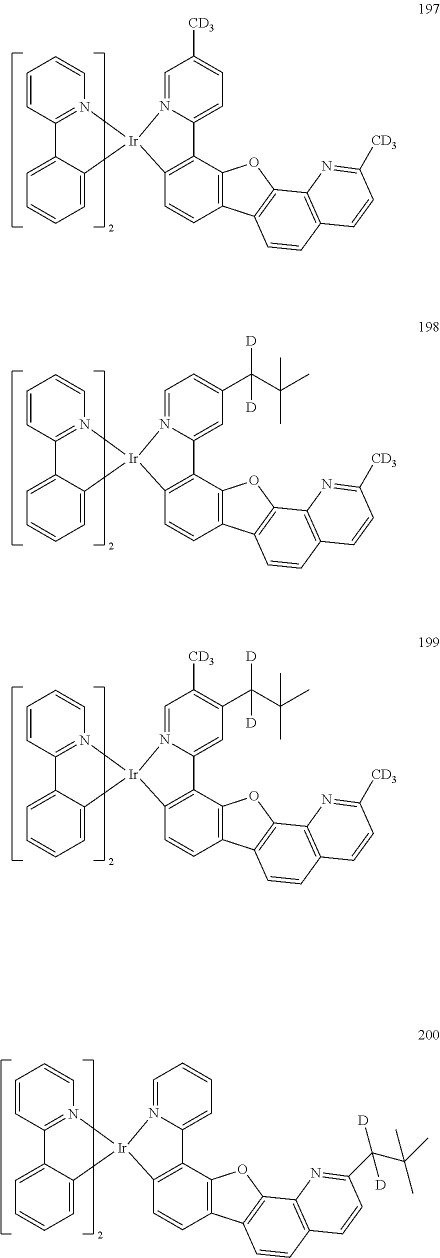

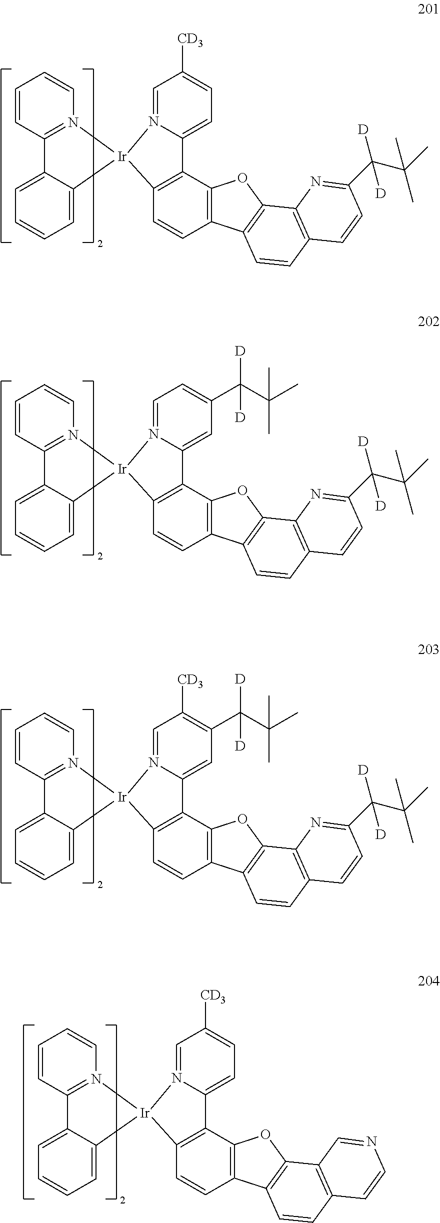

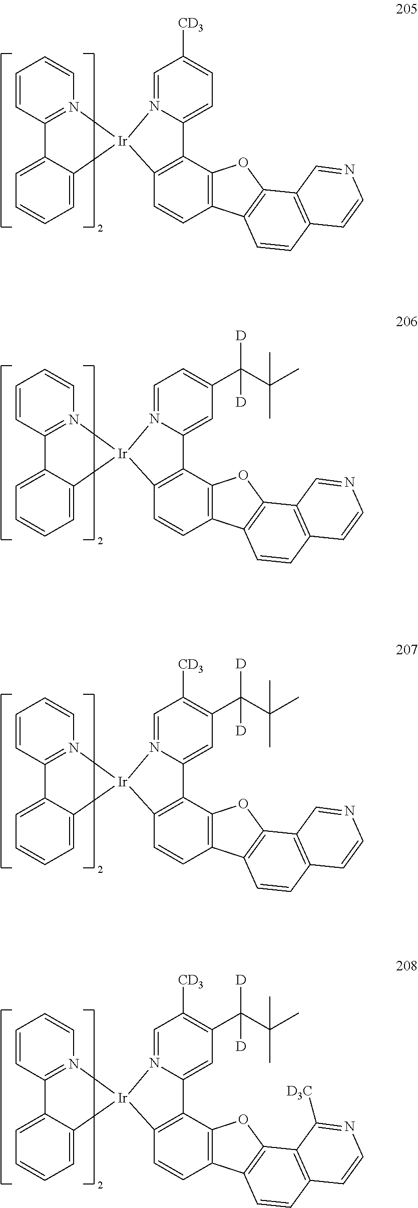

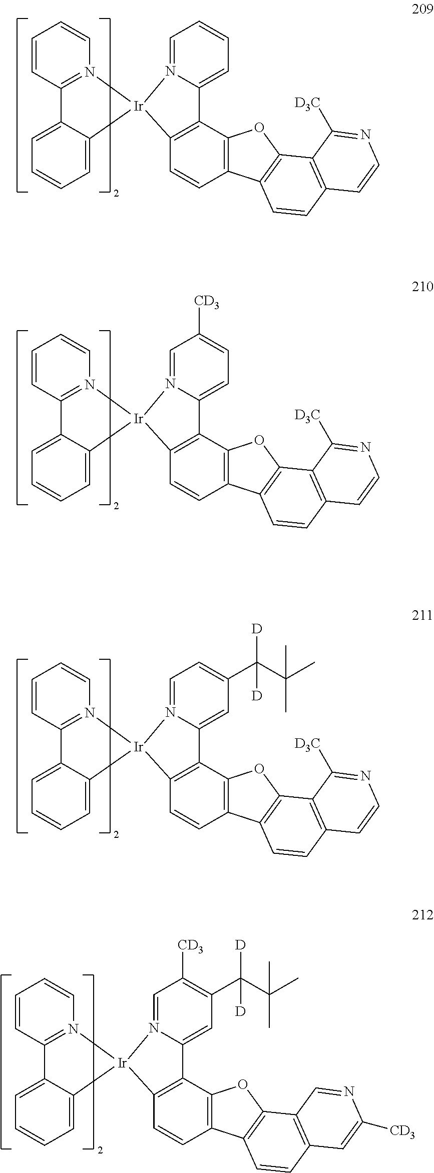

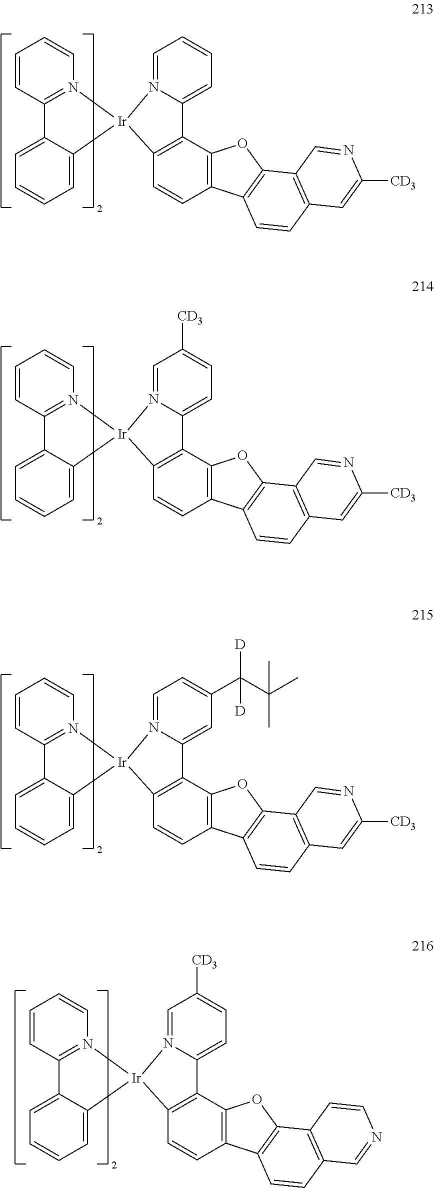

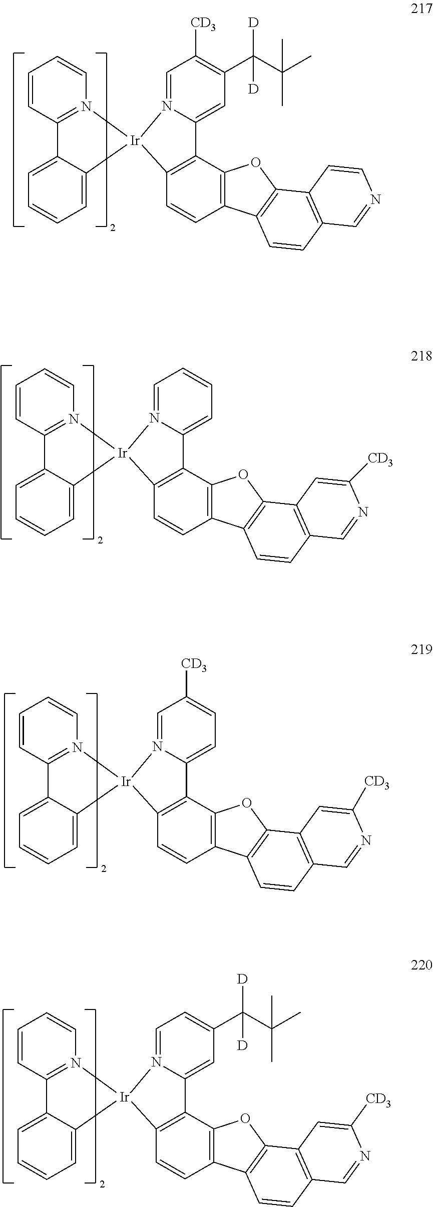

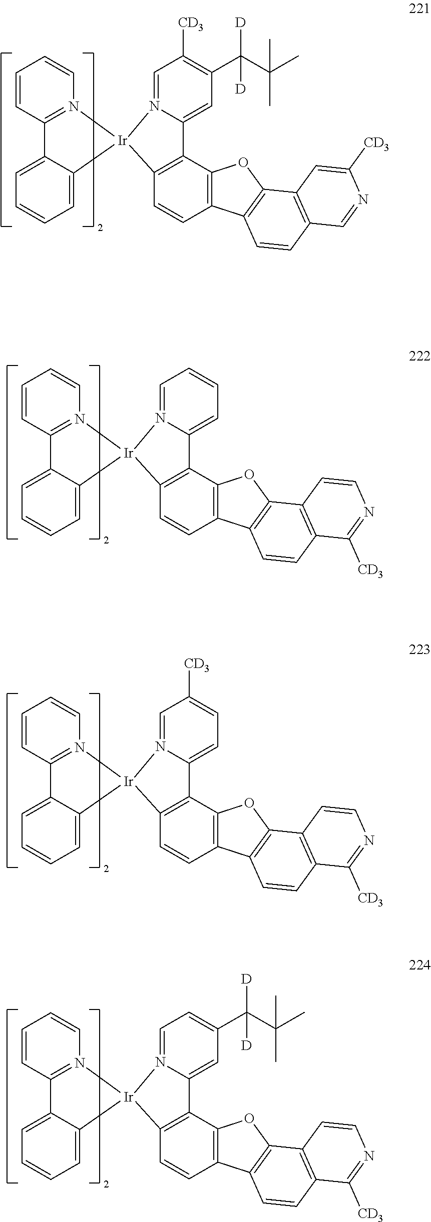

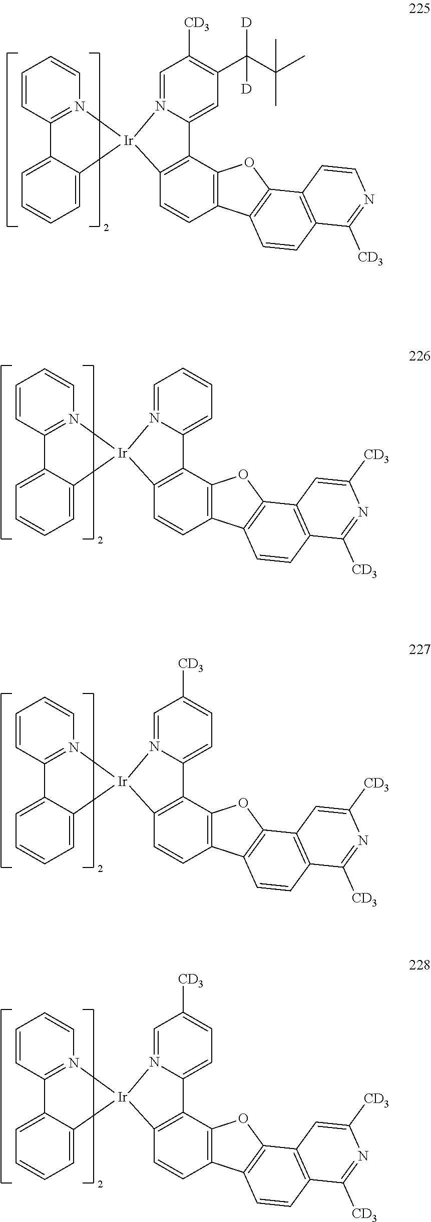

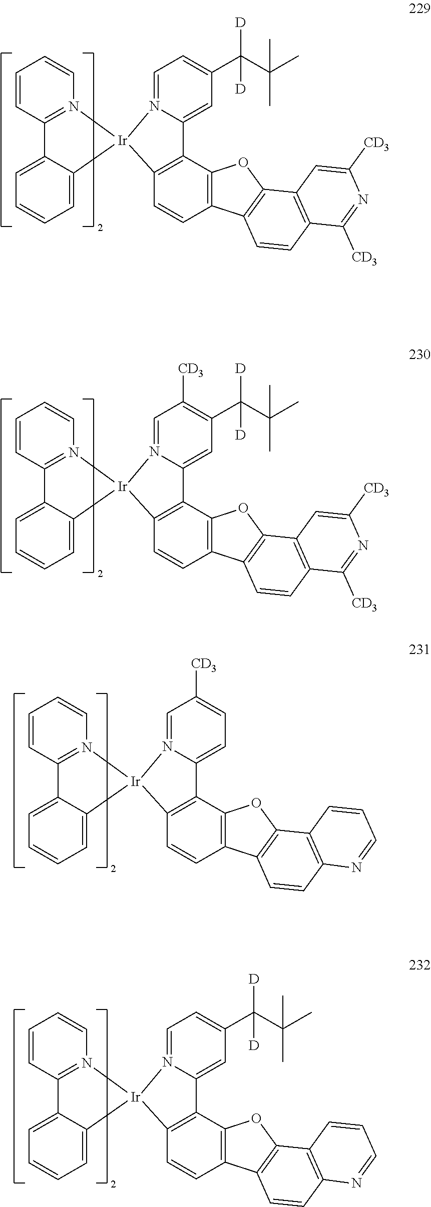

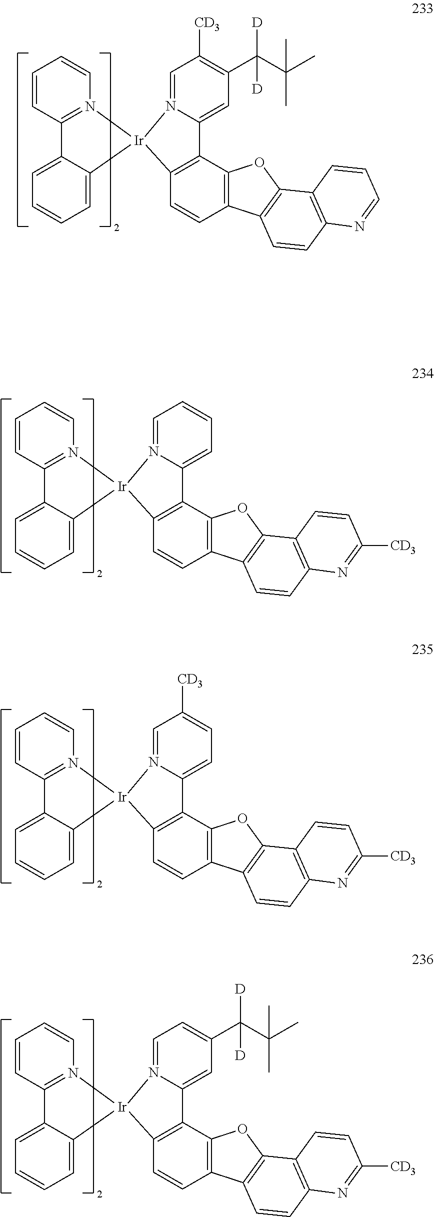

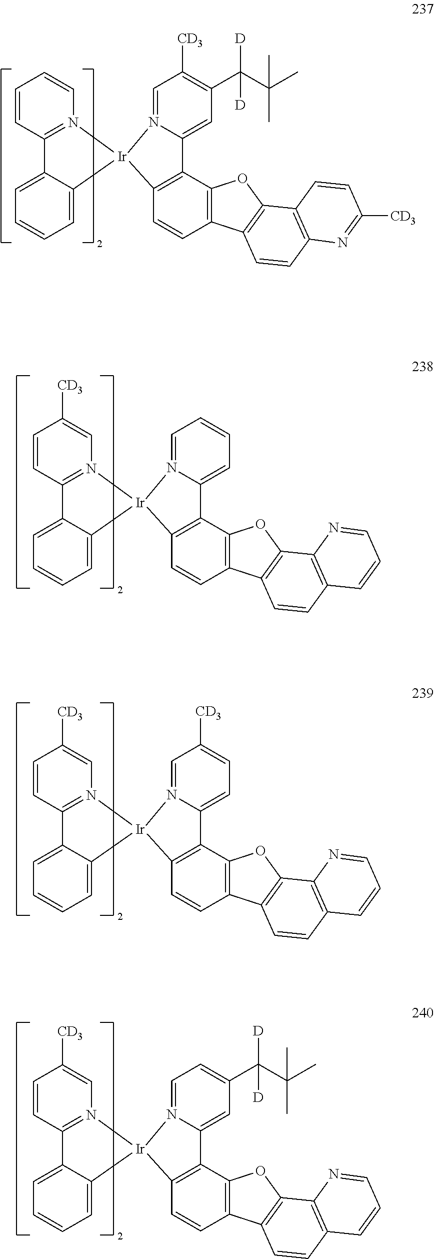

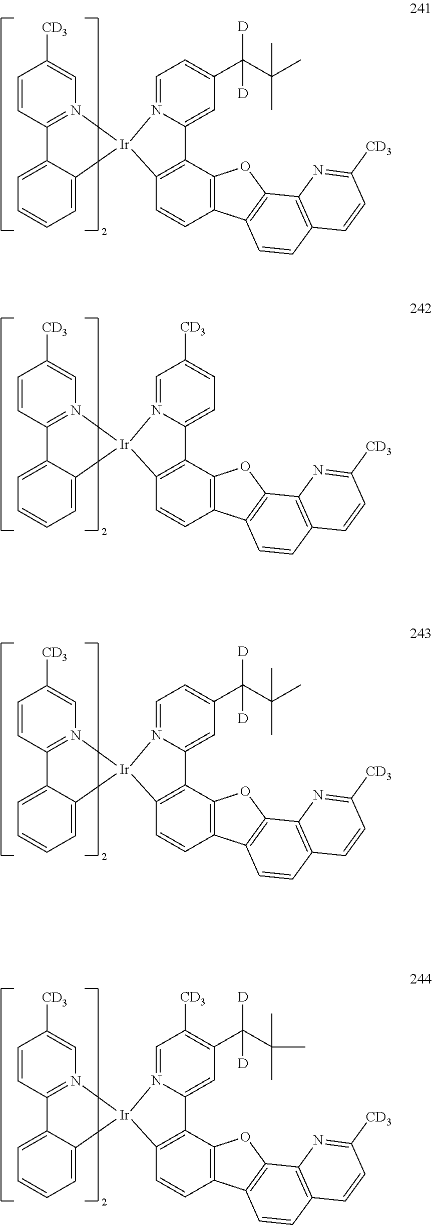

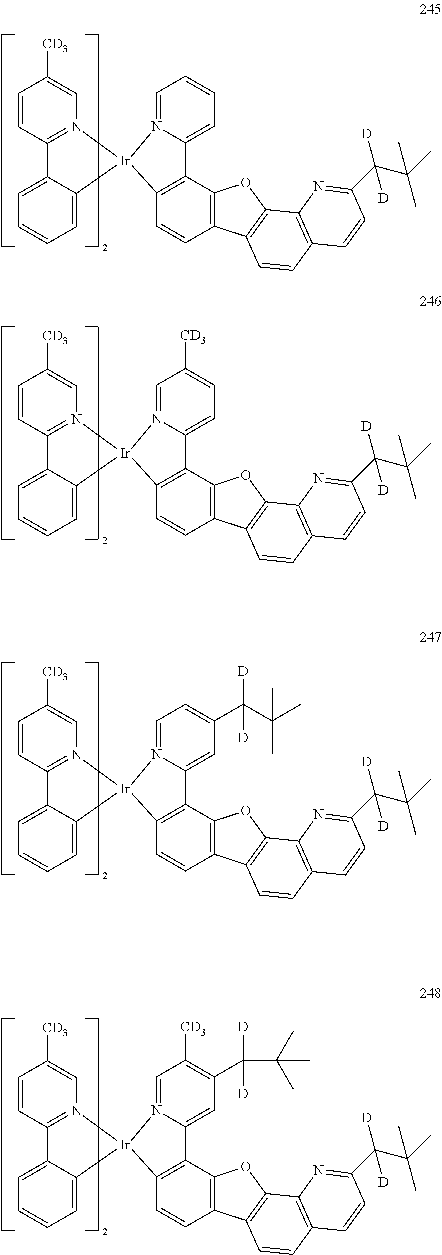

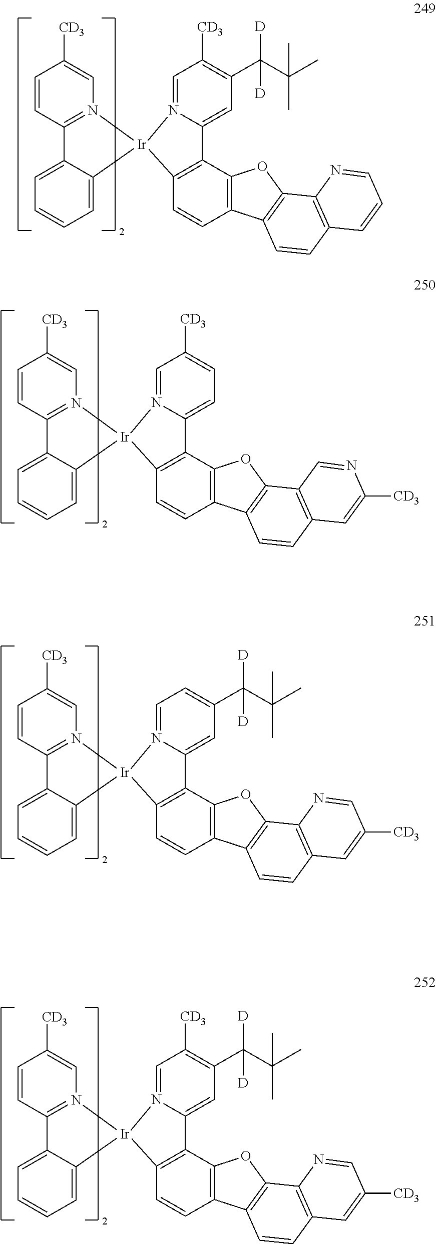

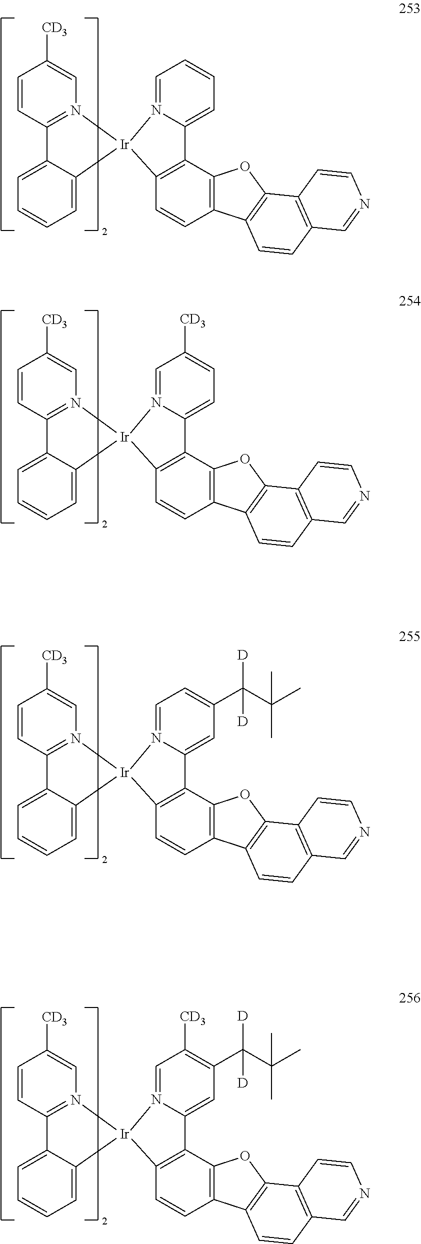

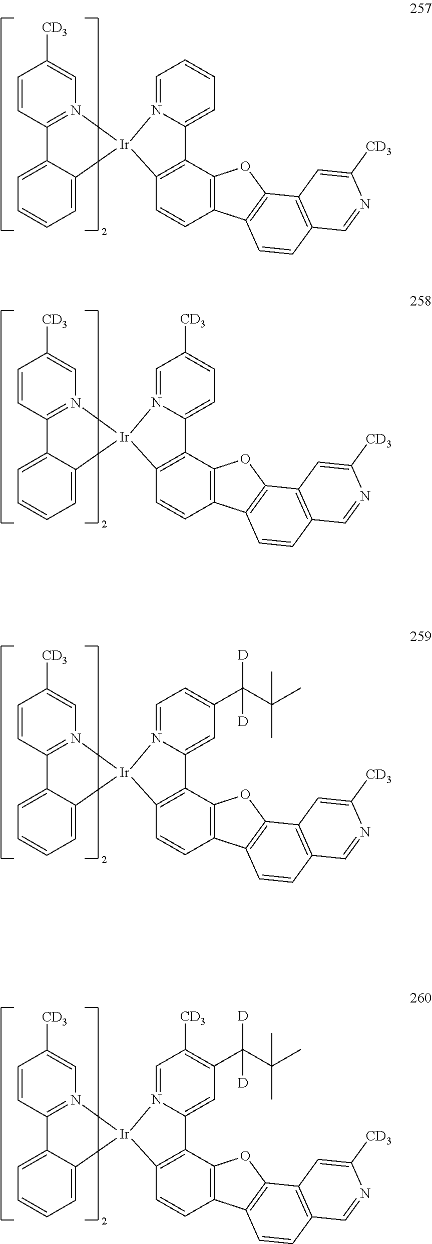

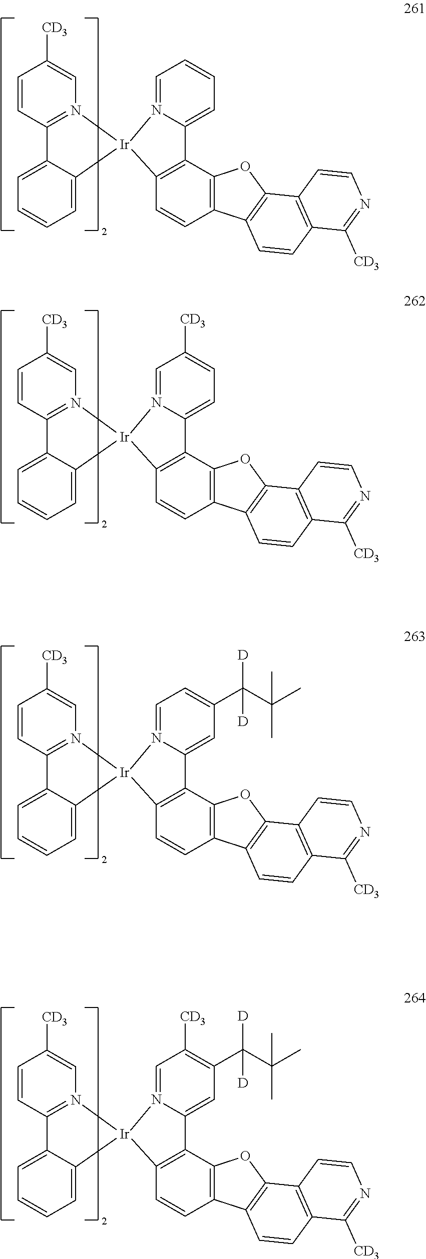

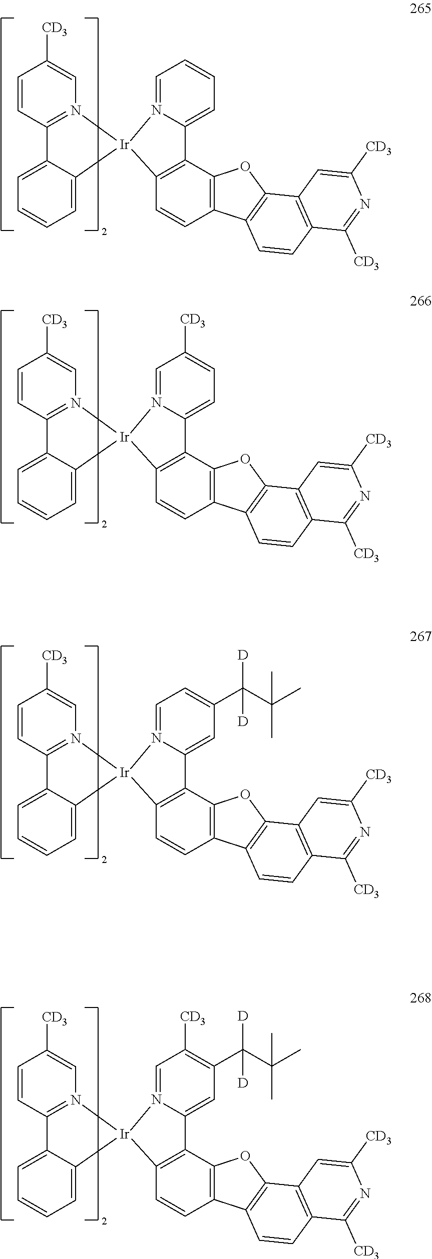

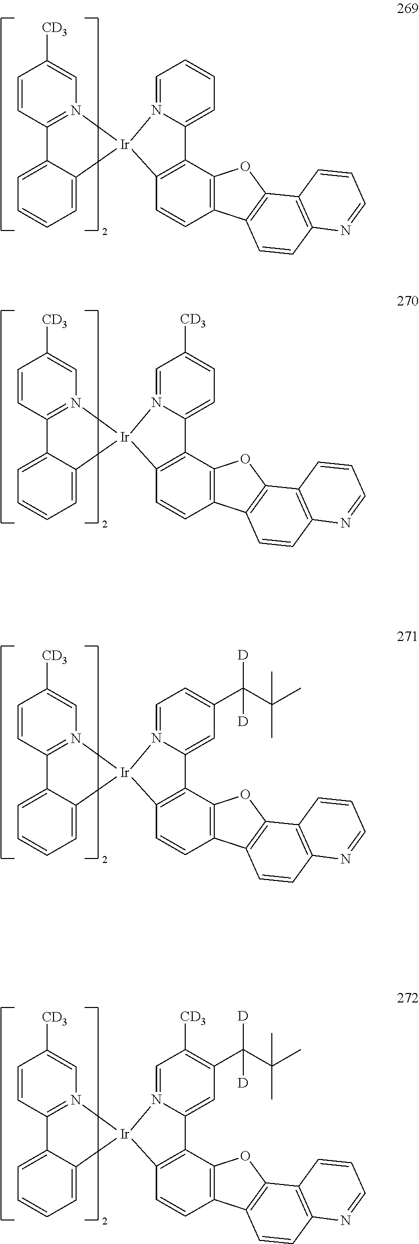

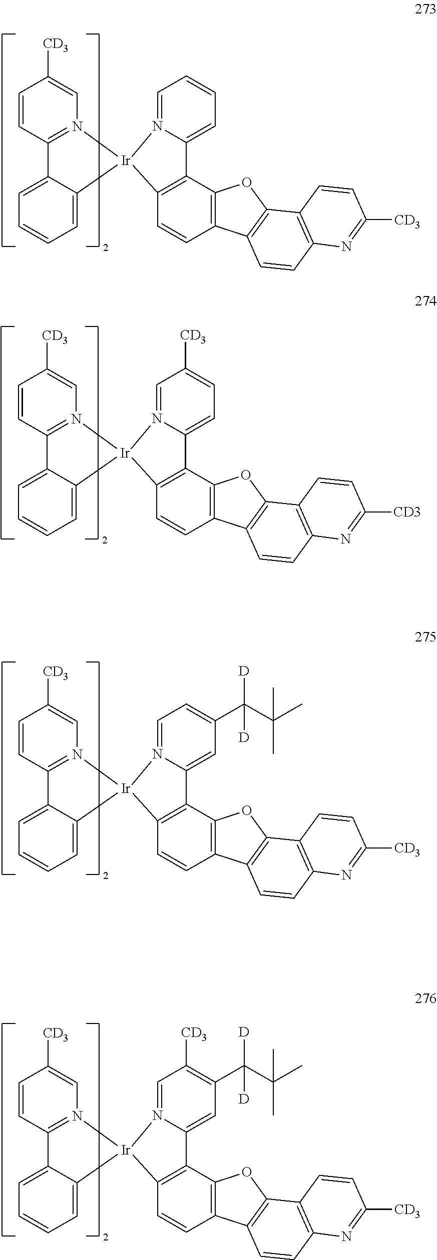

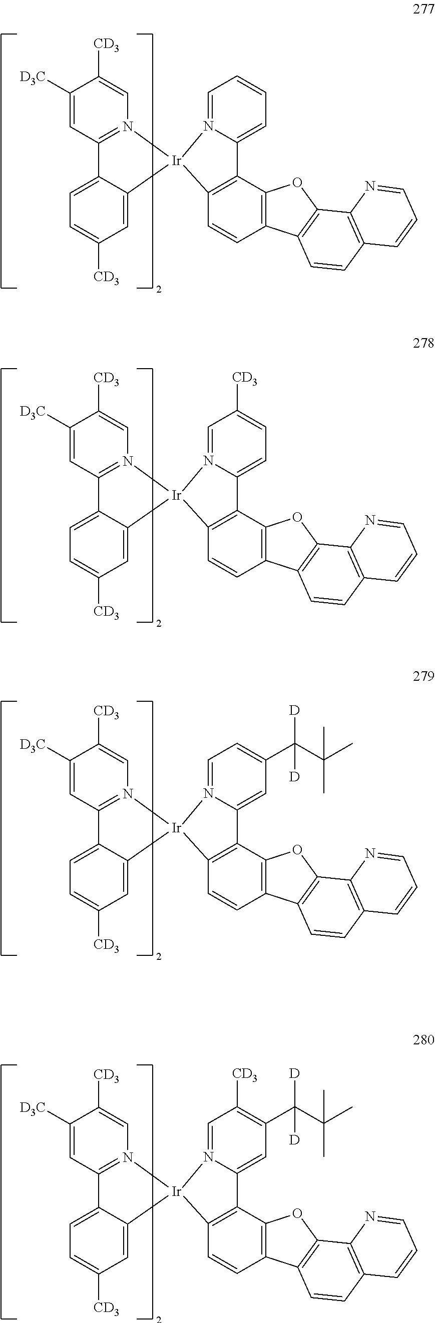

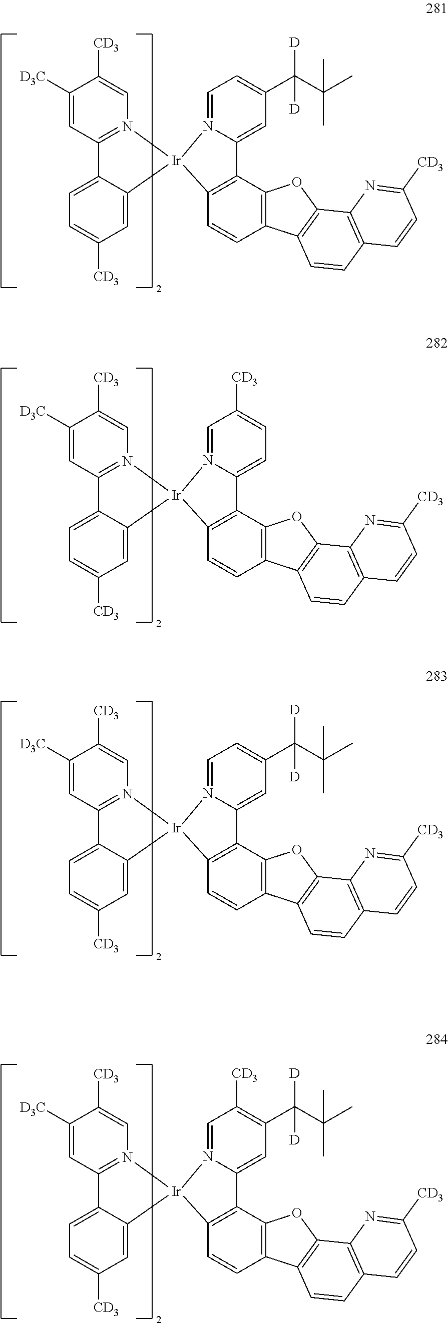

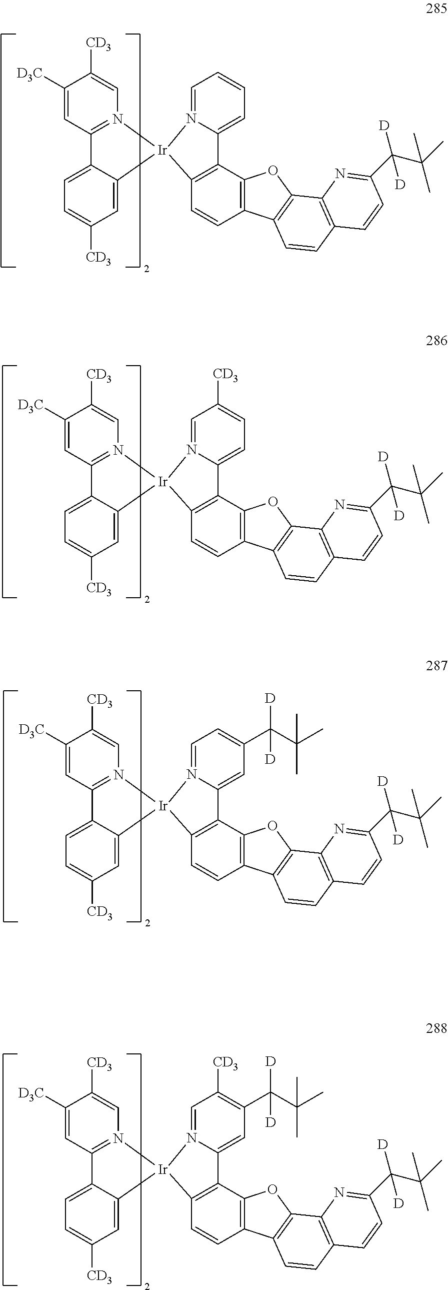

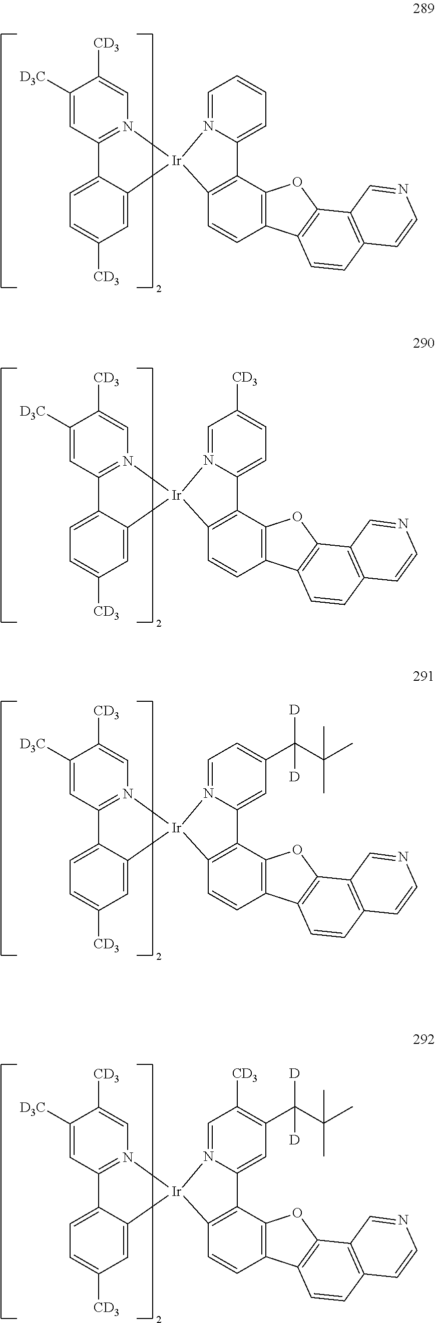

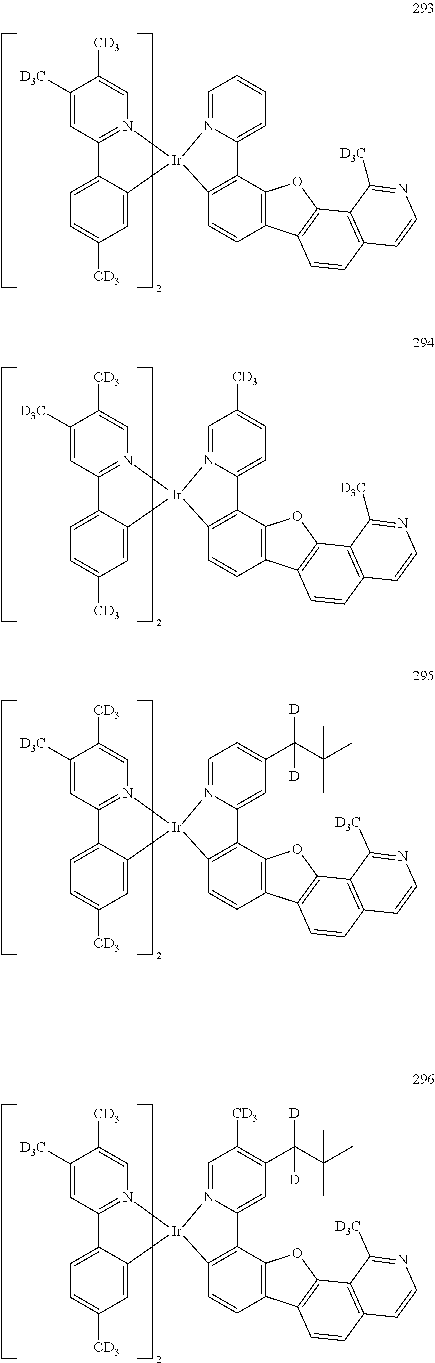

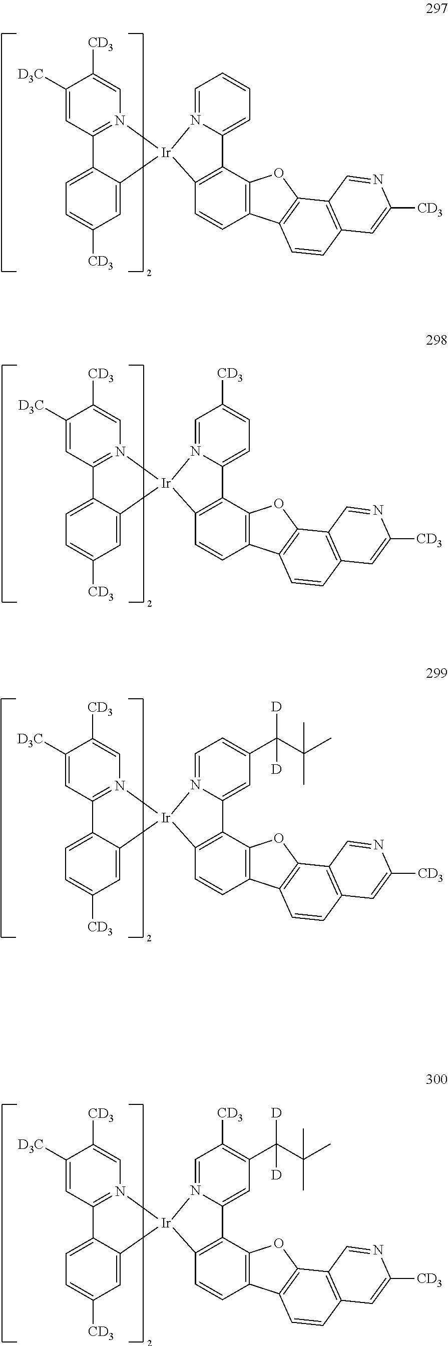

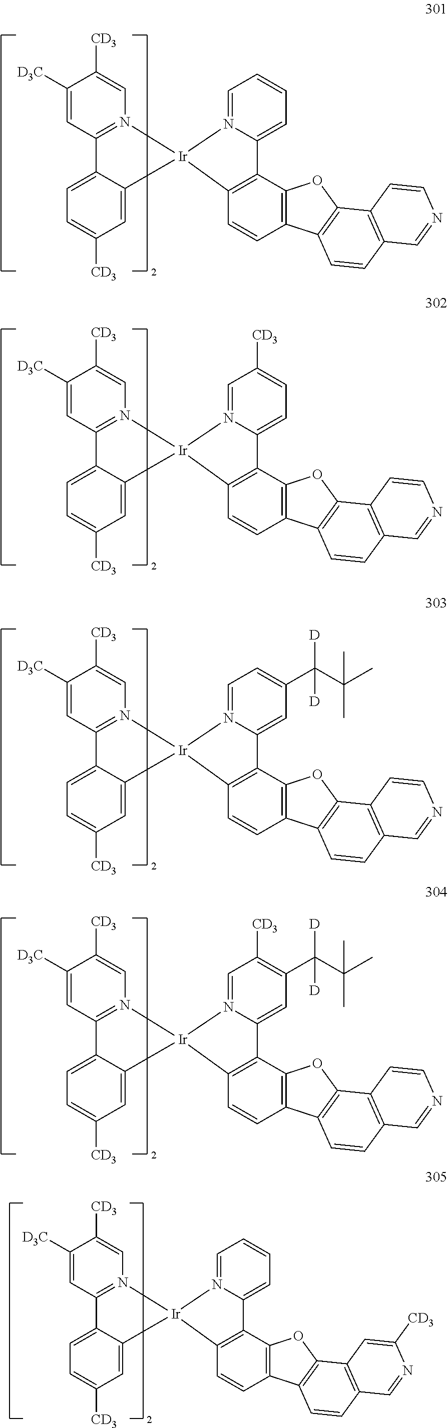

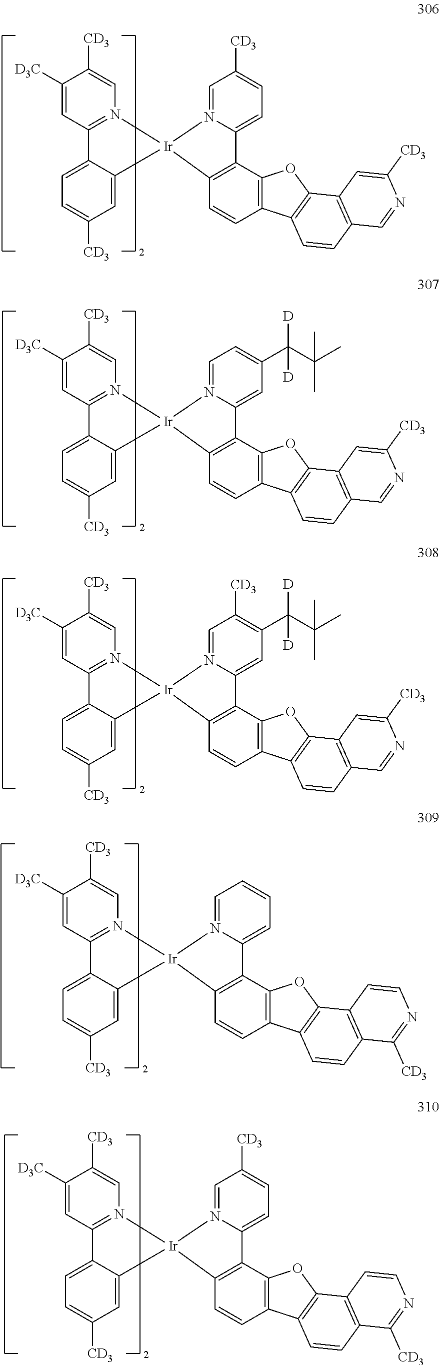

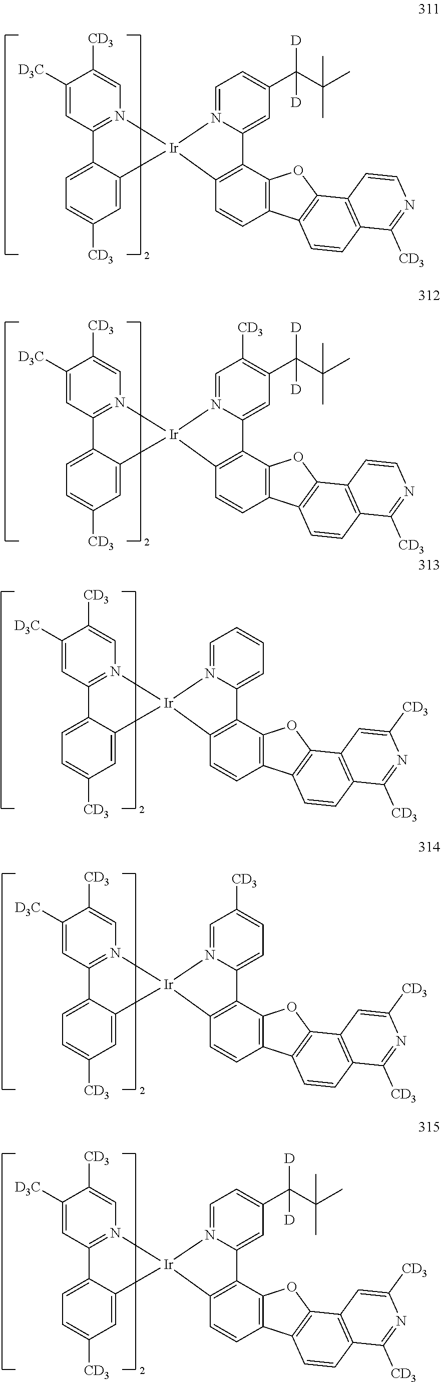

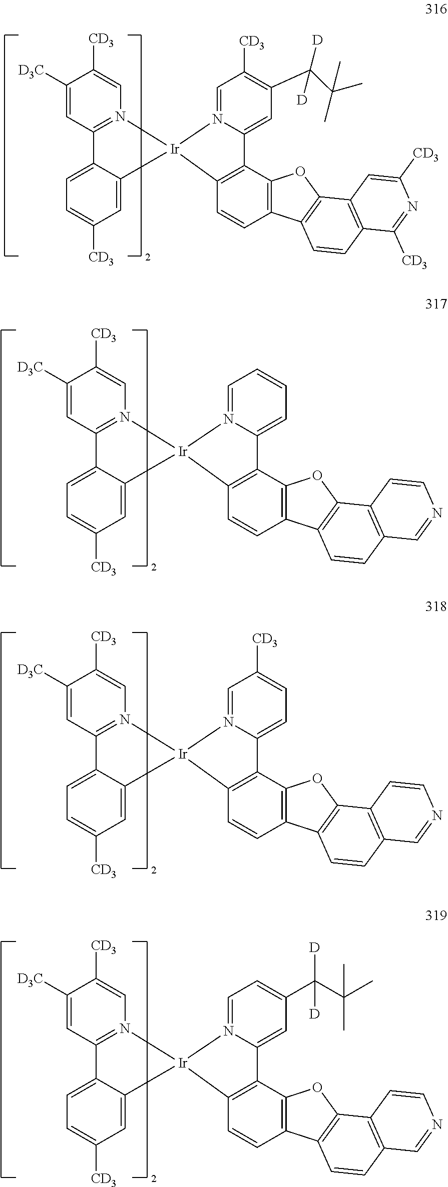

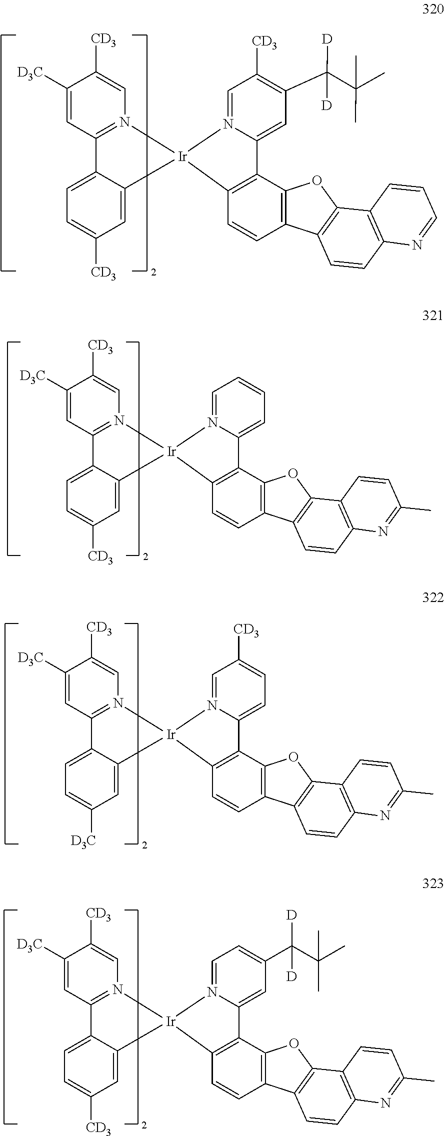

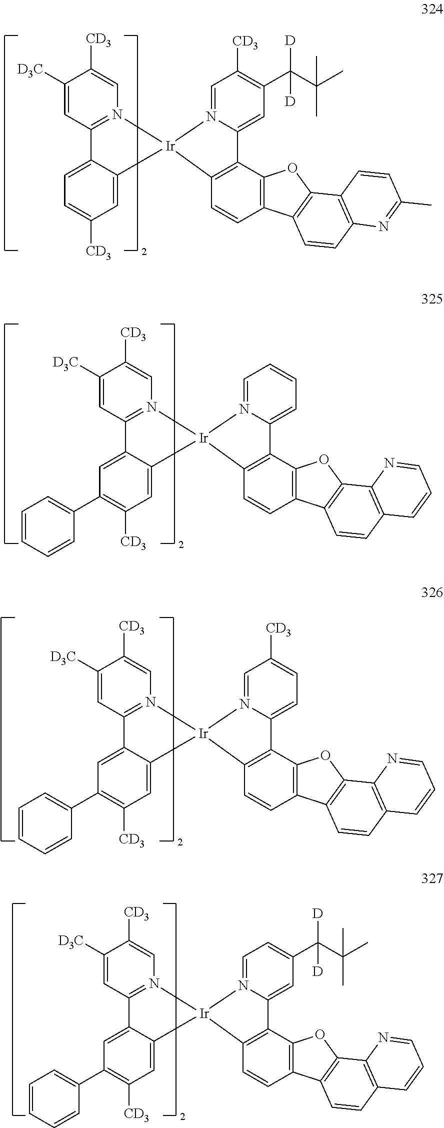

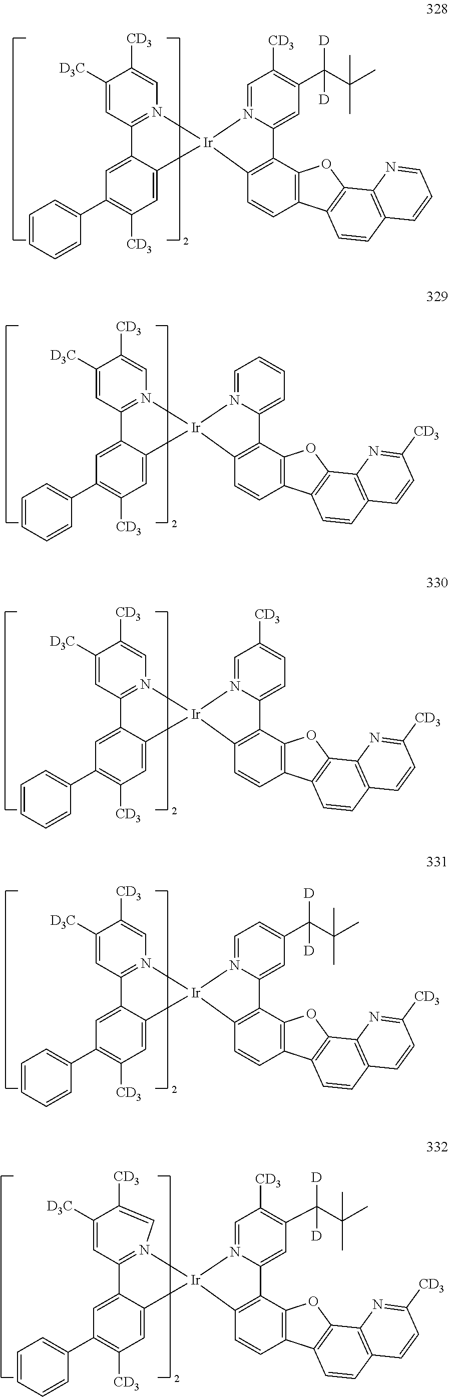

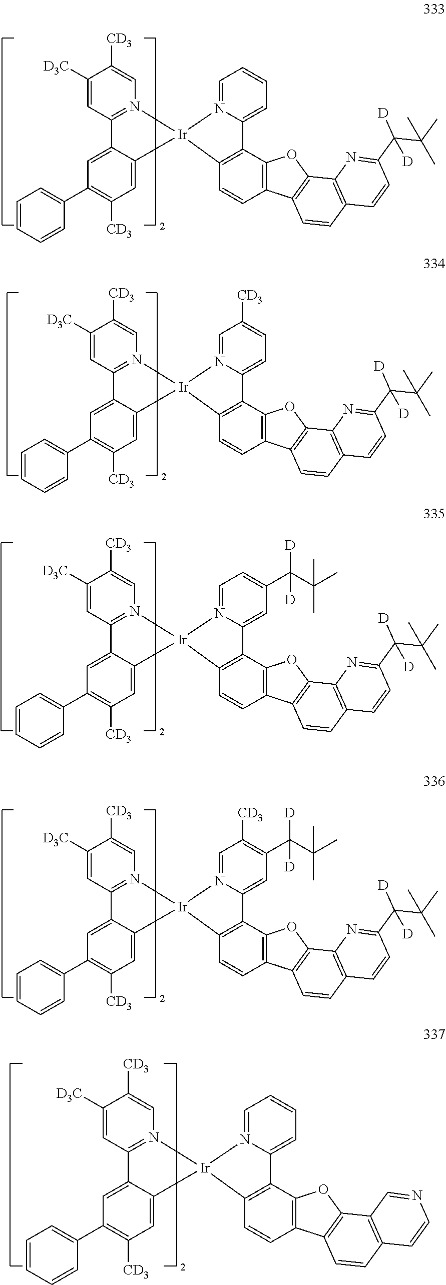

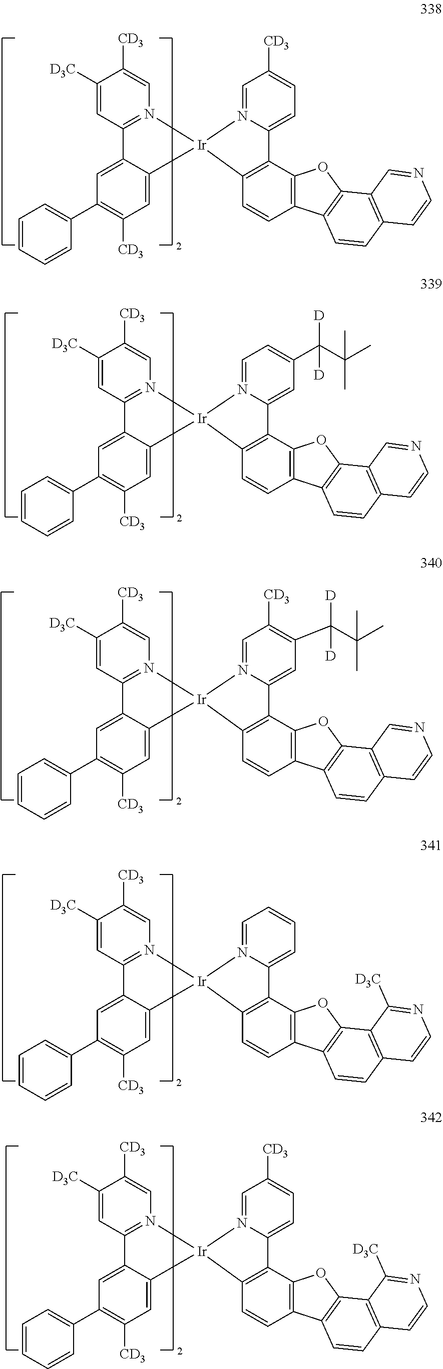

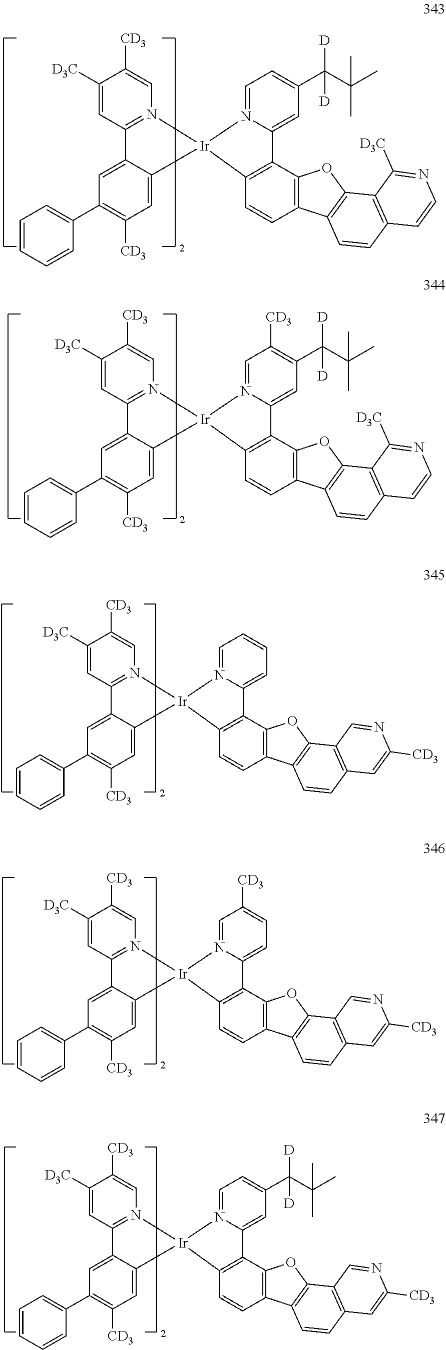

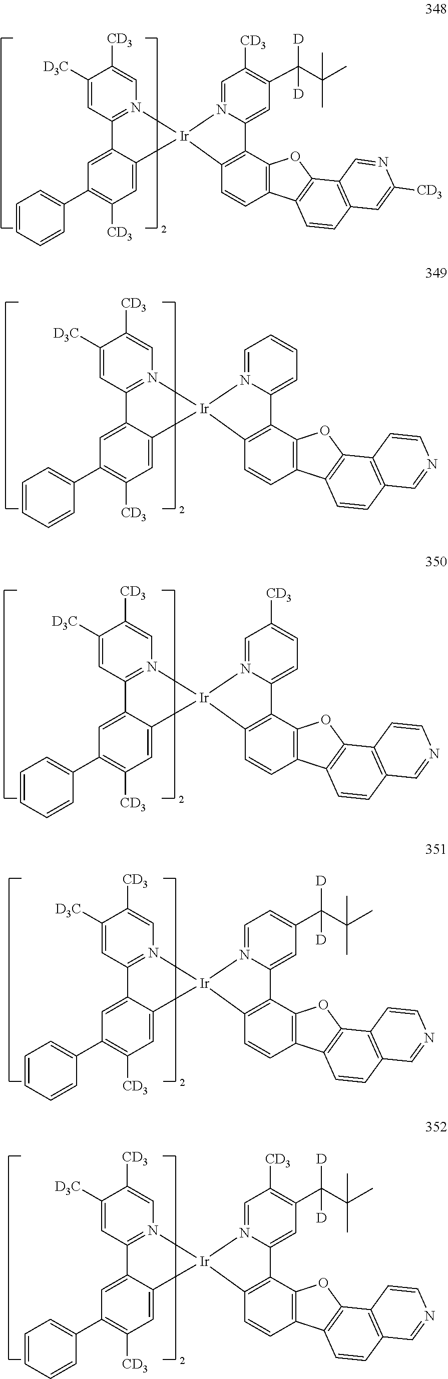

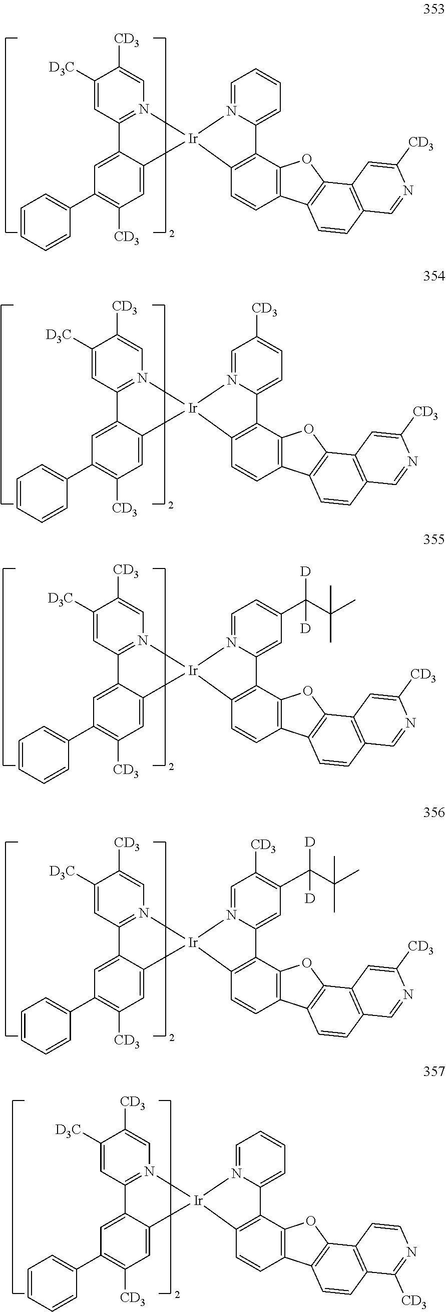

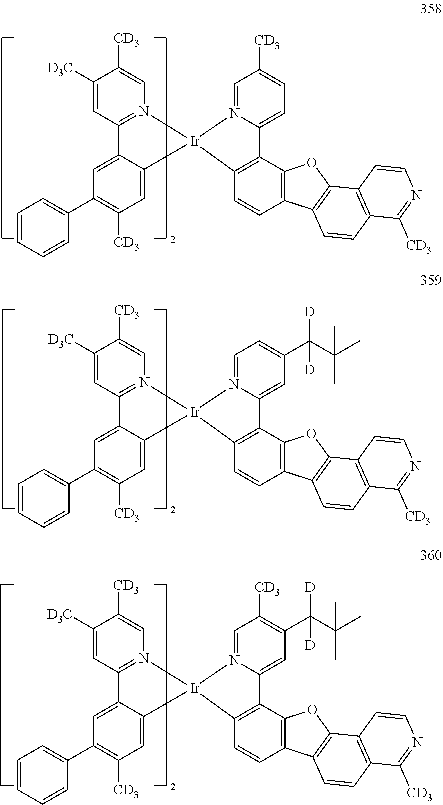

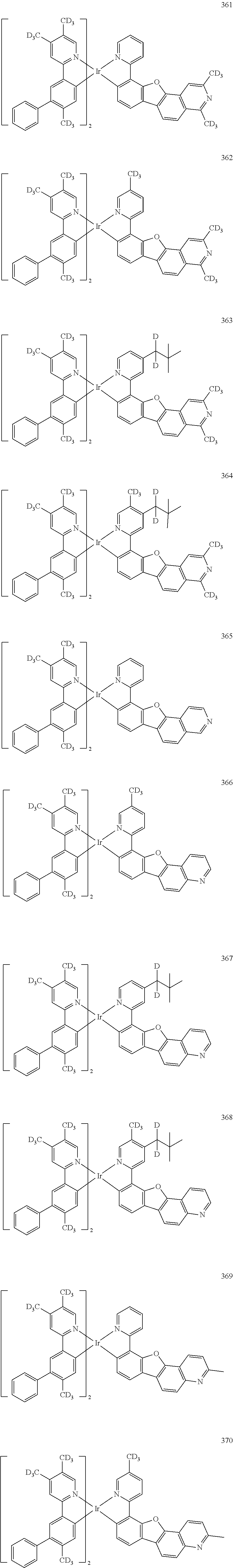

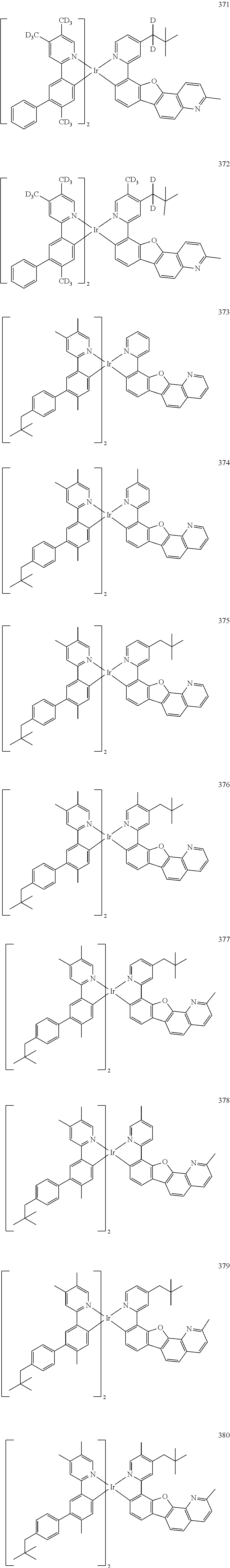

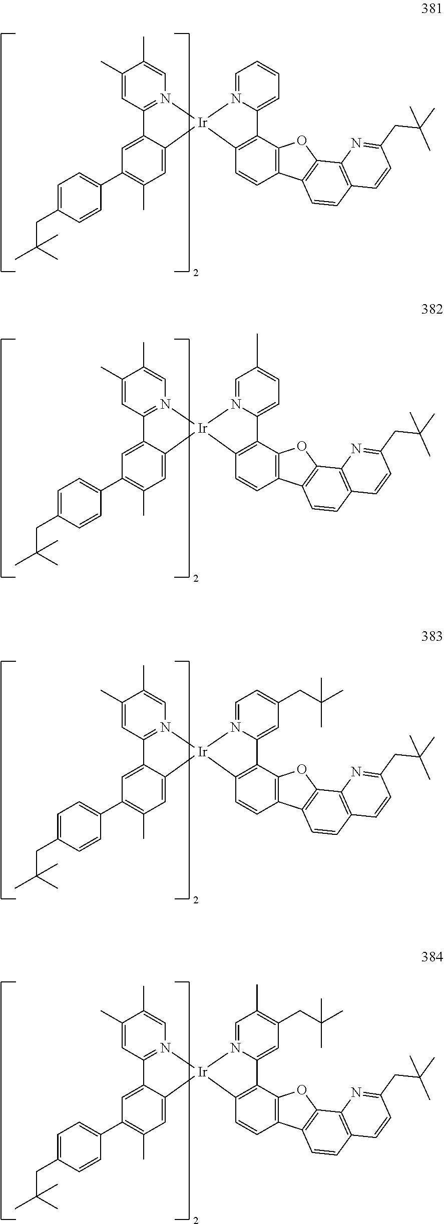

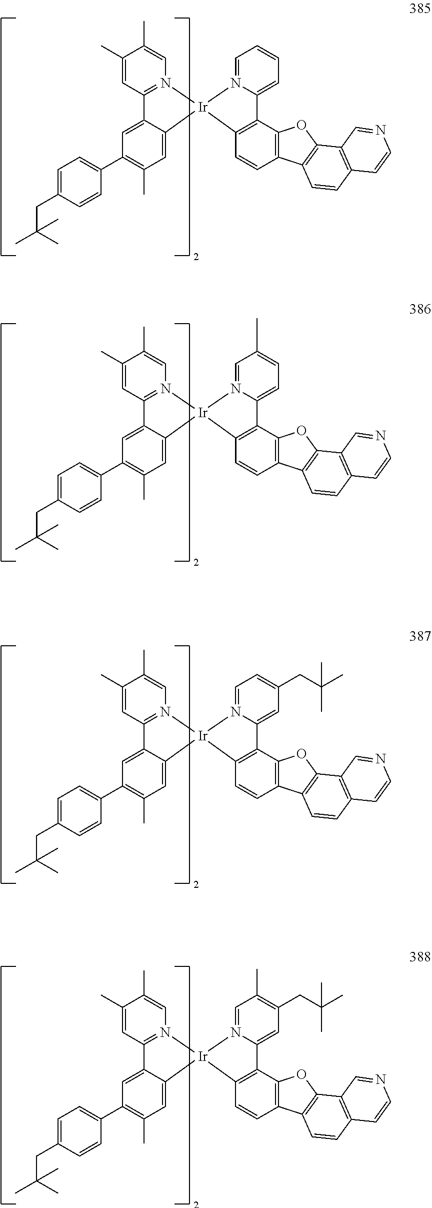

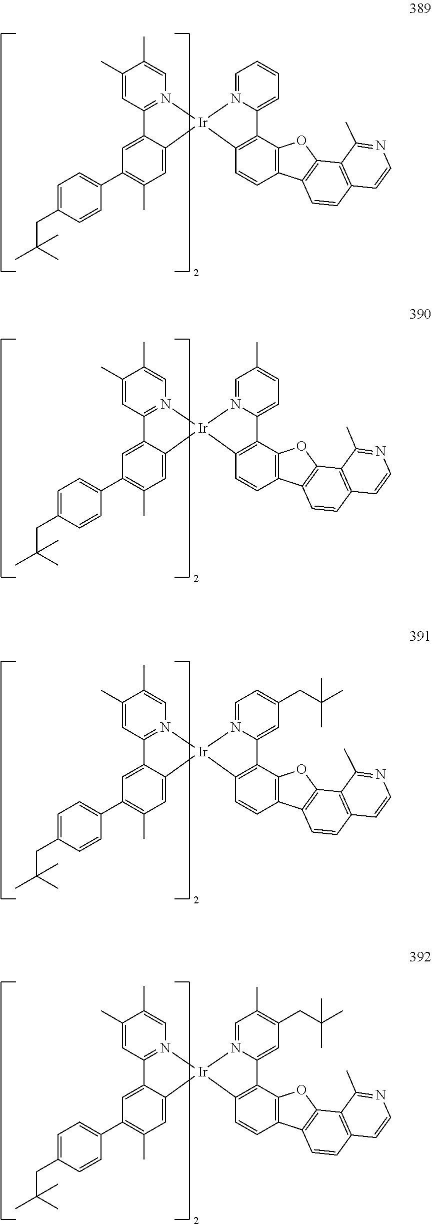

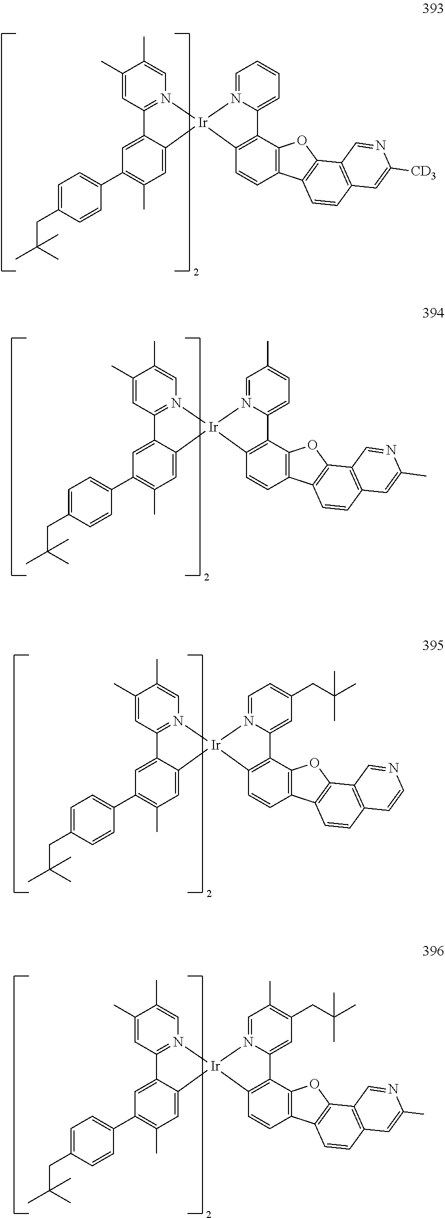

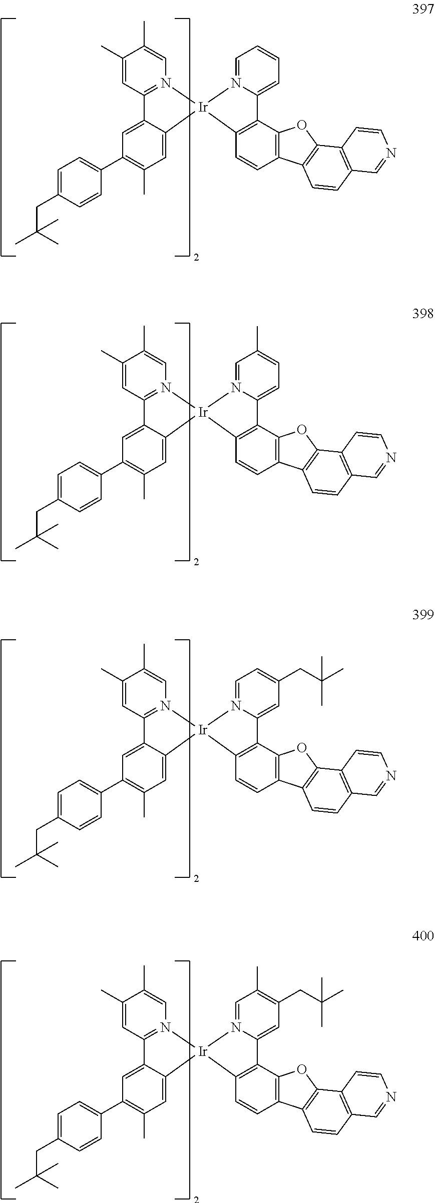

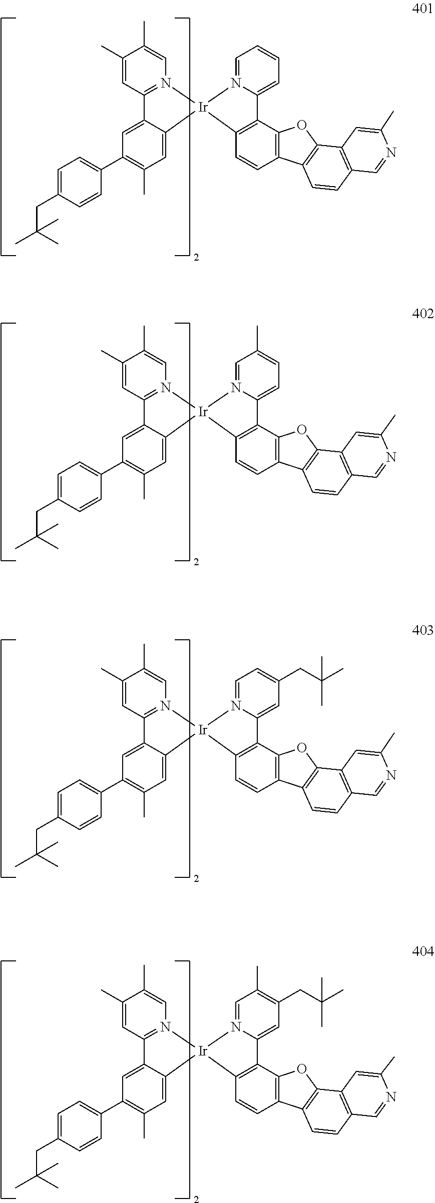

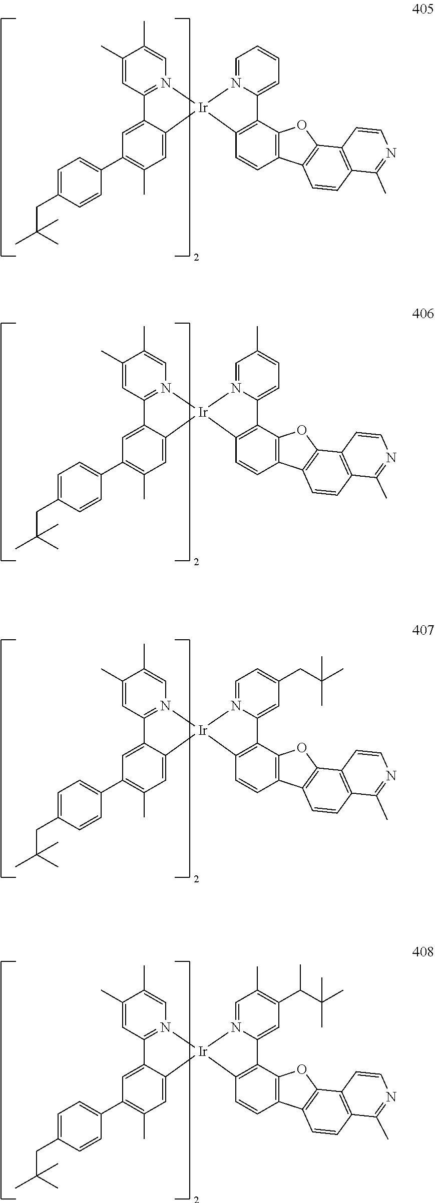

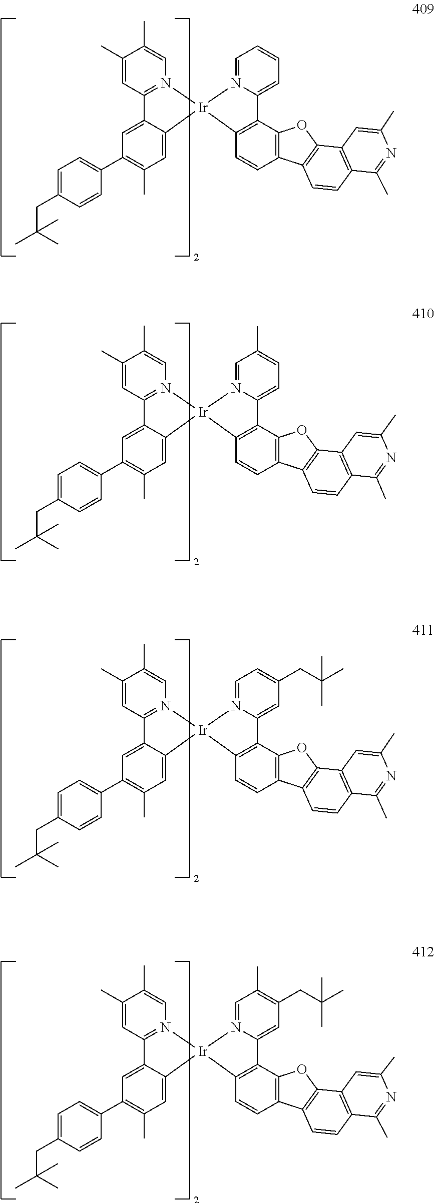

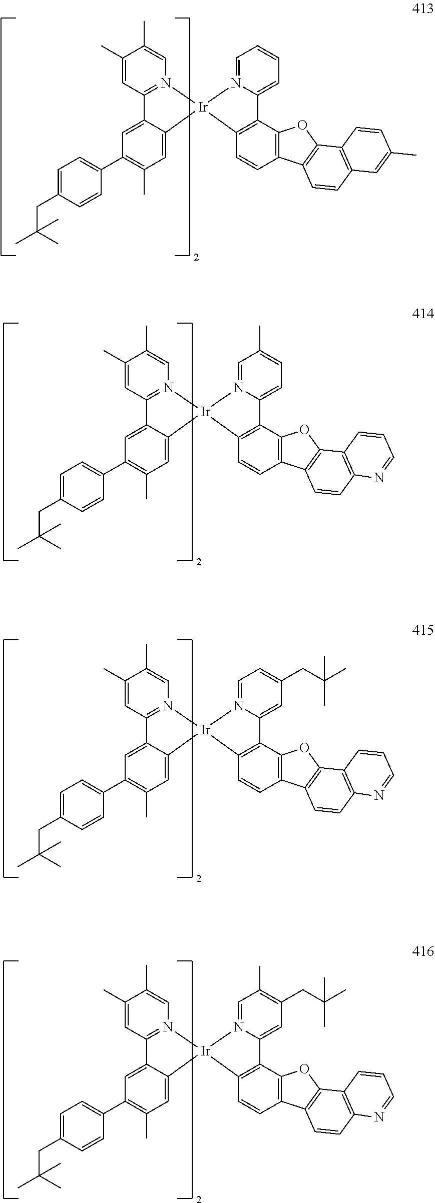

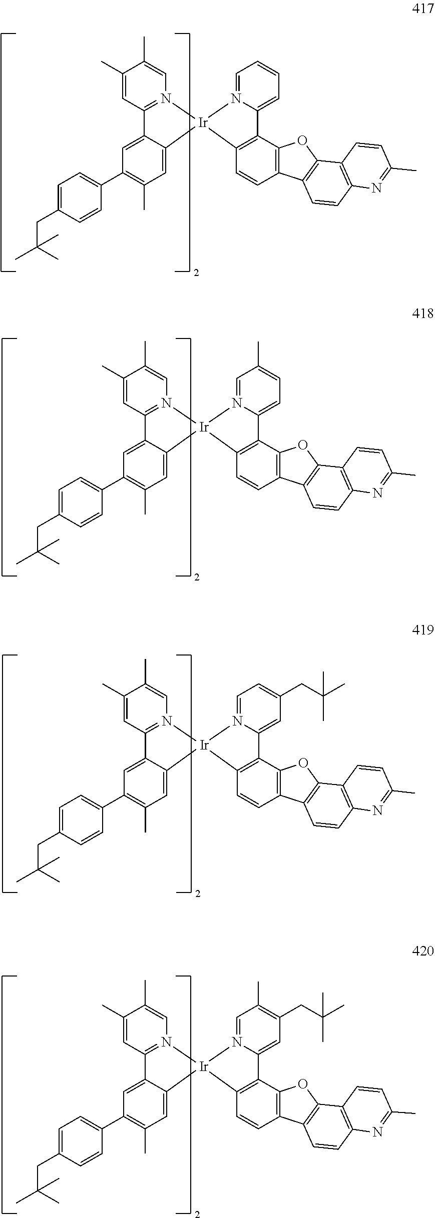

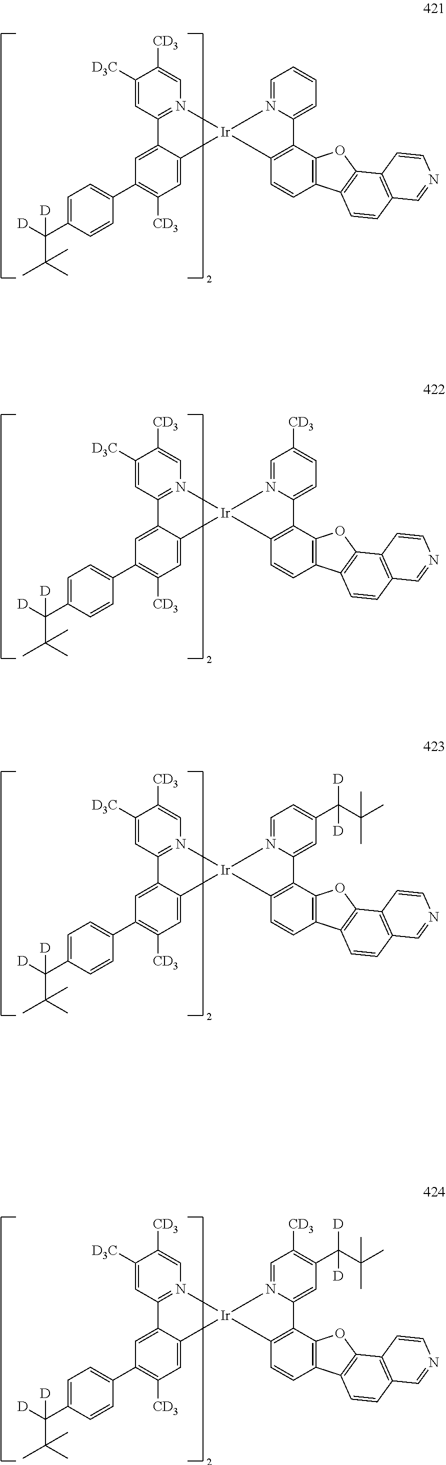

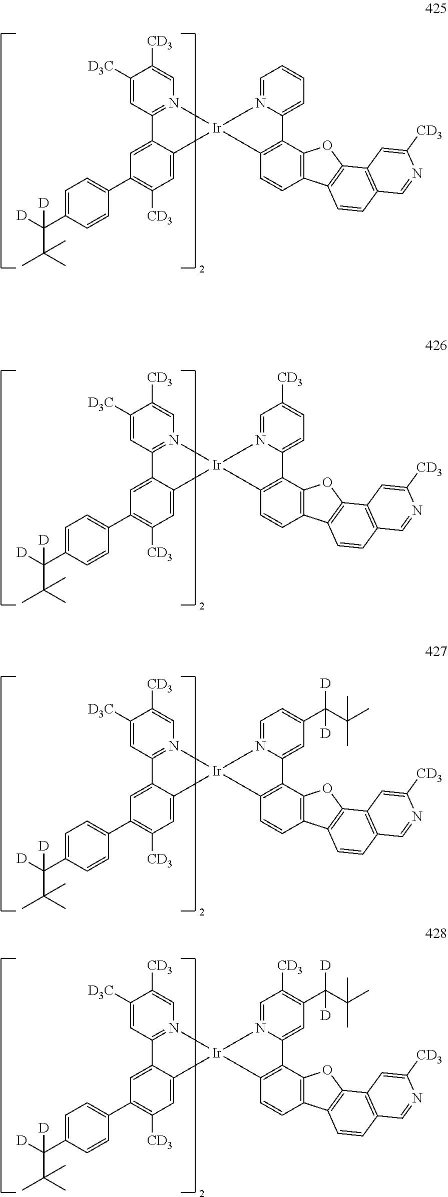

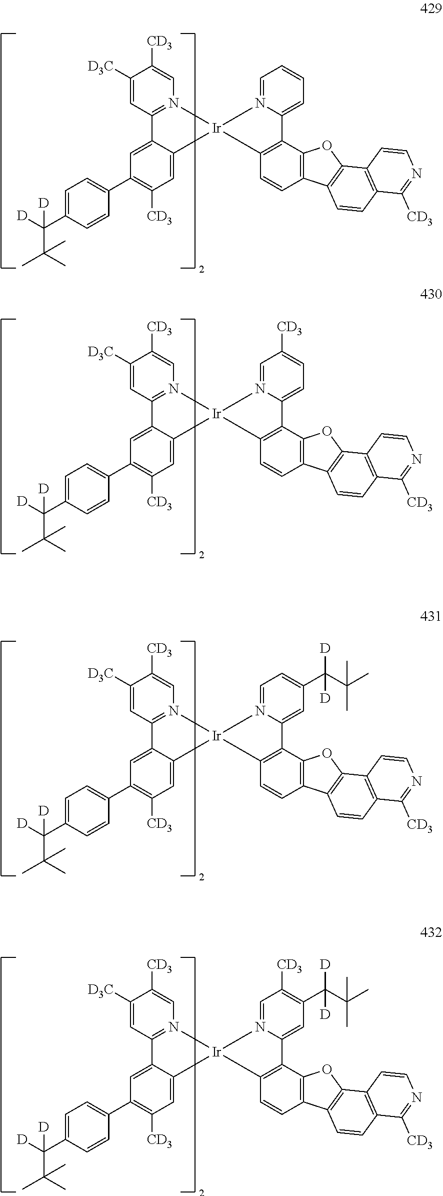

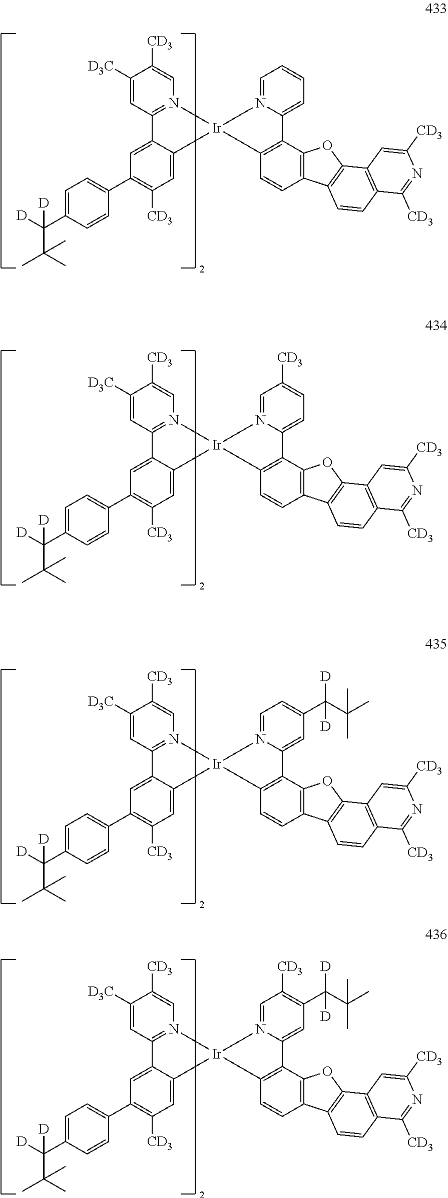

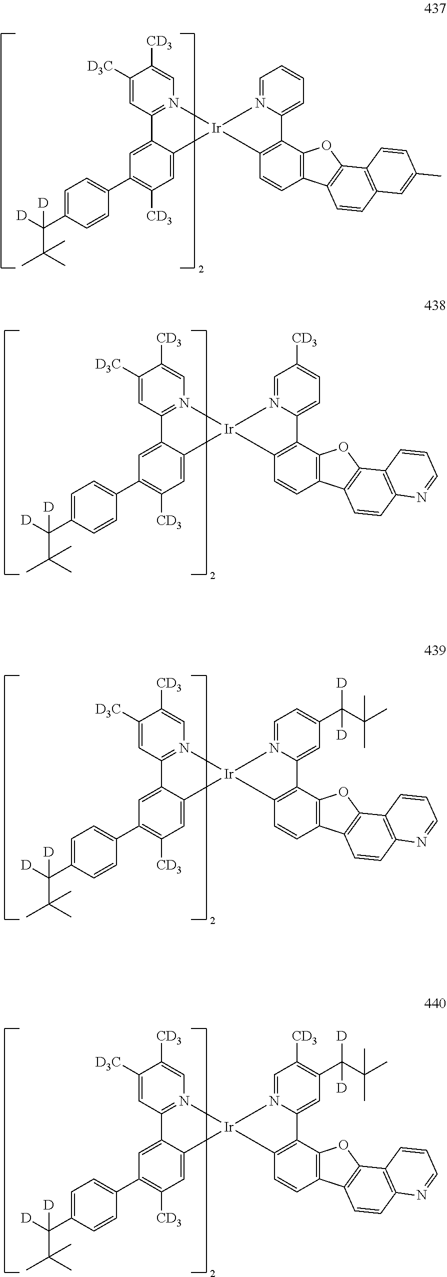

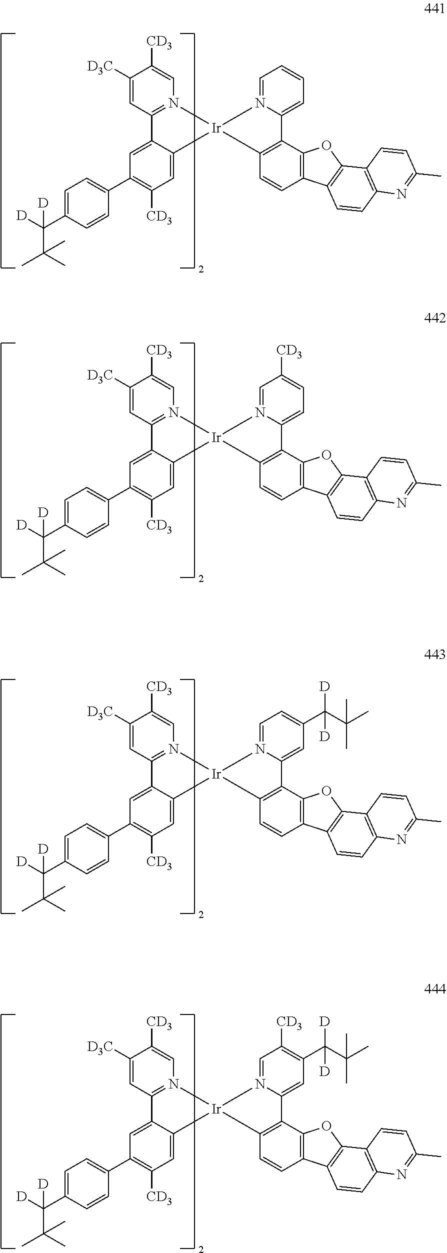

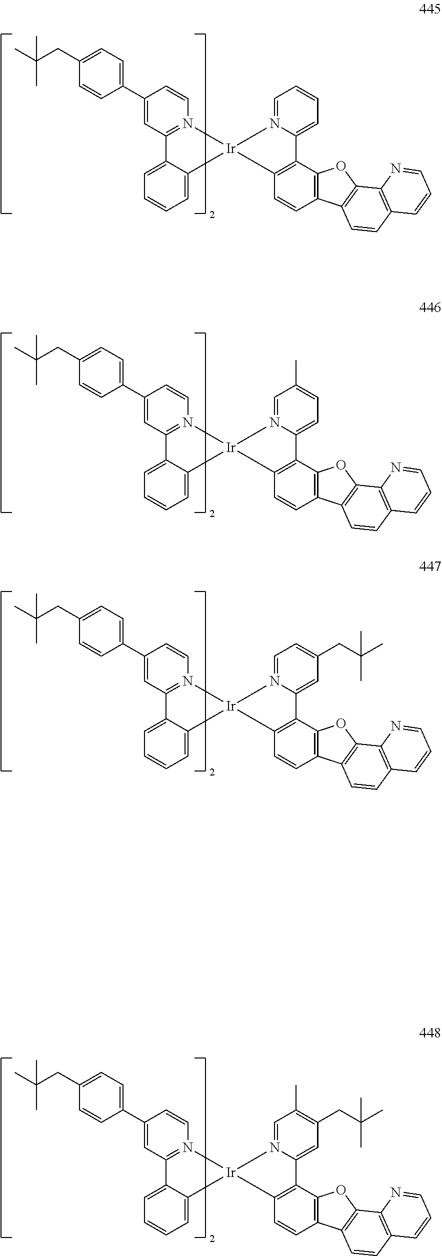

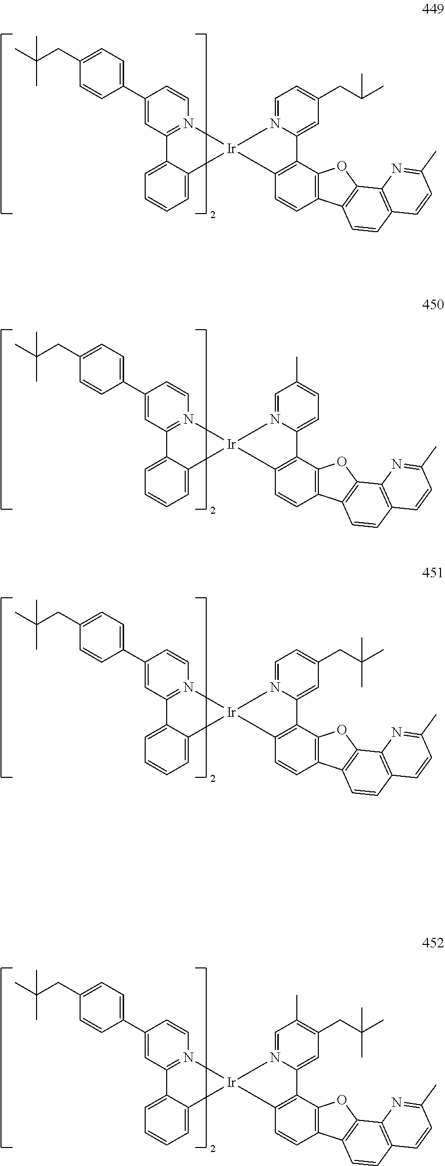

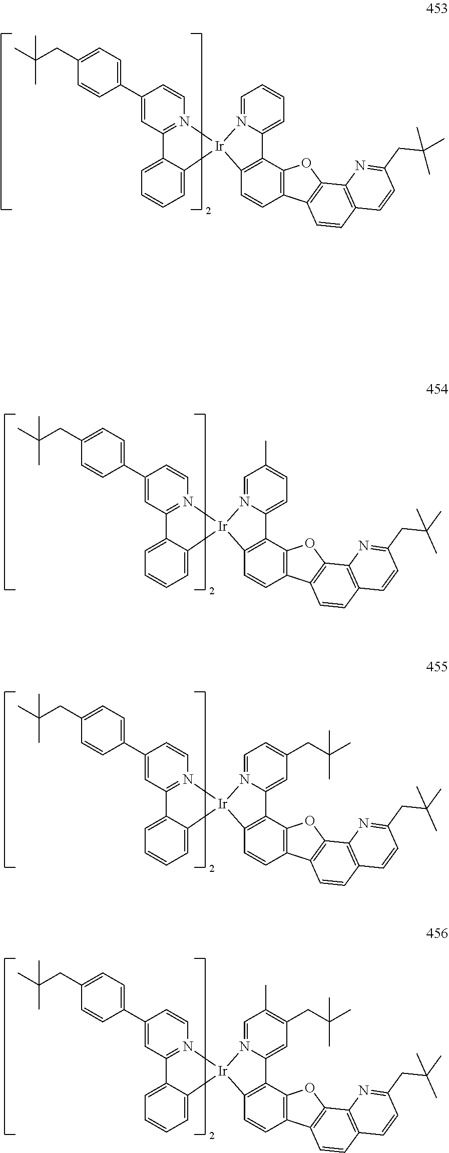

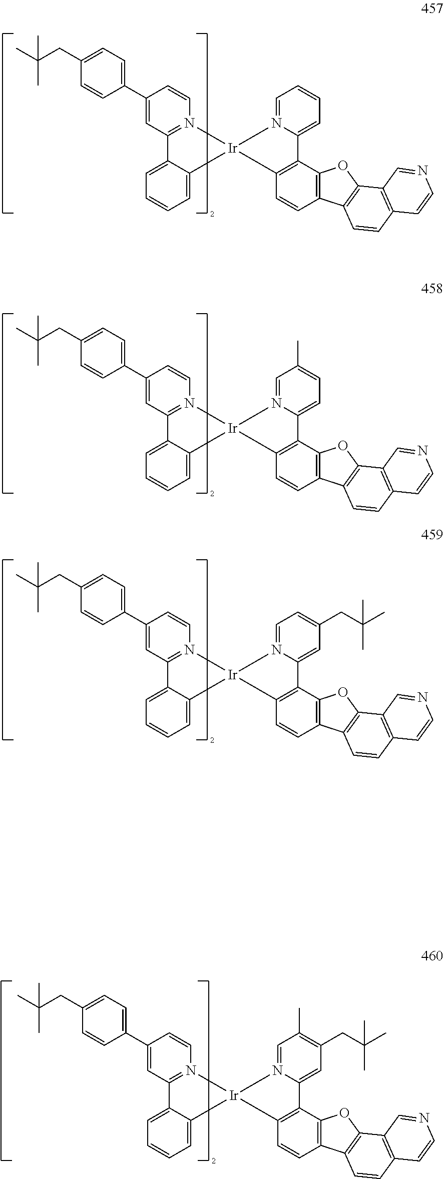

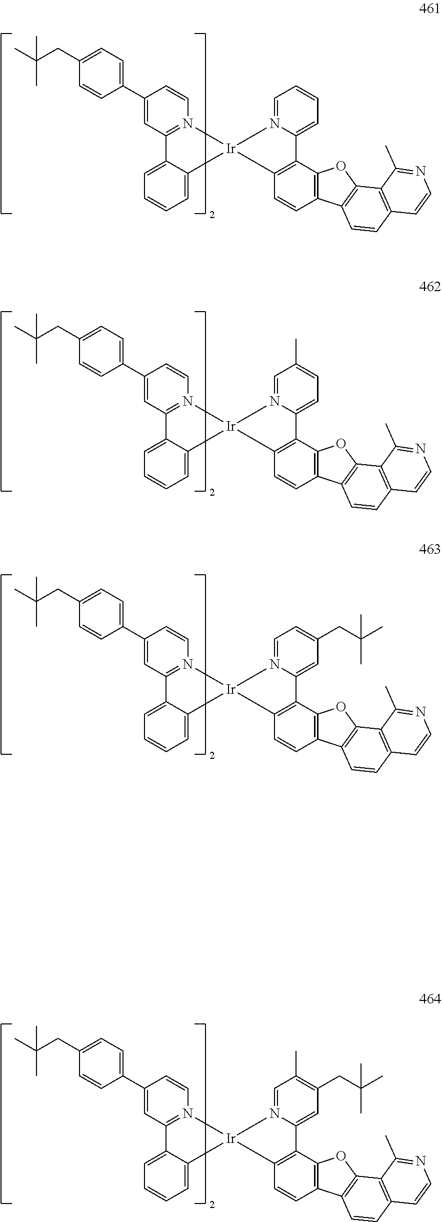

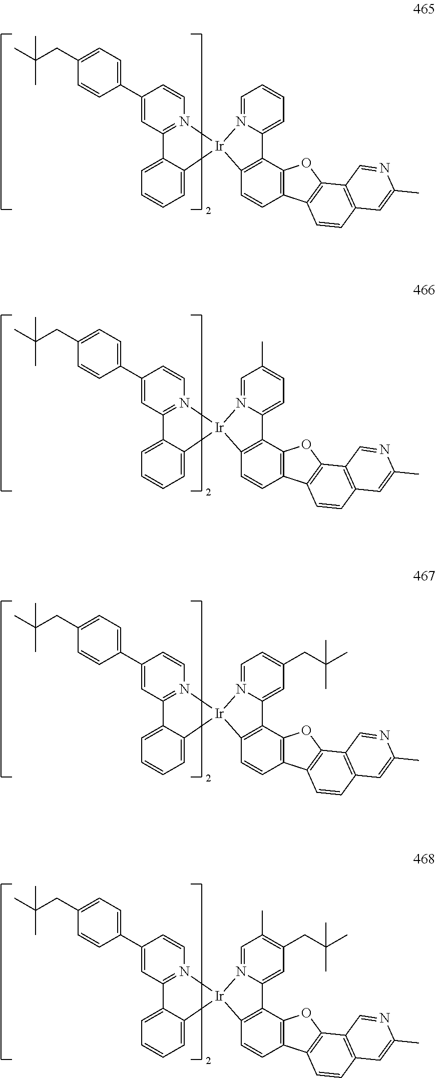

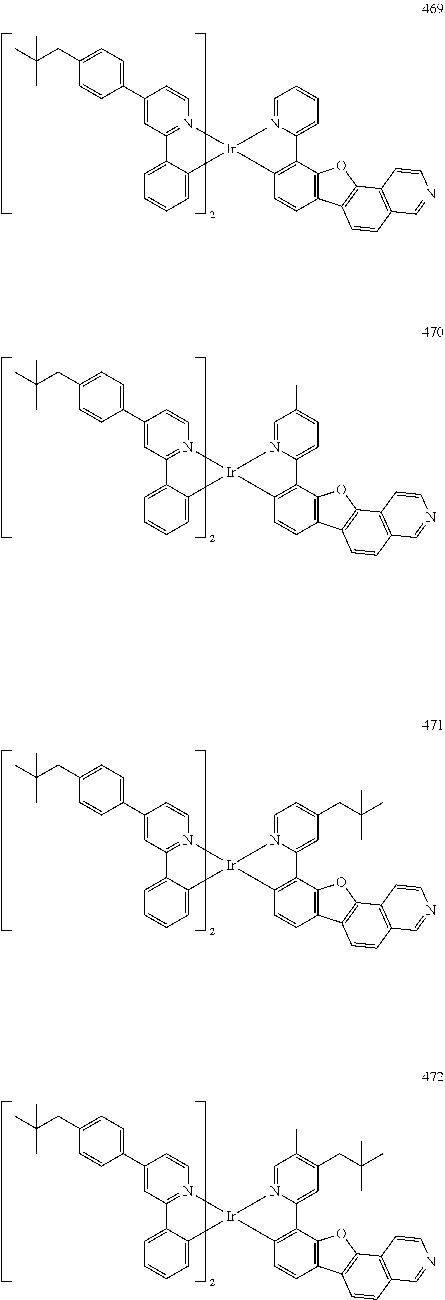

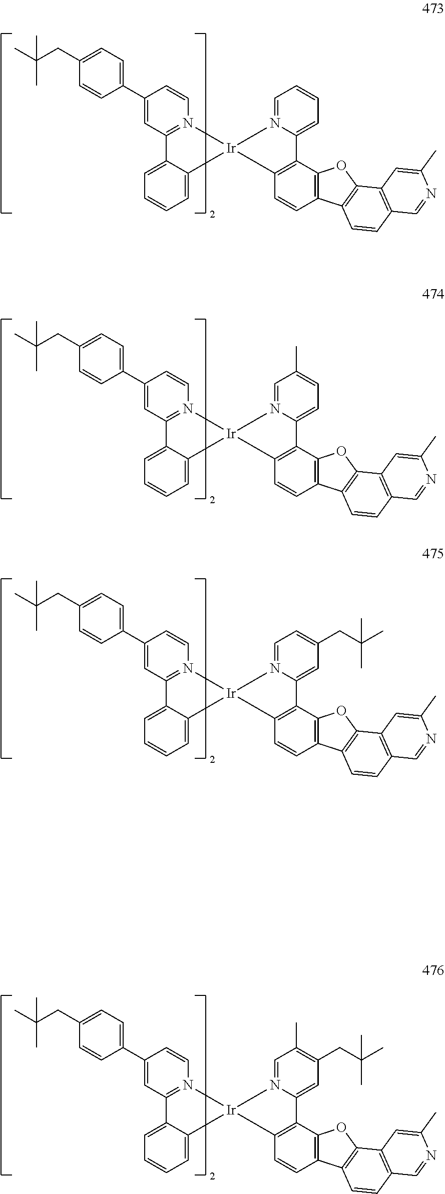

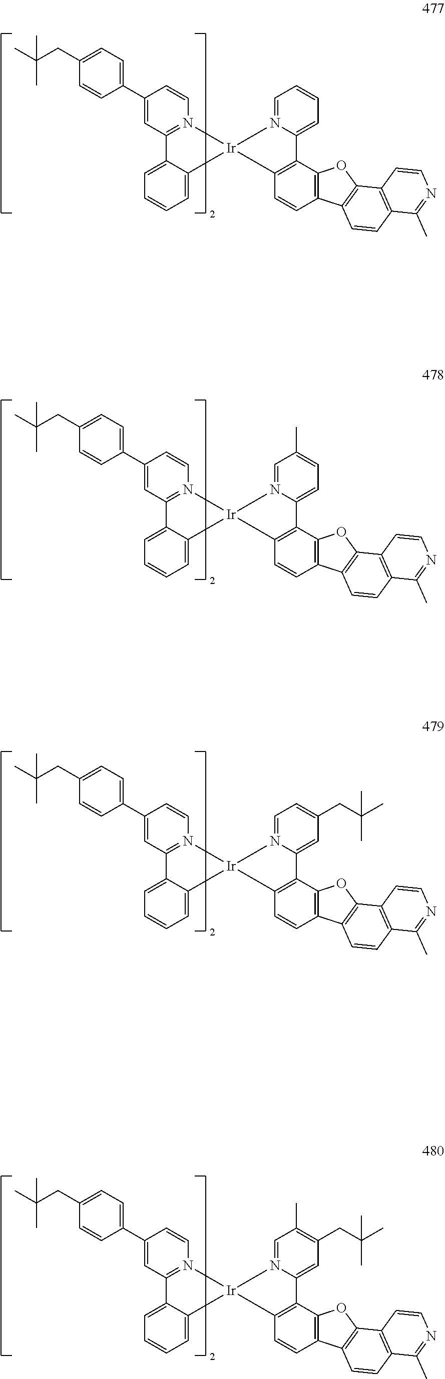

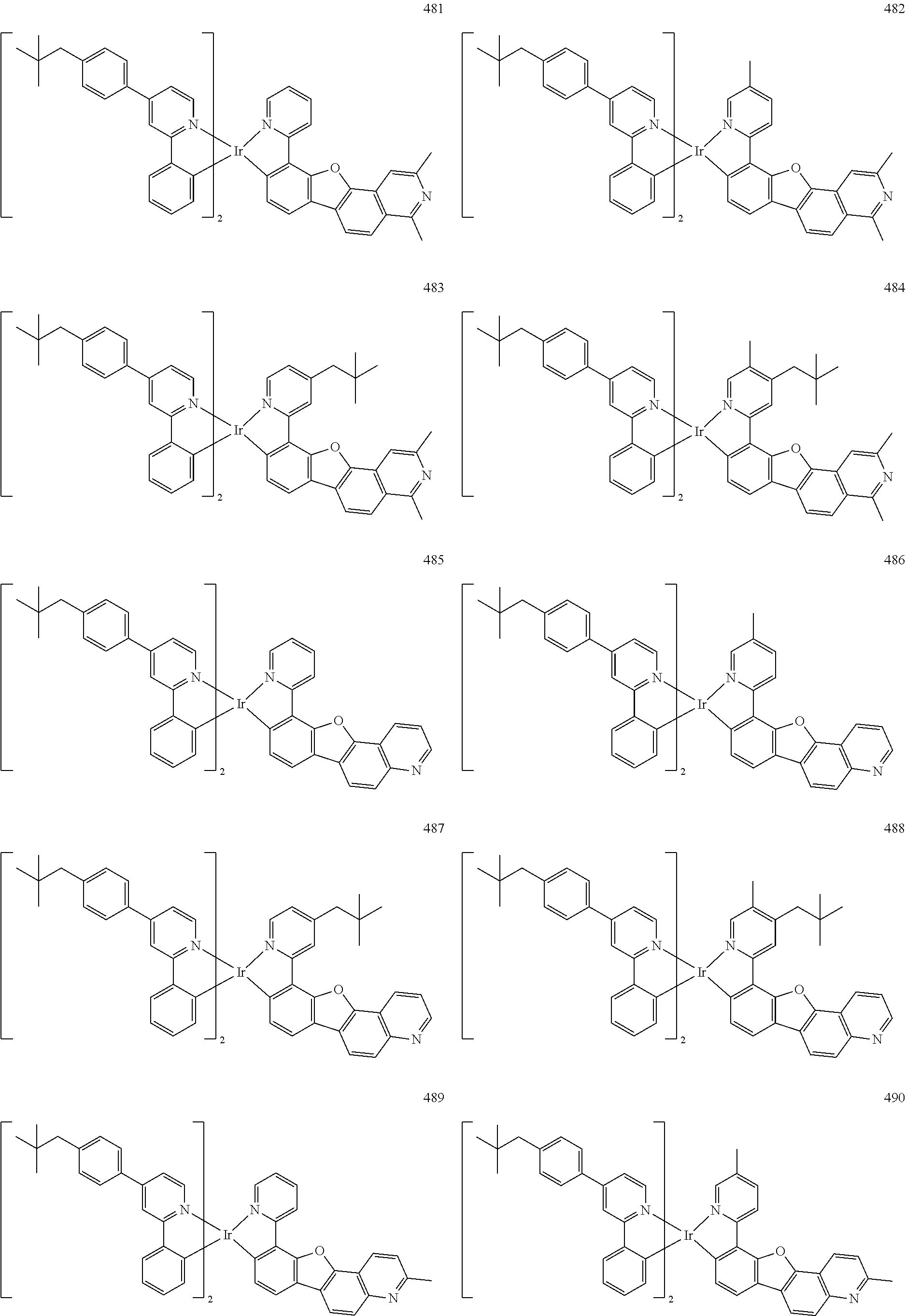

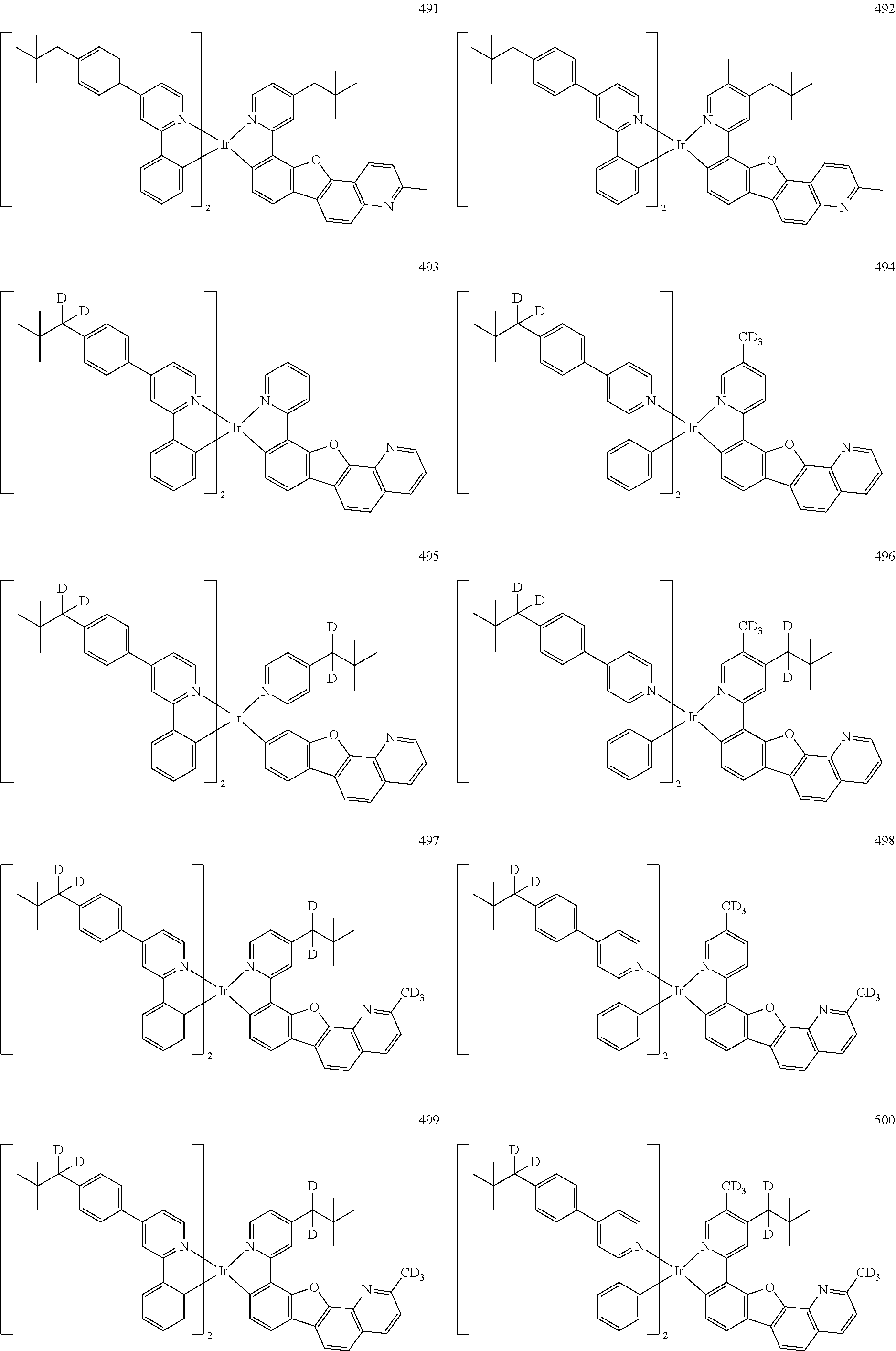

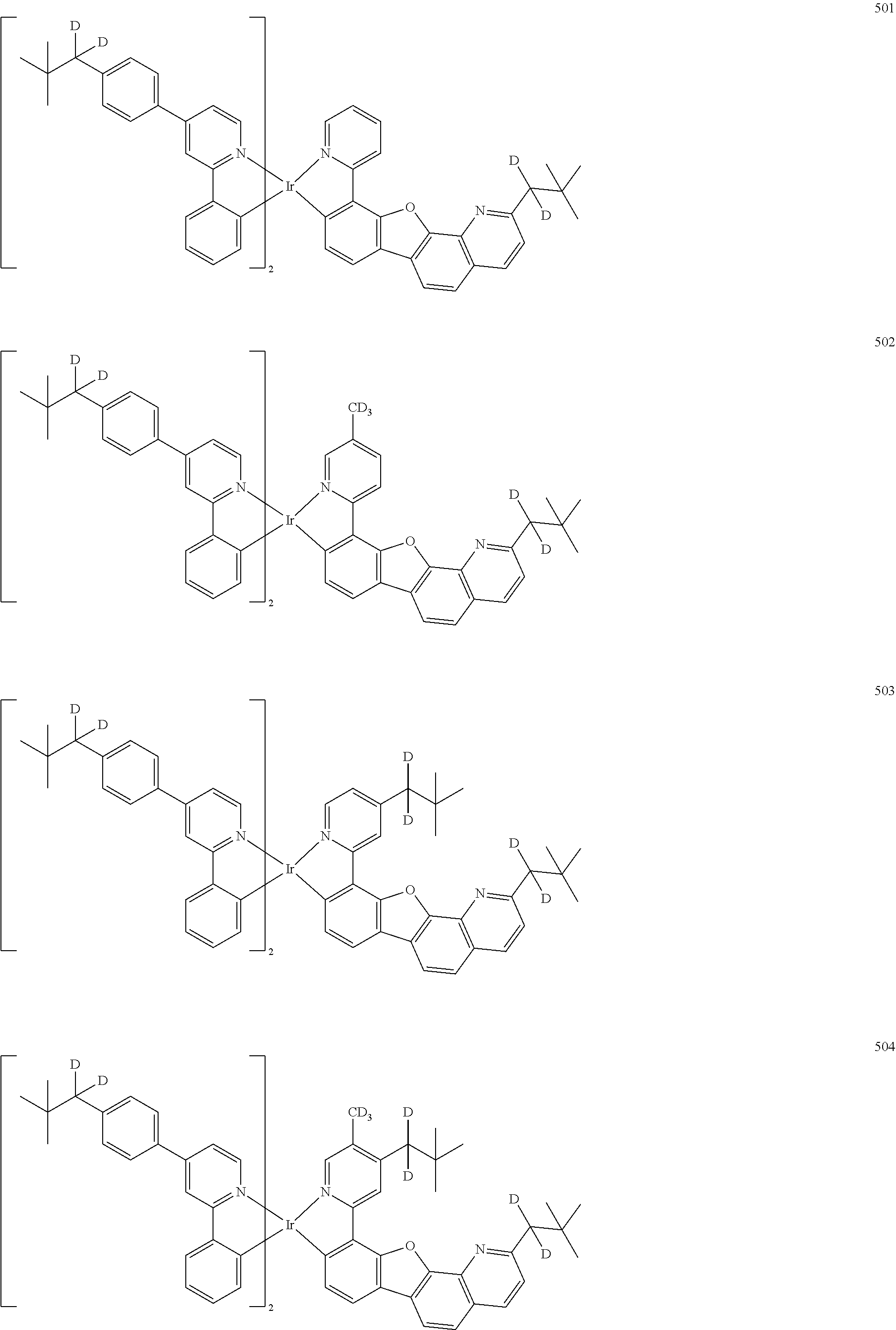

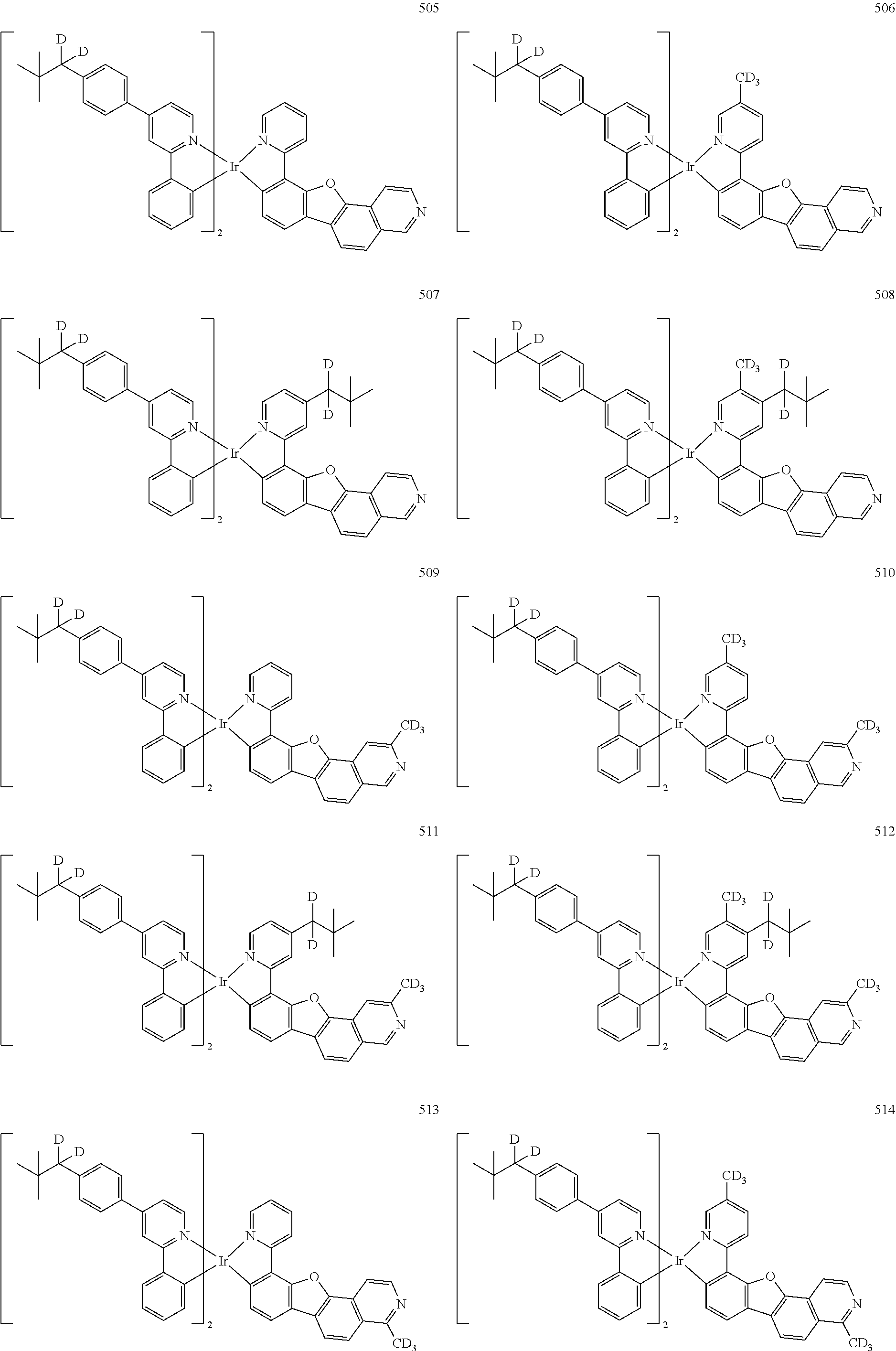

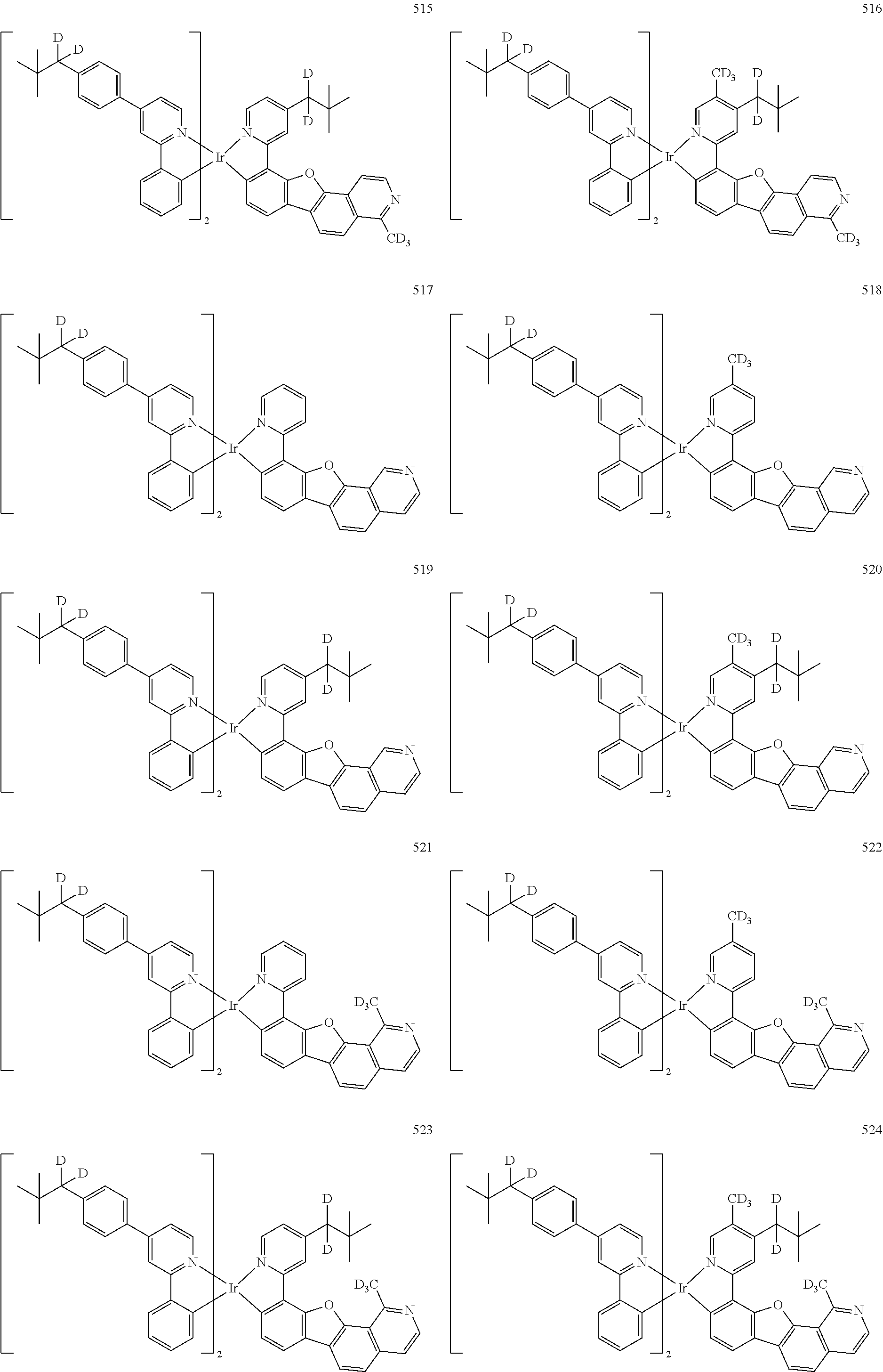

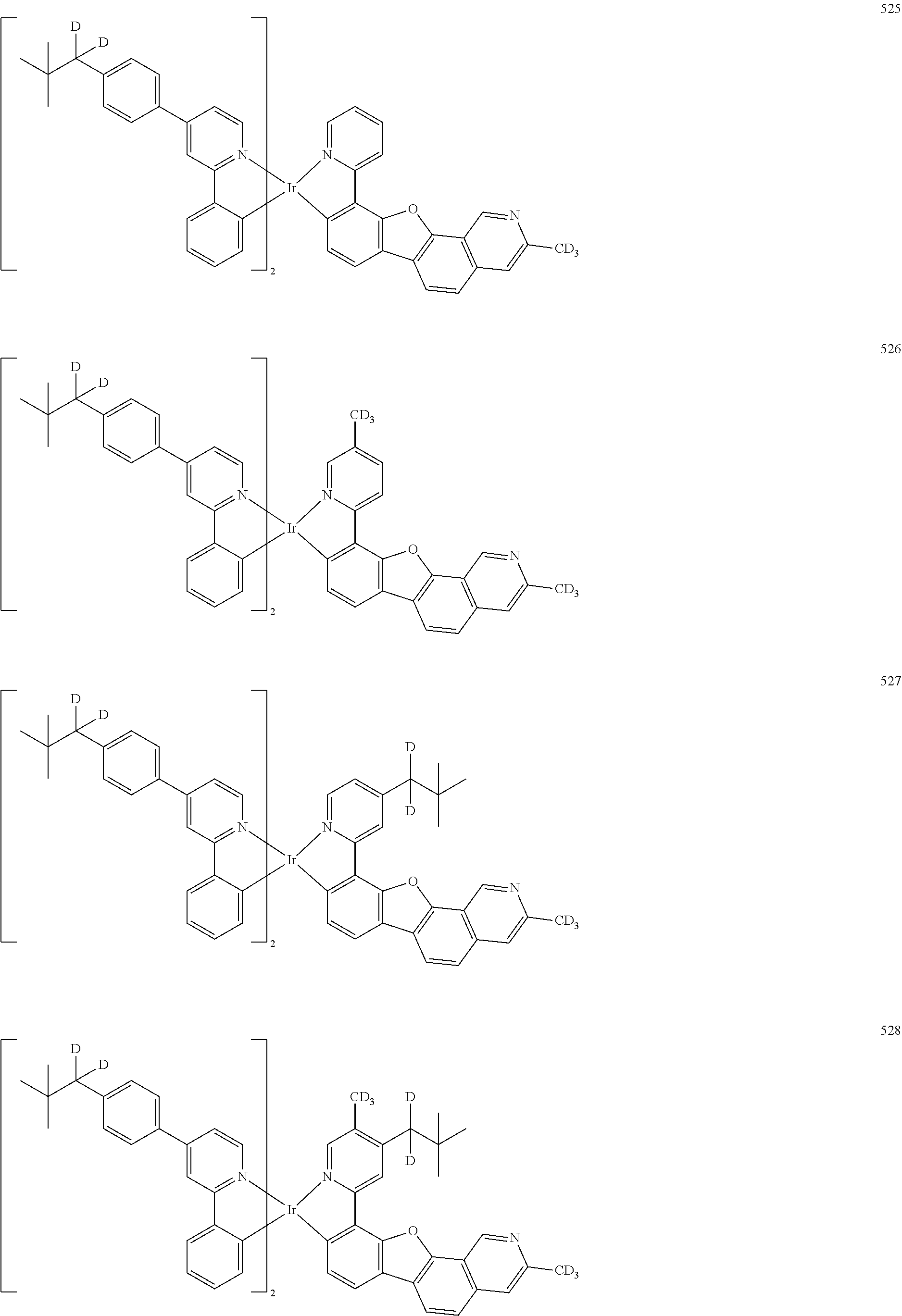

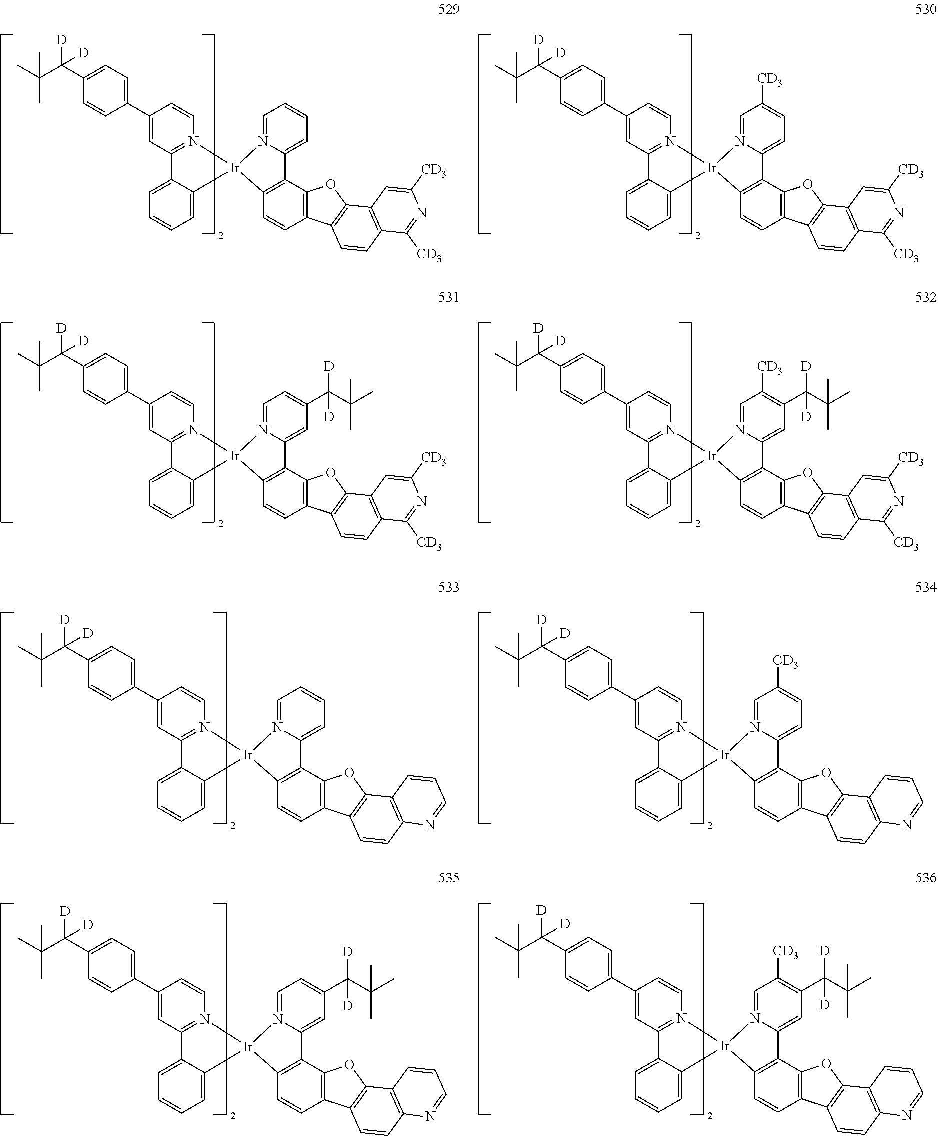

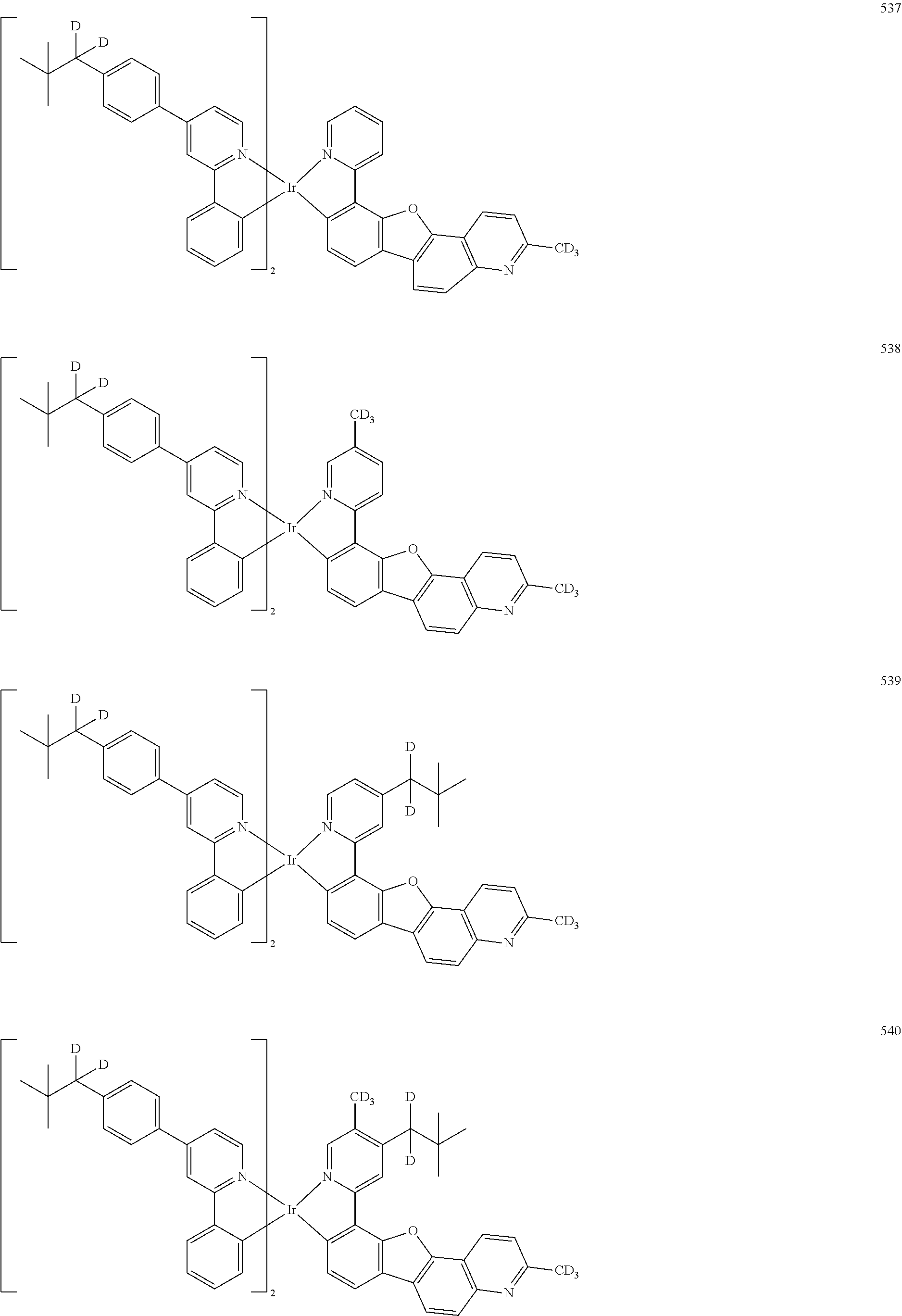

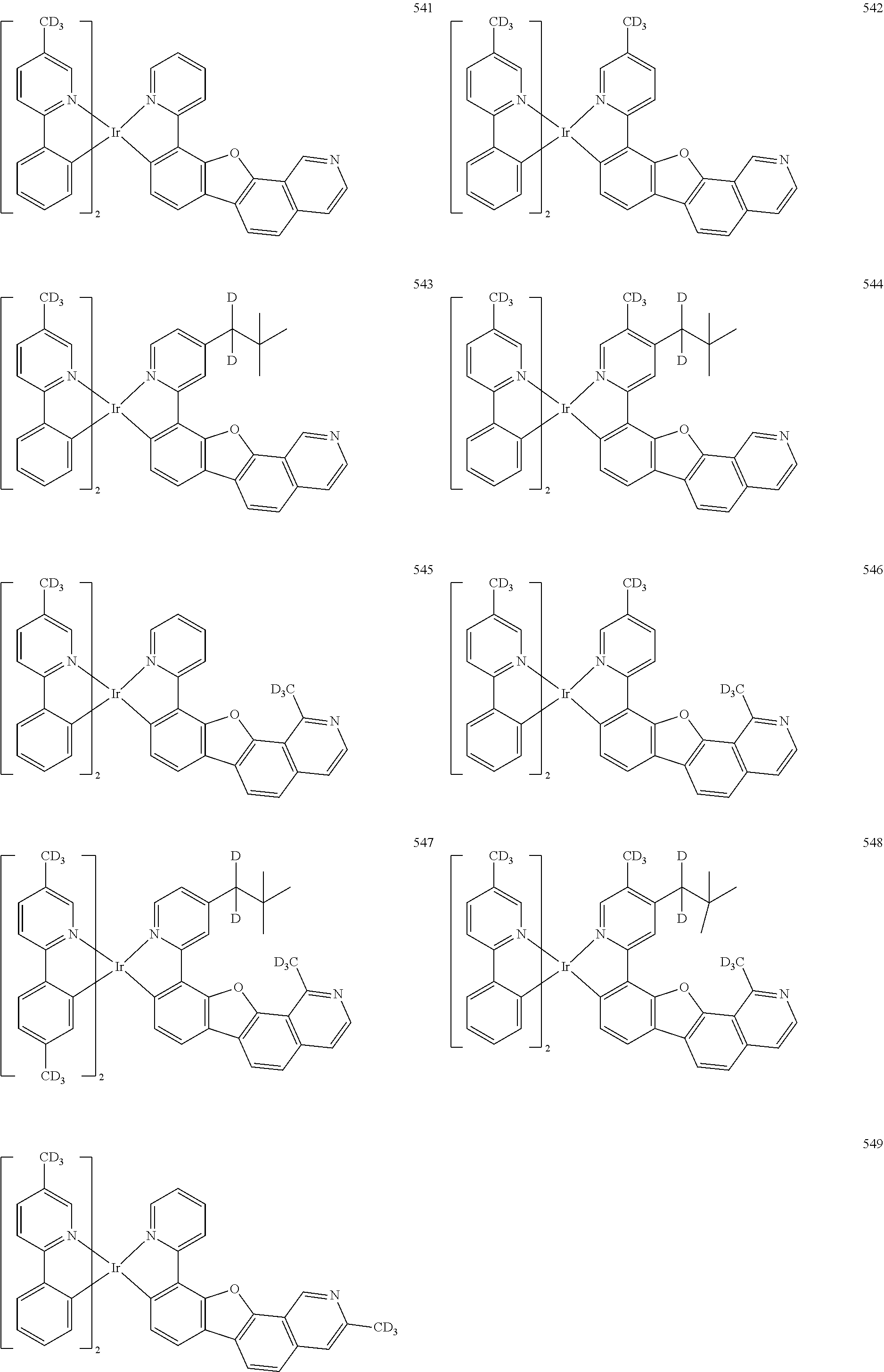

According to some example embodiments of the present disclosure, the organometallic compound represented by Chemical Formula 1 of the present disclosure may be used as a dopant material achieving red phosphorescence or a green phosphorescence. In some example embodiments of the present disclosure, the organometallic compound represented by Chemical Formula 1 may be used as a dopant material achieving the green phosphorescence.

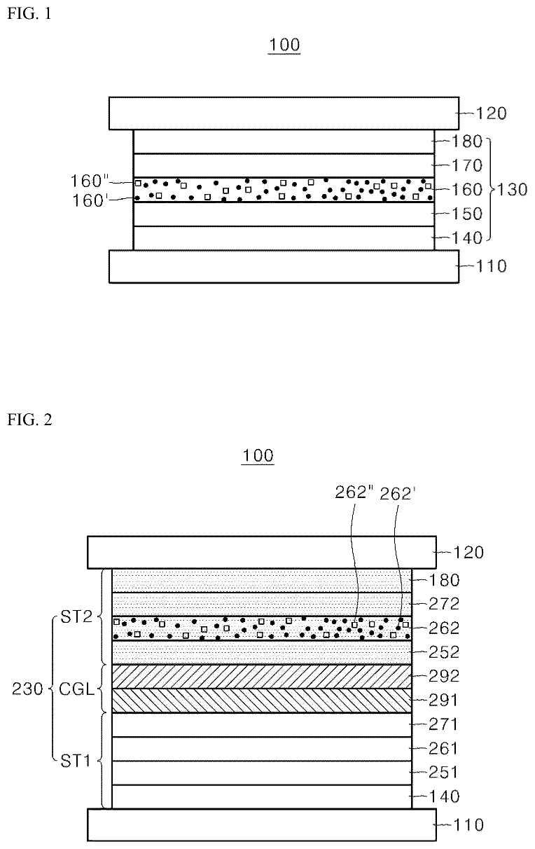

According to example embodiments of the present disclosure as illustrated in FIG. 1, an organic light-emitting diode 100 may be provided which includes a first electrode 110; a second electrode 120 facing the first electrode 110; and an organic layer 130 disposed between the first electrode 110 and the second electrode 120. The organic layer 130 may include a light-emitting layer 160, and the light-emitting layer 160 may include a host material 160′ and dopant 160″. The dopant 160″ may be made of or may include the organometallic compound represented by Chemical Formula 1. In addition, in the organic light-emitting diode 100, the organic layer 130 disposed between the first electrode 110 and the second electrode 120 may be formed by sequentially stacking a hole injection layer 140 (HIL), a hole transport layer 150 (HTL), a light-emitting layer 160 (EML), an electron transport layer 170 (ETL) and an electron injection layer 180 (EIL) on the first electrode 110. The second electrode 120 may be formed on or disposed on the electron injection layer 180, and a protective layer (not shown) may be formed thereon.

Further, although not illustrated in the example embodiment illustrated in FIG. 1, a hole transport auxiliary layer and/or an electron blocking layer may be further added between the hole transport layer 150 and the light-emitting layer 160.

The hole transport auxiliary layer may contain a compound having good hole transport properties, and may reduce a difference between HOMO energy levels of the hole transport layer 150 and the light-emitting layer 160 so as to adjust the hole injection properties. Thus, accumulation of holes at an interface between the hole transport auxiliary layer and the light-emitting layer 160 may be reduced, thereby reducing a quenching phenomenon in which excitons disappear at the interface due to polarons. Accordingly, deterioration of the element may be reduced and the element may be stabilized, thereby improving efficiency and lifespan thereof.

The electron blocking layer controls the movement of electrons and combination thereof with holes, thereby minimizing the chances of electrons flowing into the hole transport layer or preventing electrons from flowing into the hole transport layer, thereby improving the efficiency and lifespan of the organic light-emitting diode. The material of the electron blocking layer may include TCTA, tris[4-(diethylamino)phenyl]amine, N-(biphenyl-4-yl)-9,9-dimethyl-N-(4-(9-phenyl-9H-carbazol-3-yl)phenyl)-9H-fluoren-2-amine, TAPC, MTDATA, mCP, mCBP, CuPC, DNTPD, TDAPB, DCDPA, 2,8-bis(9-phenyl-9H-carbazol-3-yl)dibenzo[b,d]thiophene, etc. Alternatively, the electron blocking layer may include an inorganic compound. The inorganic compound may be selected from halide compounds such as LiF, NaF, KF, RbF, CsF, FrF, MgF₂, CaF₂, SrF₂, BaF₂, LiCi, NaCl, KCl, RbCl, CsCl, FrCl, etc. and oxides such as Li₂O, Li₂O₂, Na₂O, K₂O, Rb₂O, Rb₂O₂, Cs₂O, Cs₂O₂, LiAlO₂, LiBO₂, LiTaO₃, LiNbO₃, LiWO₄, Li₂CO, NaWO₄, KAlO₂, K₂SiO₃, B₂O₅, Al₂O₃, SiO₂, etc. However, the present disclosure is not necessarily limited thereto.

The first electrode 110 may act as a positive electrode, and may be made of or may include ITO, IZO, tin-oxide, or zinc-oxide as a conductive material having a relatively large work function value. However, the present disclosure is not limited thereto.

The second electrode 120 may act as a negative electrode, and may include Al, Mg, Ca, or Ag as a conductive material having a relatively small work function value, or an alloy or combinations thereof. However, the present disclosure is not limited thereto.

The hole injection layer 140 may be positioned between the first electrode 110 and the hole transport layer 150. The hole injection layer 140 may have a function of improving interface characteristics between the first electrode 110 and the hole transport layer 150, and may be selected from a material having appropriate conductivity. The hole injection layer 140 may include a compound selected from the group consisting of MTDATA, CuPc, TCTA, HATCN, TDAPB, PEDOT/PSS, and N1,N1′-([1,1′-biphenyl]-4,4′-diyl)bis(N1,N4,N4)-triphenylbenzene-1,4-diamine). In some example embodiments of the present disclosure, the hole injection layer 140 may include N1,N1′-([1,1′-biphenyl]-4,4′-diyl)bis(N1,N4,N4-triphenylbenzene-1,4-diamine). However, the present disclosure is not limited thereto.

The hole transport layer 150 may be positioned adjacent to the light-emitting layer and between the first electrode 110 and the light-emitting layer 160. A material of the hole transport layer 150 may include a compound selected from the group consisting of TPD, NPB, CBP, N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl)biphenyl)-4-amine, etc. In some example embodiments of the present disclosure, the material of the hole transport layer 150 may include NPB. However, the present disclosure is not limited thereto.

According to the present disclosure, the light-emitting layer 160 may be formed by doping a host material 160′ with the organometallic compound represented by Chemical Formula 1 as a dopant 160″ in order to improve luminous efficiency of the organic light-emitting diode 100. The dopant 160″ may be used as a green or red light-emitting material. In some example embodiments of the present disclosure, the dopant 160″ may be used as a green phosphorescent material.

A doping concentration of the dopant 160″ according to the present disclosure may be adjusted to be within a range of 1 to 30% by weight based on a total weight of the host material 160′. However, the disclosure is not limited thereto. For example, the doping concentration may be in a range of 2 to 20 wt %, for example, 3 to 15 wt %, for example, 5 to 10 wt %, for example, 3 to 8 wt %, for example, 2 to 7 wt %, for example, 5 to 7 wt %, or for example, 5 to 6 wt %.

The light-emitting layer 160 according to the present disclosure contains the host material 160′, which may be known in the art and may achieve an effect of the present disclosure while the light-emitting layer 160 contains the organometallic compound represented by Chemical Formula 1 as the dopant 160″. For example, in accordance with the present disclosure, the host material 160′ may include a compound containing a carbazole group, and may include, for example, one host material selected from the group consisting of CBP (carbazole biphenyl), mCP (1,3-bis(carbazol-9-yl), and the like. However, the disclosure is not limited thereto.

Further, the electron transport layer 170 and the electron injection layer 180 may be sequentially stacked between the light-emitting layer 160 and the second electrode 120. A material of the electron transport layer 170 may have high electron mobility such that electrons may be stably supplied to the light-emitting layer under smooth electron transport.

For example, the material of the electron transport layer 170 may be known in the art and may include a compound selected from the group consisting of Alq3 (tris(8-hydroxyquinolino)aluminum), Liq (8-hydroxyquinolinolatolithium), PBD (2-(4-biphenylyl)-5-(4-tert-butylphenyl)-1,3,4-oxadiazole), TAZ (3-(4-biphenyl)4-phenyl-5-tert-butylphenyl-1,2,4-triazole), spiro-PBD, BAlq (bis(2-methyl-8-quinolinolate)-4-(phenylphenolato)aluminium), SAlq, TPBi (2,2′,2-(1,3,5-benzinetriyl)-tris(1-phenyl-1-H-benzimidazole), oxadiazole, triazole, phenanthroline, benzoxazole, benzothiazole, and 2-(4-(9,10-di(naphthalen-2-yl)anthracen-2-yl)phenyl)-1-phenyl-1H-benzo[d]imidazole. In some example embodiments of the present disclosure, the material of the electron transport layer 170 may include 2-(4-(9,10-di(naphthalen-2-yl)anthracen-2-yl)phenyl)-1-phenyl-1H-benzo[d]imidazole. However, the present disclosure is not limited thereto.

The electron injection layer 180 serves to facilitate electron injection. A material of the electron injection layer may be known in the art and may include a compound selected from the group consisting of Alq3 (tris(8-hydroxyquinolino)aluminum), PBD, TAZ, spiro-PBD, BAlq, SAlq, etc. However, the present disclosure is not limited thereto. Alternatively, the electron injection layer 180 may be made of or may include a metal compound. The metal compound may include, for example, one or more selected from the group consisting of Liq, LiF, NaF, KF, RbF, CsF, FrF, BeF₂, MgF₂, CaF₂, SrF₂, BaF₂, and RaF₂. However, the present disclosure is not limited thereto.

The organic light-emitting diode according to the present disclosure may be embodied as a white light-emitting diode having a tandem structure. In the tandem organic light-emitting diode according to an example embodiment of the present disclosure, single light-emitting stacks (or light-emitting parts) are formed as two or more connected structure via a charge generation layer (CGL). The organic light-emitting diode may include the first and the second electrodes on a substrate, facing each other, and at least two light-emitting stacks each having a light-emitting layer being disposed between the first and the second electrodes so as to emit light in a specific wavelength band. The plurality of light-emitting stacks may emit light of the same color or different colors. In addition, one or more light-emitting layers may be included in one light-emitting stack, and the plurality of light-emitting layers may emit light of the same color or different colors.

In this case, the light-emitting layer included in at least one of the plurality of light-emitting stacks may contain the organometallic compound represented by Chemical Formula 1 according to the present disclosure as the dopant. Adjacent ones of the plurality of light-emitting stacks in the tandem structure may be connected to each other via the charge generation layer CGL including an N-type charge generation layer and a P-type charge generation layer.

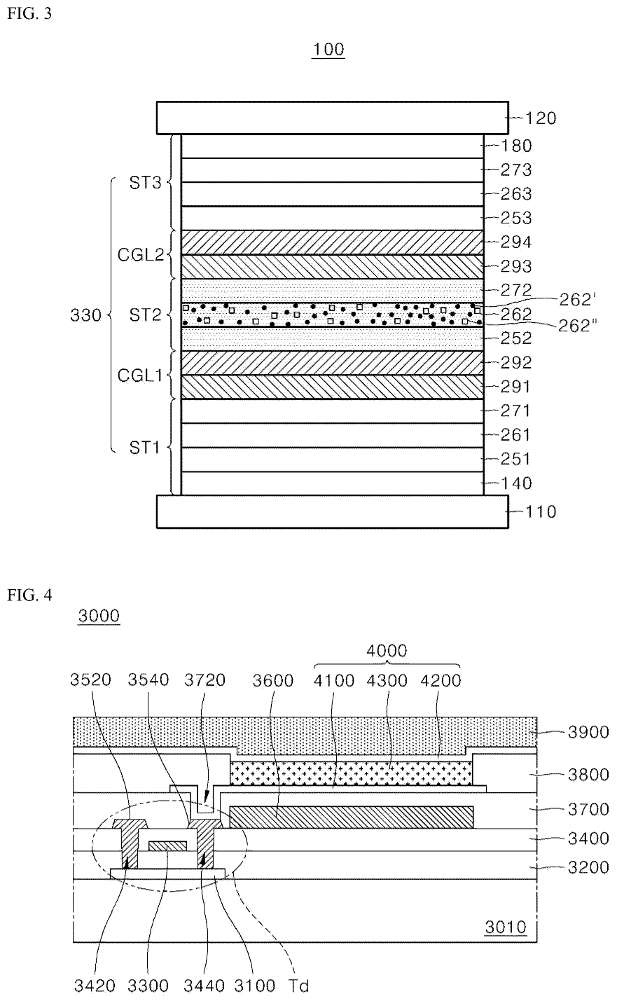

FIG. 2 and FIG. 3 are cross-sectional views schematically showing an organic light-emitting diode in a tandem structure having two light-emitting stacks and an organic light-emitting diode in a tandem structure having three light-emitting stacks, respectively, according to some example embodiments of the present disclosure.

As illustrated in the example embodiment of FIG. 2, an organic light-emitting diode 100 according to the present disclosure include a first electrode 110 and a second electrode 120 facing each other, and an organic layer 230 positioned between the first electrode 110 and the second electrode 120. The organic layer 230 may be positioned between the first electrode 110 and the second electrode 120 and may include a first light-emitting stack ST1 including a first light-emitting layer 261, a second light-emitting stack ST2 positioned between the first light-emitting stack ST1 and the second electrode 120 and including a second light-emitting layer 262, and the charge generation layer CGL positioned between the first and second light-emitting stacks ST1 and ST2. The charge generation layer CGL may include an N-type charge generation layer 291 and a P-type charge generation layer 292. At least one of the first light-emitting layer 261 and the second light-emitting layer 262 may contain the organometallic compound represented by Chemical Formula 1 according to the present disclosure as the dopant. For example, as illustrated in the example embodiment of FIG. 2, the second light-emitting layer 262 of the second light-emitting stack ST2 may contain a host material 262′, and dopant 262″ made of or including the organometallic compound represented by Chemical Formula 1 doped therein. Although not illustrated in the example embodiment of FIG. 2, the first and second light-emitting stacks ST1 and ST2 may each further include, in addition to the first light-emitting layer 261 and the second light-emitting layer 262, an additional light-emitting layer.

As illustrated in the example embodiment of FIG. 3, the organic light-emitting diode 100 according to the present disclosure include the first electrode 110 and the second electrode 120 facing each other, and an organic layer 330 positioned between the first electrode 110 and the second electrode 120. The organic layer 330 may be positioned between the first electrode 110 and the second electrode 120 and may include the first light-emitting stack ST1 including the first light-emitting layer 261, the second light-emitting stack ST2 including the second light-emitting layer 262, a third light-emitting stack ST3 including a third light-emitting layer 263, a first charge generation layer CGL1 positioned between the first and second light-emitting stacks ST1 and ST2, and a second charge generation layer CGL2 positioned between the second and third light-emitting stacks ST2 and ST3. The first charge generation layer CGL1 may include a N-type charge generation layers 291 and a P-type charge generation layer 292. The second charge generation layer CGL2 may include a N-type charge generation layers 293 and a P-type charge generation layer 294. At least one of the first light-emitting layer 261, the second light-emitting layer 262, and the third light-emitting layer 263 may contain the organometallic compound represented by Chemical Formula 1 according to the present disclosure as the dopant. For example, as illustrated in the example embodiment of FIG. 3, the second light-emitting layer 262 of the second light-emitting stack ST2 may contain the host material 262′, and the dopant 262″ made of or including the organometallic compound represented by Chemical Formula 1 doped therein. Although not illustrated in the example embodiment of FIG. 3, the first, second and third light-emitting stacks ST1, ST2 and ST3 may each further include an additional light-emitting layer, in addition to the first light-emitting layer 261, the second light-emitting layer 262 and the third light-emitting layer 263.

Furthermore, an organic light-emitting diode according to some example embodiments of the present disclosure may include a tandem structure in which four or more light-emitting stacks and three or more charge generating layers are disposed between the first electrode and the second electrode.

The organic light-emitting diode according to the present disclosure may be used as a light-emitting element in an organic light-emitting display device and in a lighting device. In an example embodiment, FIG. 4 is a cross-sectional view schematically illustrating an organic light-emitting display device including the organic light-emitting diode according to some embodiments of the present disclosure as a light-emitting element thereof.

As illustrated in the example embodiment of FIG. 4, an organic light-emitting display device 3000 includes a substrate 3010, an organic light-emitting diode 4000, and an encapsulation film 3900 covering the organic light-emitting diode 4000. A driving thin-film transistor Td as a driving element, and the organic light-emitting diode 4000 connected to the driving thin-film transistor Td are positioned on the substrate 3010.

Although not illustrated explicitly in the example embodiment of FIG. 4, a gate line and a data line that intersect each other to define a pixel area, a power line extending parallel to and spaced from one of the gate line and the data line, a switching thin film transistor connected to the gate line and the data line, and a storage capacitor connected to one electrode of the thin film transistor and the power line are further formed on or disposed on the substrate 3010.

The driving thin-film transistor Td is connected to the switching thin film transistor, and includes a semiconductor layer 3100, a gate electrode 3300, a source electrode 3520, and a drain electrode 3540.

The semiconductor layer 3100 may be formed on or disposed on the substrate 3010 and may be made of or may include an oxide semiconductor material or polycrystalline silicon. When the semiconductor layer 3100 is made of or may include an oxide semiconductor material, a light-shielding pattern (not illustrated) may be formed under or disposed under the semiconductor layer 3100. The light-shielding pattern minimizes the chances of light being incident to the semiconductor layer 3100 or prevents light from being incident to the semiconductor layer 3100 to minimize the chances of to the semiconductor layer 3100 deteriorating or prevent the semiconductor layer 3100 from being deteriorated due to the light. Alternatively, the semiconductor layer 3100 may be made of or may include polycrystalline silicon. In this case, both edges of the semiconductor layer 3100 may be doped with impurities.

The gate insulating layer 3200 made of or including an insulating material is formed over or disposed over an entirety of a surface of the substrate 3010 and on the semiconductor layer 3100. The gate insulating layer 3200 may be made of or may include an inorganic insulating material such as silicon oxide or silicon nitride.

The gate electrode 3300 made of or including a conductive material such as a metal is formed on or disposed on the gate insulating layer 3200 and corresponds to a center of the semiconductor layer 3100. The gate electrode 3300 is connected to the switching thin film transistor.

The interlayer insulating layer 3400 made of or including an insulating material is formed over or disposed over the entirety of the surface of the substrate 3010 and on the gate electrode 3300. The interlayer insulating layer 3400 may be made of or may include an inorganic insulating material such as silicon oxide or silicon nitride, or an organic insulating material such as benzocyclobutene or photo-acryl.

The interlayer insulating layer 3400 has first and second semiconductor layer contact holes 3420 and 3440 defined therein respectively exposing both opposing sides of the semiconductor layer 3100. The first and second semiconductor layer contact holes 3420 and 3440 are respectively positioned on both opposing sides of the gate electrode 3300 and are spaced apart from the gate electrode 3300.

The source electrode 3520 and the drain electrode 3540 made of or including a conductive material such as metal are formed on or disposed on the interlayer insulating layer 3400. The source electrode 3520 and the drain electrode 3540 are positioned around the gate electrode 3300, and are spaced apart from each other, and respectively contact both opposing sides of the semiconductor layer 3100 via the first and second semiconductor layer contact holes 3420 and 3440, respectively. The source electrode 3520 is connected to a power line (not illustrated).

The semiconductor layer 3100, the gate electrode 3300, the source electrode 3520, and the drain electrode 3540 constitute the driving thin-film transistor Td. The driving thin-film transistor Td has a coplanar structure in which the gate electrode 3300, the source electrode 3520, and the drain electrode 3540 are positioned on top of the semiconductor layer 3100.

Alternatively, the driving thin-film transistor Td may have an inverted staggered structure in which the gate electrode is disposed under the semiconductor layer while the source electrode and the drain electrode are disposed above the semiconductor layer. In this case, the semiconductor layer may be made of or may include amorphous silicon. In an example, the switching thin-film transistor (not illustrated) may have substantially the same structure as that of the driving thin-film transistor (Td).

In an example, the organic light-emitting display device 3000 may include a color filter 3600 absorbing the light generated from the electroluminescent element (organic light-emitting diode) 4000. For example, the color filter 3600 may absorb red (R), green (G), blue (B), and white (W) light. In this case, red, green, and blue color filter patterns that absorb light may be formed separately in different pixel areas. These color filter patterns may be disposed to overlap each organic layer 4300 of the organic light-emitting diode 4000 to emit light of a wavelength band corresponding to each color filter. Adopting the color filter 3600 may allow the organic light-emitting display device 3000 to realize full-color.

For example, when the organic light-emitting display device 3000 is of a bottom emission type, the color filter 3600 absorbing light may be positioned on a portion of the interlayer insulating layer 3400 corresponding to the organic light-emitting diode 4000. In an optional embodiment, when the organic light-emitting display device 3000 is of a top emission type, the color filter may be positioned on top of the organic light-emitting diode 4000, that is, on top of a second electrode 4200. For example, the color filter 3600 may be formed to have a thickness of 2 to 5 m.

In an example, a planarization layer 3700 having a drain contact hole 3720 defined therein exposing the drain electrode 3540 of the driving thin-film transistor Td is formed to cover the driving thin-film transistor Td.

On the planarization layer 3700, each first electrode 4100 connected to the drain electrode 3540 of the driving thin-film transistor Td via the drain contact hole 3720 is formed individually in each pixel area.

The first electrode 4100 may act as a positive electrode (anode), and may be made of or may include a conductive material having a relatively large work function value. For example, the first electrode 4100 may be made of or may include a transparent conductive material such as ITO, IZO or ZnO.

In an example, when the organic light-emitting display device 3000 is of a top-emission type, a reflective electrode or a reflective layer may be further formed under or disposed under the first electrode 4100. For example, the reflective electrode or the reflective layer may be made of or may include one of aluminum (Al), silver (Ag), nickel (Ni), and an aluminum-palladium-copper (APC) alloy.

A bank layer 3800 covering an edge of the first electrode 4100 is formed on or disposed on the planarization layer 3700. The bank layer 3800 exposes a center of the first electrode 4100 corresponding to the pixel area.

An organic layer 4300 is formed on or disposed on the first electrode 4100. Optionally, the organic light-emitting diode 4000 may have a tandem structure. Regarding the tandem structure, reference may be made to example embodiments illustrated in FIG. 2 to FIG. 4, which show some embodiments of the present disclosure, and the above descriptions thereof.

The second electrode 4200 is formed on or disposed on the substrate 3010 on which the organic layer 4300 has been formed or disposed. The second electrode 4200 is disposed over the entirety of the surface of the display area and is made of or may include a conductive material having a relatively small work function value and may be used as a negative electrode (a cathode). For example, the second electrode 4200 may be made of or may include one of aluminum (Al), magnesium (Mg), and an aluminum-magnesium alloy (Al—Mg).

The first electrode 4100, the organic layer 4300, and the second electrode 4200 constitute the organic light-emitting diode 4000.

An encapsulation film 3900 is formed on or disposed on the second electrode 4200 to minimize the chances of external moisture penetrating the organic light-emitting diode 4000 or prevent external moisture from penetrating the organic light-emitting diode 4000. Although not illustrated explicitly in the example embodiment of FIG. 4, the encapsulation film 3900 may have a triple-layer structure in which a first inorganic layer, an organic layer, and an inorganic layer are sequentially stacked. However, the present disclosure is not limited thereto.

Hereinafter, Preparation Examples and Present Examples of the present disclosure will be described. However, the following Present Examples are merely example embodiments of the present disclosure. The present disclosure is not limited thereto.

### Preparation Examples

### Preparation of Ligand Compound

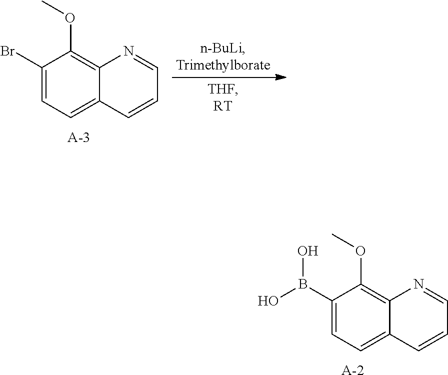

A Compound A-3 (4.01 g, 17 mmol), n-BuLi (3.0 mL, 40 mmol), and trimethylborate (6.5 mL, 60 mmol) were dissolved in 200 mL of THF in a 250 mL round bottom flask under a nitrogen atmosphere, and, thereafter, a mixed solution was stirred for 12 hours in a room temperature. After completion of a reaction, an organic layer was extracted therefrom with dichloromethane and washed sufficiently with water. Moisture was removed from the organic layer with anhydrous magnesium sulfate, and the mixture was filtered using a filter. The filtrate was concentrated under reduced pressure and then was subjected to separation using column chromatography with ethyl acetate and hexane to obtain the Compound A-2 (2.48 g, 72%).

### Preparation of Ligand Compound A-1

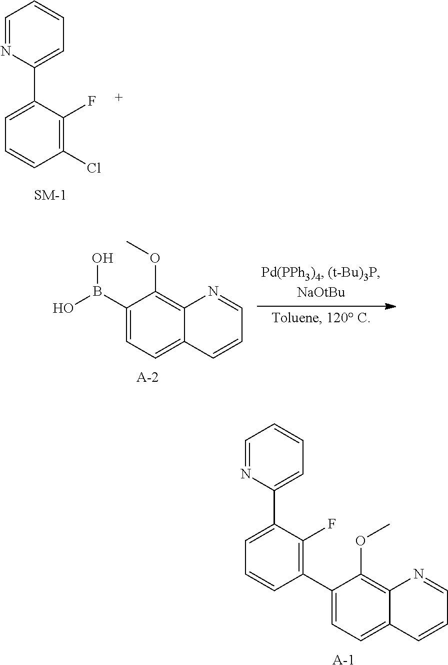

The Compound A-2 (2.48 g, 12.2 mmol), SM-1 (5.55 g, 20 mmol), Pd(PPh₃)₄ (2.31 g, 2 mmol), P(t-Bu)₃ (0.81 g, 4 mmol), and NaOtBu (7.68 g, 80 mmol) were dissolved in 200 mL of toluene in a 250 mL round bottom flask under a nitrogen atmosphere, and, thereafter, a mixed solution was heated under reflux and was stirred for 12 hours. After completion of a reaction, the temperature was lowered to room temperature, and an organic layer was extracted with dichloromethane and washed sufficiently with water. Moisture was removed from the organic layer with anhydrous magnesium sulfate, and the mixture was filtered using a filter. The filtrate was concentrated under reduced pressure and then was subjected to separation using column chromatography with ethyl acetate and hexane to obtain the Compound A-1 (3.92 g, 80%).

### Preparation of Ligand Compound A

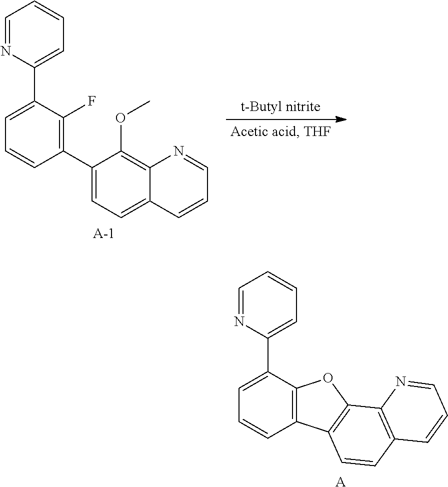

The Compound A-1 (3.92 g, 11.8 mmol) was dissolved in 80 mL of acetic acid and 25 mL of THF in a 250 mL round bottom flask under a nitrogen atmosphere, and then tert-butyl nitrite (5 mL, 38 mmol) was added to a mixed solution in a dropwise manner at 0° C. and the mixed solution was stirred. After completion of the stirring at 0° C. for 4 hours, the temperature was raised to room temperature, and an organic layer was extracted with ethyl acetate, and washed with water sufficiently. Moisture was removed from the organic layer with anhydrous magnesium sulfate, and the mixture was filtered using a filter. The filtrate was concentrated under reduced pressure and then was subjected to separation using column chromatography with dichloromethane and hexane to obtain the Compound A (2.68 g, 83%).

### Preparation of Ligand Compound B-2

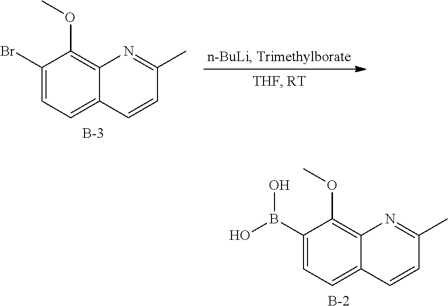

The Compound B-3 (5.25 g, 21 mmol), n-BuLi (3.0 mL, 40 mmol), and trimethylborate (6.5 mL, 60 mmol) were dissolved in 200 mL of THF in a 250 mL round bottom flask under a nitrogen atmosphere, and, thereafter, a mixed solution was stirred for 12 hours in a room temperature. After completion of a reaction, an organic layer was extracted therefrom with dichloromethane and washed sufficiently with water. Moisture was removed from the organic layer with anhydrous magnesium sulfate, and the mixture was filtered using a filter. The filtrate was concentrated under reduced pressure and then was subjected to separation using column chromatography with ethyl acetate and hexane to obtain the Compound B-2 (3.46 g, 76%).

### Preparation of Ligand Compound B-1

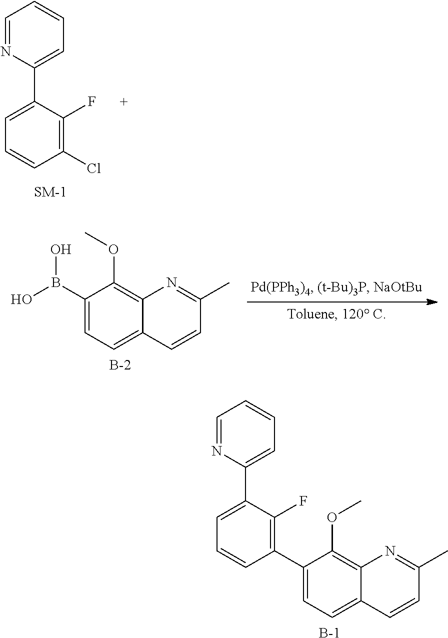

The Compound B-2 (3.46 g, 16 mmol), SM-1 (5.55 g, 20 mmol), Pd(PPh₃)₄ (2.31 g, 2 mmol), P(t-Bu)₃ (0.81 g, 4 mmol), and NaOtBu (7.68 g, 80 mmol) were dissolved in 200 mL of toluene in a 250 mL round bottom flask under a nitrogen atmosphere, and, thereafter, a mixed solution was heated under reflux and was stirred for 12 hours. After completion of a reaction, the temperature was lowered to room temperature, and an organic layer was extracted with dichloromethane and washed sufficiently with water. Moisture was removed from the organic layer with anhydrous magnesium sulfate, and the mixture was filtered using a filter. The filtrate was concentrated under reduced pressure and then was subjected to separation using column chromatography with ethyl acetate and hexane to obtain the Compound B-1 (4.23 g, 77%).

### Preparation of Ligand Compound B

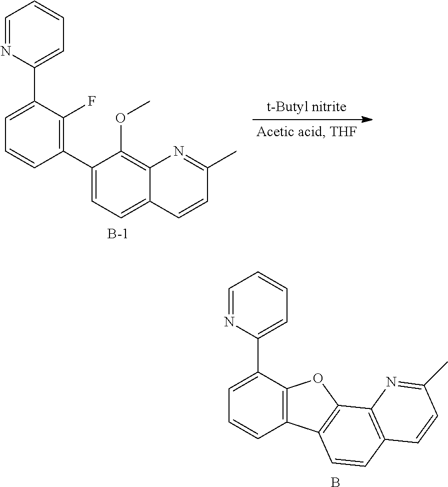

The Compound B-1 (4.23 g, 12.3 mmol) was dissolved in acetic acid 80 mL and THF 25 mL in a 250 mL round bottom flask under a nitrogen atmosphere, and then tert-butyl nitrite (5 mL, 38 mmol) was added to a mixed solution in a dropwise manner at 0° C. and the mixed solution was stirred. After completion of the stirring at 0° C. for 4 hours, the temperature was raised to room temperature, and an organic layer was extracted with ethyl acetate, and washed with water sufficiently. Moisture was removed from the organic layer with anhydrous magnesium sulfate, and the mixture was filtered using a filter. The filtrate was concentrated under reduced pressure and then was subjected to separation using column chromatography with dichloromethane and hexane to obtain the Compound B (2.61 g, 78%).

### Preparation of Ligand Compound DB

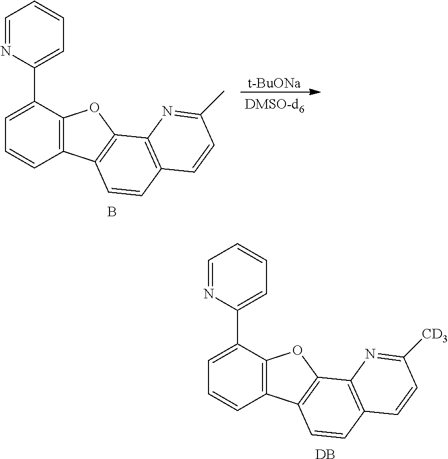

The Compound B (6.2 g, 20 mmol) and sodium tert-butoxide (4 mL, 40 mmol) were dissolved in DMSO-d₆ 100 mL in a 250 mL round bottom flask under a nitrogen atmosphere, thereafter, a mixed solution was heated to 135° C. and was stirred for 48 hours. After completion of a reaction, the temperature of a reaction vessel was lowered to room temperature, and an organic layer was extracted with ethyl acetate, and washed with water sufficiently. Moisture was removed from the organic layer with anhydrous magnesium sulfate, and the mixture was filtered using a filter. The filtrate was concentrated under reduced pressure and then was subjected to separation using column chromatography with ethyl acetate and dichloromethane to obtain the Compound DB (5.0 g, 72%).

### Preparation of Ligand Compound C-2

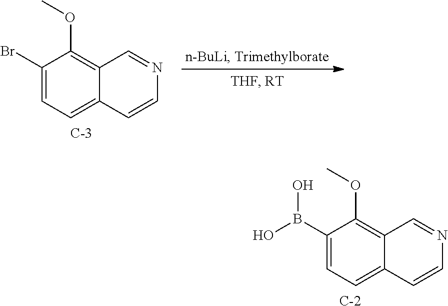

A Compound C-3 (4.01 g, 17 mmol), n-BuLi (3.0 mL, 40 mmol), and trimethylborate (6.5 mL, 60 mmol) were dissolved in 200 mL of THF in a 250 mL round bottom flask under a nitrogen atmosphere, and, thereafter, a mixed solution was stirred for 12 hours in a room temperature. After completion of a reaction, an organic layer was extracted therefrom with dichloromethane and washed sufficiently with water. Moisture was removed from the organic layer with anhydrous magnesium sulfate, and the mixture was filtered using a filter. The filtrate was concentrated under reduced pressure and then was subjected to separation using column chromatography with ethyl acetate and hexane to obtain the Compound C-2 (2.48 g, 72%).

### Preparation of Ligand Compound C-1

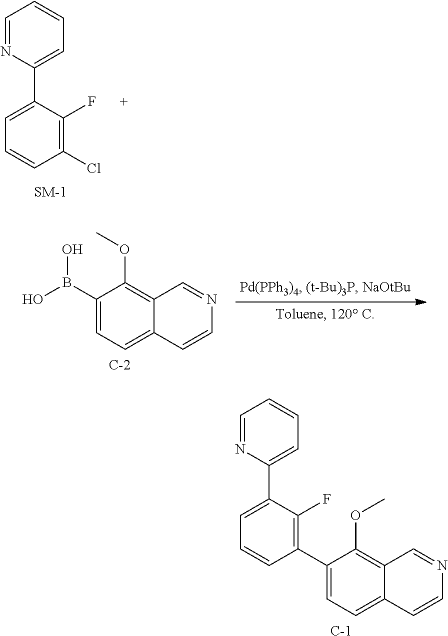

The Compound C-2 (2.48 g, 12.2 mmol), SM-1 (5.55 g, 20 mmol), Pd(PPh₃)₄ (2.31 g, 2 mmol), P(t-Bu)₃ (0.81 g, 4 mmol), and NaOtBu (7.68 g, 80 mmol) were dissolved in 200 mL of toluene in a 250 mL round bottom flask under a nitrogen atmosphere, and, thereafter, a mixed solution was heated under reflux and was stirred for 12 hours. After completion of a reaction, the temperature was lowered to room temperature, and an organic layer was extracted with dichloromethane and washed sufficiently with water. Moisture was removed from the organic layer with anhydrous magnesium sulfate, and the mixture was filtered using a filter. The filtrate was concentrated under reduced pressure and then was subjected to separation using column chromatography with ethyl acetate and hexane to obtain the Compound C-1 (3.27 g, 81%).

### Preparation of Ligand Compound C

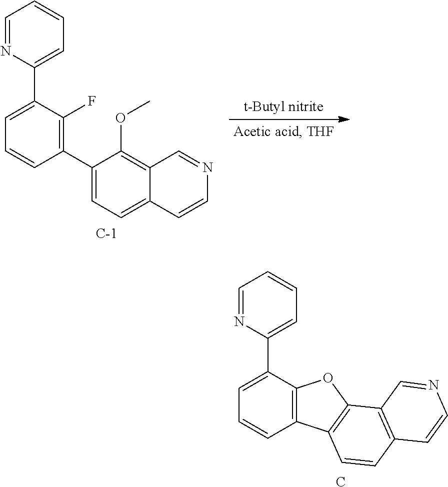

The Compound C-1 (3.27 g, 9.9 mmol) was dissolved in 80 mL of acetic acid and 25 mL of THF in a 250 mL round bottom flask under a nitrogen atmosphere, and then tert-butyl nitrite (5 mL, 38 mmol) was added to a mixed solution in a dropwise manner at 0° C. and the mixed solution was stirred. After completion of the stirring at 0° C. for 4 hours, the temperature was raised to room temperature, and an organic layer was extracted with ethyl acetate, and washed with water sufficiently. Moisture was removed from the organic layer with anhydrous magnesium sulfate, and the mixture was filtered using a filter. The filtrate was concentrated under reduced pressure and then was subjected to separation using column chromatography with dichloromethane and hexane to obtain the Compound C (2.32 g, 78%).

### Preparation of Ligand Compound D-2

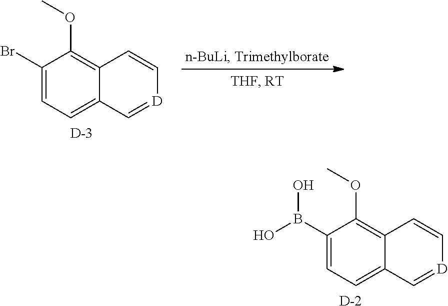

A Compound D-3 (4.48 g, 19 mmol), n-BuLi (3.0 mL, 40 mmol), and trimethylborate (6.5 mL, 60 mmol) were dissolved in 200 mL of THF in a 250 mL round bottom flask under a nitrogen atmosphere, and, thereafter, a mixed solution was stirred for 12 hours in a room temperature. After completion of a reaction, an organic layer was extracted therefrom with dichloromethane and washed sufficiently with water. Moisture was removed from the organic layer with anhydrous magnesium sulfate, and the mixture was filtered using a filter. The filtrate was concentrated under reduced pressure and then was subjected to separation using column chromatography with ethyl acetate and hexane to obtain the Compound D-2 (2.85 g, 74%).

### Preparation of Ligand Compound D-1

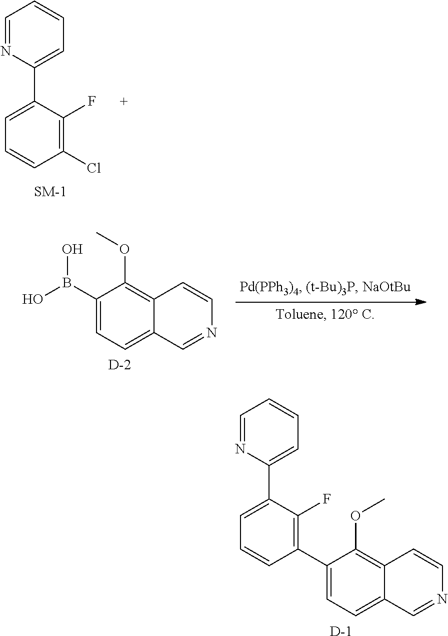

The Compound D-2 (2.85 g, 14 mmol), SM-1 (5.55 g, 20 mmol), Pd(PPh₃)₄ (2.31 g, 2 mmol), P(t-Bu)₃ (0.81 g, 4 mmol), and NaOtBu (7.68 g, 80 mmol) were dissolved in 200 mL of toluene in a 250 mL round bottom flask under a nitrogen atmosphere, and, thereafter, a mixed solution was heated under reflux and was stirred for 12 hours. After completion of a reaction, the temperature was lowered to room temperature, and an organic layer was extracted with dichloromethane and washed sufficiently with water. Moisture was removed from the organic layer with anhydrous magnesium sulfate, and the mixture was filtered using a filter. The filtrate was concentrated under reduced pressure and then was subjected to separation using column chromatography with ethyl acetate and hexane to obtain the Compound D-1 (3.62 g, 78%).

### Preparation of Ligand Compound D

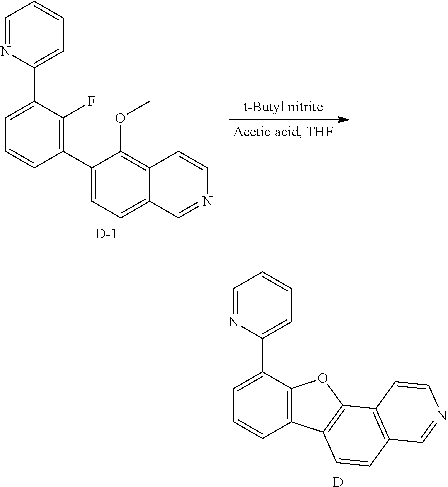

The Compound D-1 (3.62 g, 11 mmol) was dissolved in 80 mL of acetic acid and 25 mL of THF in a 250 mL round bottom flask under a nitrogen atmosphere, and then tert-butyl nitrite (5 mL, 38 mmol) was added to a mixed solution in a dropwise manner at 0° C. and the mixed solution was stirred. After completion of the stirring at 0° C. for 4 hours, the temperature was raised to room temperature, and an organic layer was extracted with ethyl acetate, and washed with water sufficiently. Moisture was removed from the organic layer with anhydrous magnesium sulfate, and the mixture was filtered using a filter. The filtrate was concentrated under reduced pressure and then was subjected to separation using column chromatography with dichloromethane and hexane to obtain the Compound D (2.53 g, 78%).

### Preparation of Ligand Compound E-2

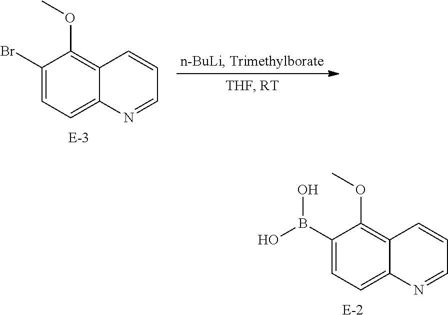

A Compound E-3 (4.01 g, 17 mmol), n-BuLi (3.0 mL, 40 mmol), and trimethylborate (6.5 mL, 60 mmol) were dissolved in 200 mL of THF in a 250 mL round bottom flask under a nitrogen atmosphere, and, thereafter, a mixed solution was stirred for 12 hours in a room temperature. After completion of a reaction, an organic layer was extracted therefrom with dichloromethane and washed sufficiently with water. Moisture was removed from the organic layer with anhydrous magnesium sulfate, and the mixture was filtered using a filter. The filtrate was concentrated under reduced pressure and then was subjected to separation using column chromatography with ethyl acetate and hexane to obtain the Compound E-2 (2.48 g, 72%).

### Preparation of Ligand Compound E-1

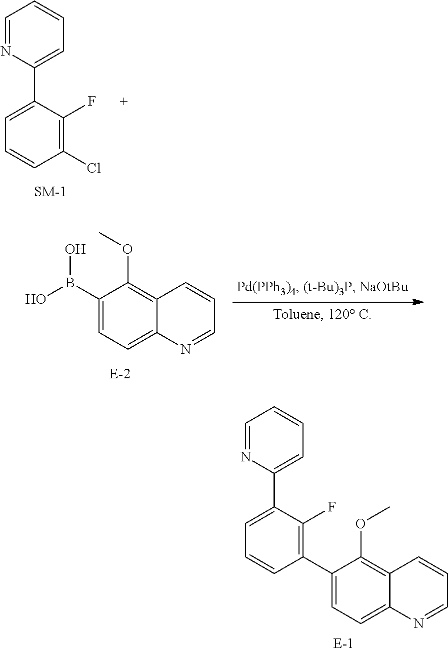

The Compound E-2 (2.48 g, 12.2 mmol), SM-1 (5.55 g, 20 mmol), Pd(PPh₃)₄ (2.31 g, 2 mmol), P(t-Bu)₃ (0.81 g, 4 mmol), and NaOtBu (7.68 g, 80 mmol) were dissolved in 200 mL of toluene in a 250 mL round bottom flask under a nitrogen atmosphere, and, thereafter, a mixed solution was heated under reflux and was stirred for 12 hours. After completion of a reaction, the temperature was lowered to room temperature, and an organic layer was extracted with dichloromethane and washed sufficiently with water. Moisture was removed from the organic layer with anhydrous magnesium sulfate, and the mixture was filtered using a filter. The filtrate was concentrated under reduced pressure and then was subjected to separation using column chromatography with ethyl acetate and hexane to obtain the Compound E-1 (3.15 g, 78%).

### Preparation of Ligand Compound E

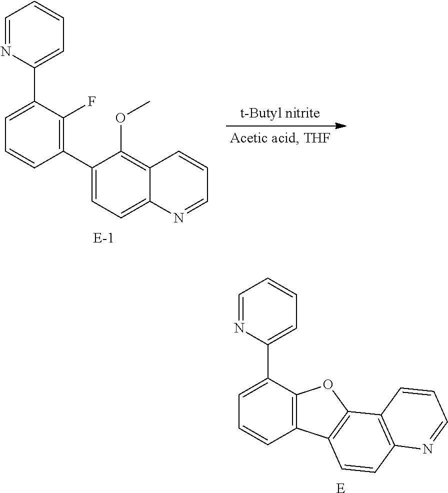

The Compound E-1 (3.15 g, 9.5 mmol) was dissolved in 80 mL of acetic acid and 25 mL of THF in a 250 mL round bottom flask under a nitrogen atmosphere, and then tert-butyl nitrite (5 mL, 38 mmol) was added to a mixed solution in a dropwise manner at 0° C. and the mixed solution was stirred. After completion of the stirring at 0° C. for 4 hours, the temperature was raised to room temperature, and an organic layer was extracted with ethyl acetate, and washed with water sufficiently. Moisture was removed from the organic layer with anhydrous magnesium sulfate, and the mixture was filtered using a filter. The filtrate was concentrated under reduced pressure and then was subjected to separation using column chromatography with dichloromethane and hexane to obtain the Compound E (2.32 g, 82%).

### Preparation of Ligand Compound MM

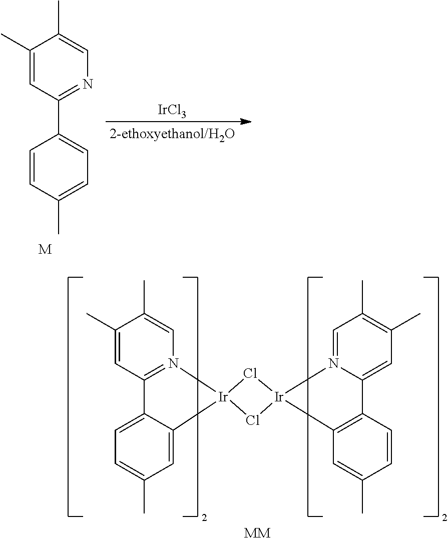

Under a nitrogen atmosphere and in a 250 mL round bottom flask, a Compound M (3.94 g, 20 mmol) and IrCl₃ (2.37 g, 8.0 mmol) were dissolved in a mixed solvent (ethoxyethanol: distilled water=90 mL: 30 mL), followed by stirring under reflux for 24 hours. After completion of the reaction, the temperature was lowered to room temperature, and a resulting solid was separated via filtration under reduced pressure. The solid collected on the filter was thoroughly washed with water and cold methanol, and a filtration under reduced pressure was performed. The filtration and washing were repeated several times to obtain a solid Compound MM 3.94 g (93%).

### Preparation of Ligand Compound NN

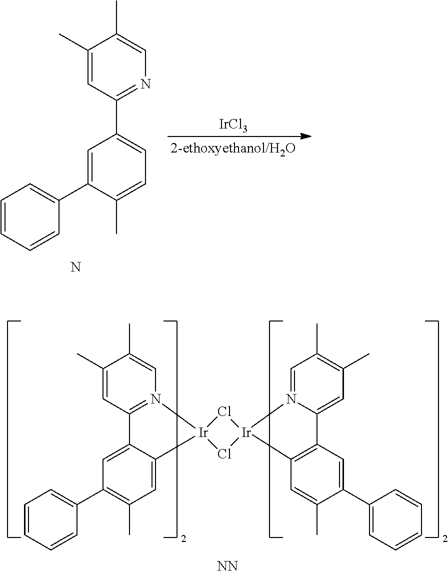

Under a nitrogen atmosphere and in a 250 mL round bottom flask, a Compound N (5.46 g, 20 mmol) and IrCl₃ (2.4 g, 8.0 mmol) were dissolved in a mixed solvent (ethoxyethanol: distilled water=90 mL: 30 mL), followed by stirring under reflux for 24 hours. After completion of the reaction, the temperature was lowered to room temperature, and a resulting solid was separated via filtration under reduced pressure. The solid collected on the filter was thoroughly washed with water and cold methanol, and a filtration under reduced pressure was performed. The filtration and washing were repeated several times to obtain a solid Compound NN 5.98 g (95%).

### Preparation of Ligand Compound DNN

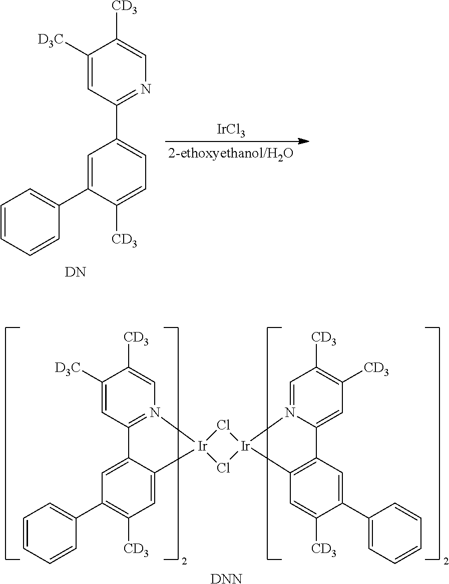

Under a nitrogen atmosphere and in a 250 mL round bottom flask, a Compound DN (5.64 g, 20 mmol), and IrCl₃ (2.4 g, 8.0 mmol) were dissolved in a mixed solvent (ethoxyethanol: distilled water=90 mL: 30 mL), followed by stirring under reflux for 24 hours. After completion of the reaction, the temperature was lowered to room temperature, and a resulting solid was separated via filtration under reduced pressure. The solid collected on the filter was thoroughly washed with water and cold methanol, and a filtration under reduced pressure was performed. The filtration and washing were repeated several times to obtain a solid Compound DNN 6.01 g (94%).

### Preparation of Ligand Compound M′

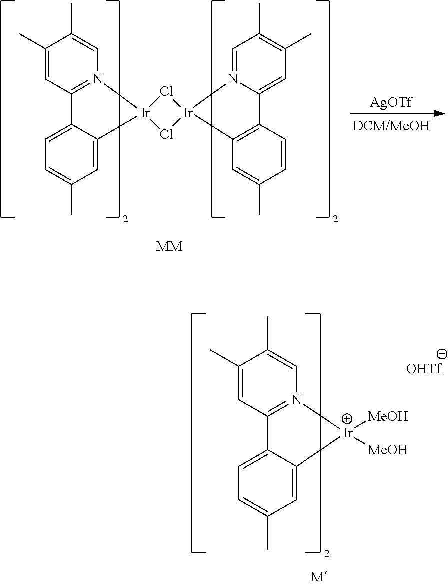

In a 250 mL round bottom flask, the Compound MM (4.54 g, 4 mmol), and silver trifluoromethanesulfonate (AgOTf, 3.04 g, 12 mmol) were dissolved in dichloromethane, followed by stirring at room temperature for 24 hours. After completion of the reaction, a reaction product is filtered with Celite to remove solid precipitates therefrom. The filtrate obtained through the filter was subjected to distillation under reduced pressure to obtain a solid Compound M′ 4.48 g (93%).

### Preparation of Ligand Compound N′

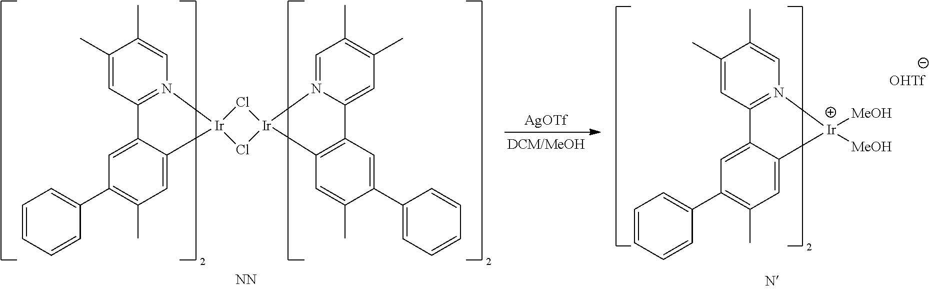

In a 250 mL round bottom flask, the Compound NN (6.18 g, 4 mmol) and silver trifluoromethanesulfonate (AgOTf, 2.99 g, 12 mmol) were dissolved in dichloromethane, followed by stirring at room temperature for 24 hours. After completion of the reaction, a reaction product is filtered with Celite to remove solid precipitates therefrom. The filtrate obtained through the filter was subjected to distillation under reduced pressure to obtain a solid Compound N′ 5.02 g (90%).

### Preparation of Ligand Compound DN′

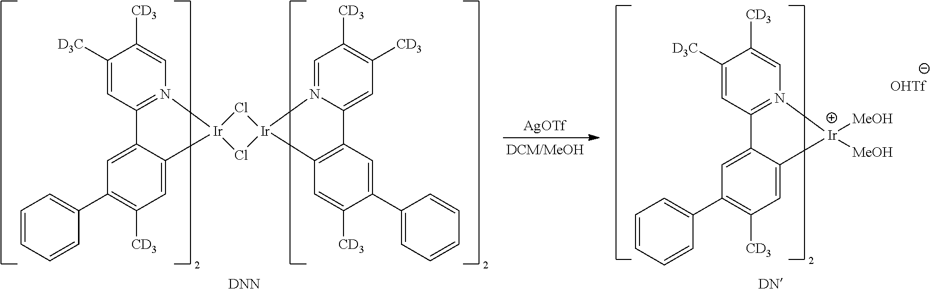

In a 250 mL round bottom flask, the Compound DNN (6.32 g, 4 mmol), and silver trifluoromethanesulfonate (AgOTf, 2.99 g, 12 mmol) were dissolved in dichloromethane, followed by stirring at room temperature for 24 hours. After completion of the reaction, a reaction product is filtered with Celite to remove solid precipitates therefrom. The filtrate obtained through the filter was subjected to distillation under reduced pressure to obtain a solid Compound DN′ 5.09 g (90%).

### Preparation of Iridium Compound 97

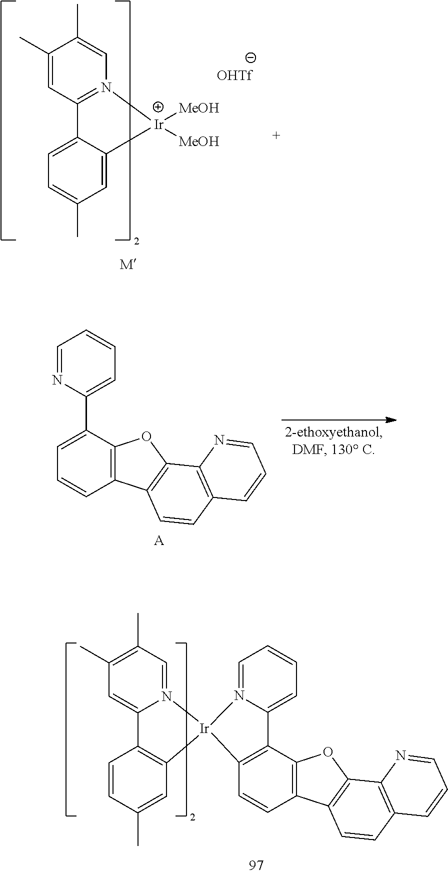

An iridium precursor M′ (4.07 g, 5.1 mmol) and the ligand A (2.87 g, 9.7 mmol) were input into 2-ethoxyethanol (100 mL) and DMF (100 mL) in a 150 mL round bottom flask under a nitrogen atmosphere, and, thereafter, a mixed solution was heated to 130° C. and stirred for 24 hours. When a reaction was completed, the temperature was lowered to room temperature, and an organic layer was extracted using dichloromethane and distilled water, and moisture was removed from the organic layer by adding anhydrous magnesium sulfate thereto. A filtrate was obtained through filtration thereof and was depressurized to obtain a resulting crude product. The resulting crude product was purified using column chromatography under a condition of ethyl acetate:hexane=25:75 to obtain the iridium compound 97 (3.97 g, 93%).

### Preparation of Iridium Compound 101

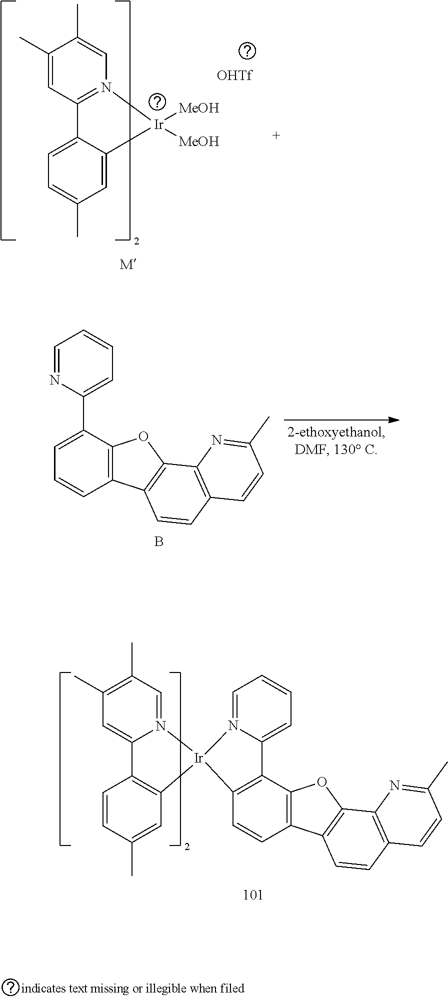

The iridium precursor M′ (3.75 g, 4.7 mmol) and the ligand B (3.07 g, 9.9 mmol) were input into 2-ethoxyethanol (100 mL) and DMF (100 mL) in a 150 mL round bottom flask under a nitrogen atmosphere, and, thereafter, a mixed solution was heated to 130° C. and stirred for 24 hours. When a reaction was completed, the temperature was lowered to room temperature, and an organic layer was extracted using dichloromethane and distilled water, and moisture was removed from the organic layer by adding anhydrous magnesium sulfate thereto. A filtrate was obtained through filtration thereof and was depressurized to obtain a resulting crude product. The resulting crude product was purified using column chromatography under a condition of ethyl acetate:hexane=25:75 to obtain the iridium compound 101 (3.74 g, 89%).

### Preparation of Iridium Compound 109

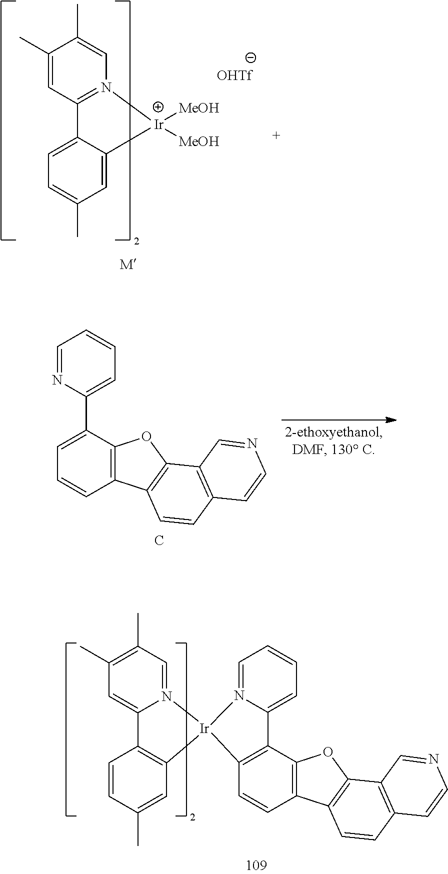

The iridium precursor M′ (3.75 g, 4.7 mmol) and the ligand C (2.9 g, 9.8 mmol) were input into 2-ethoxyethanol (100 mL) and DMF (100 mL) in a 150 mL round bottom flask under a nitrogen atmosphere, and, thereafter, a mixed solution was heated to 130° C. and stirred for 24 hours. When a reaction was completed, the temperature was lowered to room temperature, and an organic layer was extracted using dichloromethane and distilled water, and moisture was removed from the organic layer by adding anhydrous magnesium sulfate thereto. A filtrate was obtained through filtration thereof and was depressurized to obtain a resulting crude product. The resulting crude product was purified using column chromatography under a condition of ethyl acetate:hexane=25:75 to obtain the iridium compound 109 (3.68 g, 89%).

### Preparation of Iridium Compound 121

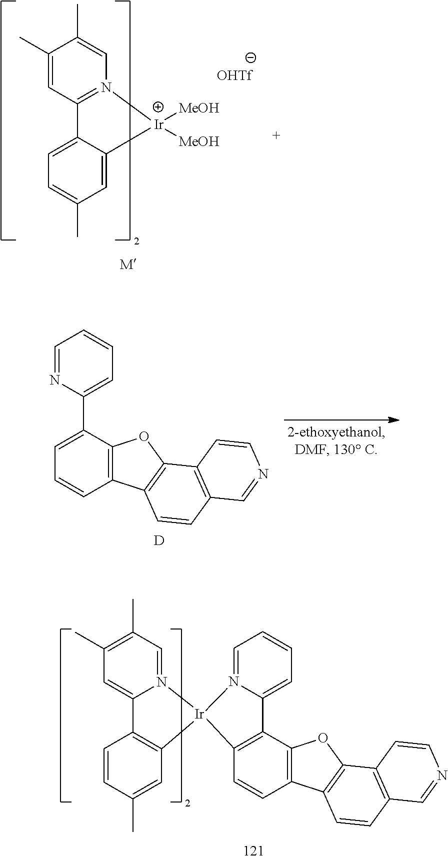

The iridium precursor M′ (4.23 g, 5.3 mmol) and the ligand D (3.01 g, 10.2 mmol) were input into 2-ethoxyethanol (100 mL) and DMF (100 mL) in a 150 mL round bottom flask under a nitrogen atmosphere, and, thereafter, a mixed solution was heated to 130° C. and stirred for 24 hours. When a reaction was completed, the temperature was lowered to room temperature, and an organic layer was extracted using dichloromethane and distilled water, and moisture was removed from the organic layer by adding anhydrous magnesium sulfate thereto. A filtrate was obtained through filtration thereof and was depressurized to obtain a resulting crude product. The resulting crude product was purified using column chromatography under a condition of ethyl acetate:hexane=25:75 to obtain the iridium compound 121 (4.26 g, 95%).

### Preparation of Iridium Compound 137

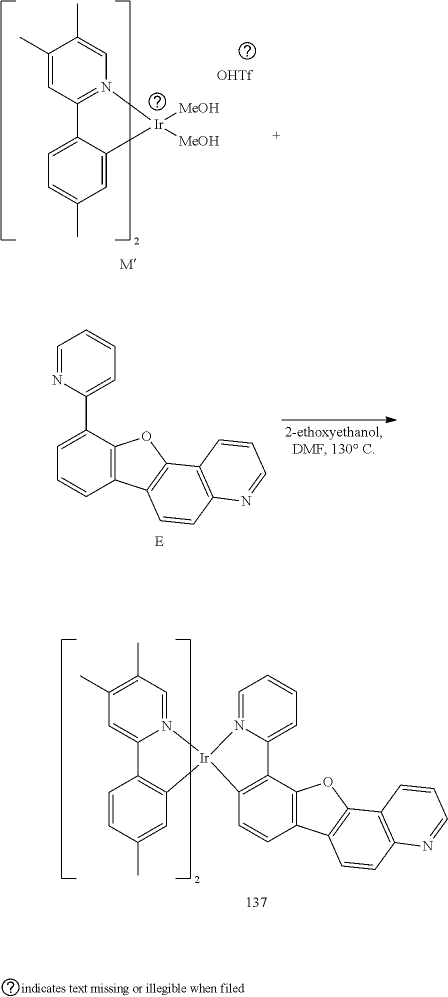

The iridium precursor M′ (4.07 g, 5.1 mmol) and the ligand E (3.1 g, 10 mmol) were input into 2-ethoxyethanol (100 mL) and DMF (100 mL) in a 150 mL round bottom flask under a nitrogen atmosphere, and, thereafter, a mixed solution was heated to 130° C. and stirred for 24 hours. When a reaction was completed, the temperature was lowered to room temperature, and an organic layer was extracted using dichloromethane and distilled water, and moisture was removed from the organic layer by adding anhydrous magnesium sulfate thereto. A filtrate was obtained through filtration thereof and was depressurized to obtain a resulting crude product. The resulting crude product was purified using column chromatography under a condition of ethyl acetate:hexane=25:75 to obtain the iridium compound 137 (4.15 g, 93%).

### Preparation of Iridium Compound 145

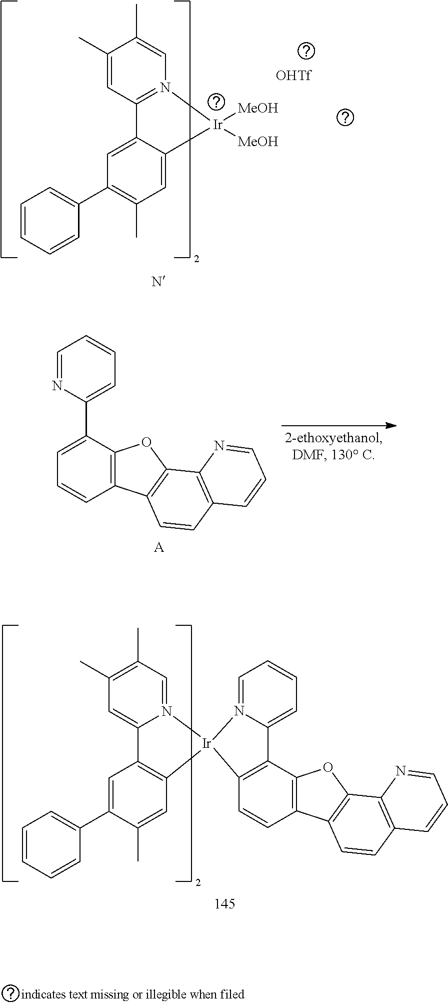

An iridium precursor N′ (4.66 g, 4.9 mmol) and the ligand A (2.87 g, 9.7 mmol) were input into 2-ethoxyethanol (100 mL) and DMF (100 mL) in a 150 mL round bottom flask under a nitrogen atmosphere, and, thereafter, a mixed solution was heated to 130° C. and stirred for 24 hours. When a reaction was completed, the temperature was lowered to room temperature, and an organic layer was extracted using dichloromethane and distilled water, and moisture was removed from the organic layer by adding anhydrous magnesium sulfate thereto. A filtrate was obtained through filtration thereof and was depressurized to obtain a resulting crude product. The resulting crude product was purified using column chromatography under a condition of ethyl acetate:hexane=25:75 to obtain the iridium compound 145 (4.48 g, 91%).

### Preparation of Iridium Compound 157

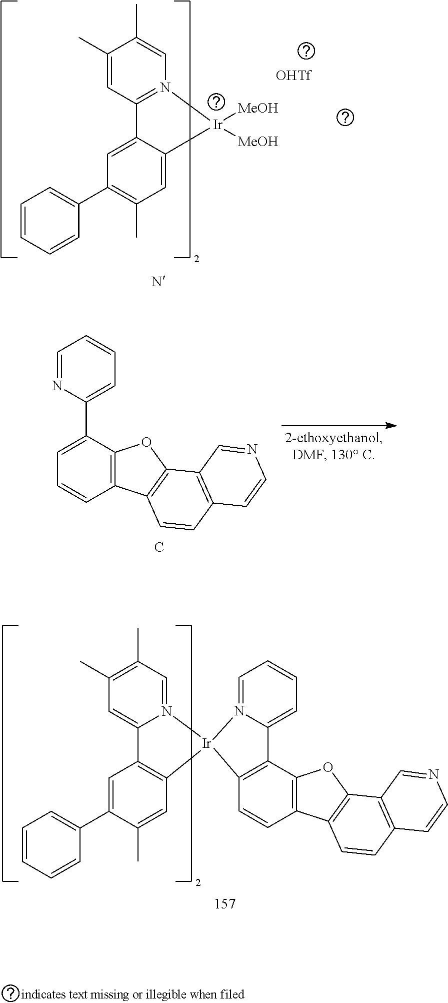

The iridium precursor N′ (4.56 g, 4.8 mmol) and the ligand C (2.9 g, 9.8 mmol) were input into 2-ethoxyethanol (100 mL) and DMF (100 mL) in a 150 mL round bottom flask under a nitrogen atmosphere, and, thereafter, a mixed solution was heated to 130° C. and stirred for 24 hours. When a reaction was completed, the temperature was lowered to room temperature, and an organic layer was extracted using dichloromethane and distilled water, and moisture was removed from the organic layer by adding anhydrous magnesium sulfate thereto. A filtrate was obtained through filtration thereof and was depressurized to obtain a resulting crude product. The resulting crude product was purified using column chromatography under a condition of ethyl acetate:hexane=25:75 to obtain the iridium compound 157 (4.39 g, 90%).

### Preparation of Iridium Compound 169

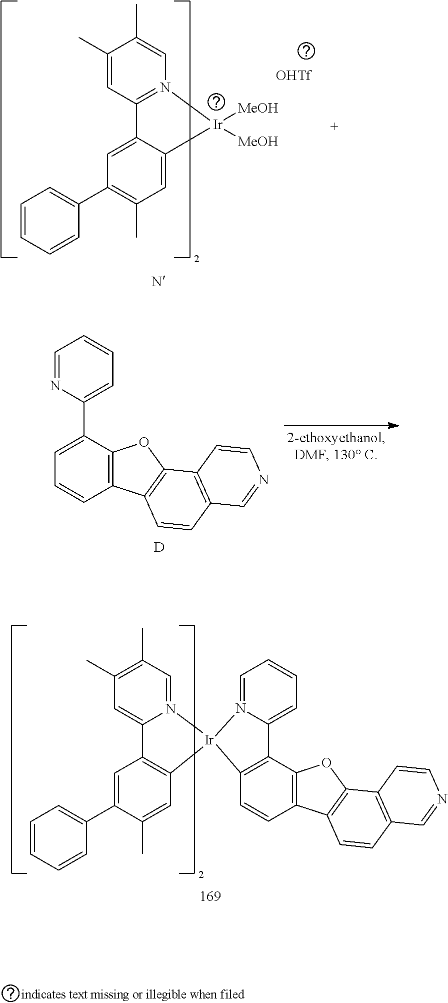

The iridium precursor N′ (4.47 g, 4.7 mmol) and the ligand D (3.01 g, 10.2 mmol) were input into 2-ethoxyethanol (100 mL) and DMF (100 mL) in a 150 mL round bottom flask under a nitrogen atmosphere, and, thereafter, a mixed solution was heated to 130° C. and stirred for 24 hours. When a reaction was completed, the temperature was lowered to room temperature, and an organic layer was extracted using dichloromethane and distilled water, and moisture was removed from the organic layer by adding anhydrous magnesium sulfate thereto. A filtrate was obtained through filtration thereof and was depressurized to obtain a resulting crude product. The resulting crude product was purified using column chromatography under a condition of ethyl acetate:hexane=25:75 to obtain the iridium compound 169 (4.25 g, 89%).

### Preparation of Iridium Compound 185

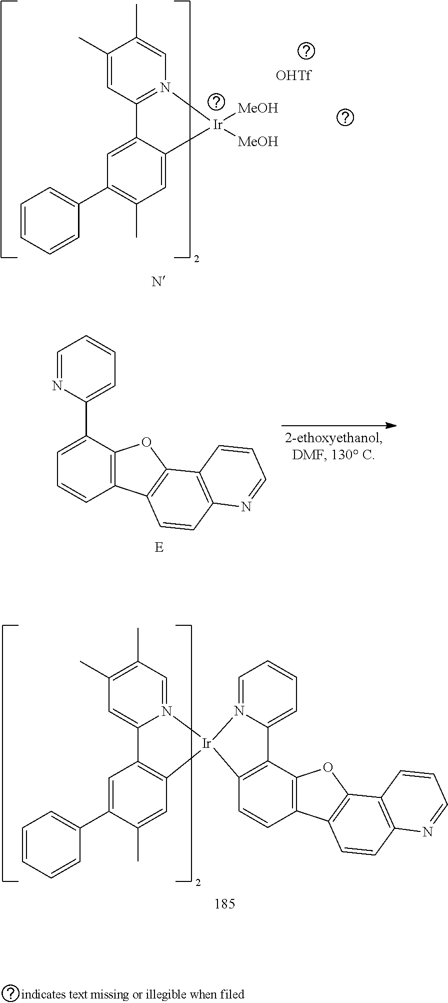

The iridium precursor N′ (5.04 g, 5.3 mmol) and the ligand E (2.99 g, 10.1 mmol) were input into 2-ethoxyethanol (100 mL) and DMF (100 mL) in a 150 mL round bottom flask under a nitrogen atmosphere, and, thereafter, a mixed solution was heated to 130° C. and stirred for 24 hours. When a reaction was completed, the temperature was lowered to room temperature, and an organic layer was extracted using dichloromethane and distilled water, and moisture was removed from the organic layer by adding anhydrous magnesium sulfate thereto. A filtrate was obtained through filtration thereof and was depressurized to obtain a resulting crude product. The resulting crude product was purified using column chromatography under a condition of ethyl acetate:hexane=25:75 to obtain the iridium compound 185 (4.88 g, 95%).

### Preparation of Iridium Compound 329

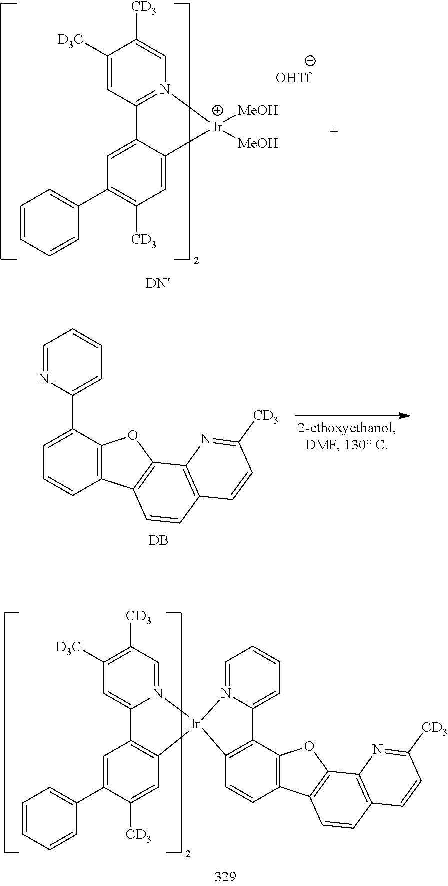

An iridium precursor DN′ (4.925 g, 5 mmol) and the ligand DB (3.22 g, 10 mmol) were input into 2-ethoxyethanol (100 mL) and DMF (100 mL) in a 150 mL round bottom flask under a nitrogen atmosphere, and, thereafter, a mixed solution was heated to 130° C. and stirred for 24 hours. When a reaction was completed, the temperature was lowered to room temperature, and an organic layer was extracted using dichloromethane and distilled water, and moisture was removed from the organic layer by adding anhydrous magnesium sulfate thereto. A filtrate was obtained through filtration thereof and was depressurized to obtain a resulting crude product. The resulting crude product was purified using column chromatography under a condition of ethyl acetate:hexane=25:75 to obtain the iridium compound 329 (4.83 g, 92%).

### PRESENT EXAMPLES

### Present Example 1

A glass substrate having a thin film of ITO (indium tin oxide) having a thickness of 1,000 Å coated thereon was washed, followed by ultrasonic cleaning with a solvent such as isopropyl alcohol, acetone, or methanol. Then, the glass substrate was dried. Thus, an ITO transparent electrode was formed. HI-1 as a hole injection material was deposited on the ITO transparent electrode via thermal vacuum deposition. Thus, a hole injection layer having a thickness of 60 nm was formed. Then, NPB as a hole transport material was deposited on the hole injection layer via thermal vacuum deposition. Thus, a hole transport layer having a thickness of 80 nm was formed. Then, CBP as a host material of a light-emitting layer was deposited on the hole transport layer via thermal vacuum deposition. The Compound 97 as a dopant was doped into the host material at a doping concentration of 5%. Thus, the light-emitting layer of a thickness of 30 nm was formed. ET-1: Liq (1:1) (30 nm) as a material for an electron transport layer and an electron injection layer was deposited on the light-emitting layer. Then, 100 nm thick aluminum was deposited thereon to form a negative electrode. In this way, an organic light-emitting diode was manufactured. The above materials are as follows:

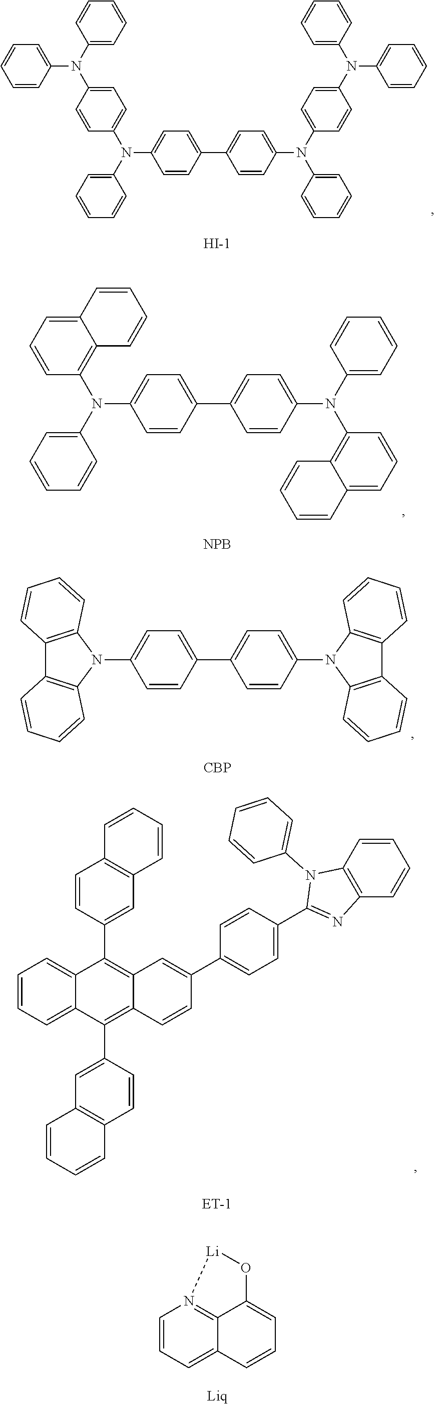

In the above materials, HI-1 is NPNPB, and ET-1 is ZADN.

### Comparative Examples 1 to 4

Organic light-emitting diodes of Comparative Examples 1 to 4 were manufactured in the same manner as in Present Example 1, except that Ref-1, Ref-2, Ref-3, and Ref-4 of following structures were used instead of the compound 97 in Present Example 1.

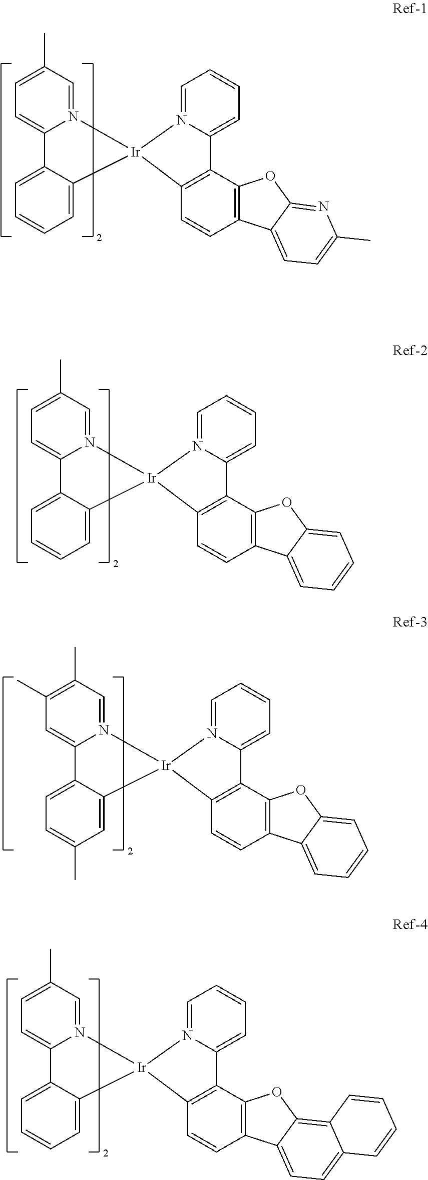

### Present Examples 2 to 12

Organic light-emitting diodes of Present Examples 2 to 12 were manufactured in the same manner as in Present Example 1, except that dopant materials as described in the following Table 1 were used instead of the compound 97 in Present Example 1.

### Experimental Example

The organic light-emitting diode as manufactured in Present Examples 1 to 8 and Comparative Examples 1 to 3 was connected to an external power source, and characteristics of the organic light-emitting diode were evaluated at room temperature using a current source and a photometer.

Operation voltage (V) at a current of 10 mA/cm², maximum luminous quantum efficiency (%, relative value), external quantum efficiency (EQE) (%, relative value), and lifespan characteristic (LT95) (%, relative value) were measured, and were calculated as values relative to those of Comparative Example 1, and the results are shown in the following Table 1.

LT95 lifetime refers to a time it takes for the display element to lose 5% of its initial brightness. LT95 is the customer specification to most difficult to meet. Whether or not image burn-in occurs on the display may be determined based on the LT95.

TABLE 1

| | | | Maximum | | |
|---|---|---|---|---|---|
| | | | luminous | | |
| | | | quantum | | |
| | | | efficiency | EQE | LT95 |
| | | Operation | (%, | (%, | (%, |
| | | voltage | relative | relative | relative |
| | Dopant | (V) | value) | value) | value) |
| Comparative | Ref-1 | 4.25 | 100 | 100 | 100 |
| Example 1 | | | | | |
| Comparative | Ref-2 | 4.26 | 113 | 109 | 31 |
| Example 2 | | | | | |
| Comparative | Ref-3 | 4.25 | 105 | 103 | 95 |
| Example 3 | | | | | |
| Comparative | Ref-4 | 4.27 | 97 | 95 | 106 |
| Example 4 | | | | | |
| Present | Compound | 4.27 | 129 | 130 | 128 |
| Example 1 | 97 | | | | |
| Present | Compound | 4.32 | 122 | 127 | 128 |
| Example 2 | 101 | | | | |
| Present | Compound | 4.26 | 131 | 125 | 131 |
| Example 3 | 109 | | | | |
| Present | Compound | 4.2 | 125 | 129 | 123 |
| Example 4 | 121 | | | | |
| Present | Compound | 4.3 | 129 | 132 | 131 |
| Example 5 | 145 | | | | |
| Present | Compound | 4.3 | 122 | 123 | 128 |
| Example 6 | 157 | | | | |
| Present | Compound | 4.26 | 123 | 126 | 131 |
| Example 7 | 169 | | | | |
| Present | Compound | 4.2 | 126 | 132 | 129 |
| Example 8 | 185 | | | | |
| Present | Compound | 4.2 | 127 | 128 | 126 |
| Example 9 | 137 | | | | |
| Present | Compound | 4.24 | 135 | 136 | 181 |
| Example 10 | 329 | | | | |

From the results of Table 1, the organic light-emitting diode of Present Examples 1 to 8 in which the organometallic compound satisfying the structure represented by Chemical Formula 1 of the present disclosure is used as the dopant of the light-emissive layer has lowered operation voltage, and improved maximum luminous quantum efficiency, external quantum efficiency (EQE) and lifetime (LT95), compared to the organic light-emitting diode of Comparative Examples 1 to 4 in which the compound not satisfying the structure represented by Chemical Formula 1 of the present disclosure is used as the dopant of the light-emissive layer.

Although embodiments of the present disclosure have been described with reference to the accompanying drawings, the present disclosure is not limited to the above embodiments and may be modified in a various manner within the scope of the technical spirit of the present disclosure. Accordingly, the embodiments as disclosed in the present disclosure are intended to describe rather than limit the technical idea of the present disclosure, and the scope of the technical idea of the present disclosure is not limited by these embodiments. Therefore, it should be appreciated that the embodiments as described above is not restrictive but illustrative in all aspects.

### DESCRIPTION OF REFERENCE NUMERALS

100, 4000: organic light emitting diode (OLED)
110, 4100: first electrode
120, 4200: second electrode
130, 230, 330, 4300: intermediate layer
140: hole injection layer
150: hole transport layer, 251: first hole transport layer, 252: second hole transport layer, 253: third hole transport layer
160: light-emitting layer, 261: first light-emitting layer, 262: second light-emitting layer, 263: third light-emitting layer
160′, 262′: host
160″, 262″: dopant
170: electron transport layer, 271: first electron transport layer, 272: second electron transport layer, 273: third electron transport layer
180: electron injection layer
3000: OLED display device
3010: substrate
3100: semiconductor layer
3200: gate insulating film
3300: gate electrode
3400: interlayer insulating film
3420, 3440: first and second semiconductor contact holes
3520: source electrode
3540: drain electrode
3600: color filter
3700: planarization layer
3720: drain contact hole
3800: bank layer
3900: encapsulation film

What is claimed is:

1. An organometallic compound represented by Chemical Formula 1:
Ir(L_{A})ₘ(L_{B})ₙ Chemical Formula 1
in Chemical Formula 1,
Ir represents iridium,
m is an integer from 1 to 3, n is an integer from 0 to 2, and a sum of m and n is 3,
L_{A} is represented by one selected from Chemical Formula 2 to Chemical Formula 4, and L_{B} is represented by Chemical Formula 5: 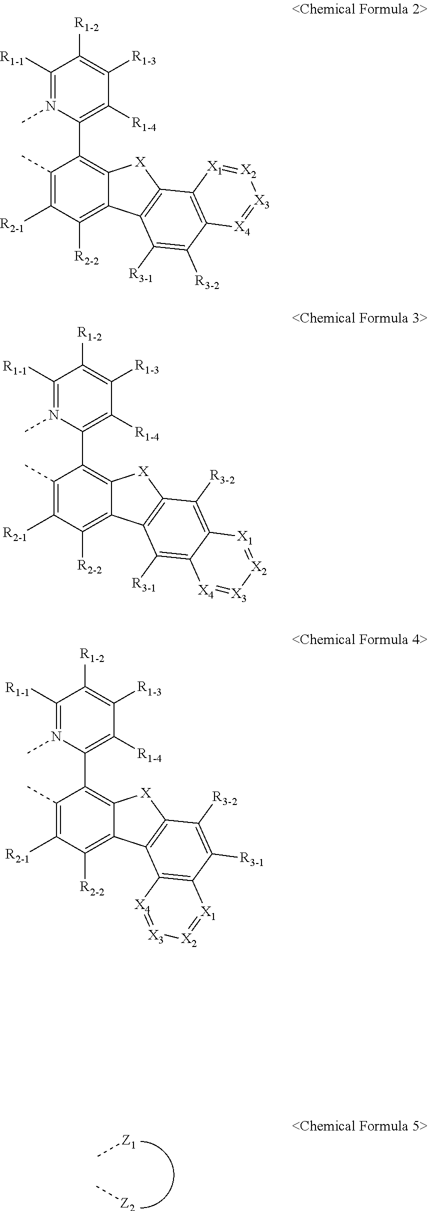
in Chemical Formula 2 to Chemical Formula 4,
X is one selected from C(Rx)₂, NRx, oxygen (O), sulfur (S), and selenium (Se),
X₁, X₂, X₃, and X₄ each independently represents one selected from C(Rx) and N; at least one of X₁, X₂, X₃, and X₄ is N; each Rx independently represents one selected from hydrogen, C1 to C20 linear alkyl, and C3 to C20 branched alkyl; and optionally, C1 to C20 linear alkyl, and C3 to C20 branched alkyl is each independently substituted with at least one substituent selected from deuterium and halogen,
R₁₋₁, R₁₋₂, R₁₋₃, R₁₋₄, R₂₋₁, R₂₋₂, R₃₋₁, and R₃₋₂ each independently represents one selected from the group consisting of hydrogen, deuterium, halogen, C1 to C20 linear alkyl, C3 to C20 branched alkyl, C3 to C20 cycloalkyl, C3 to C20 heteroalkyl, C7 to C30 arylalkyl, C1 to C10 alkoxy, C6 to C20 aryloxy, amino, silyl, C2 to C20 alkenyl, C3 to C20 cycloalkenyl, C2 to C20 heteroalkenyl, C2 to C20 alkynyl, C6 to C30 aryl, C2 to C30 heteroaryl, and acyl, and optionally, C1 to C20 linear alkyl, C3 to C20 branched alkyl, C3 to C20 cycloalkyl, C3 to C20 heteroalkyl, C7 to C30 arylalkyl, C1 to C10 alkoxy, C6 to C20 aryloxy, amino, silyl, C2 to C20 alkenyl, C3 to C20 cycloalkenyl, C2 to C20 heteroalkenyl, C2 to C20 alkynyl, C6 to C30 aryl, C2 to C30 heteroaryl, and acyl are each independently substituted with at least one substituent selected from deuterium and halogen, and
optionally, two adjacent groups among R₁₋₁, R₁₋₂, R₁₋₃, and R₁₋₄ bind to each other to form a ring structure; optionally, R₂₋₁ and R₂₋₂ bind to each other to form a ring structure; and optionally, R₃₋₁ and R₃₋₂ bind to each other to form a ring structure; and
Chemical Formula 5 represents a bidentate ligand.

2. The organometallic compound of claim 1, wherein R₁₋₁, R₁₋₂, R₁₋₃, and R₁₋₄ each independently represents one selected from the group consisting of hydrogen, C1 to C5 linear alkyl, C3 to C10 branched alkyl, C6 to C30 aryl, and C2 to C30 heteroaryl, and
optionally, C1 to C5 linear alkyl, C3 to C10 branched alkyl, C6 to C30 aryl, and C2 to C30 heteroaryl are each independently substituted with deuterium.

3. The organometallic compound of claim 1, wherein R₂₋₁ and R₂₋₂ each represents hydrogen.

4. The organometallic compound of claim 1, wherein R₃₋₁ and R₃₋₂ each represents hydrogen.

5. The organometallic compound of claim 1, wherein L_{B} includes a compound represented by one selected from the group consisting of Chemical Formula 6 and Chemical Formula 7: 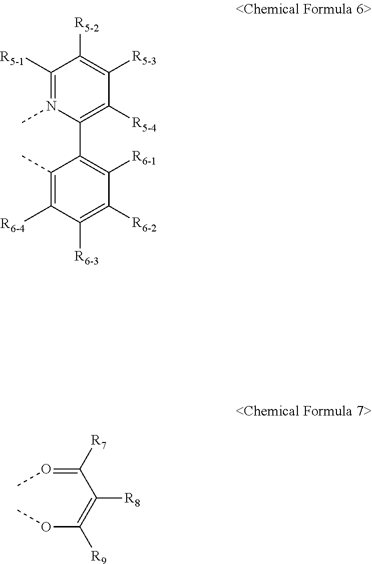
in Chemical Formula 6 and Chemical Formula 7,
R₅₋₁, R₅₋₂, R₅₋₃, R₅₋₄, R₆₋₁, R₆₋₂, R₆₋₃, and R₆₋₄ each independently represents one selected from the group consisting of hydrogen, deuterium, C1 to C5 linear alkyl, C3 to C5 branched alkyl, C6 to C10 aryl, C7 to C30 alkylaryl, and C7 to C30 arylalkyl, and optionally, C1 to C5 linear alkyl, C3 to C5 branched alkyl, and C7 to C30 arylalkyl is each independently substituted with at least one substituent selected from deuterium and halogen, and
optionally, two adjacent groups among R₅₋₁, R₅₋₂, R₅₋₃, and R₅₋₄ bind to each other to form a ring structure; and optionally, two adjacent groups among R₆₋₁, R₆₋₂, R₆₋₃, and R₆₋₄ bind to each other to form a ring structure; and
R₇, R₈, and R₉ each independently represents one selected from the group consisting of hydrogen, deuterium, C1 to C5 linear alkyl, and C3 to C5 branched alkyl, and optionally, C1 to C5 linear alkyl, or C3 to C5 branched alkyl as at least one selected from R₇, R₈, and R₉ is each independently substituted with at least one substituent selected from deuterium and halogen, and
optionally, two adjacent groups among R₇, R₈, and R₉ bind to each other to form a ring structure.

6. The organometallic compound of claim 1, wherein m is 1 and n is 2.

7. The organometallic compound of claim 1, wherein m is 2 and n is 1.

8. The organometallic compound of claim 1, wherein m is 3 and n is 0.

9. The organometallic compound of claim 1 wherein, the organometallic compound represented by Chemical Formula 1 includes one selected from the group consisting of following compounds 1 to 549:

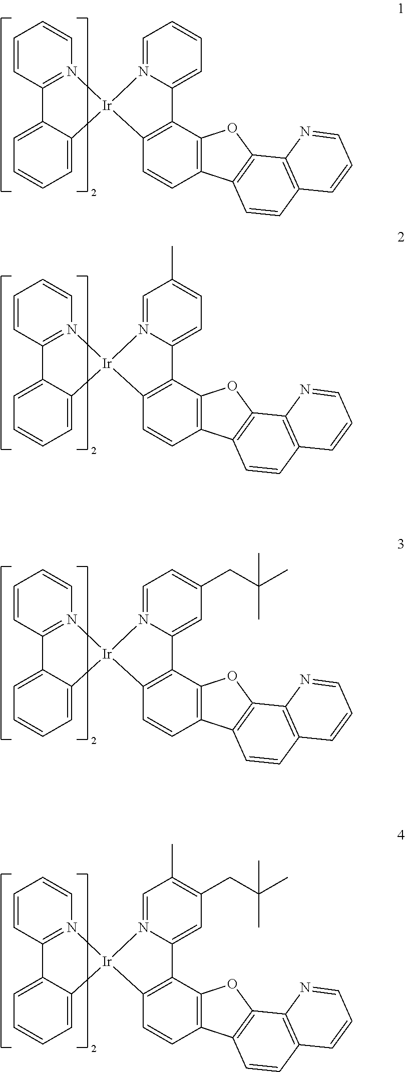

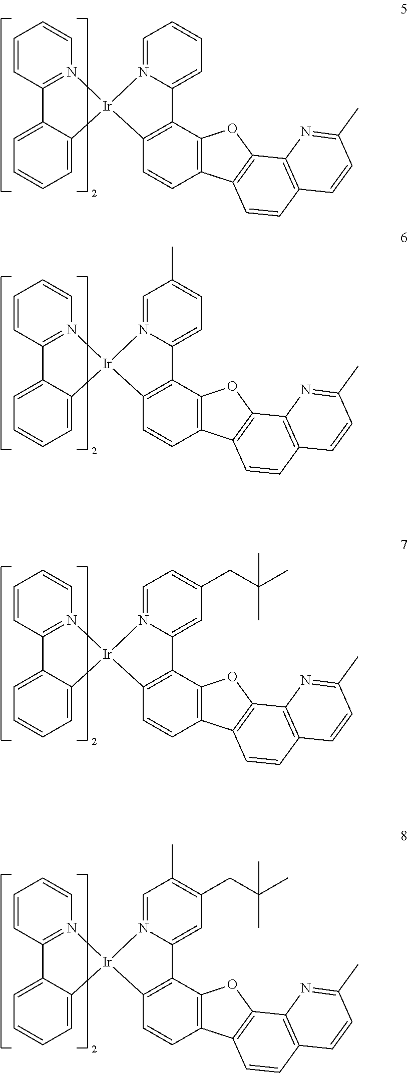

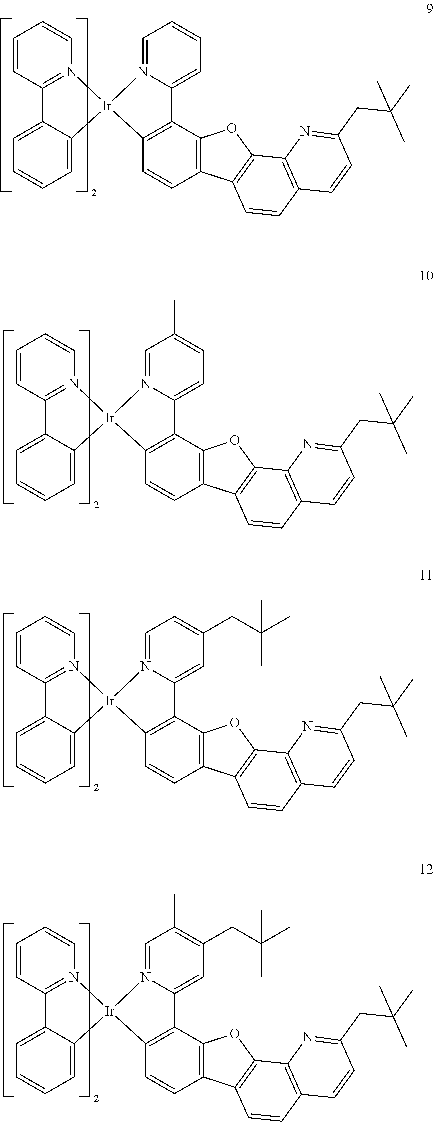

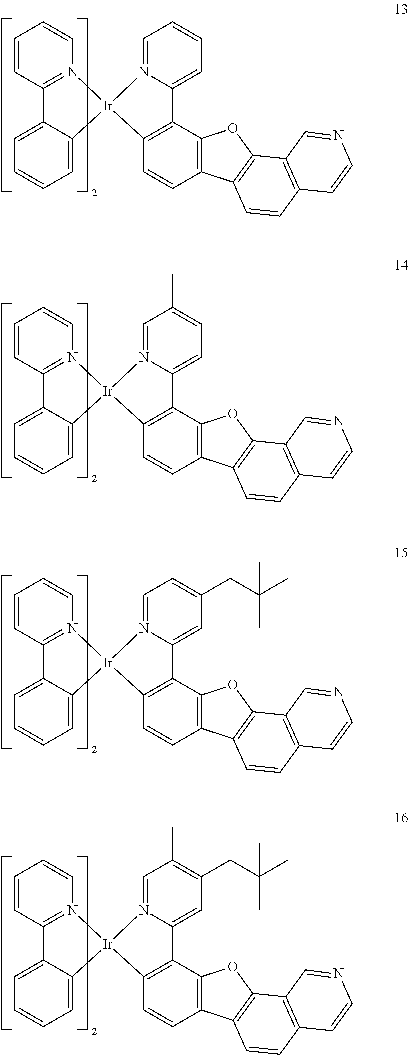

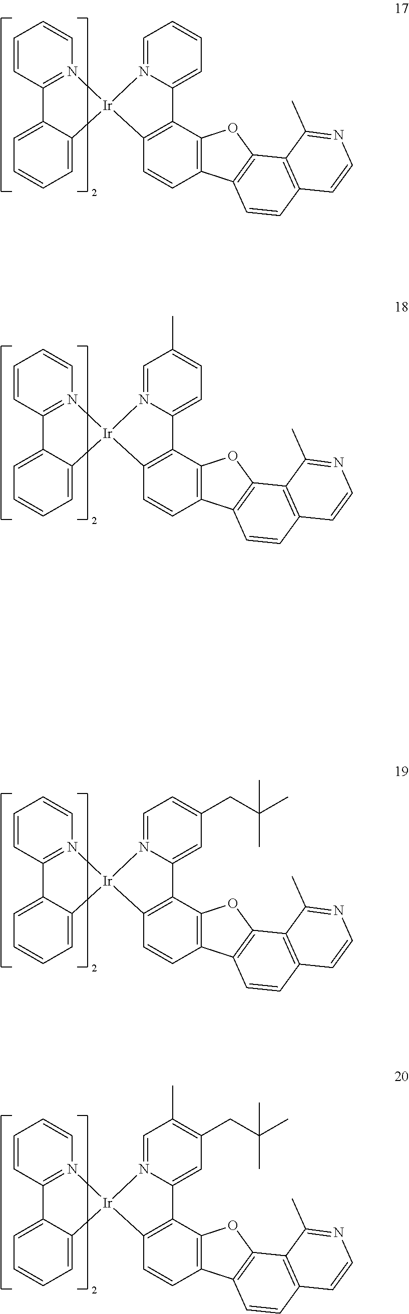

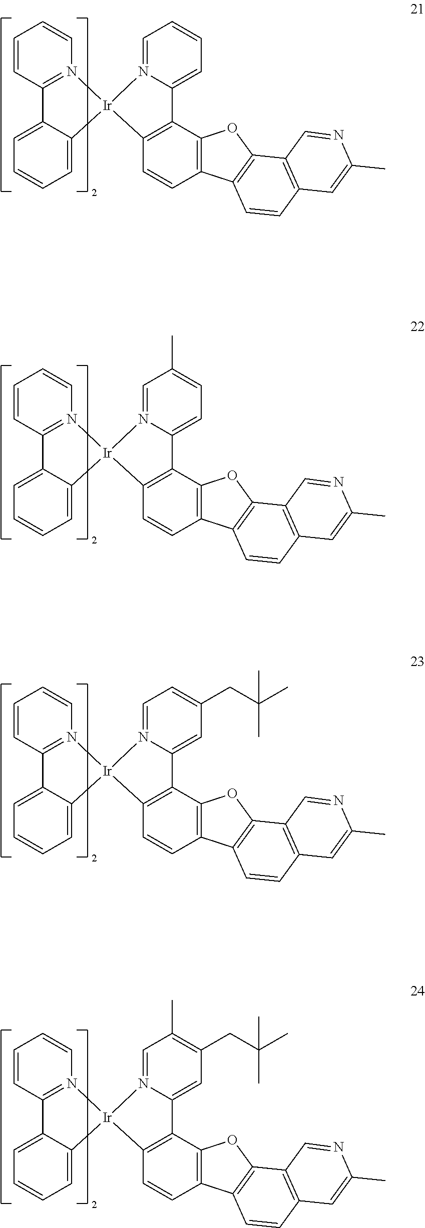

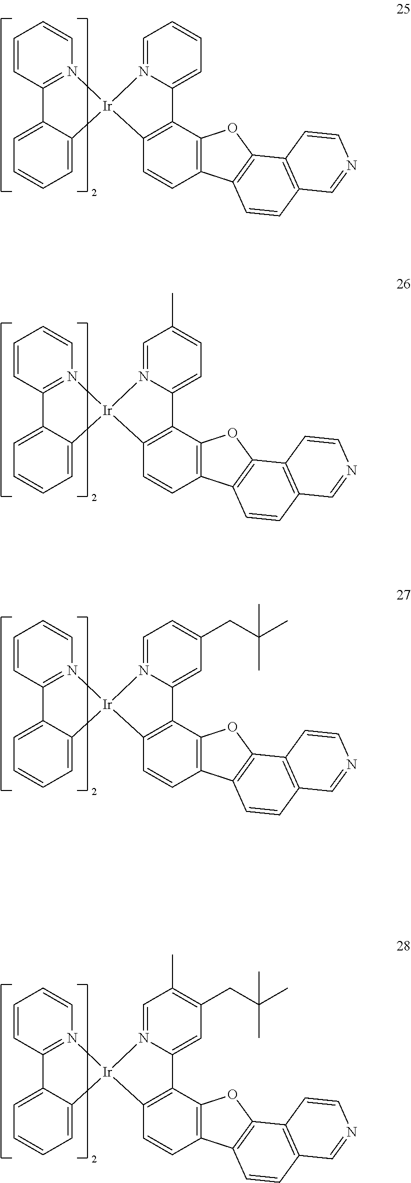

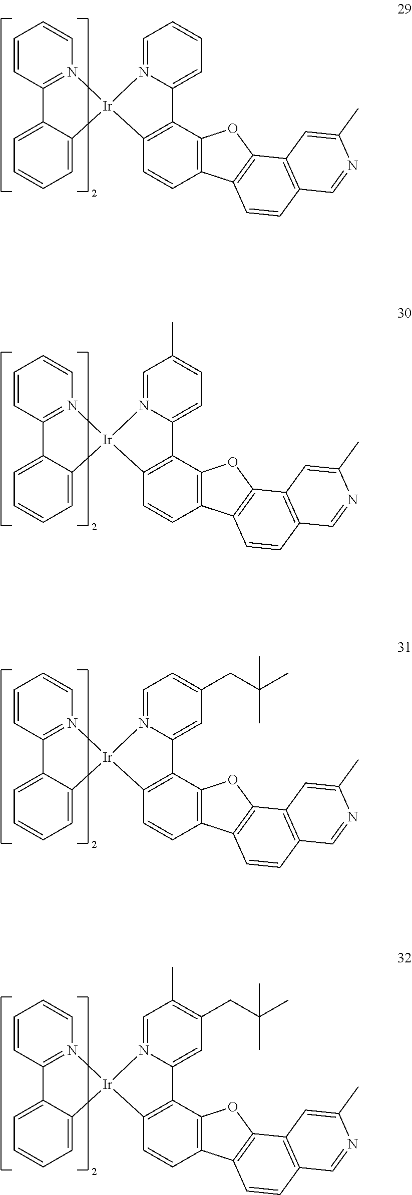

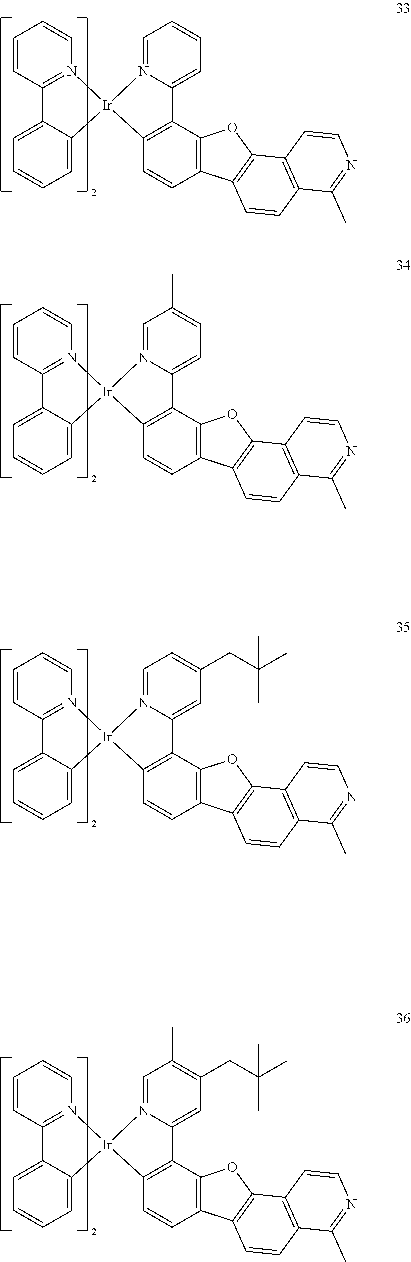

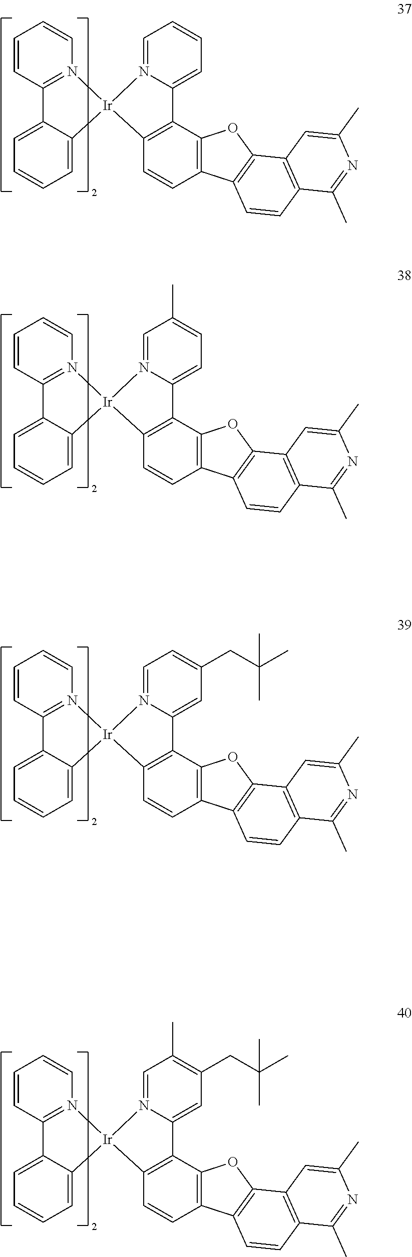

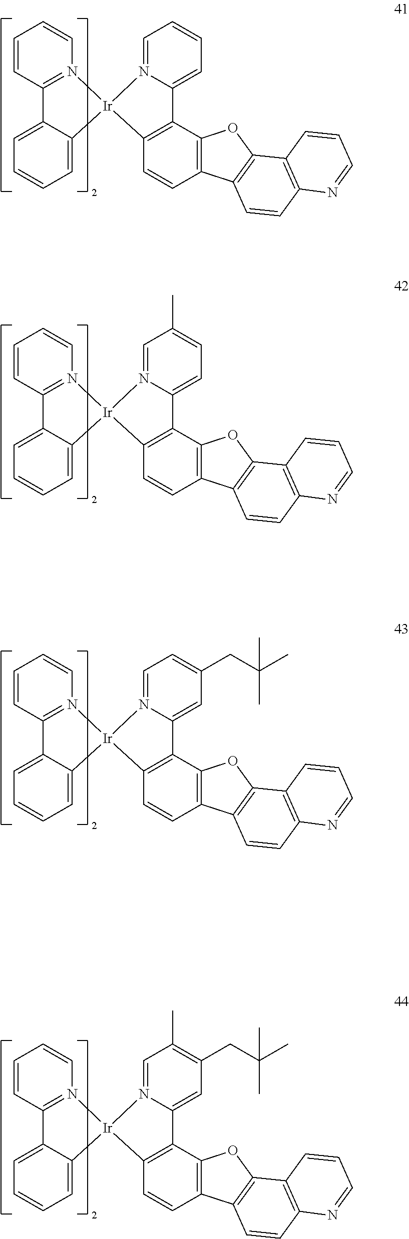

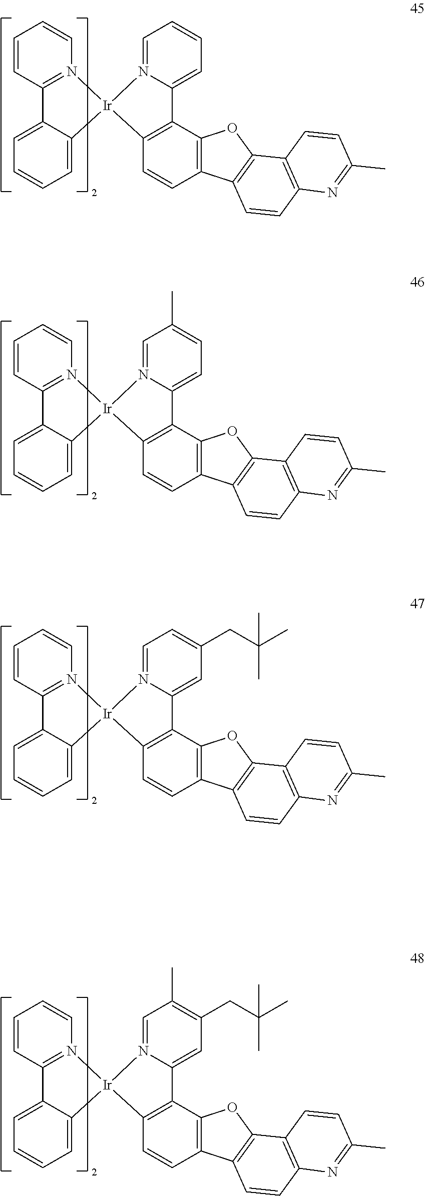

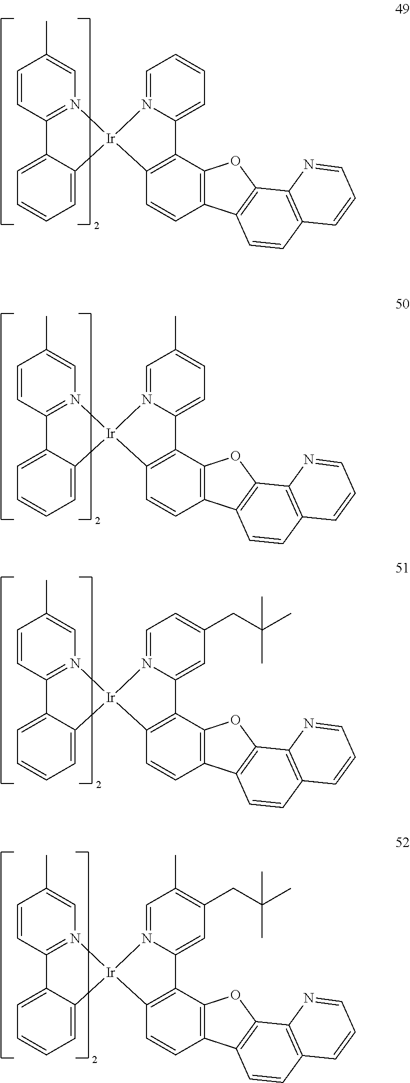

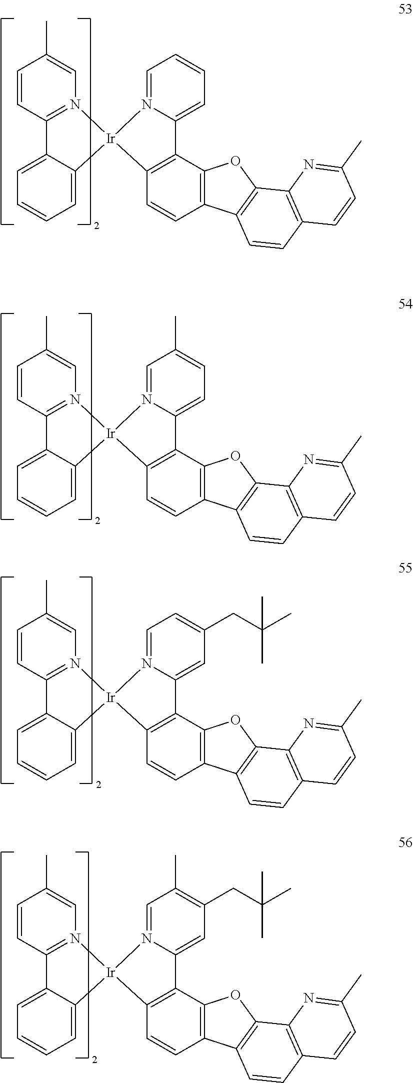

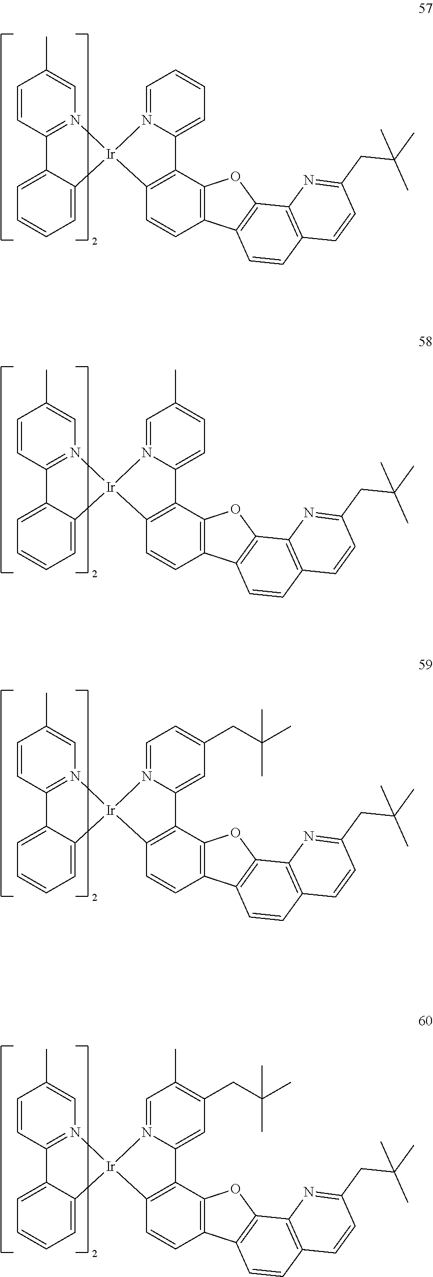

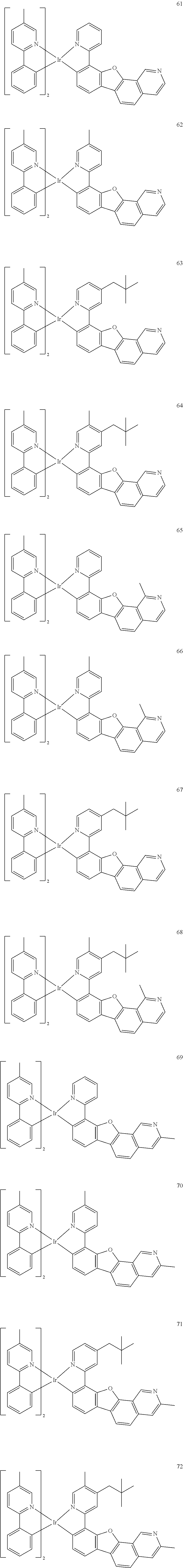

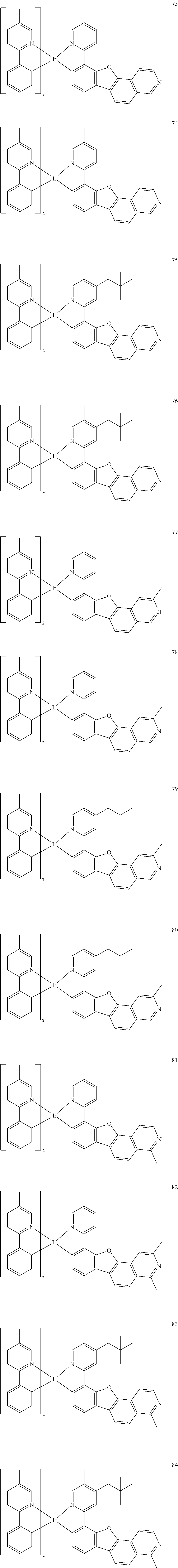

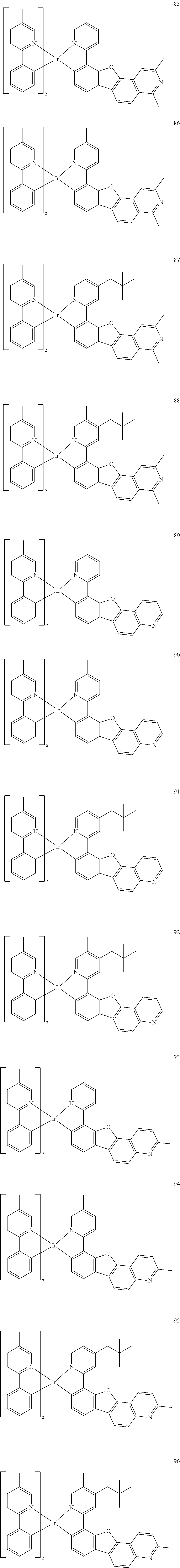

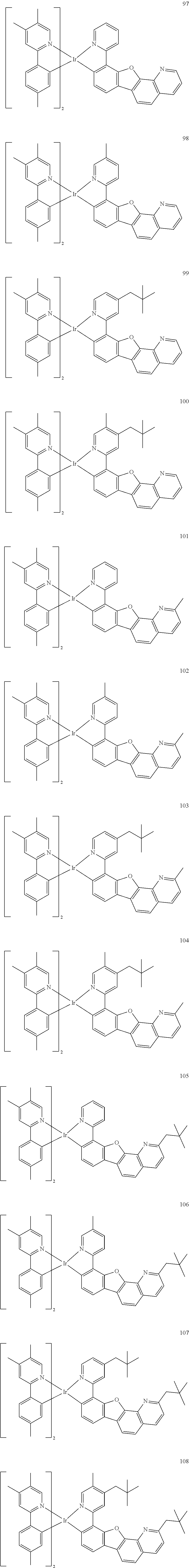

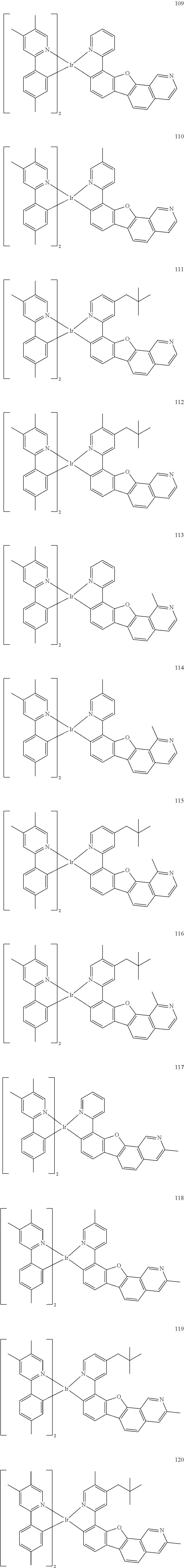

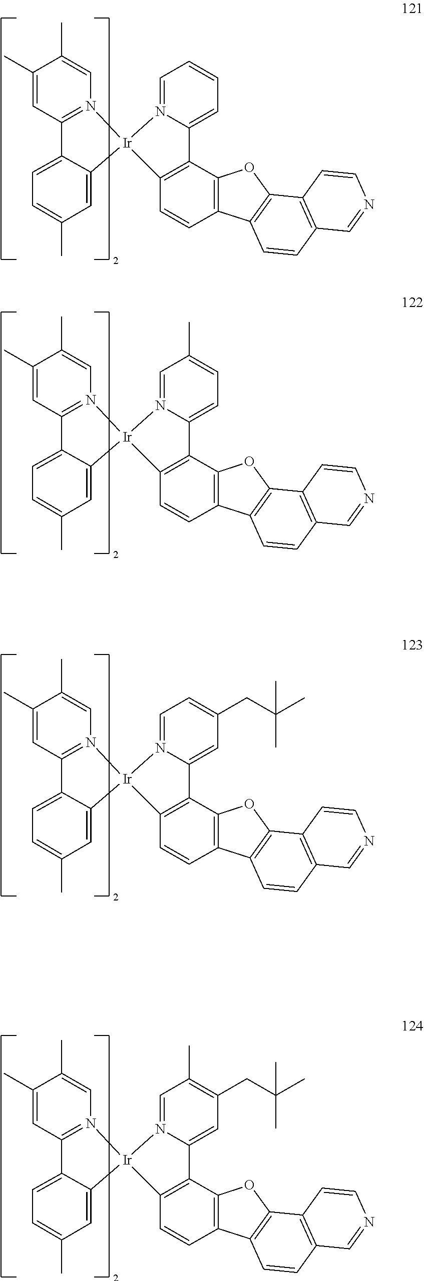

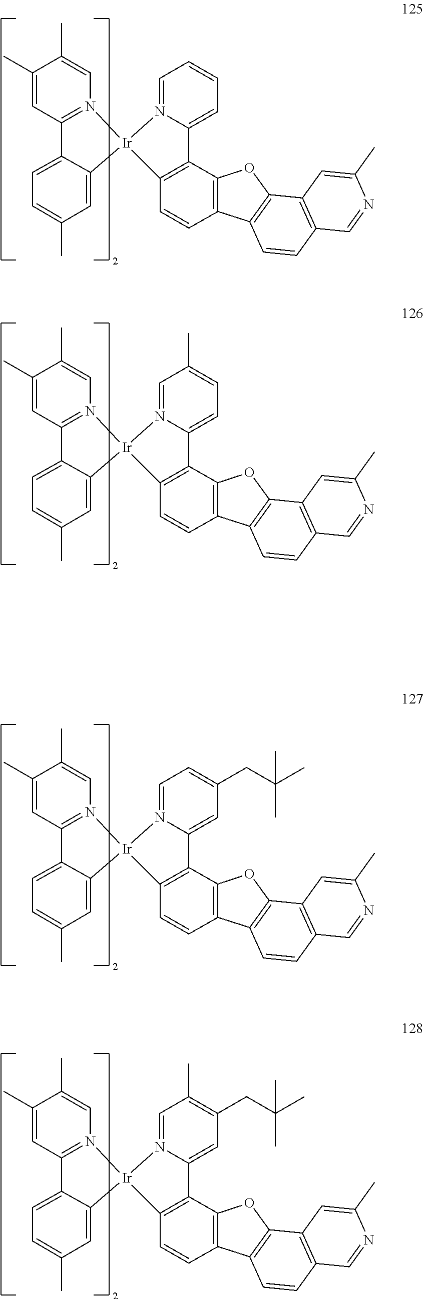

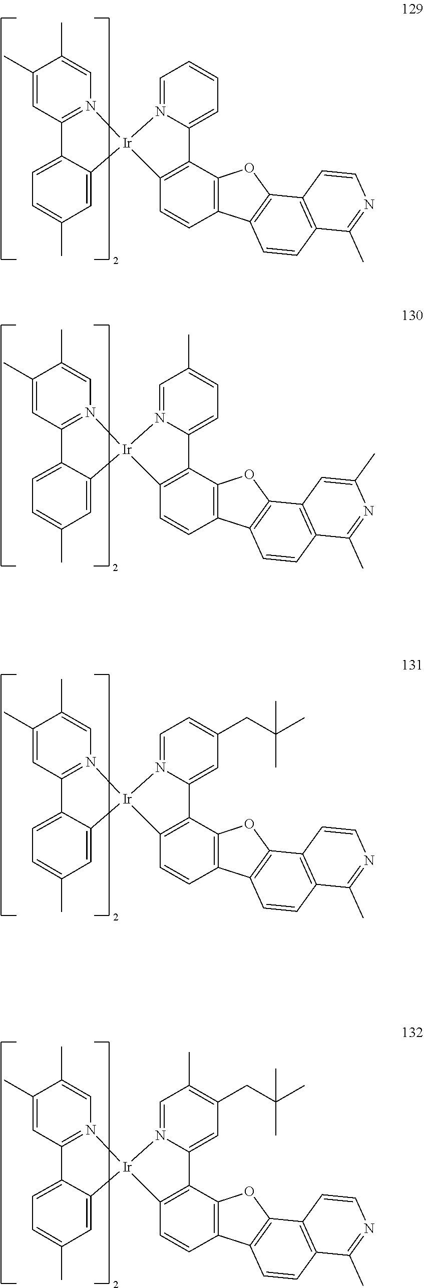

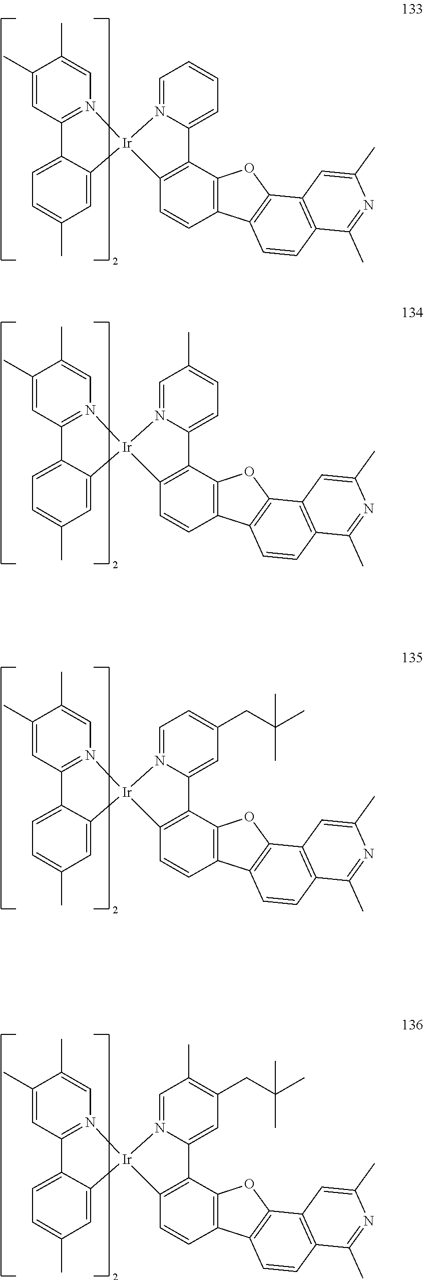

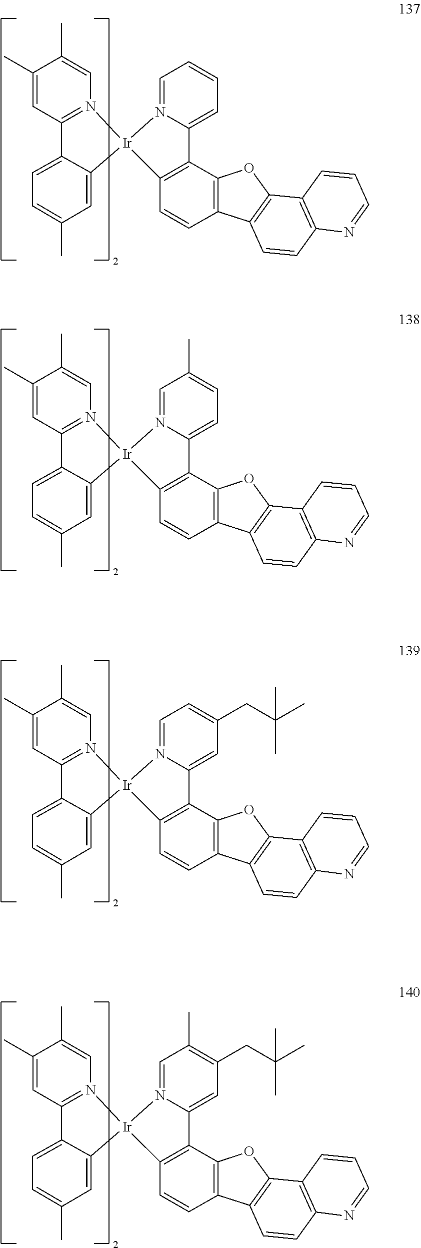

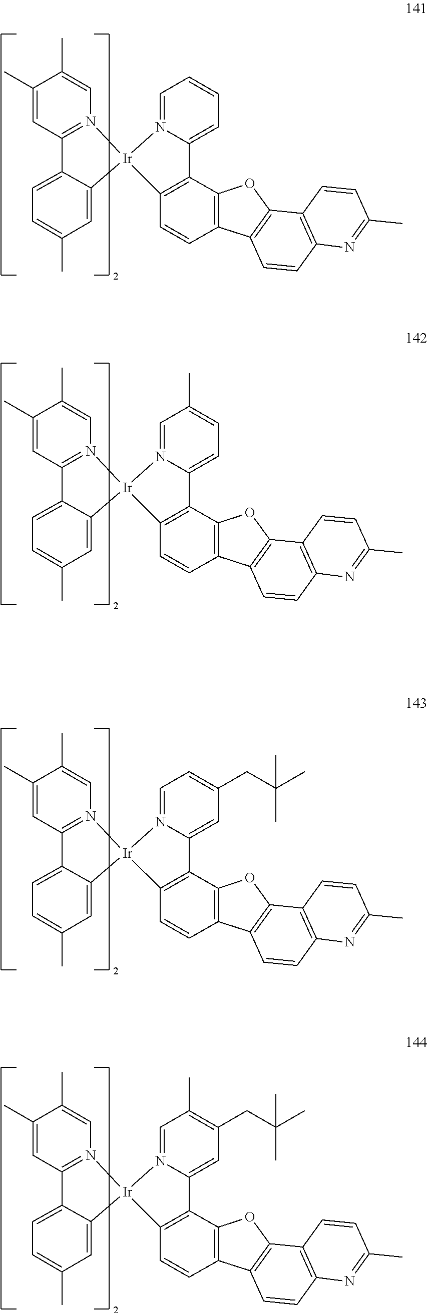

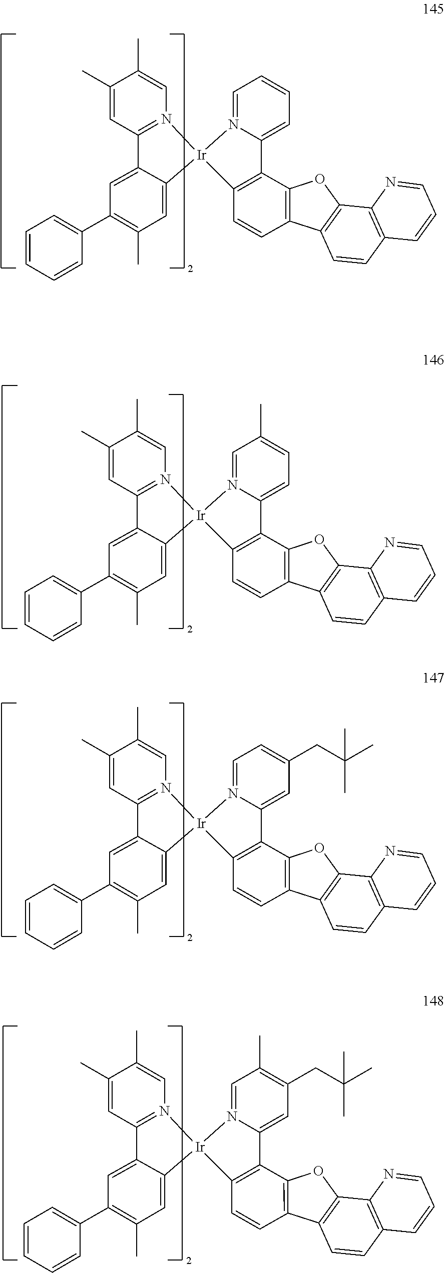

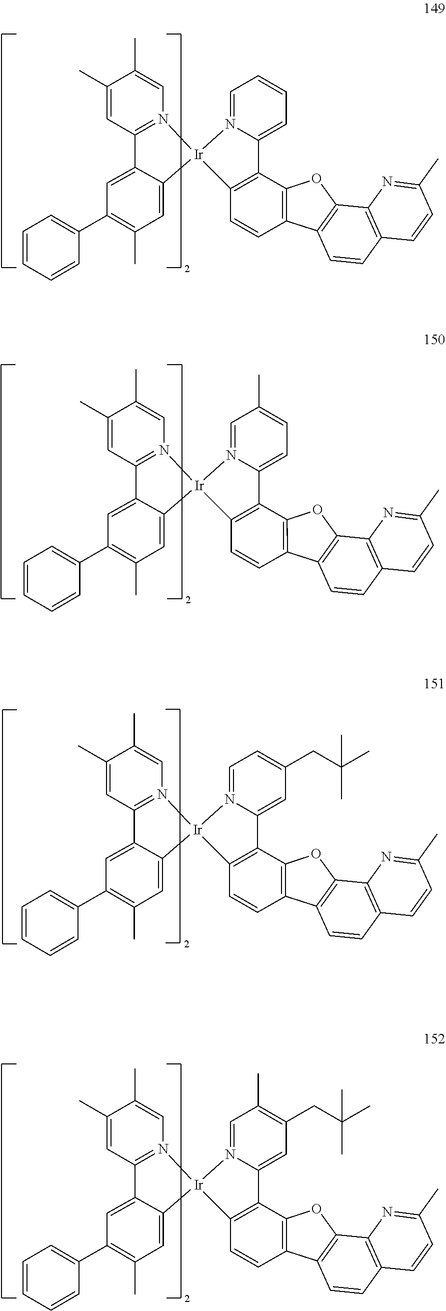

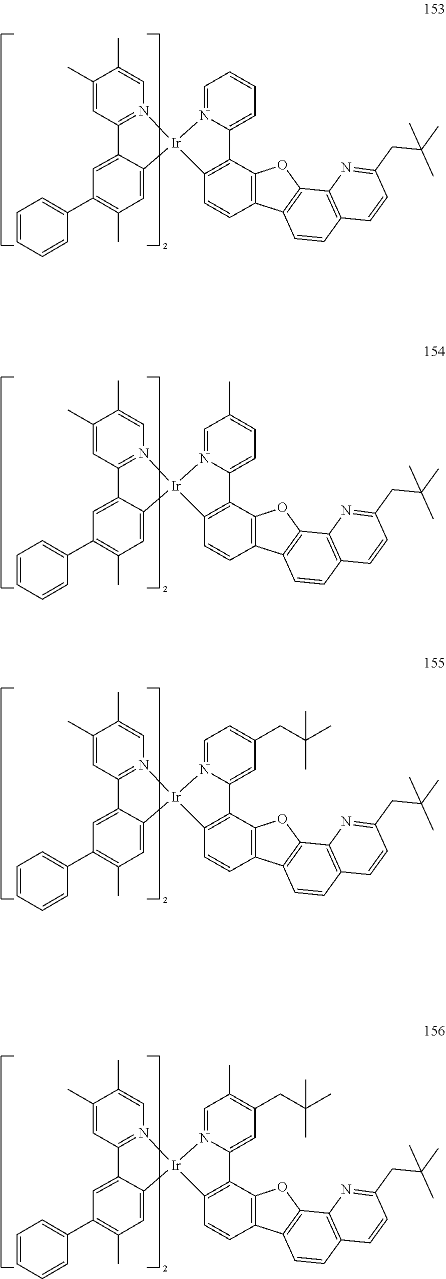

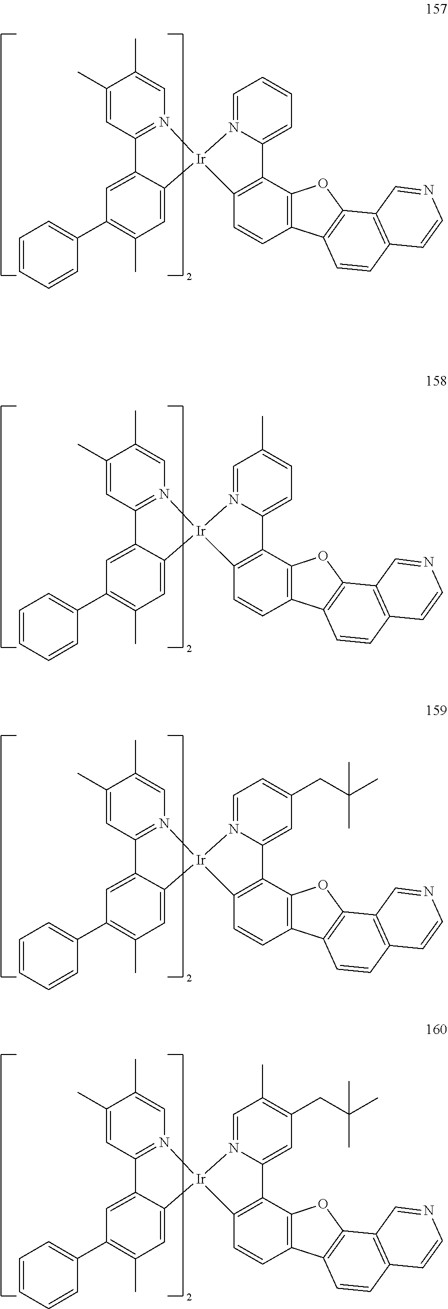

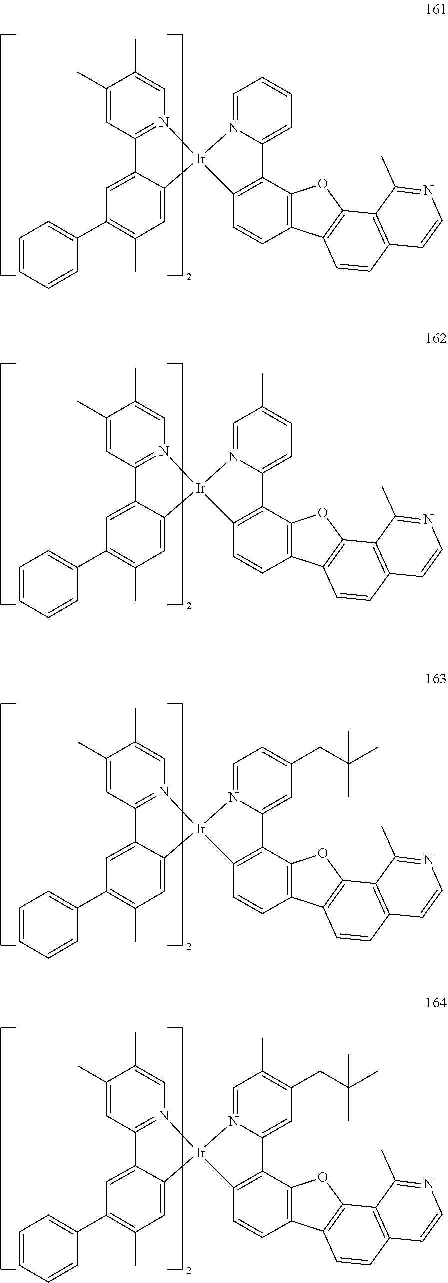

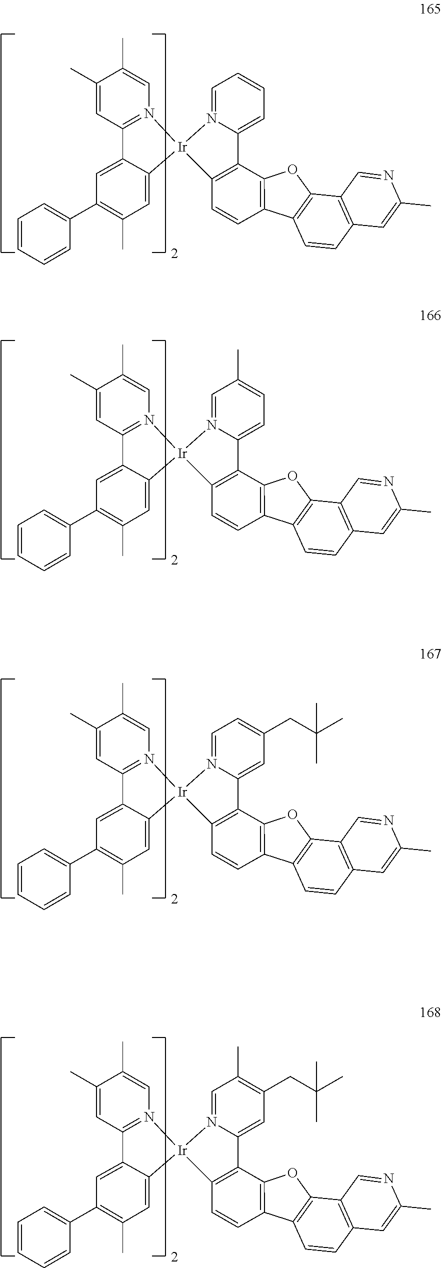

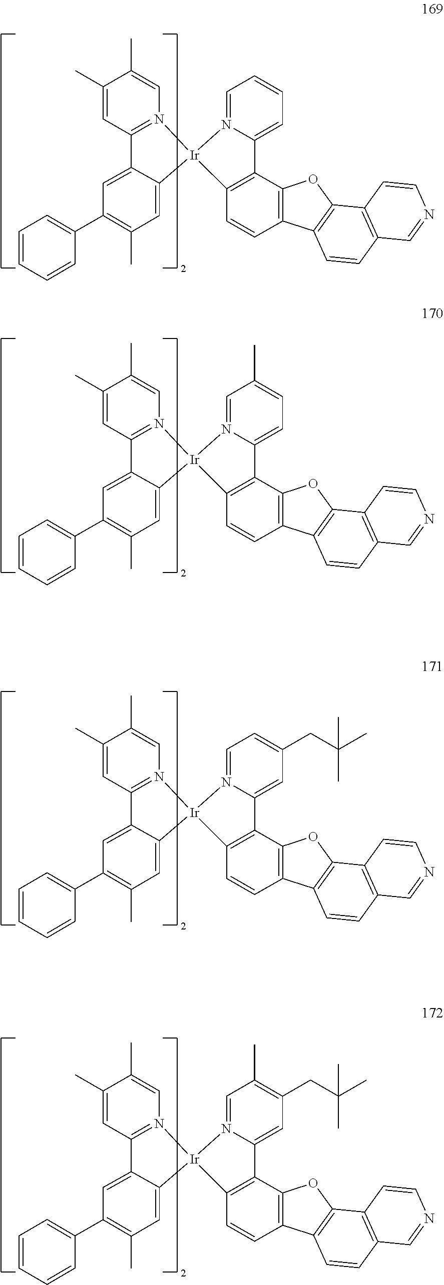

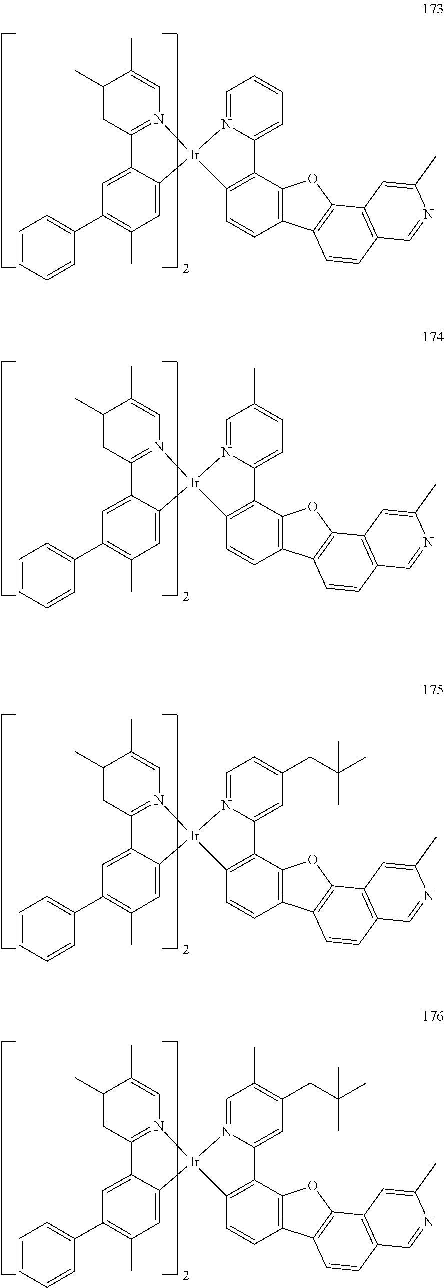

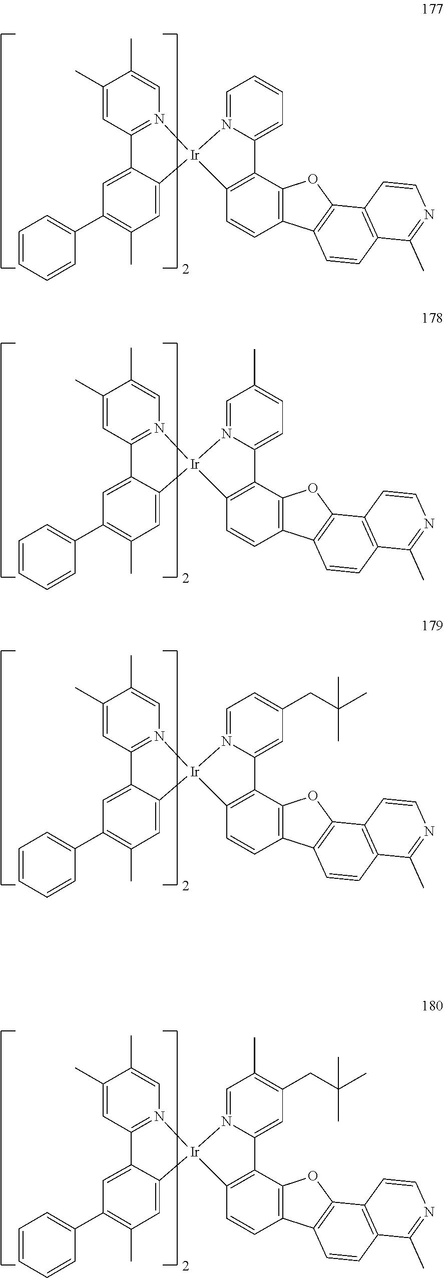

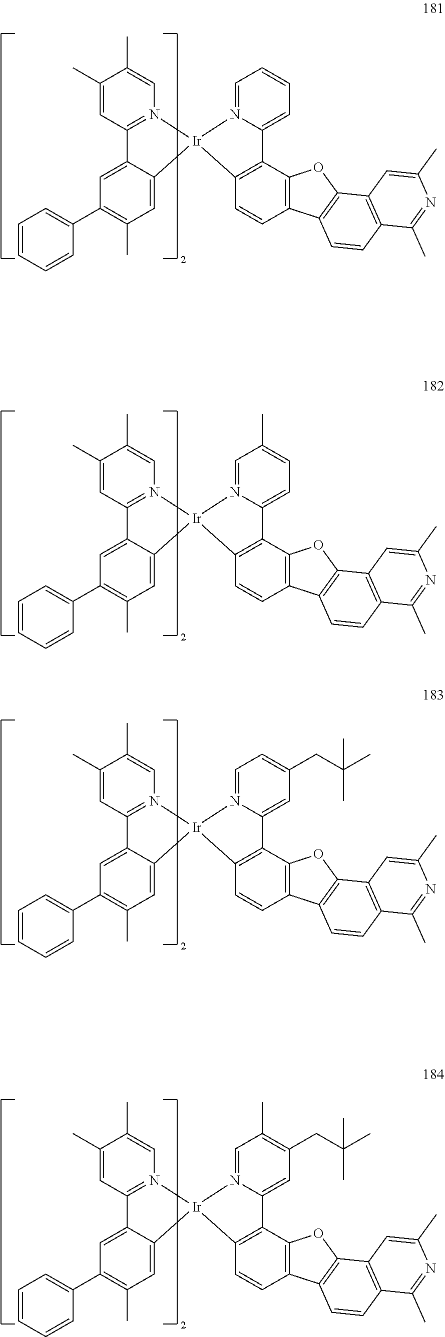

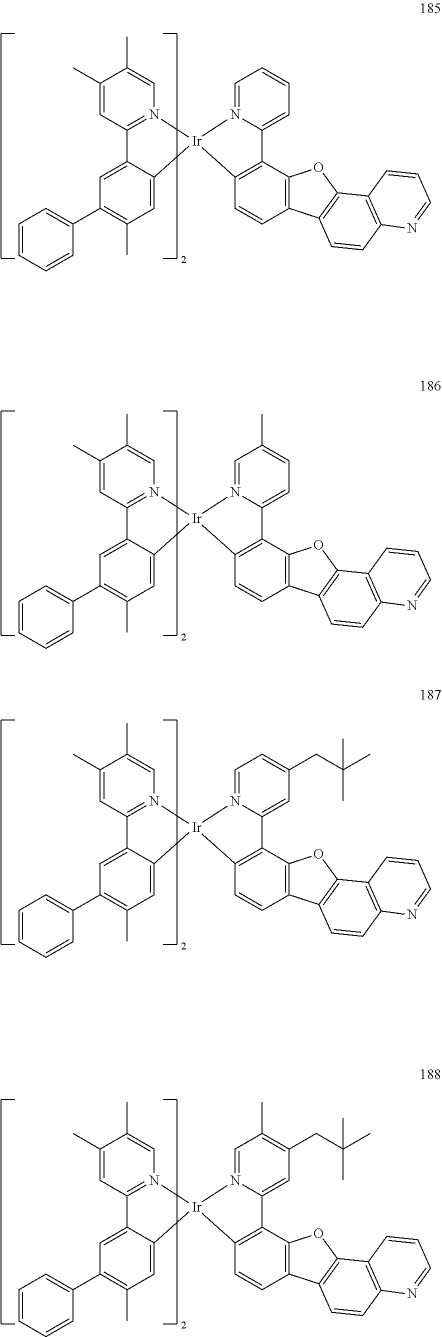

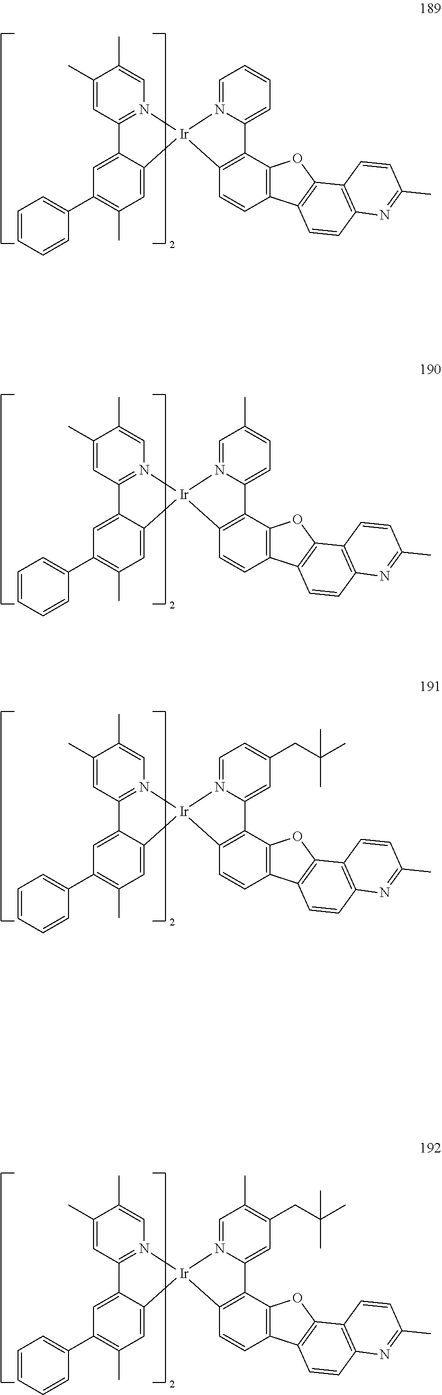

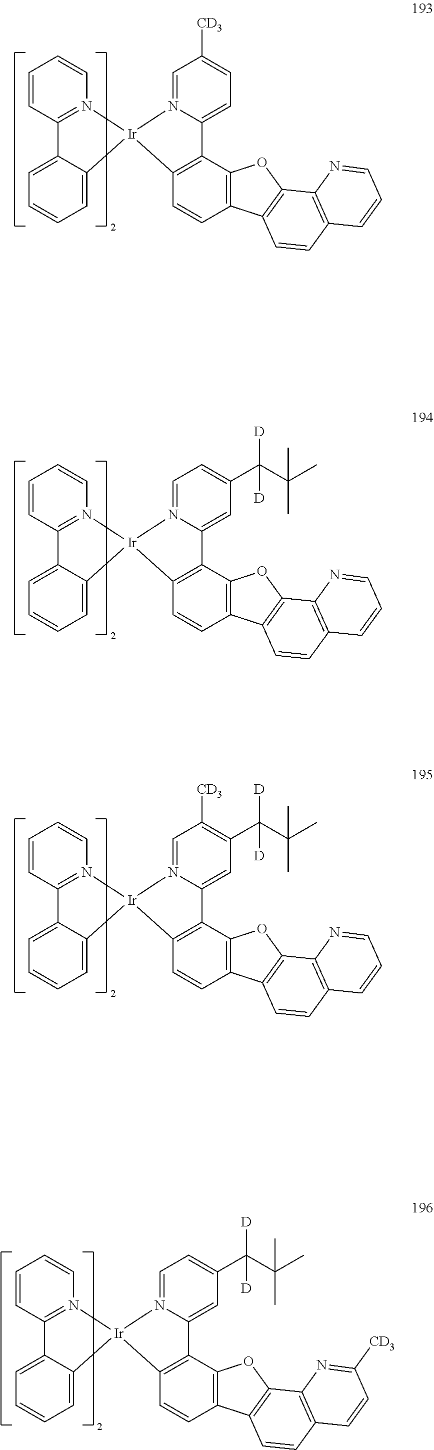

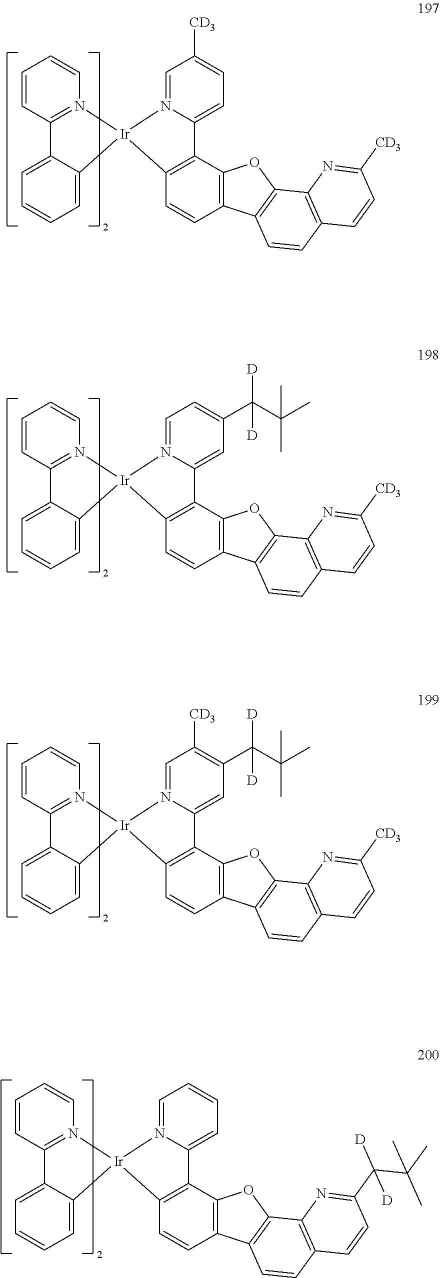

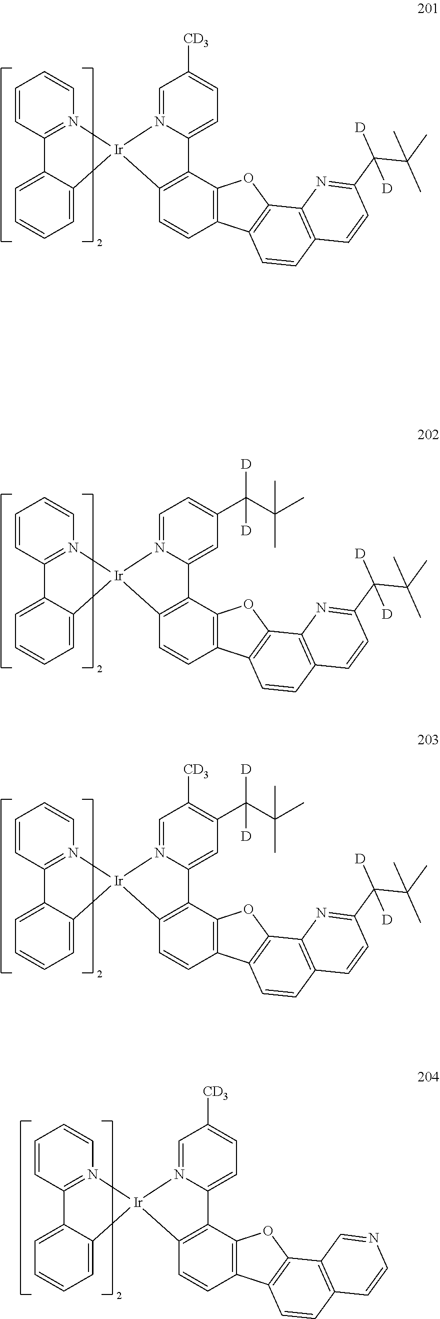

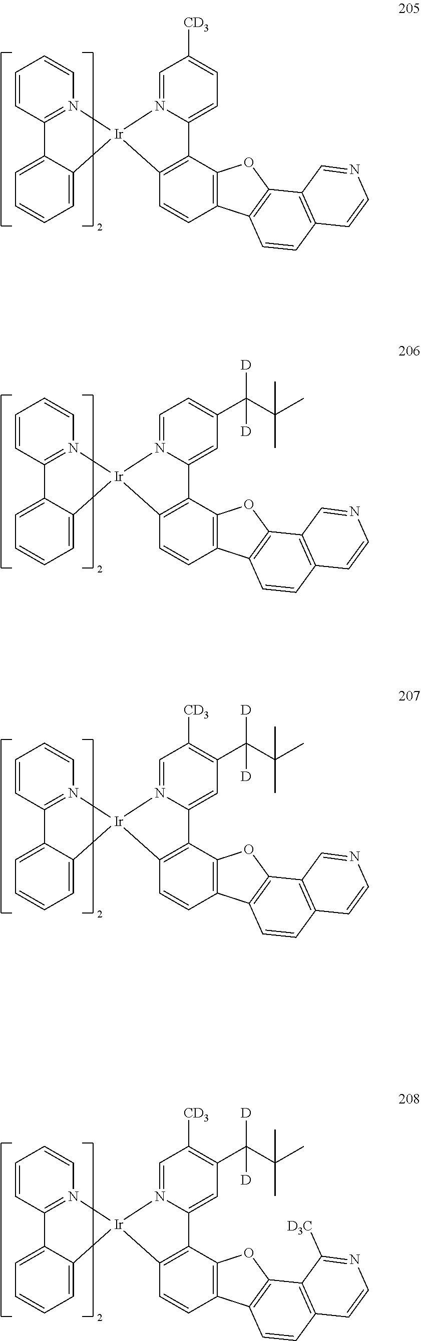

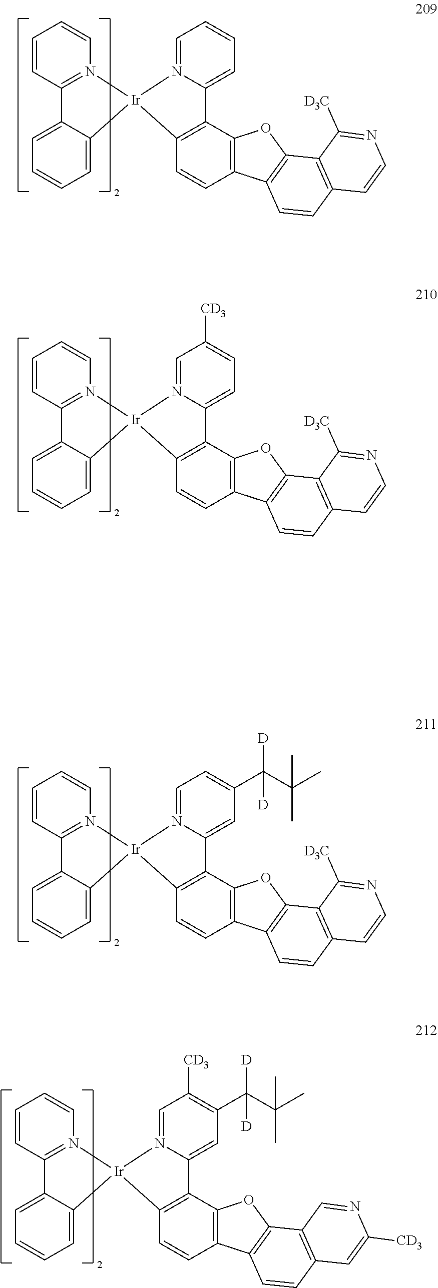

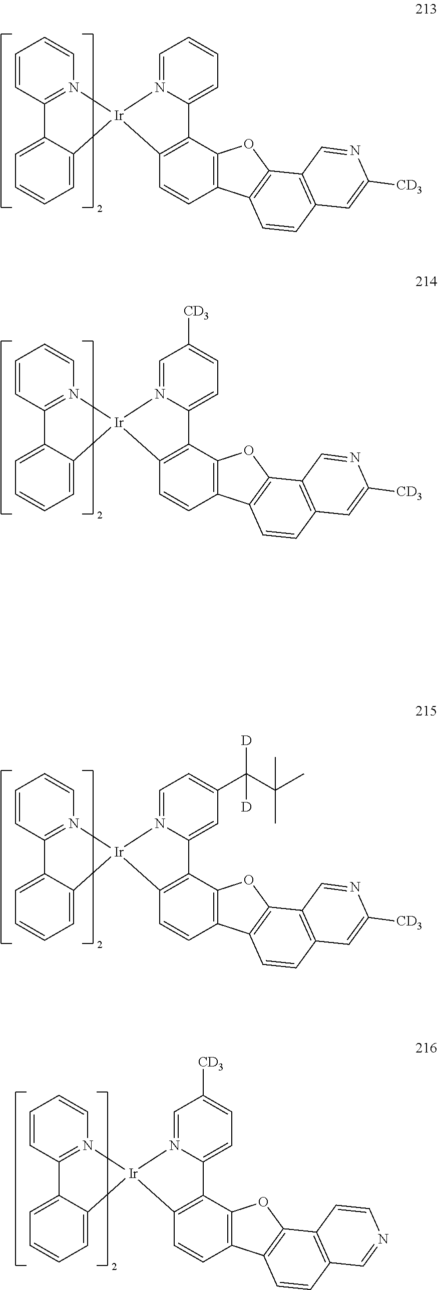

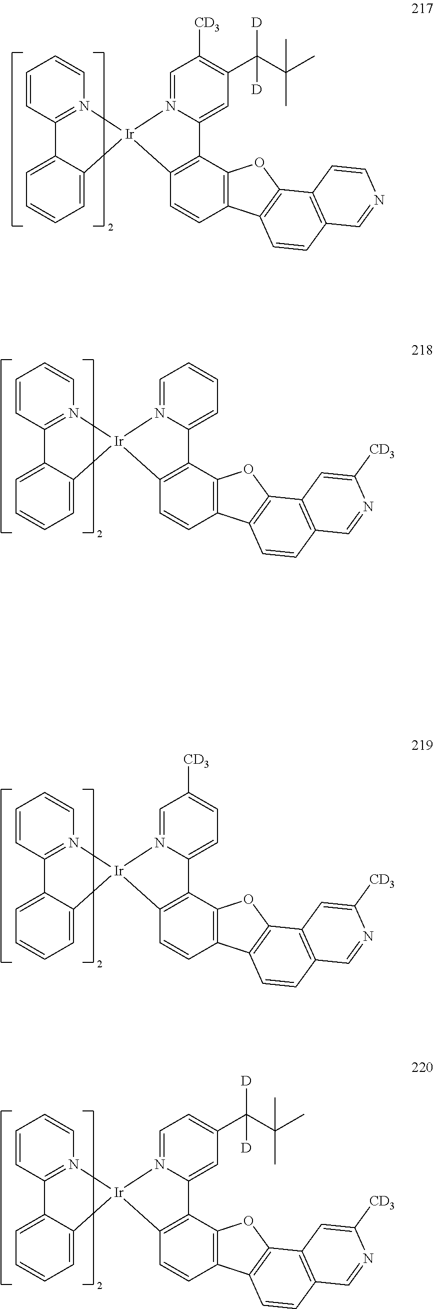

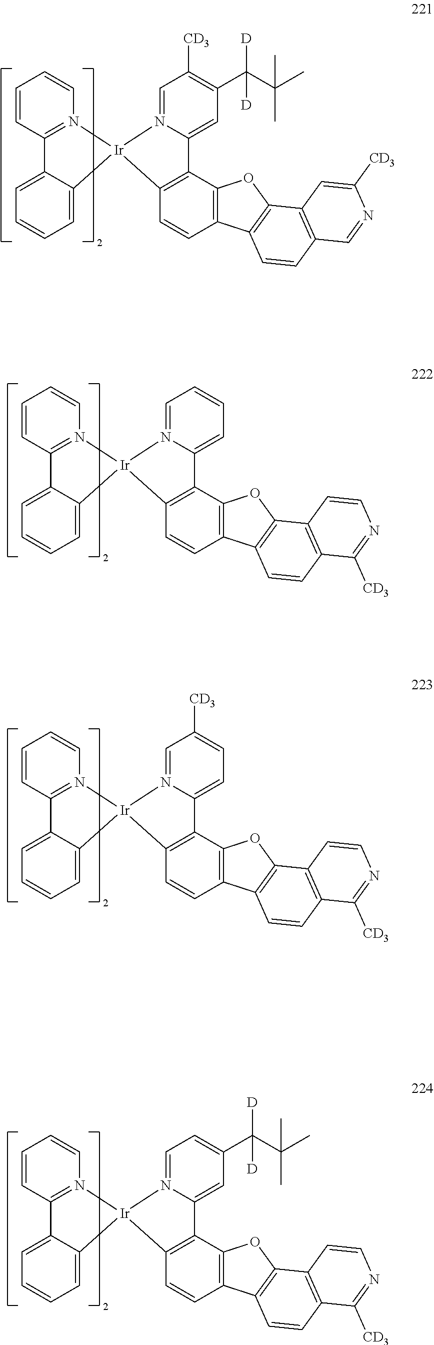

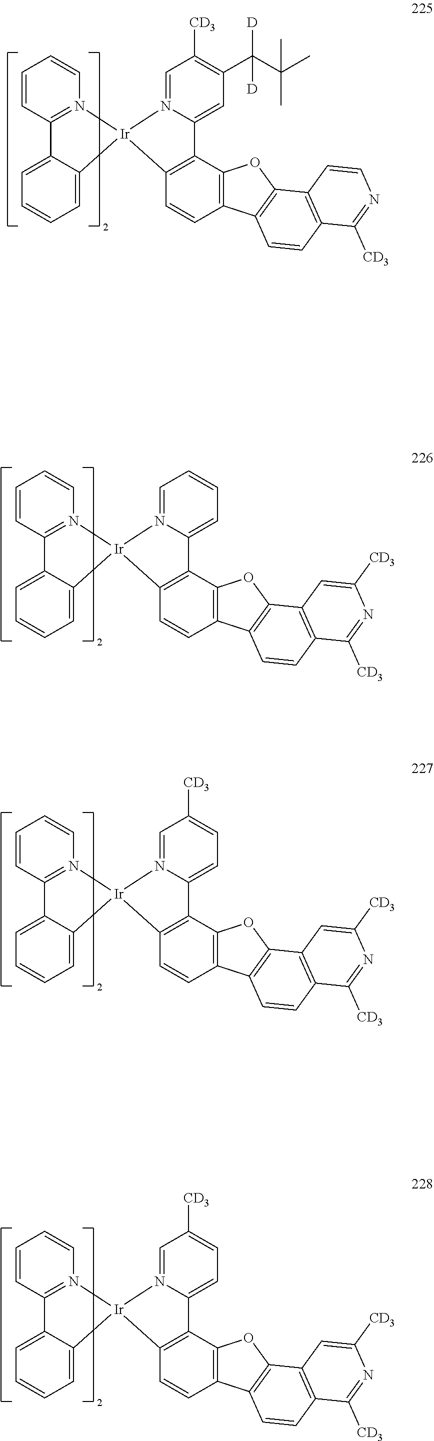

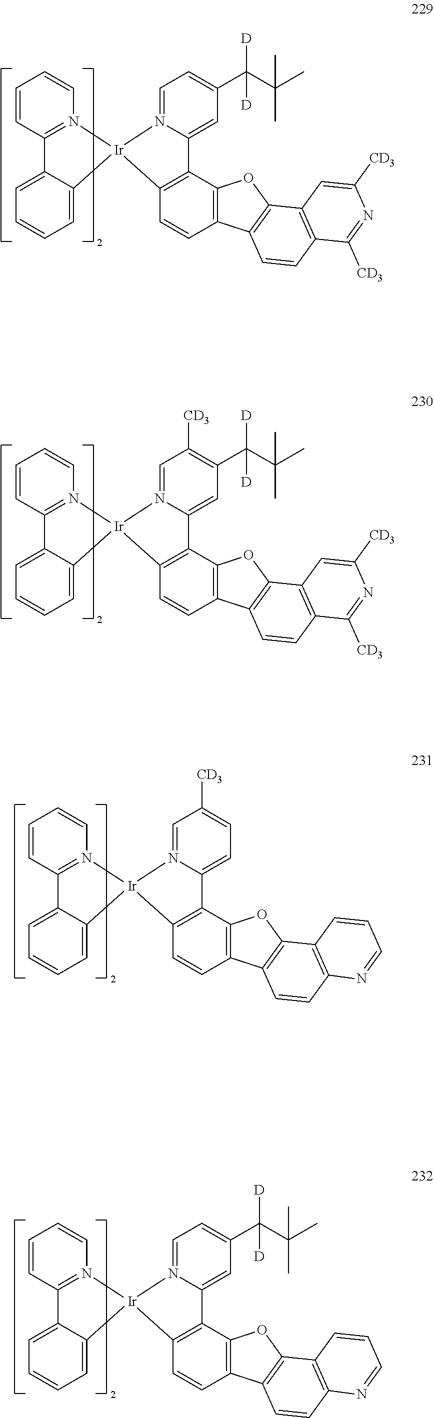

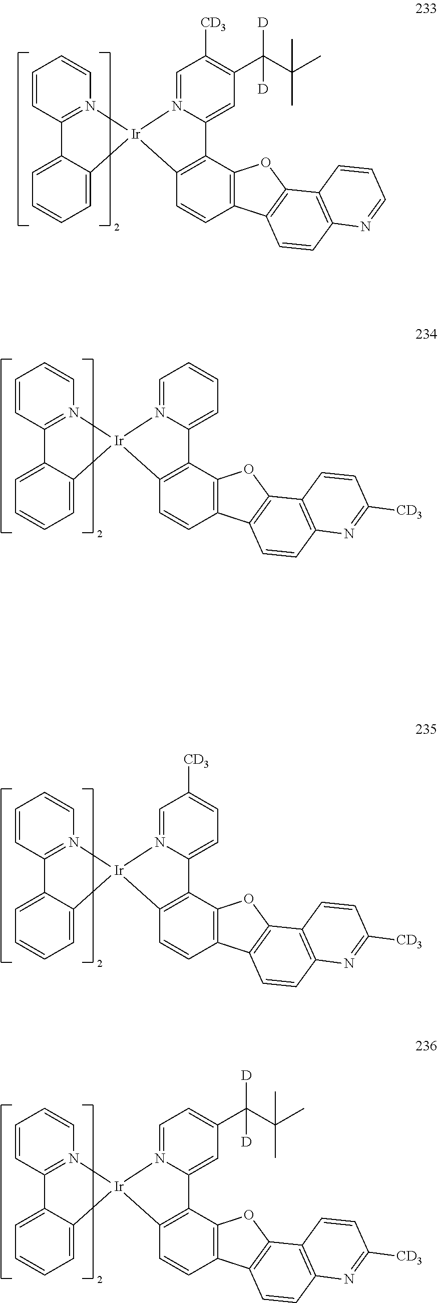

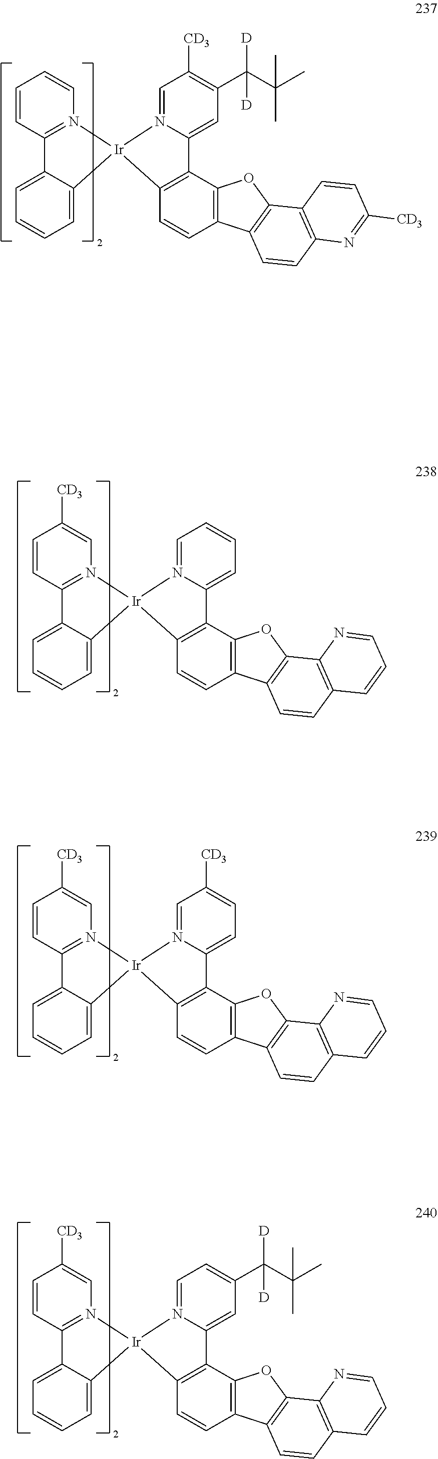

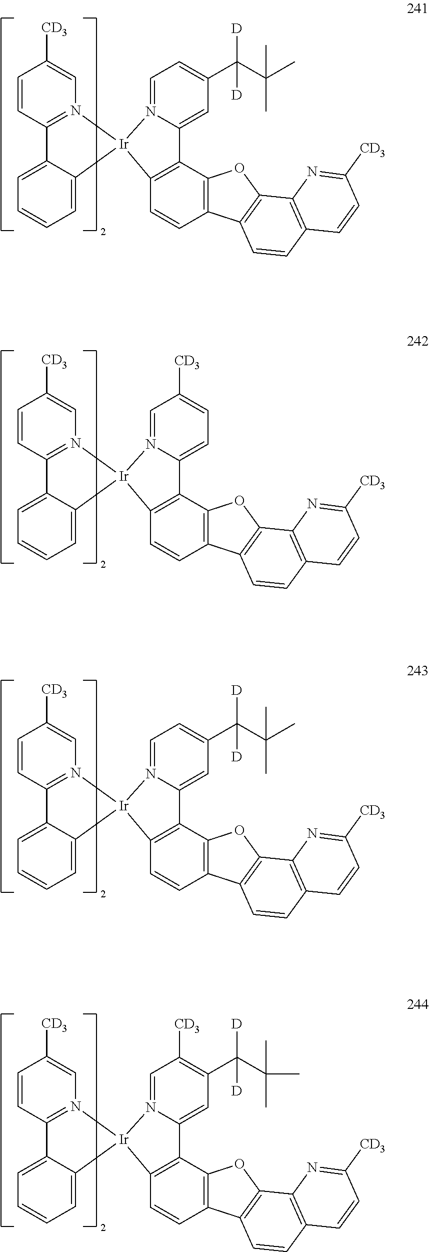

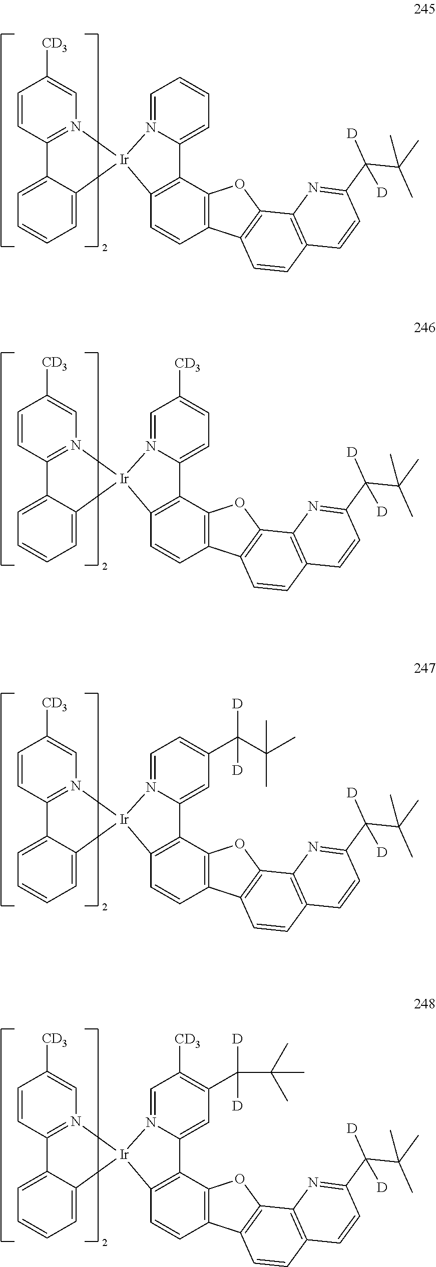

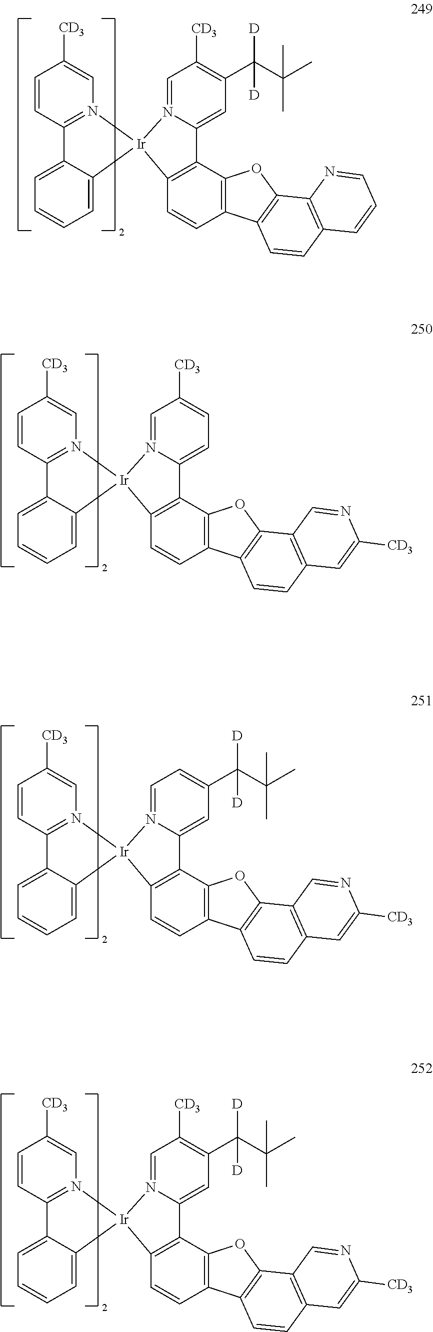

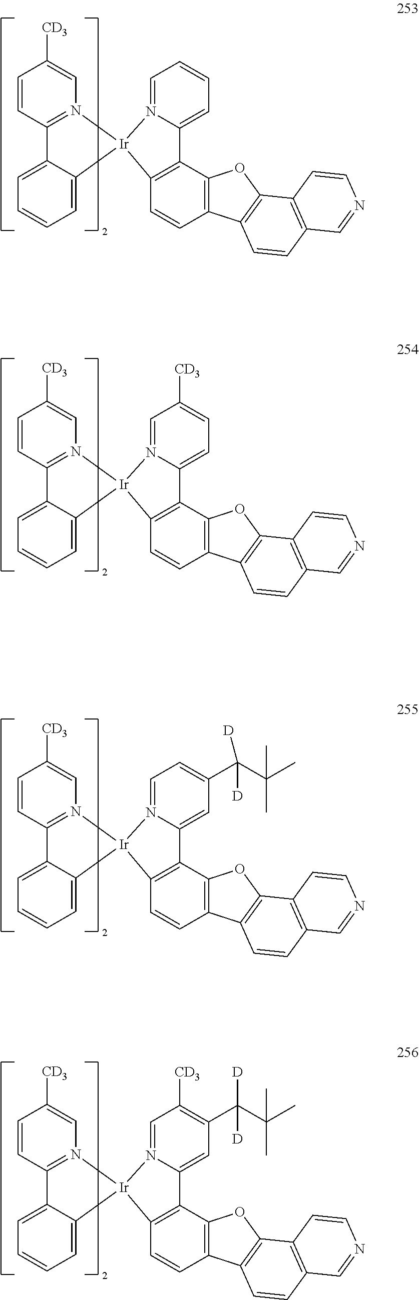

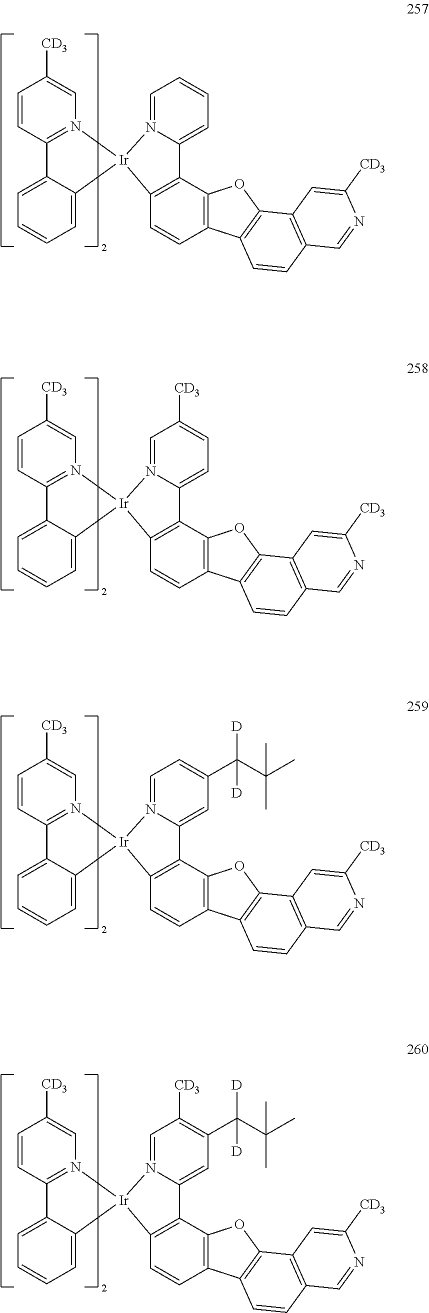

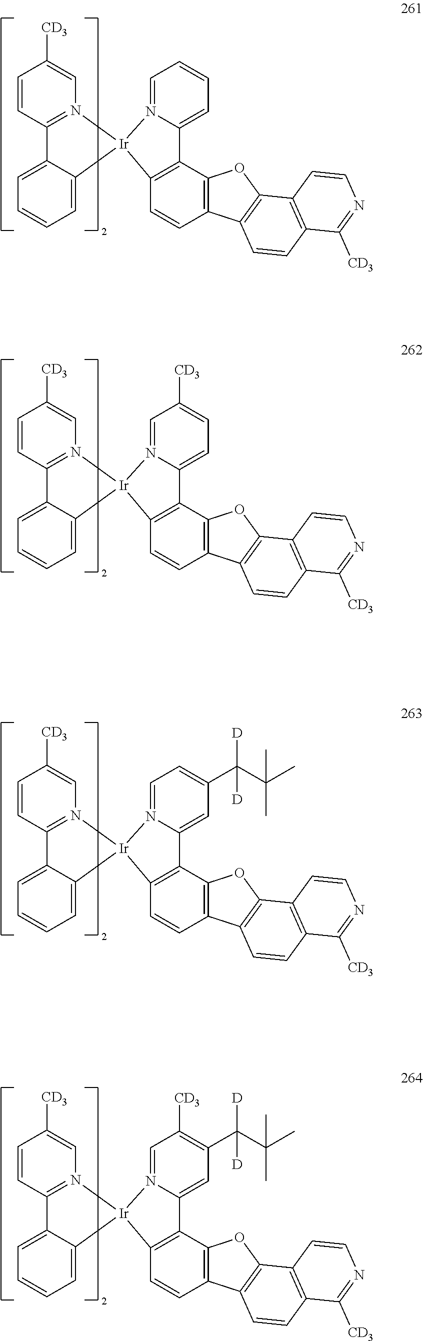

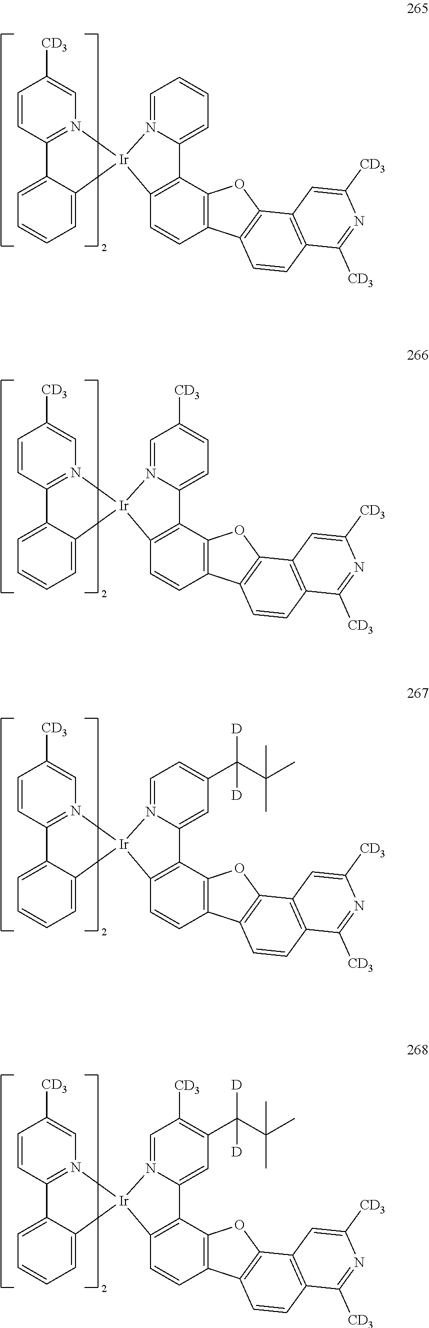

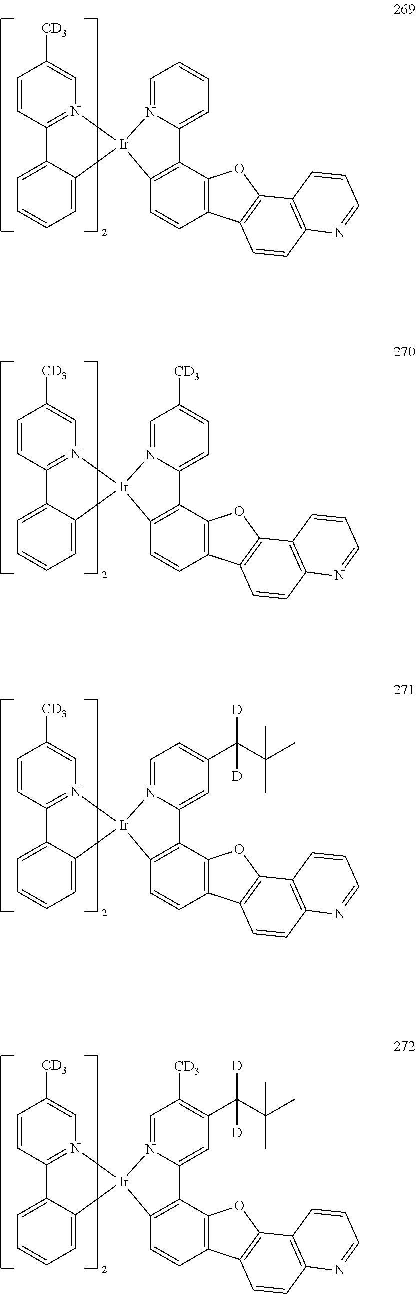

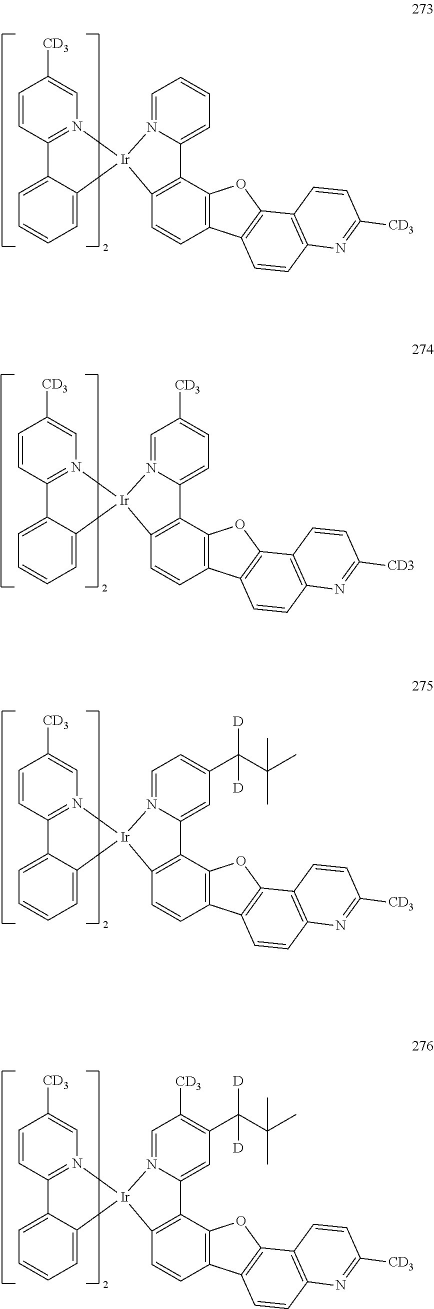

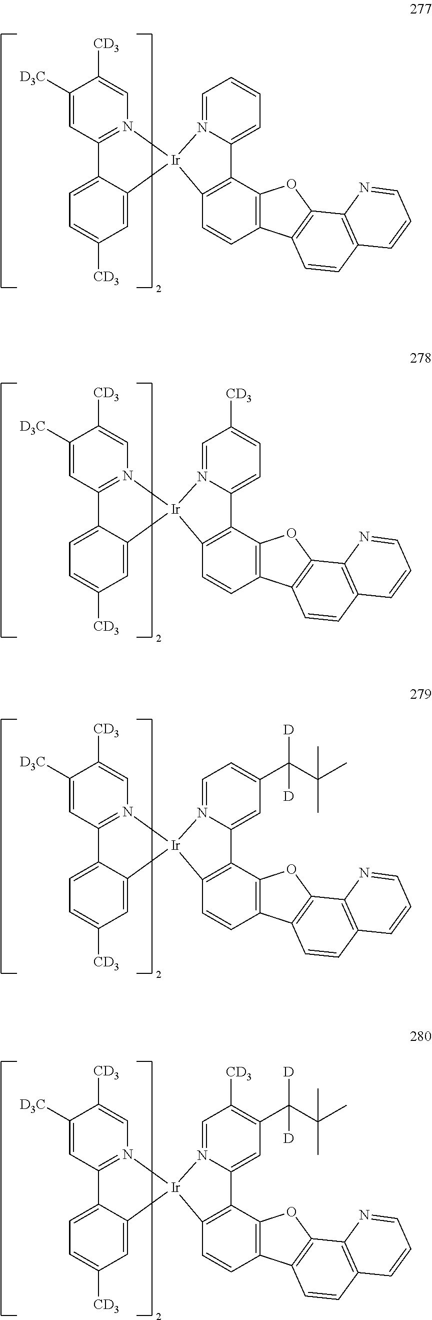

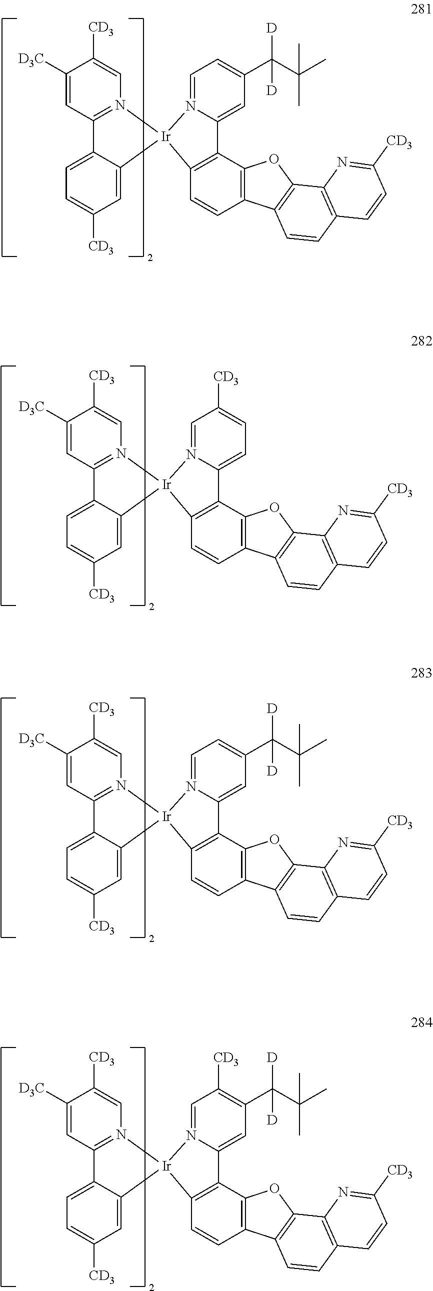

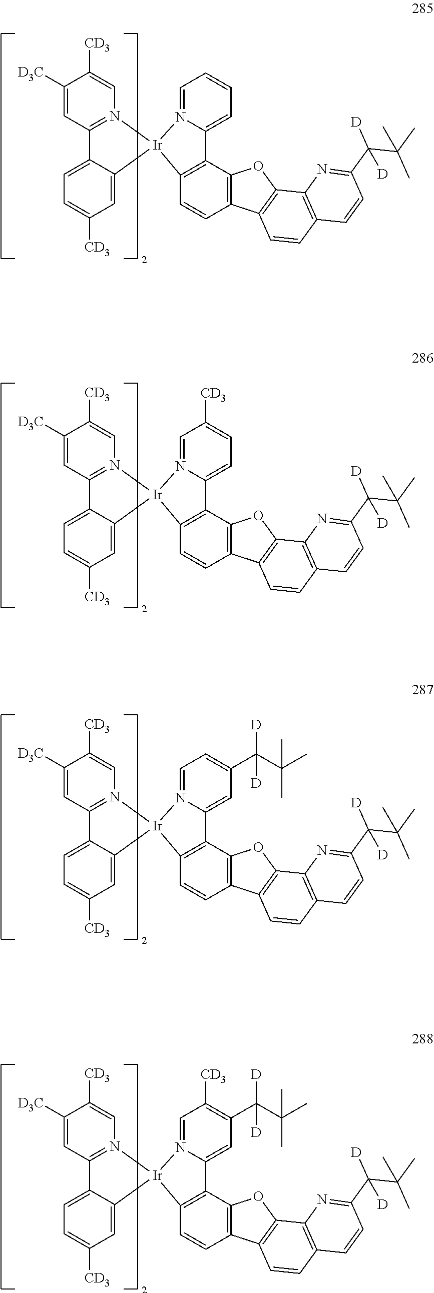

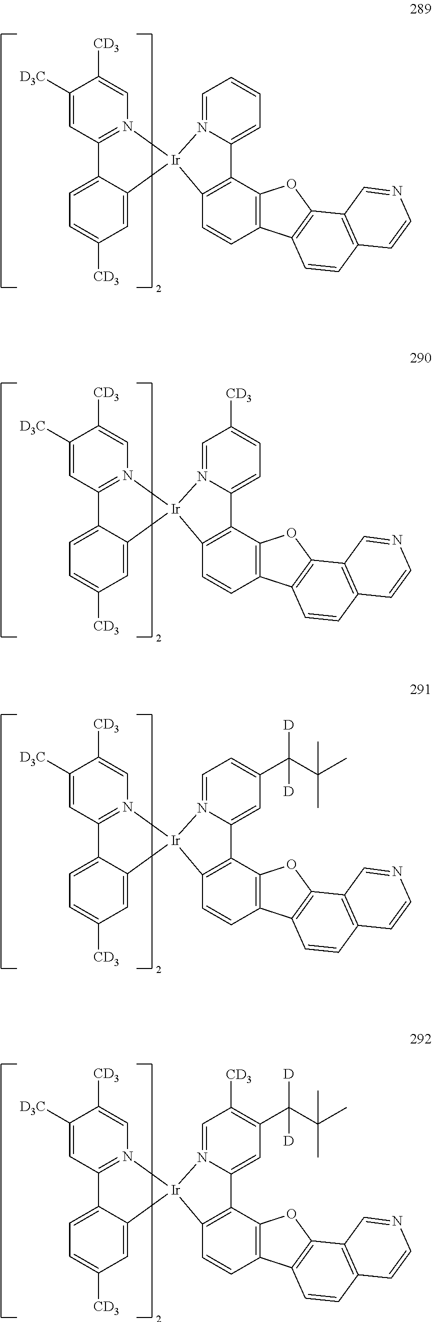

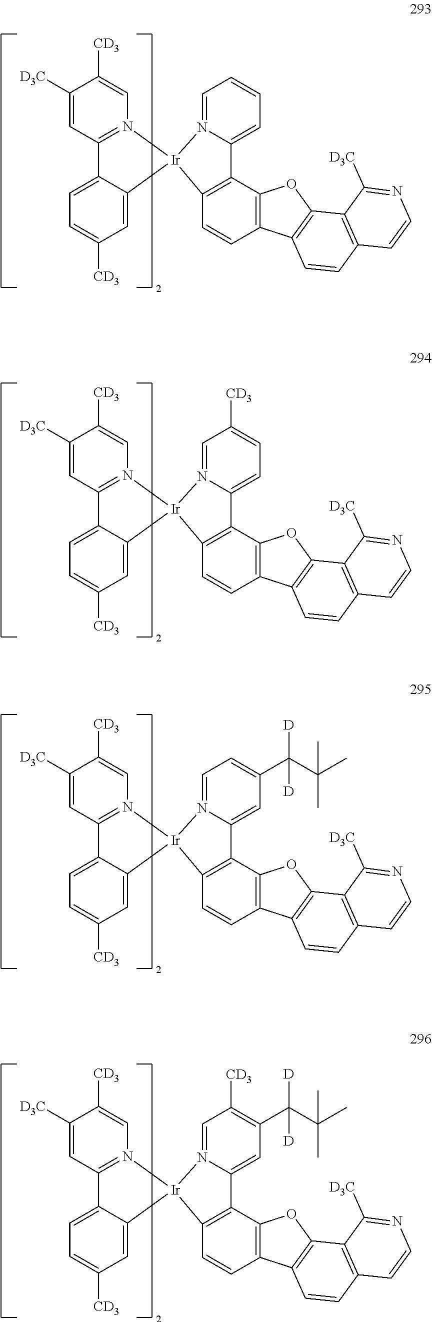

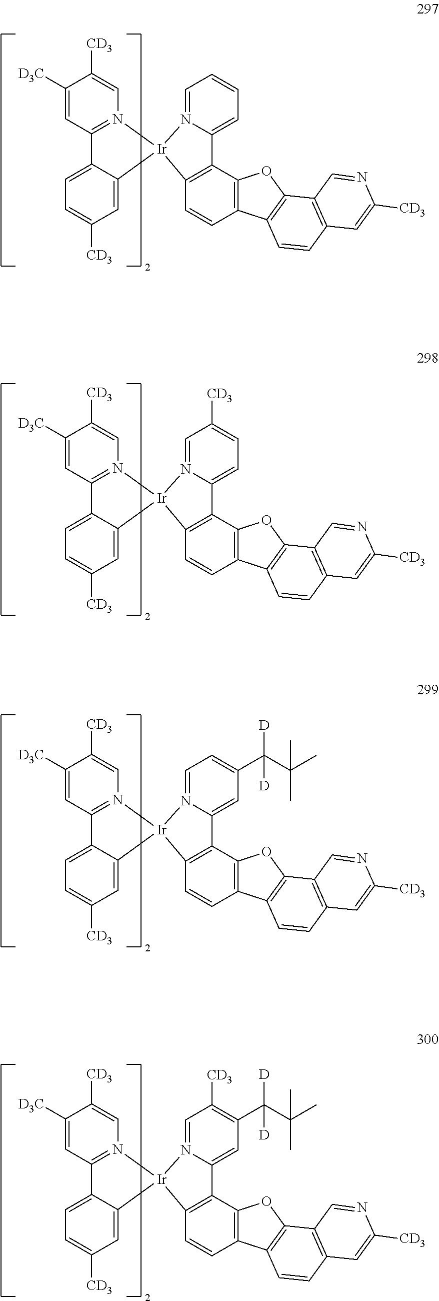

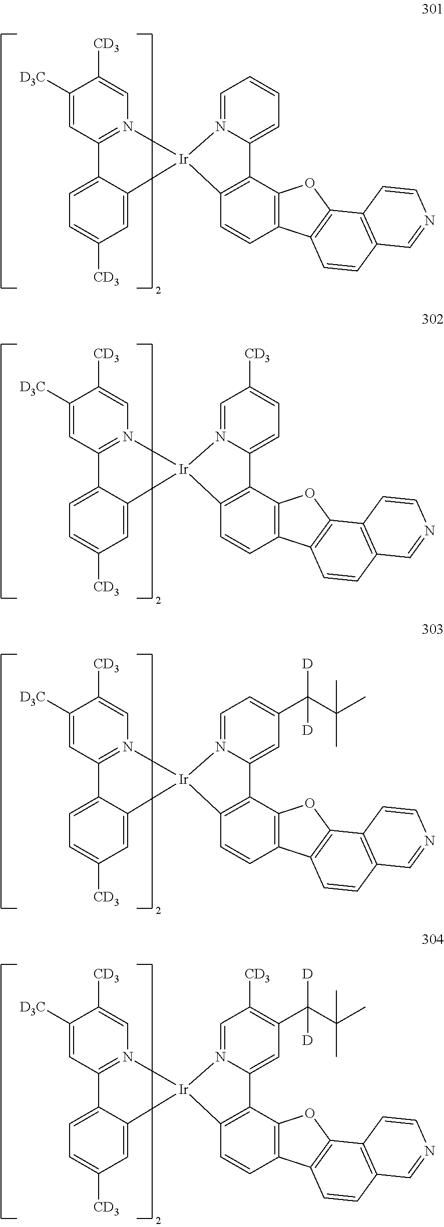

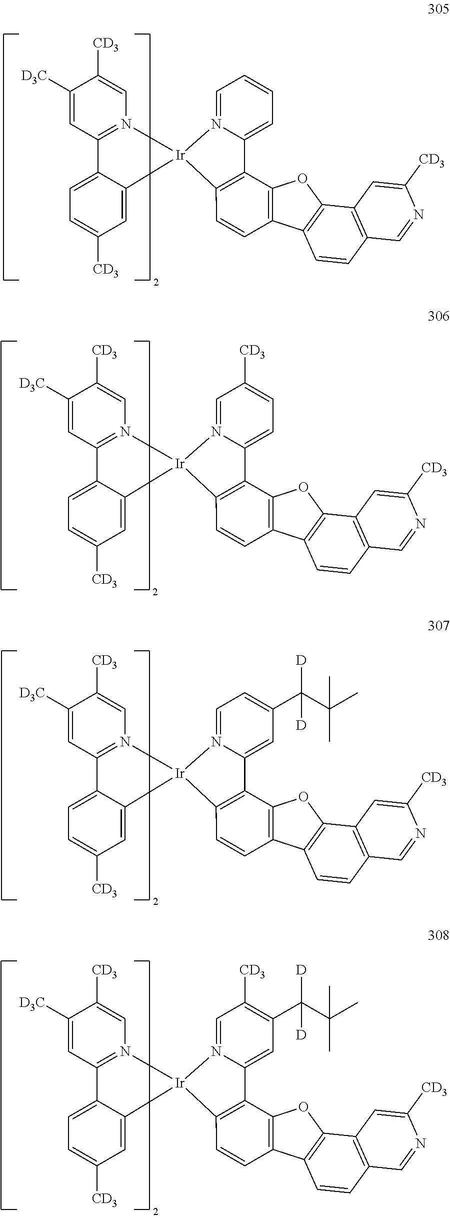

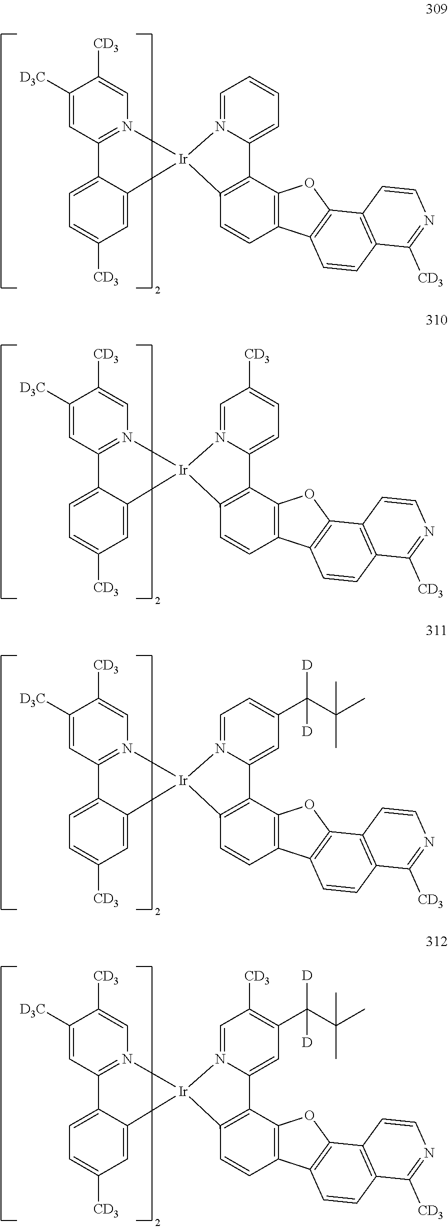

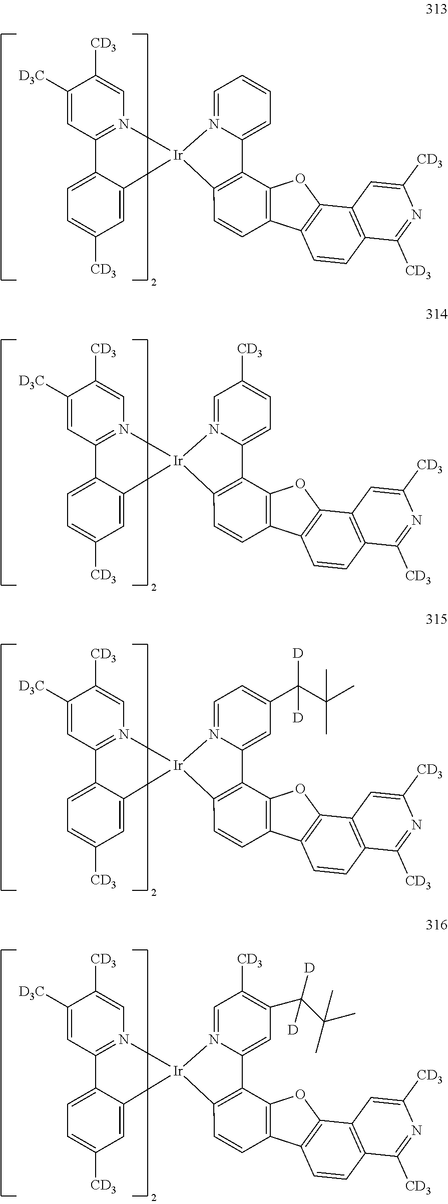

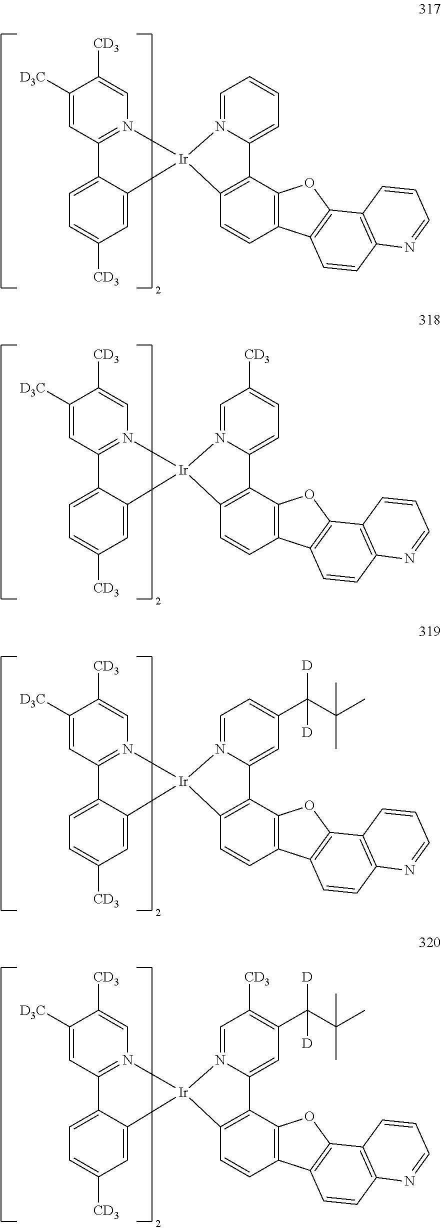

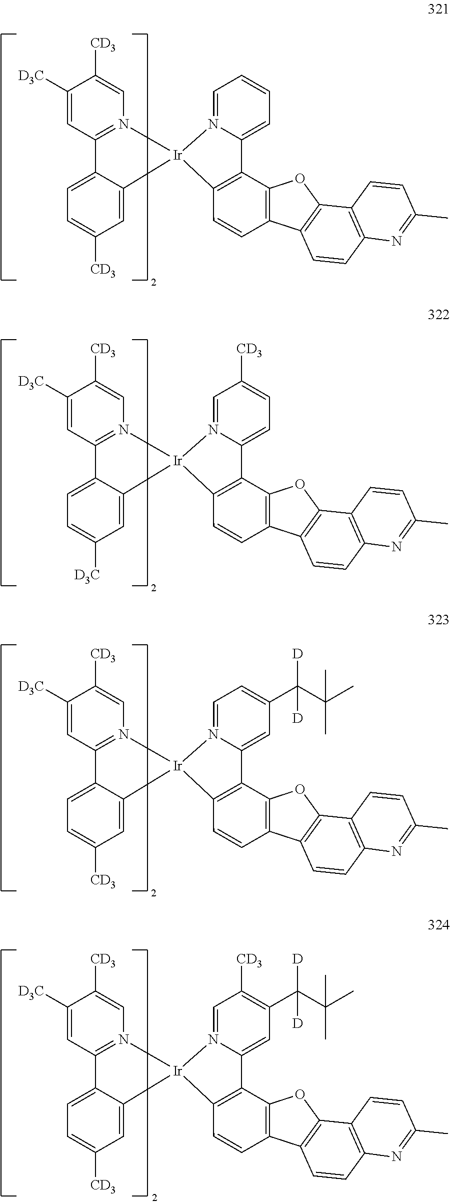

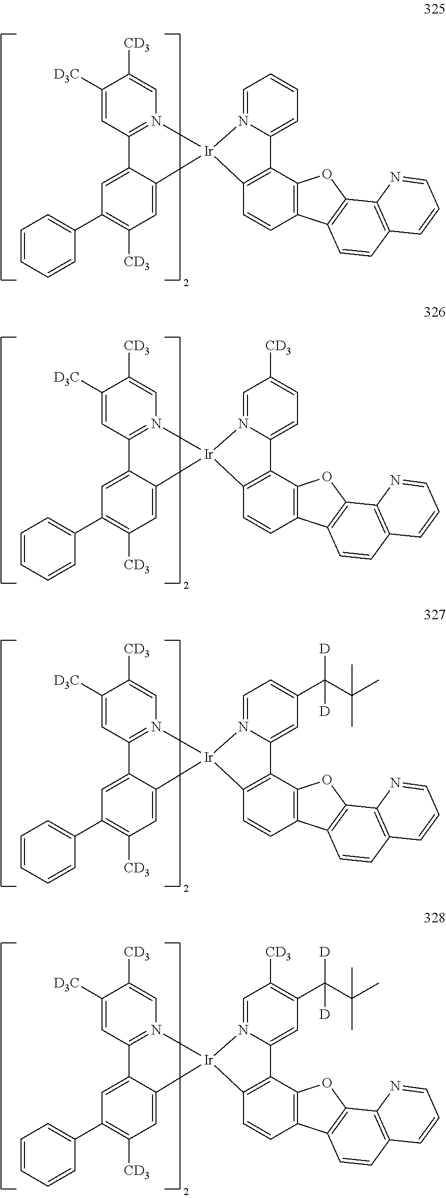

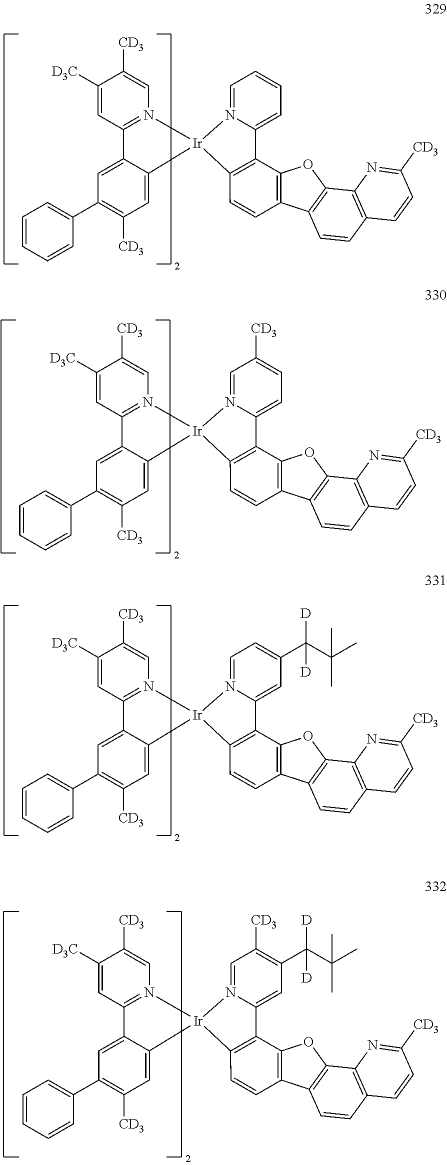

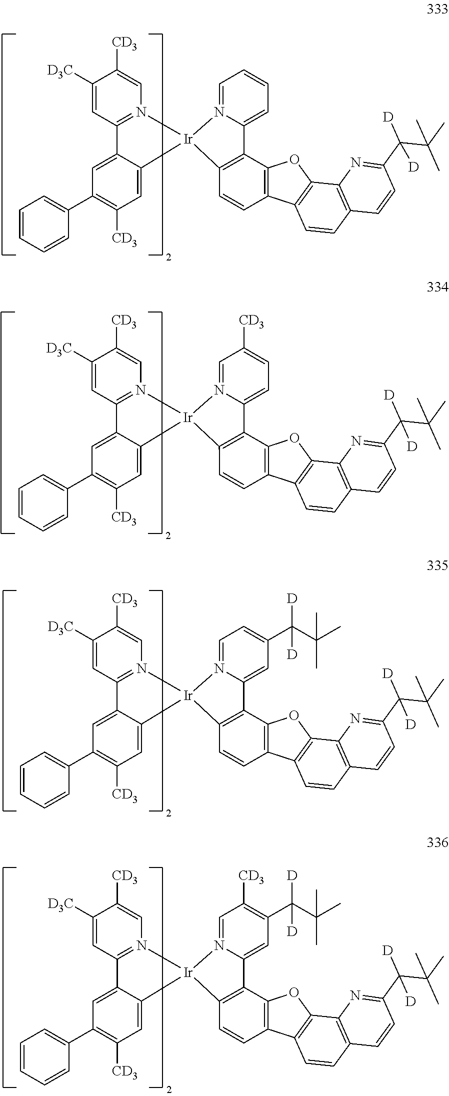

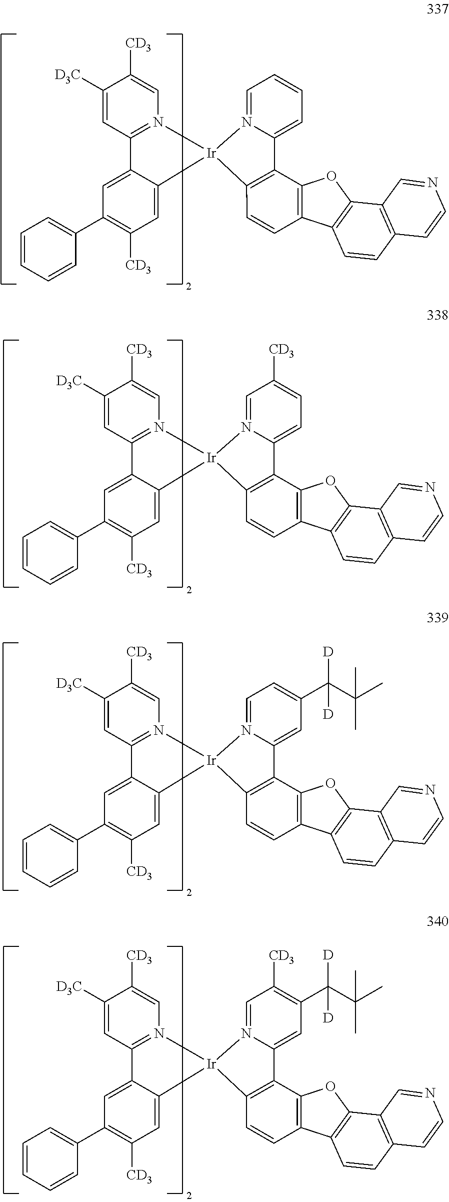

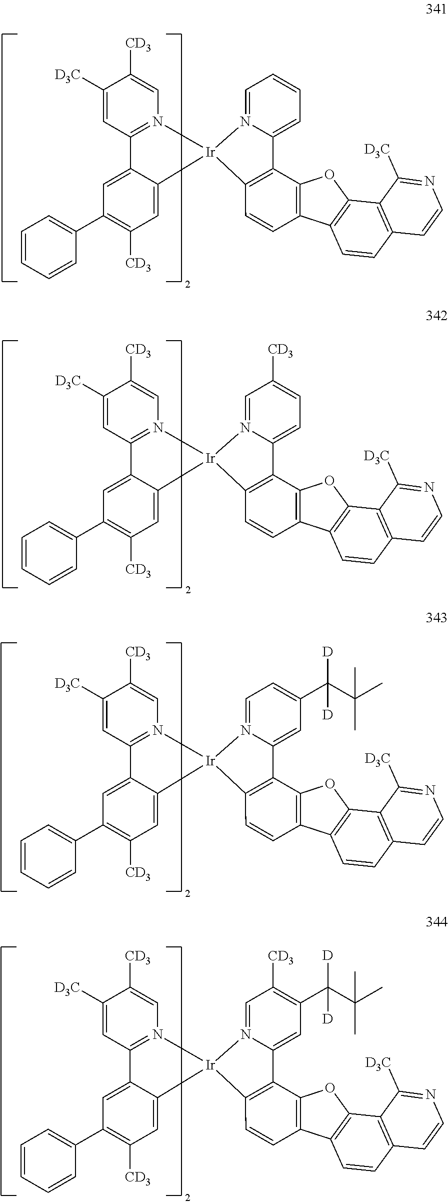

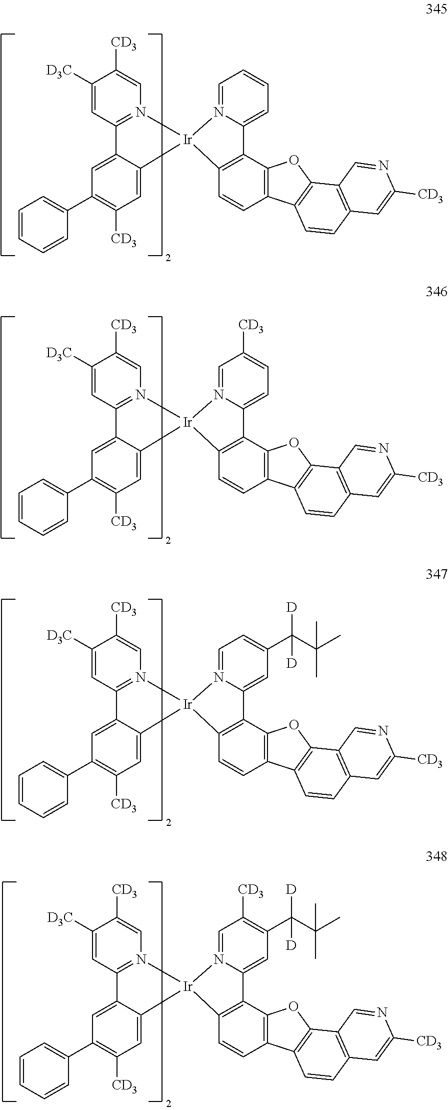

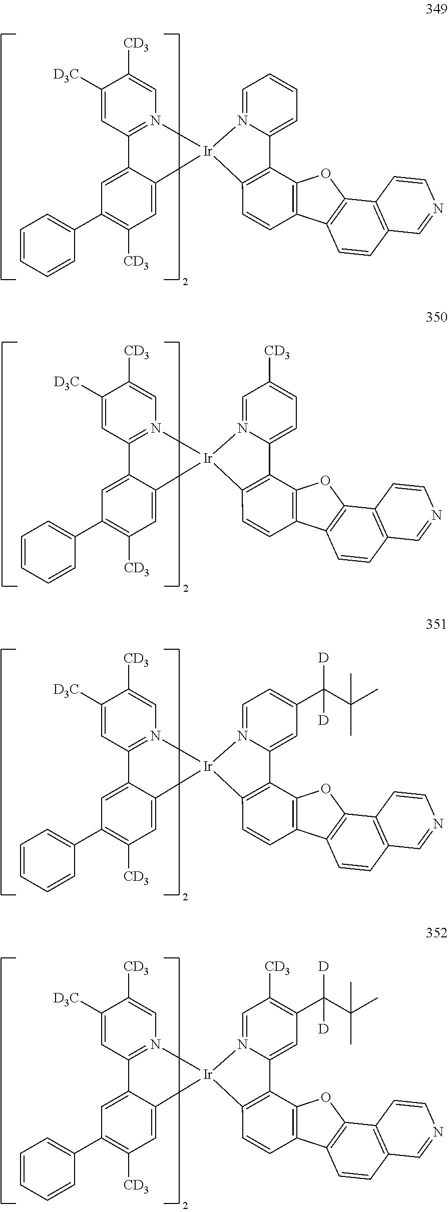

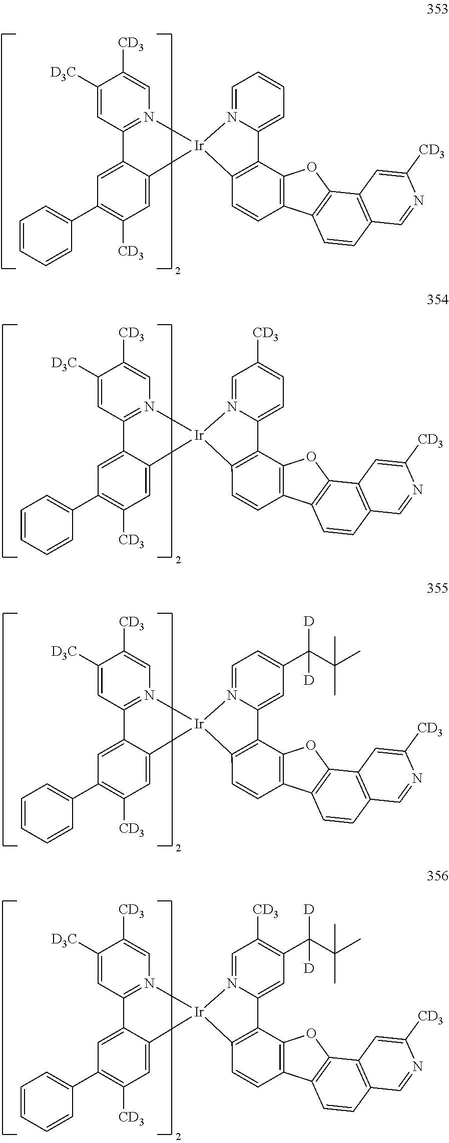

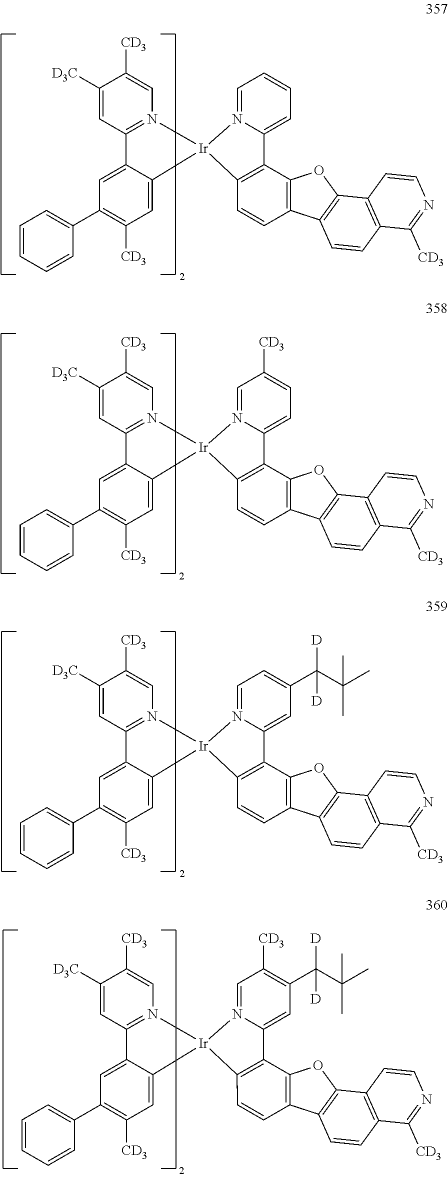

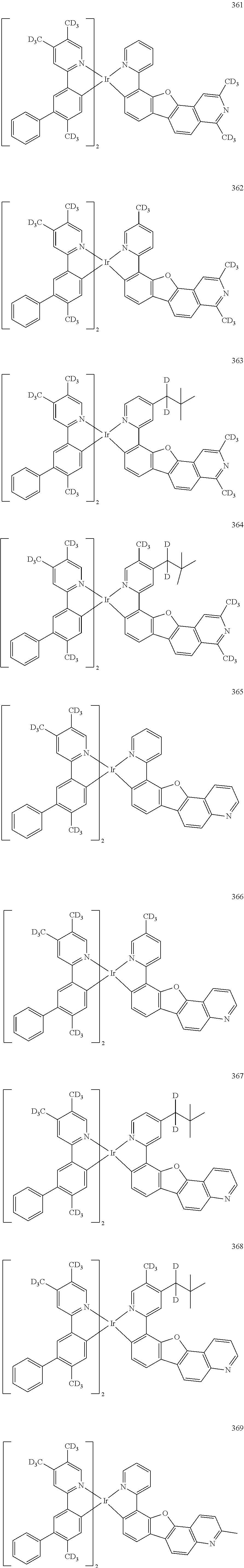

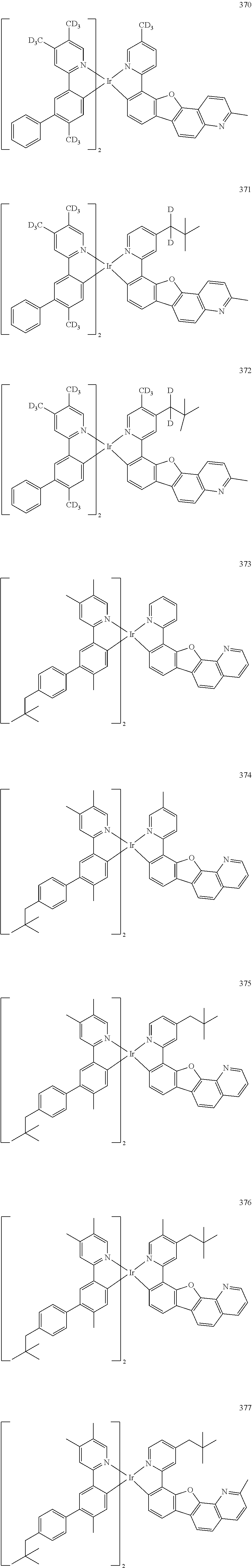

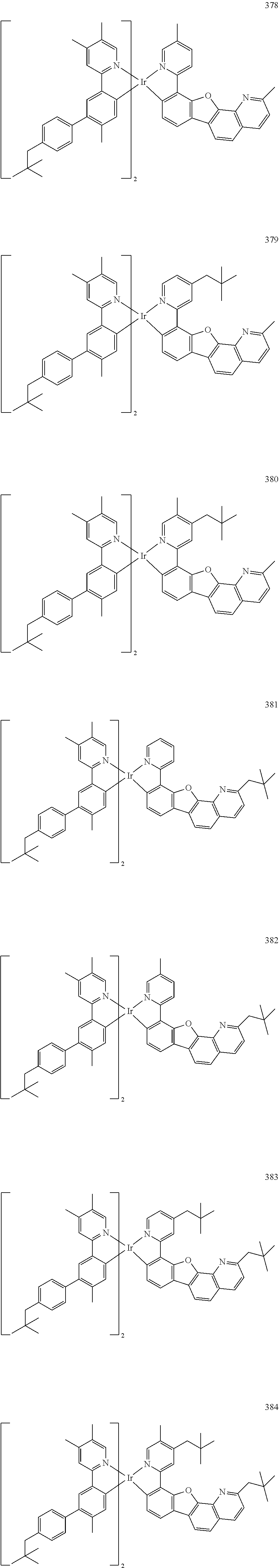

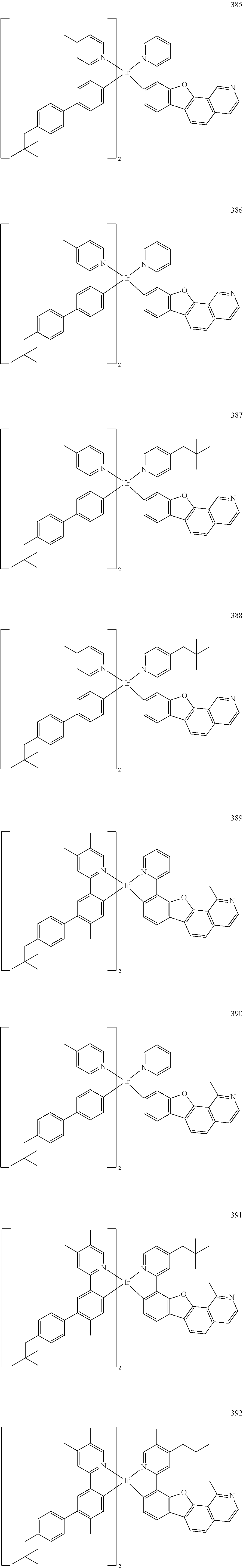

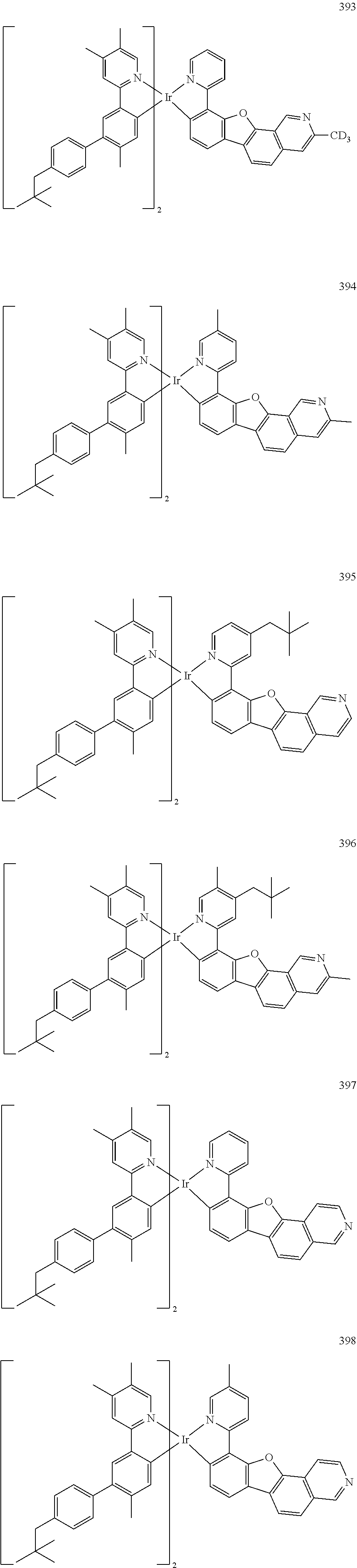

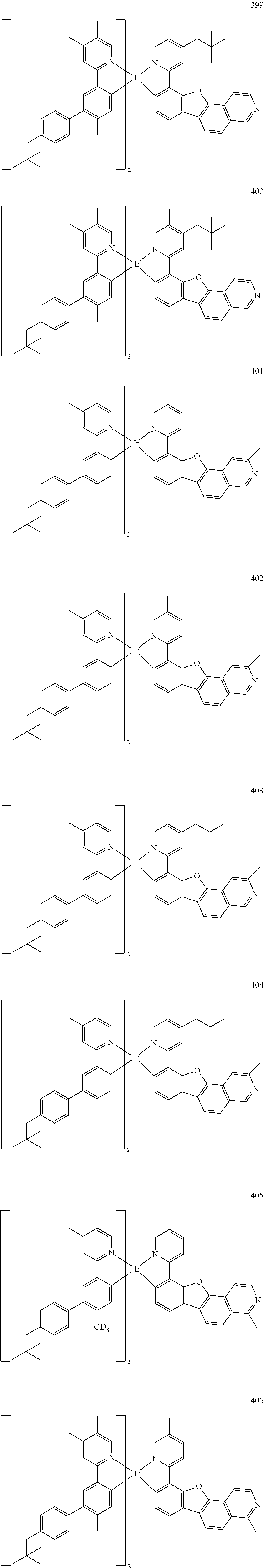

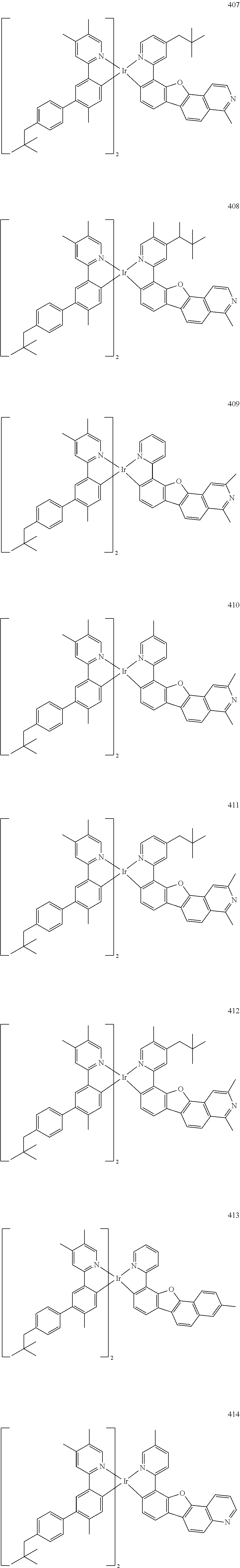

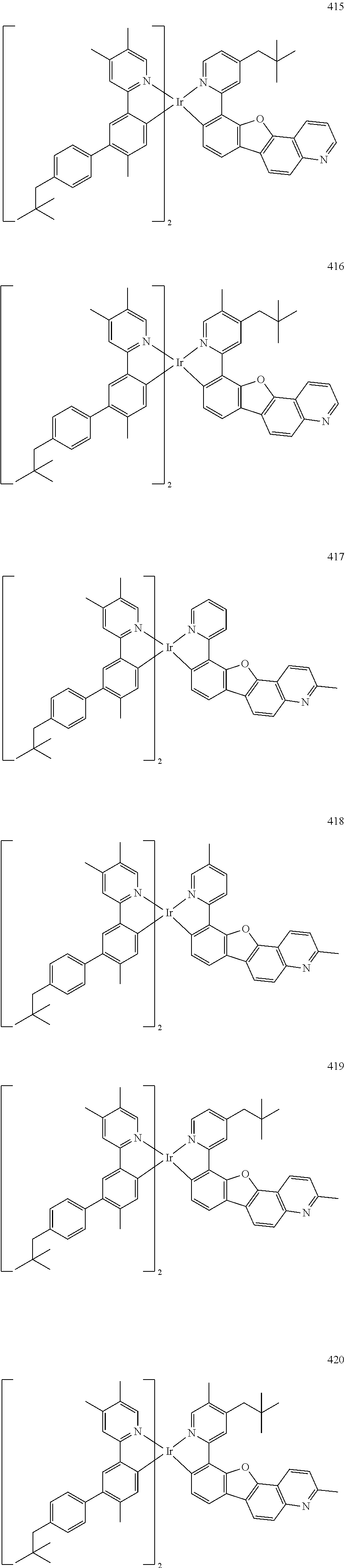

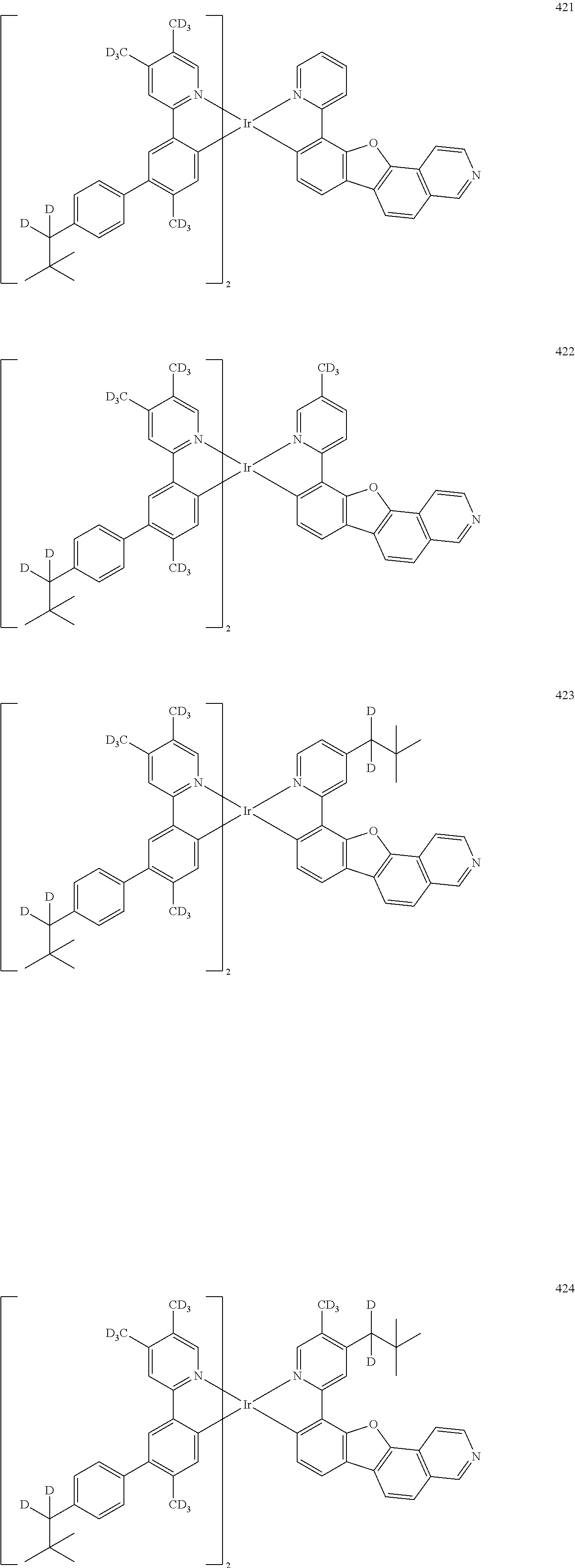

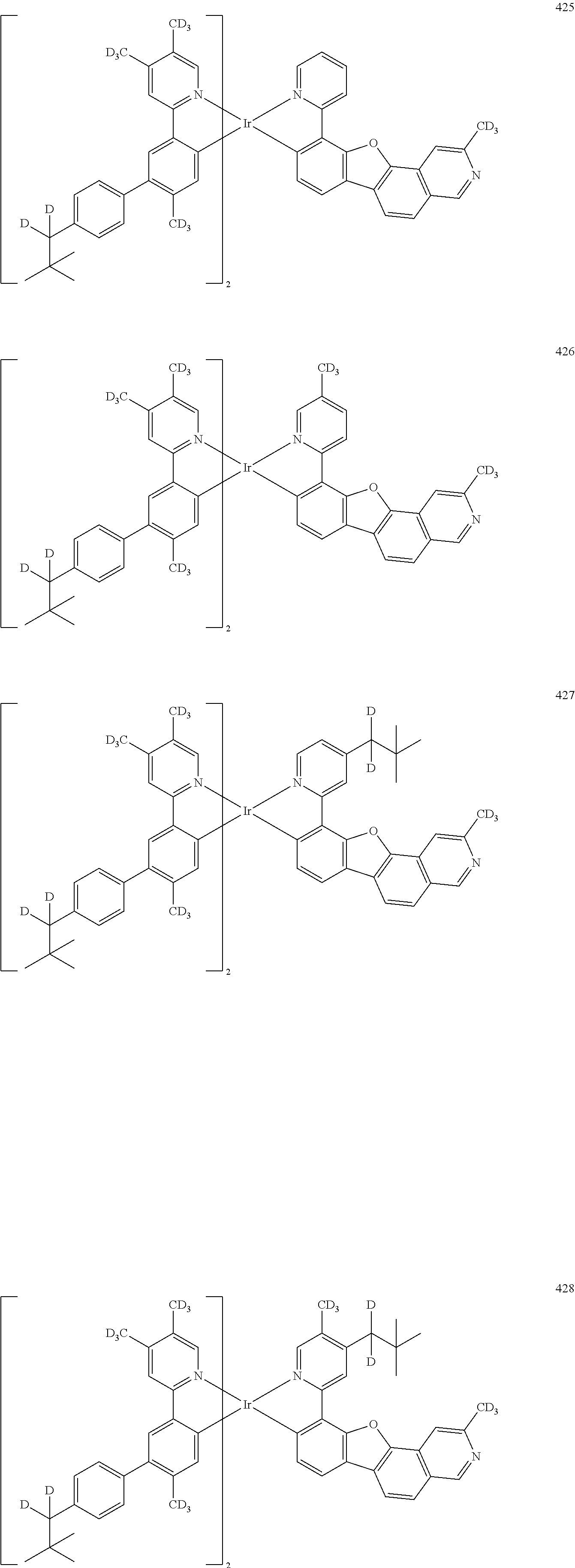

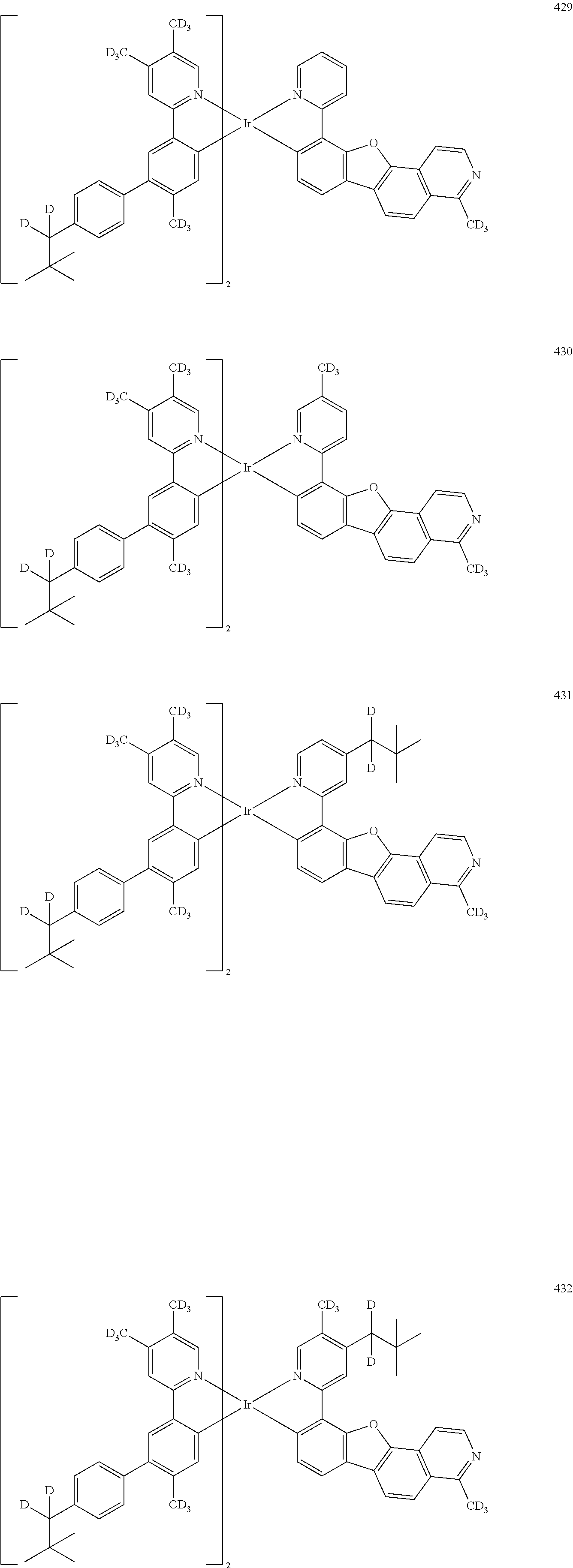

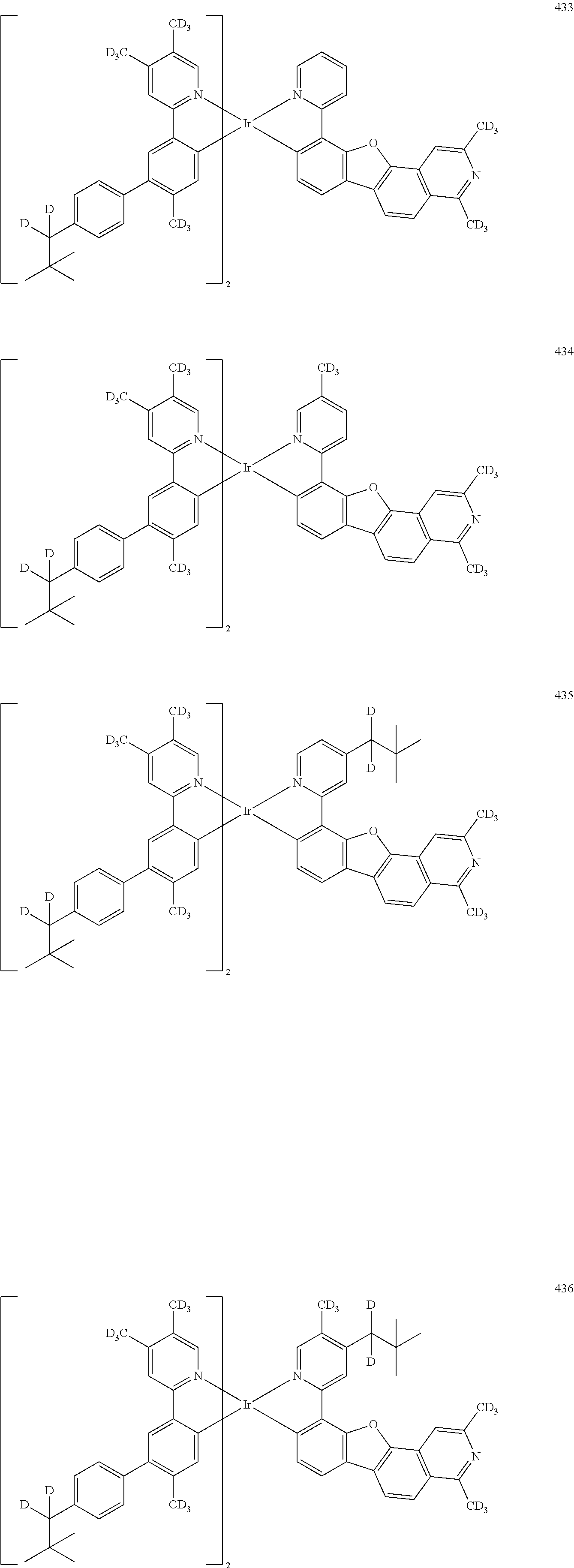

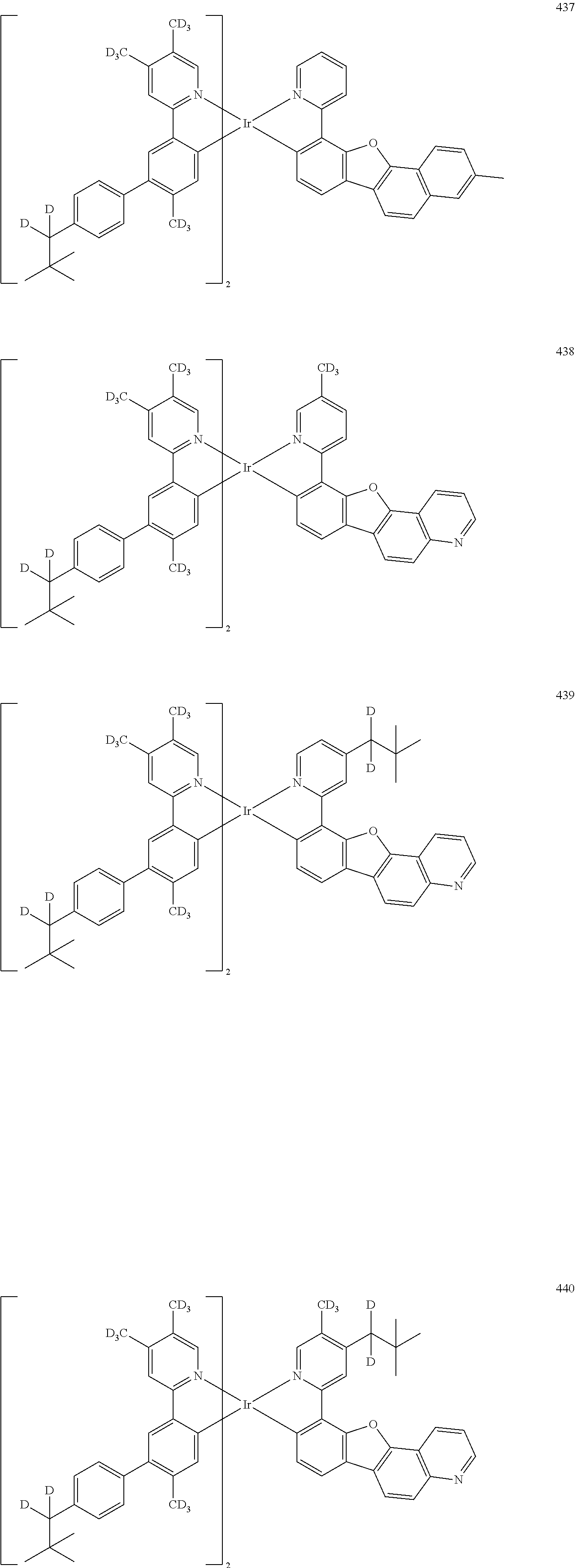

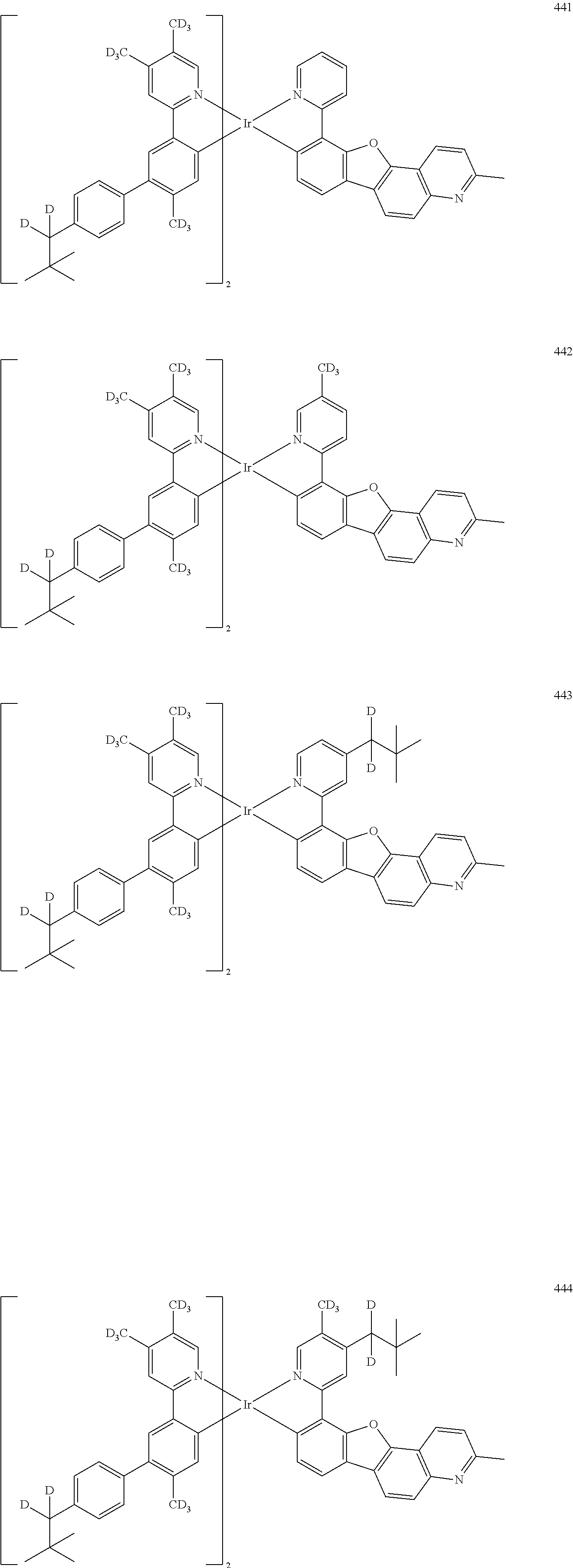

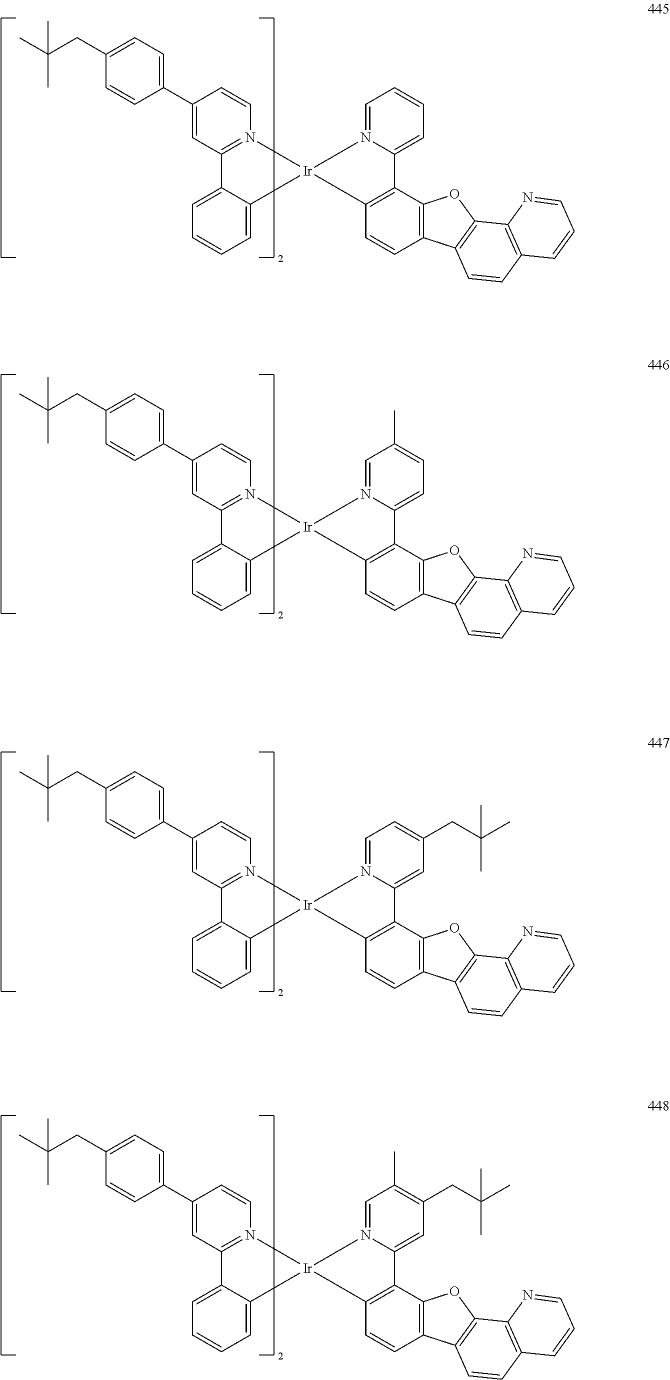

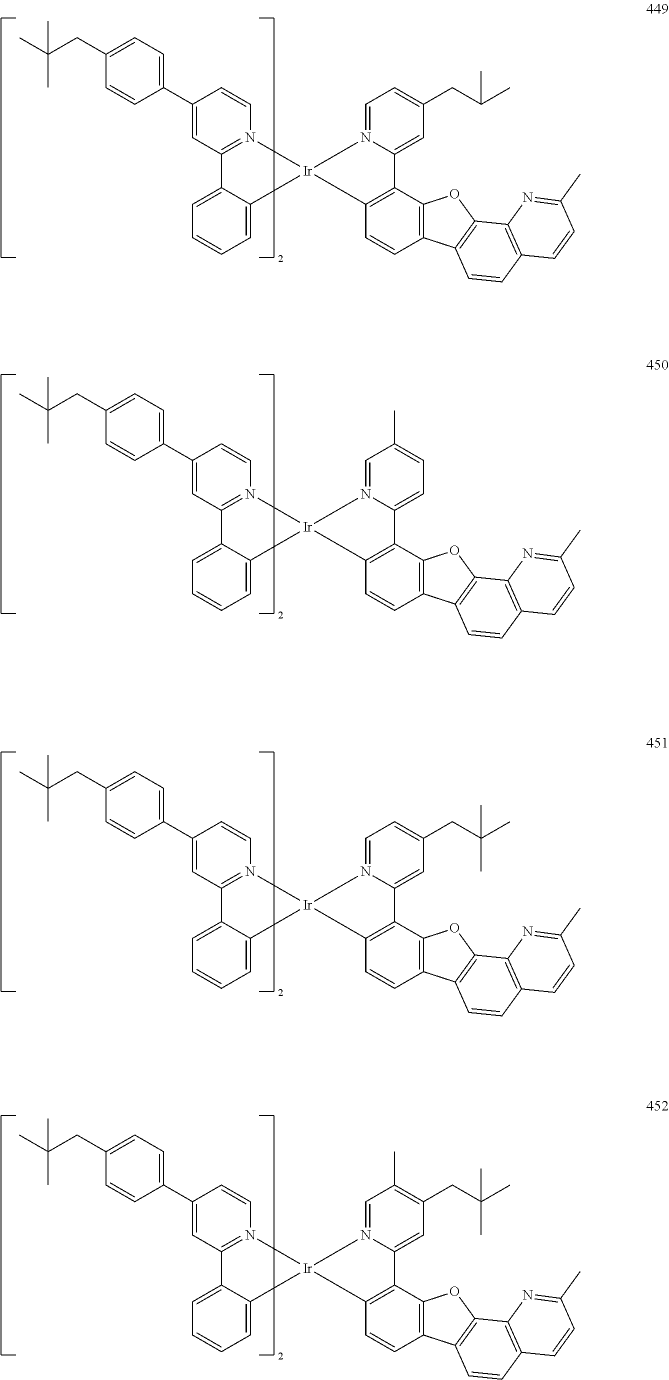

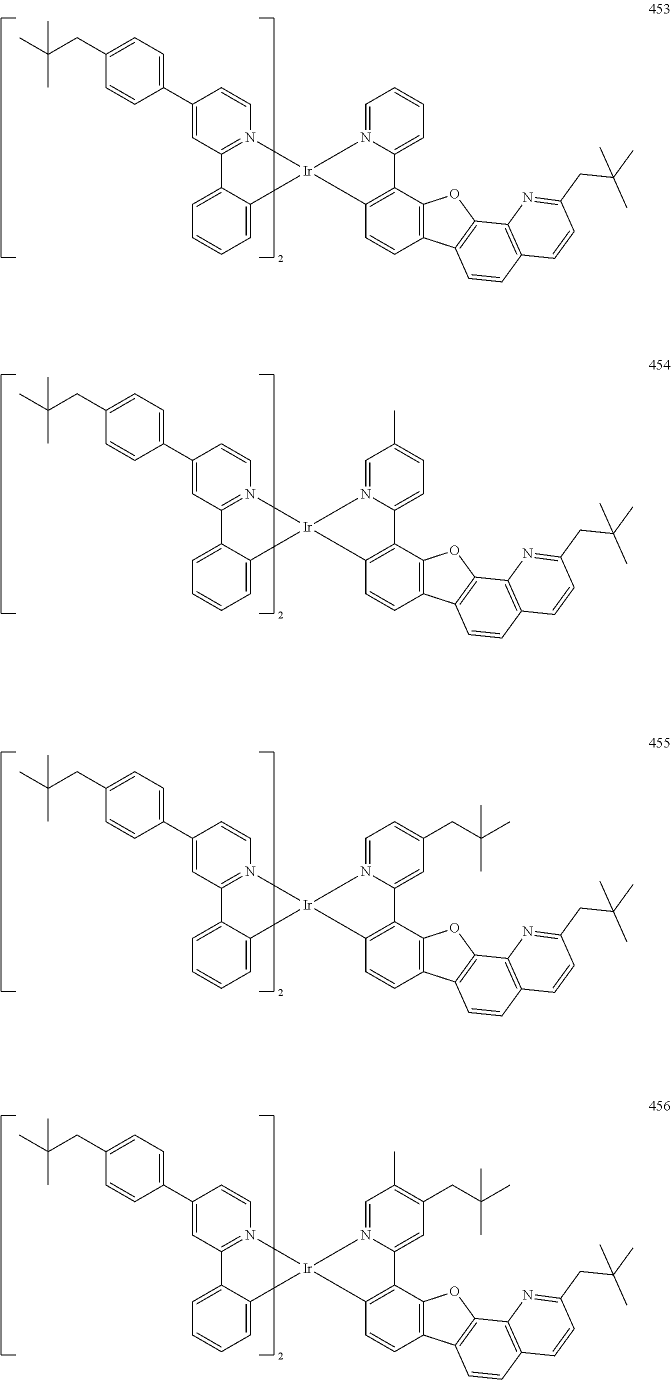

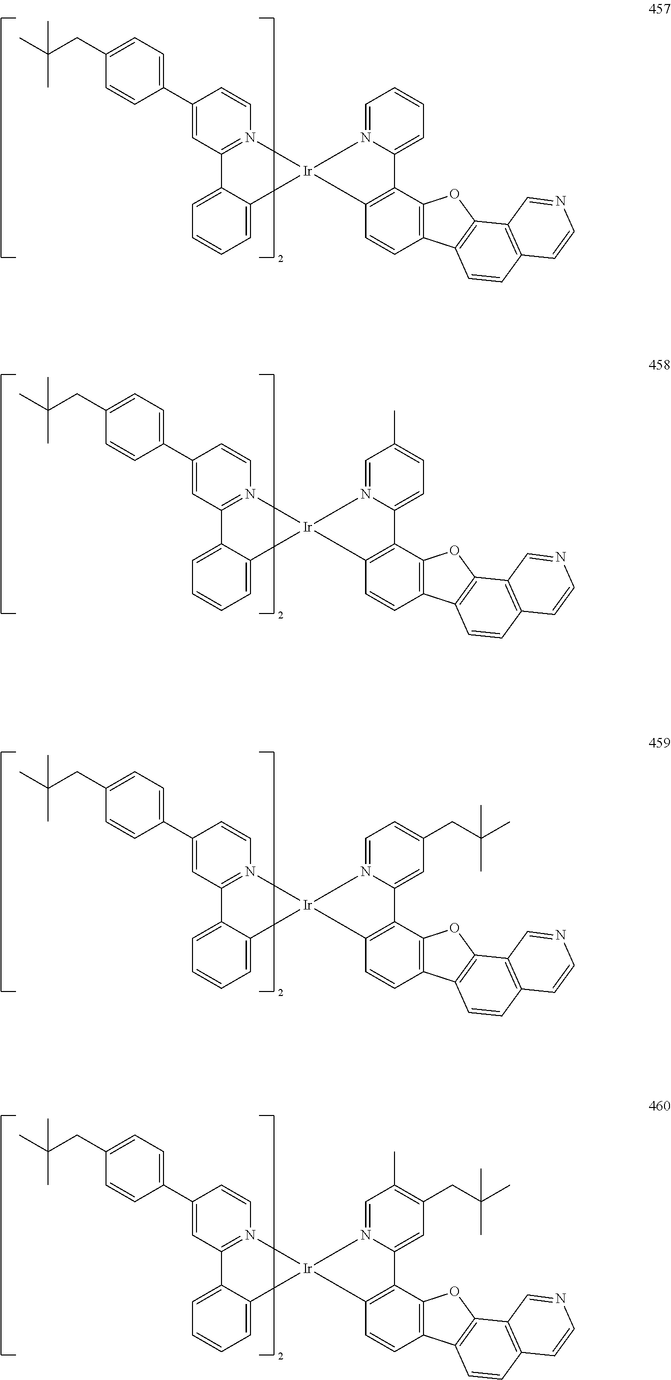

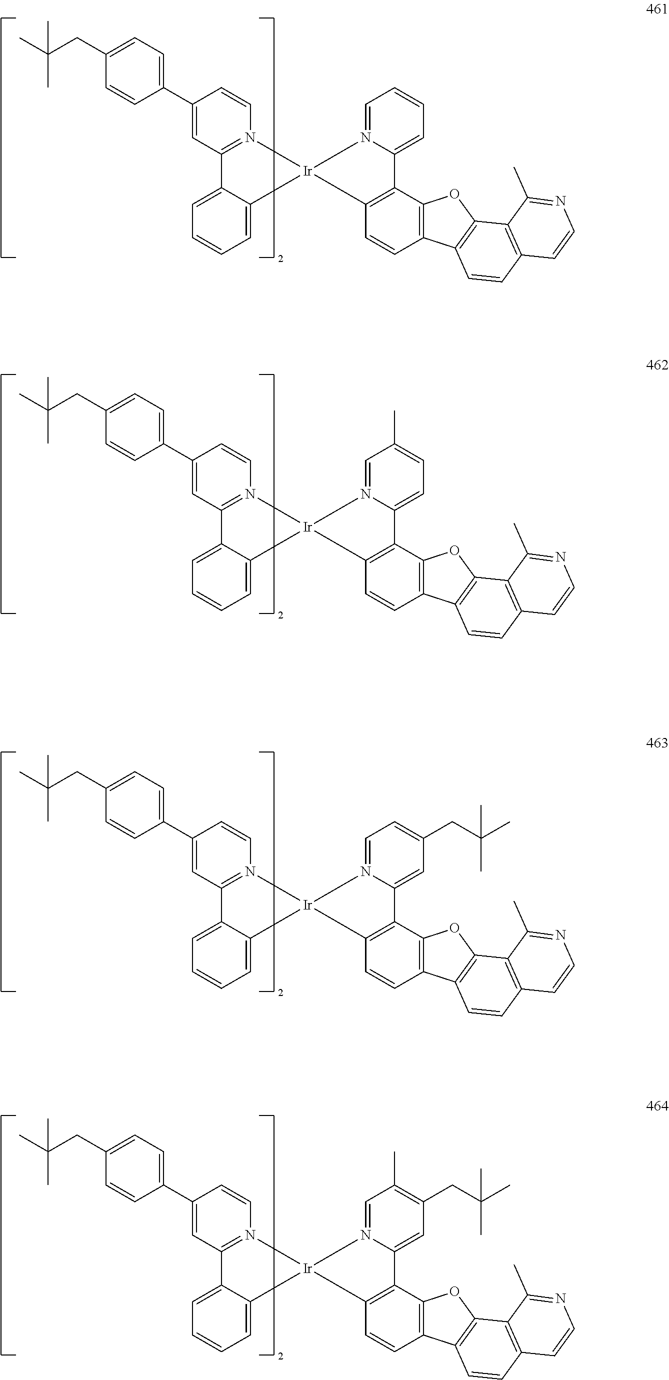

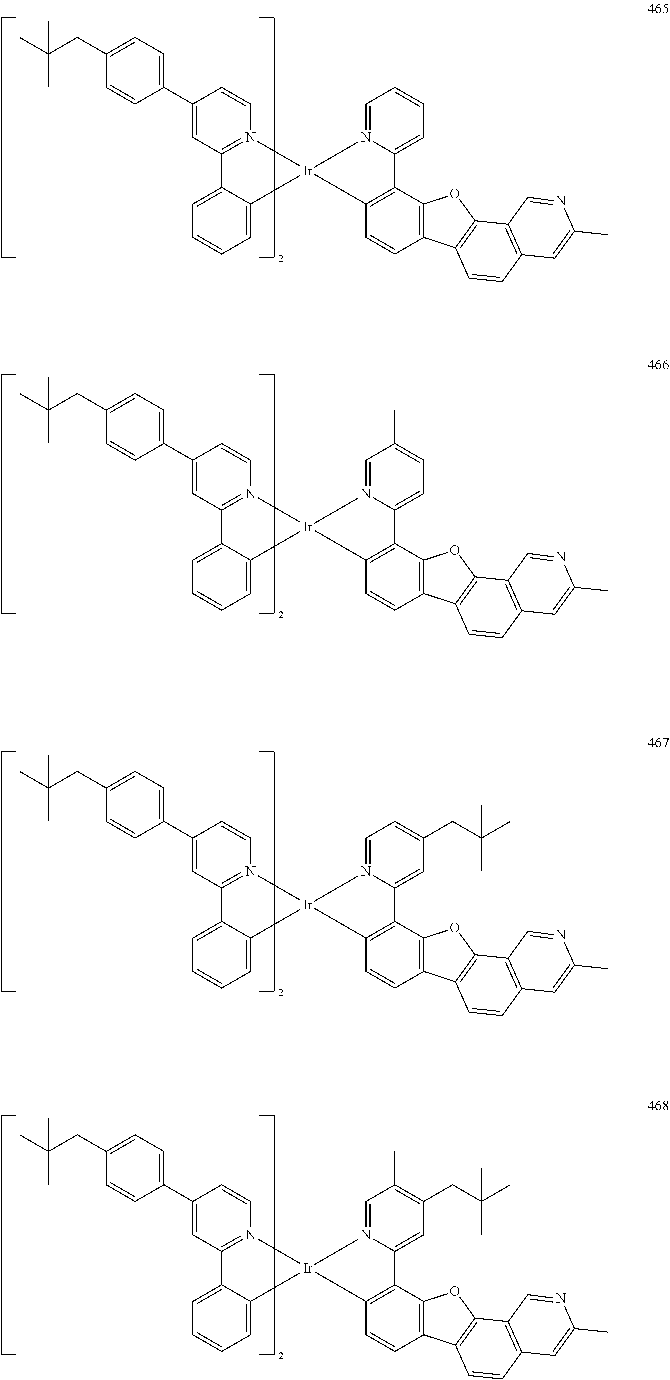

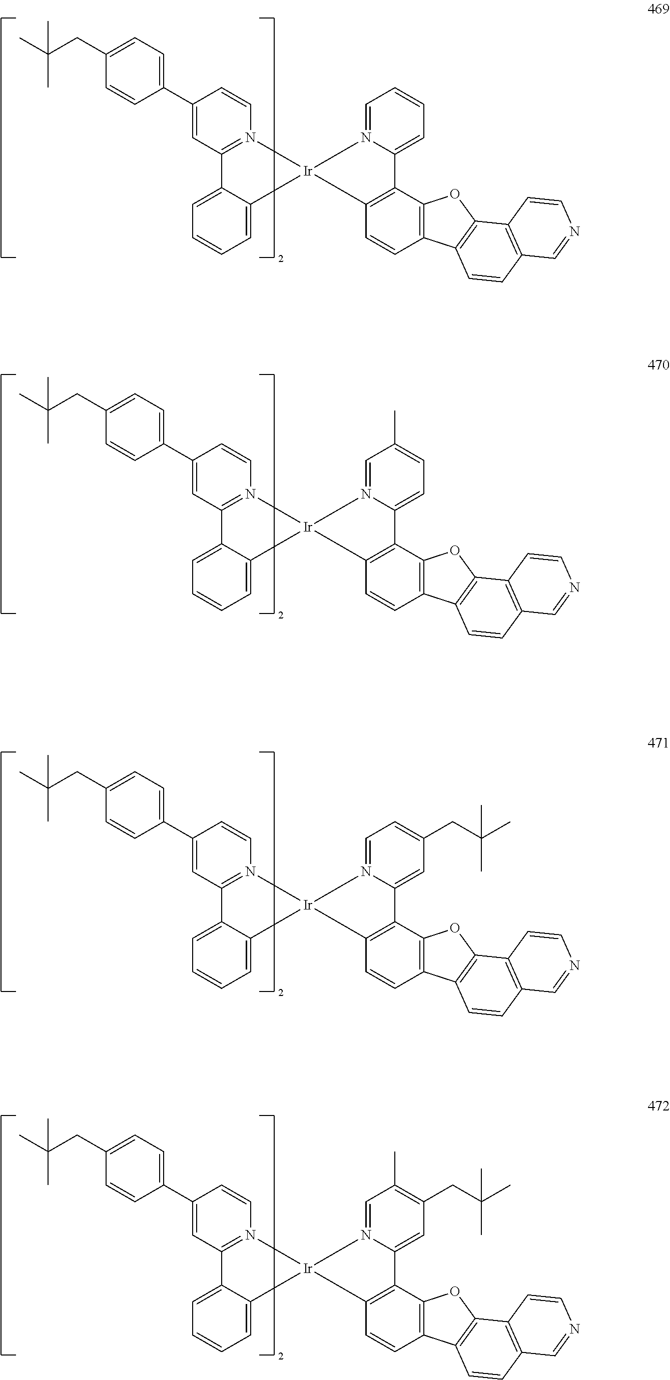

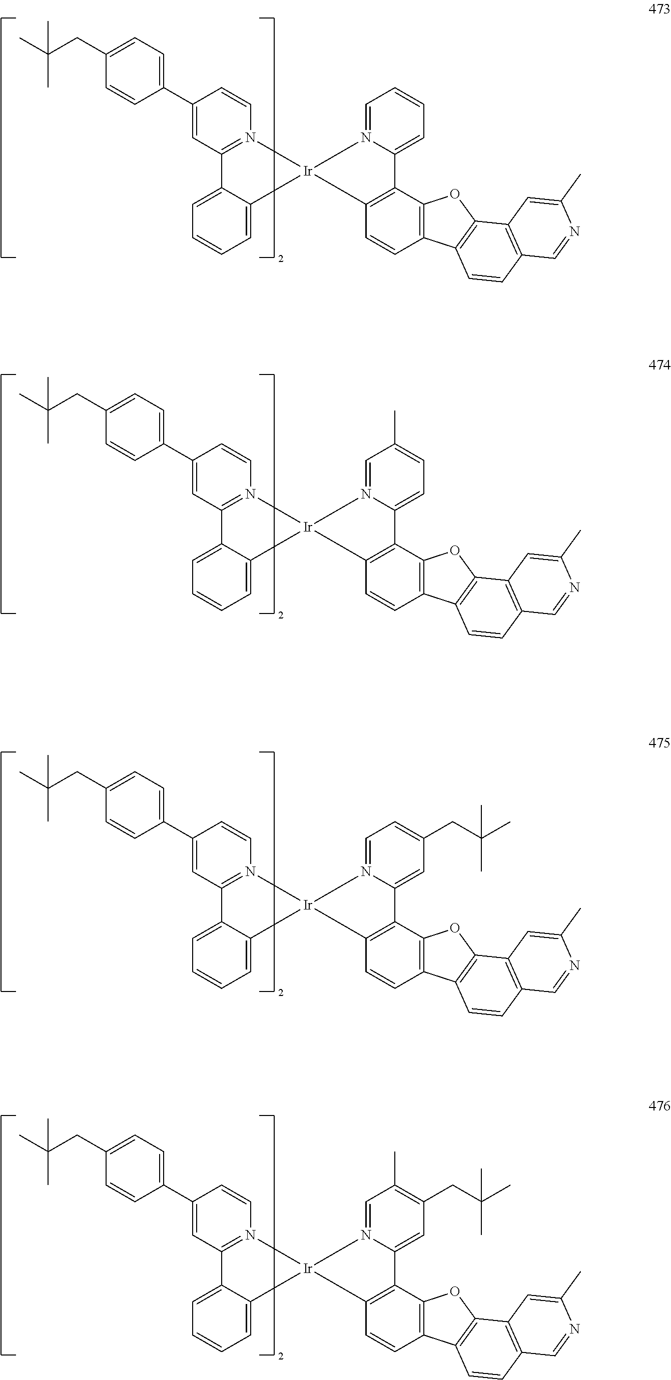

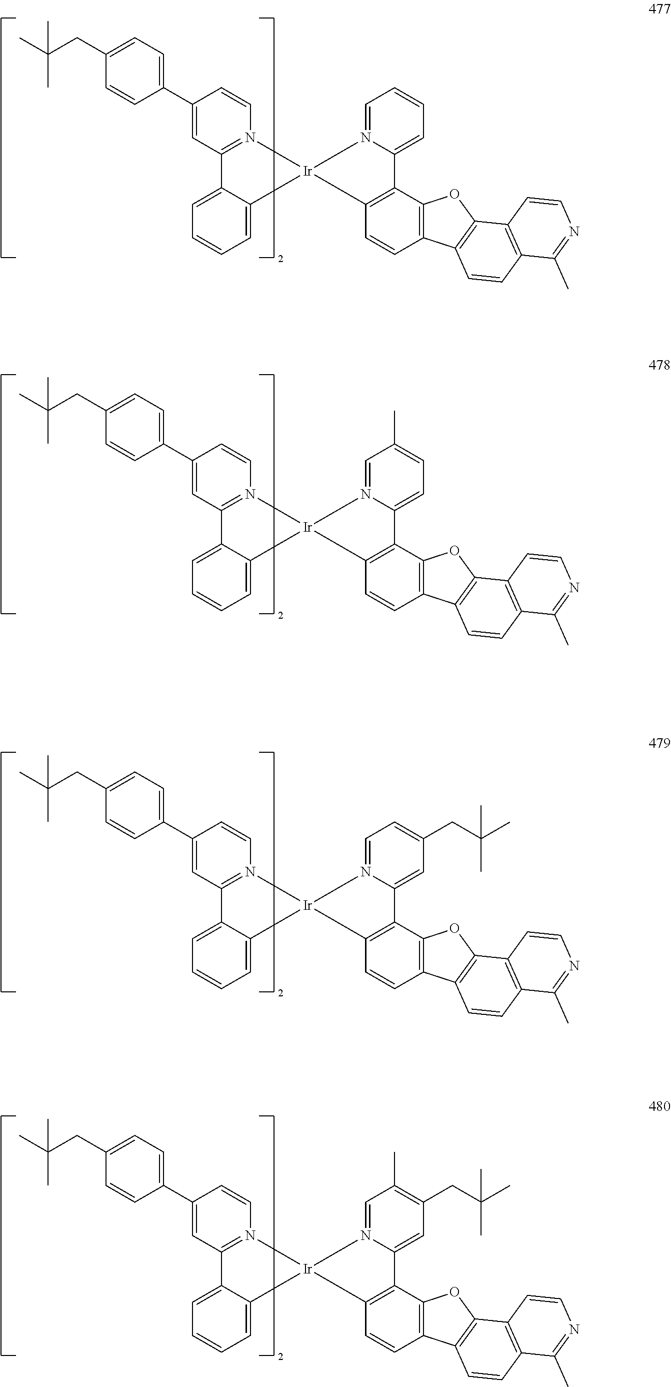

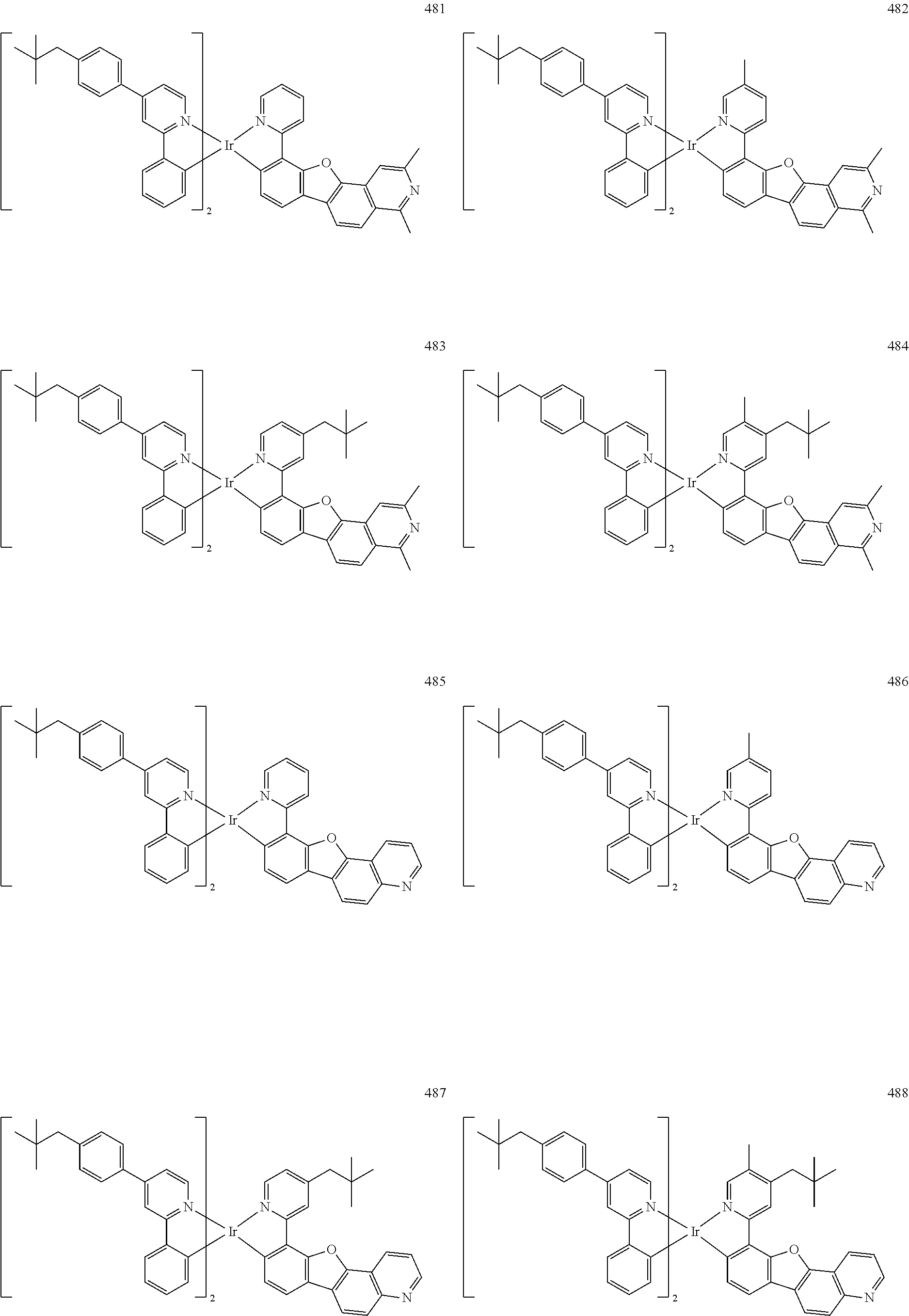

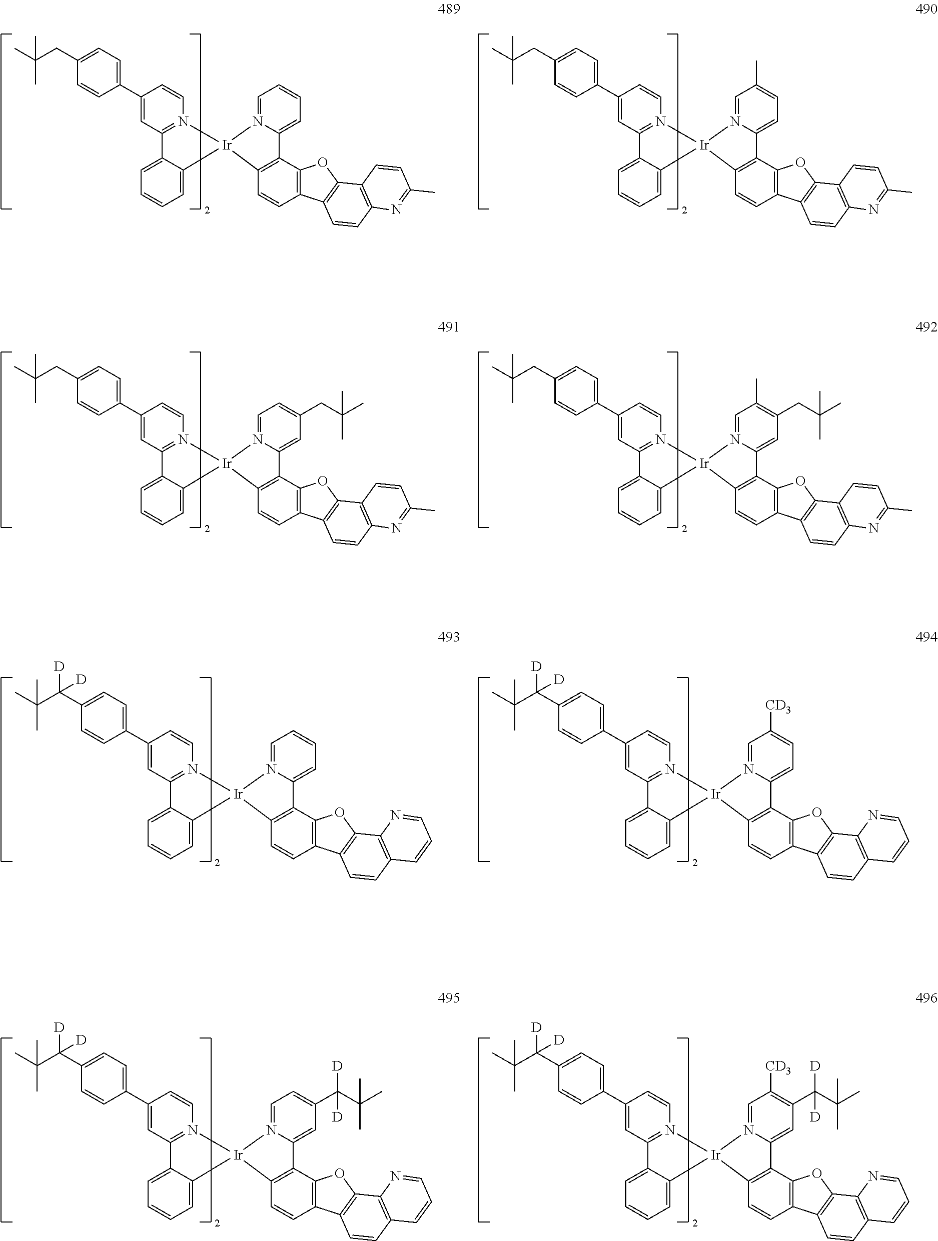

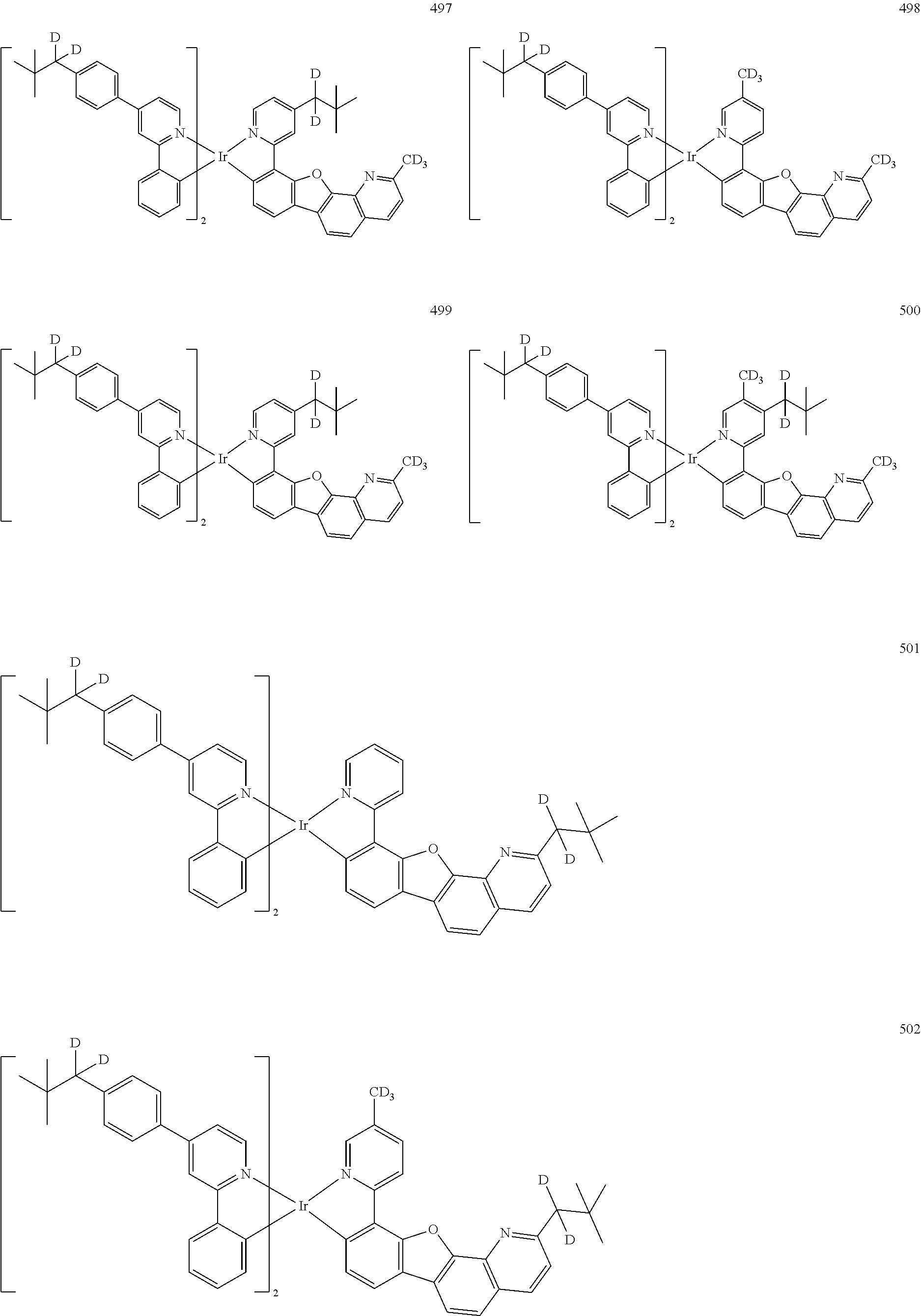

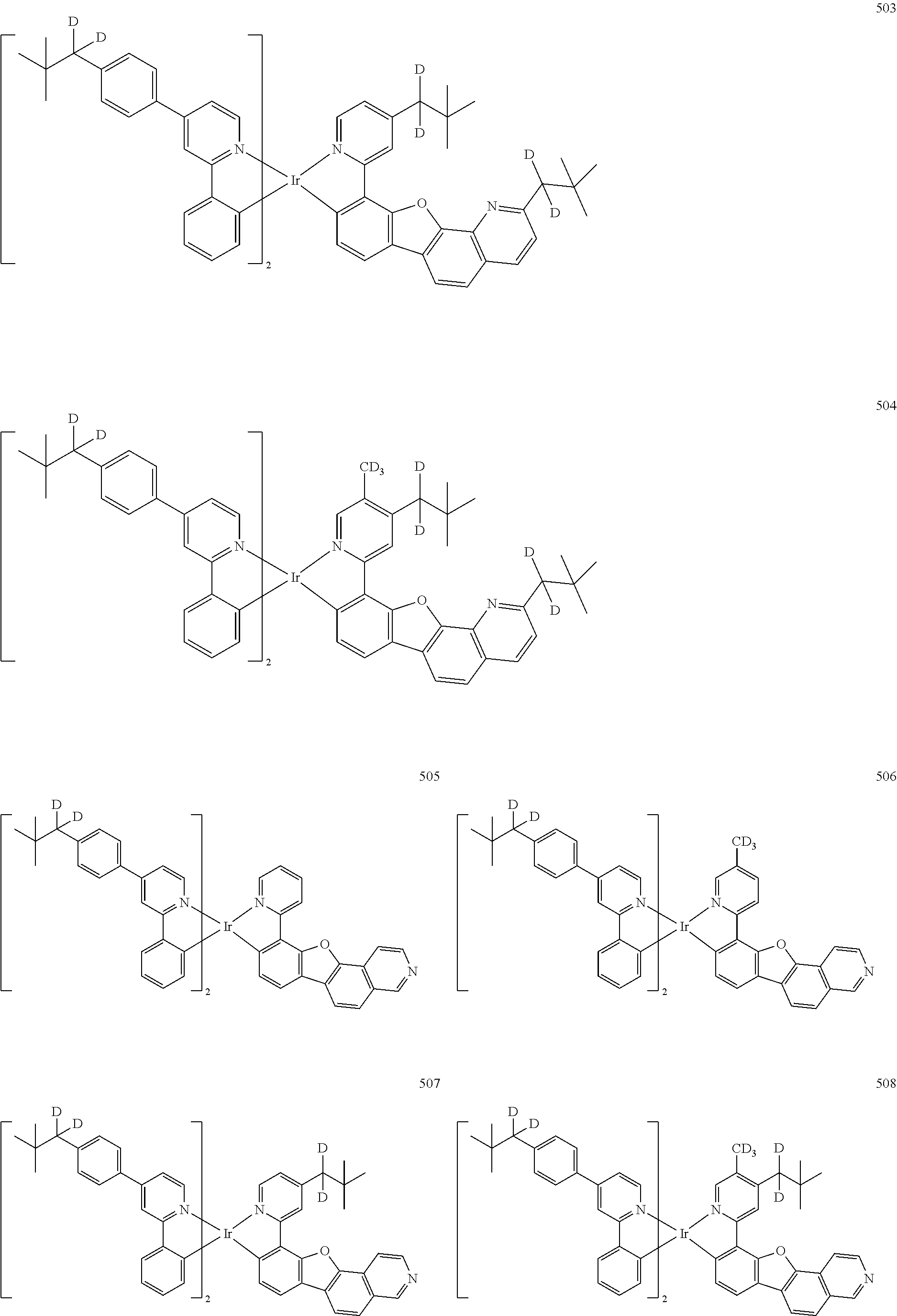

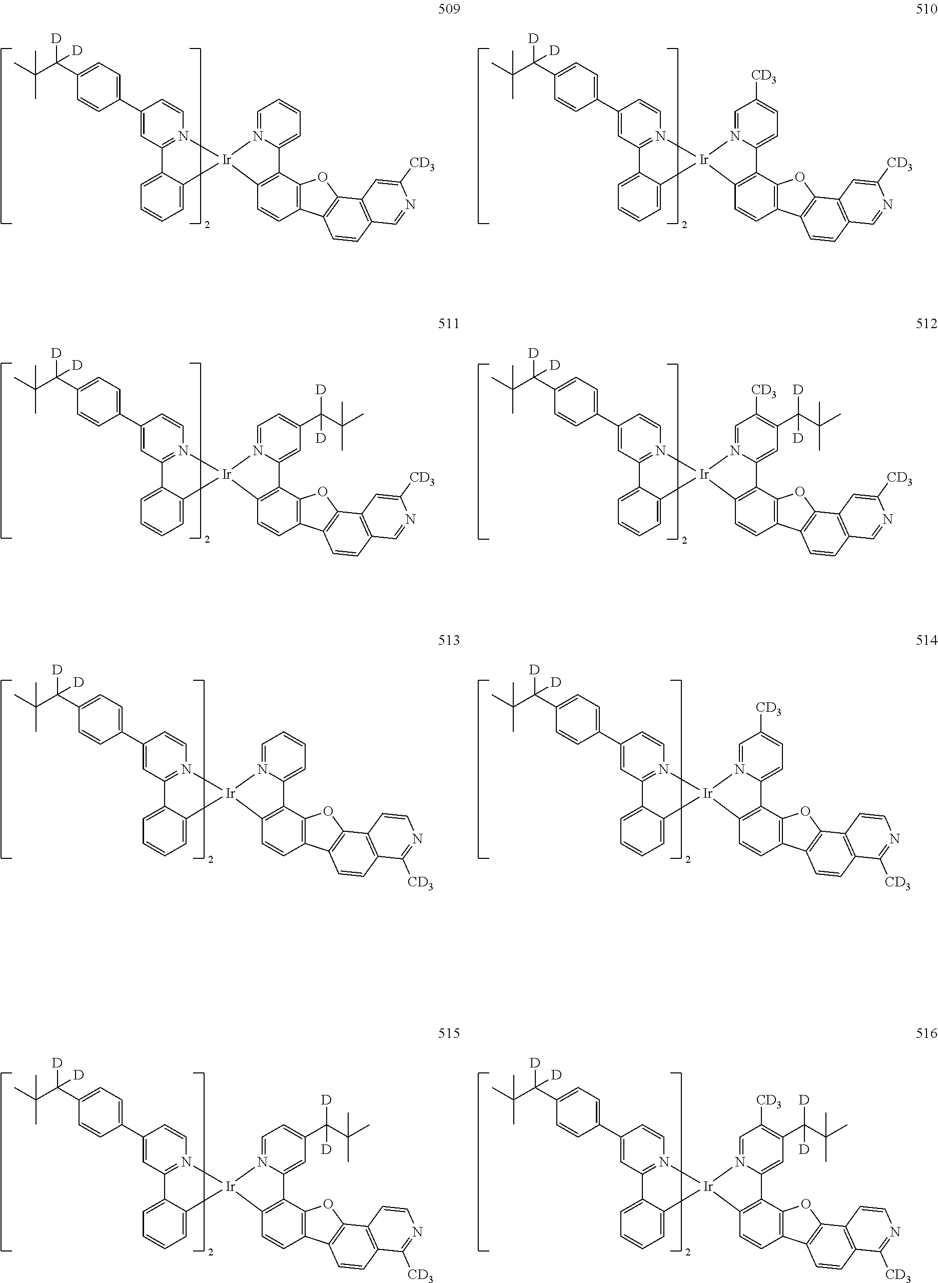

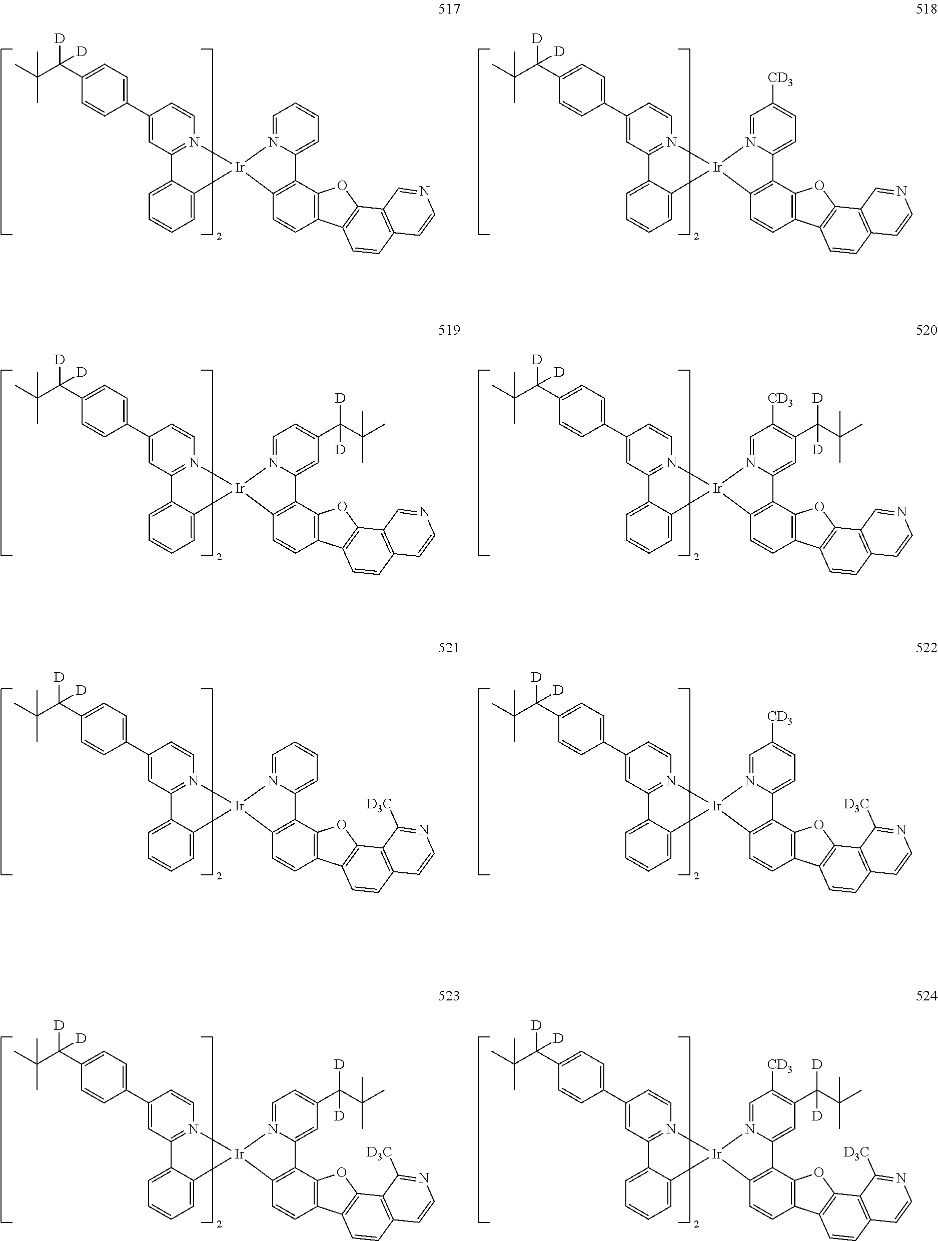

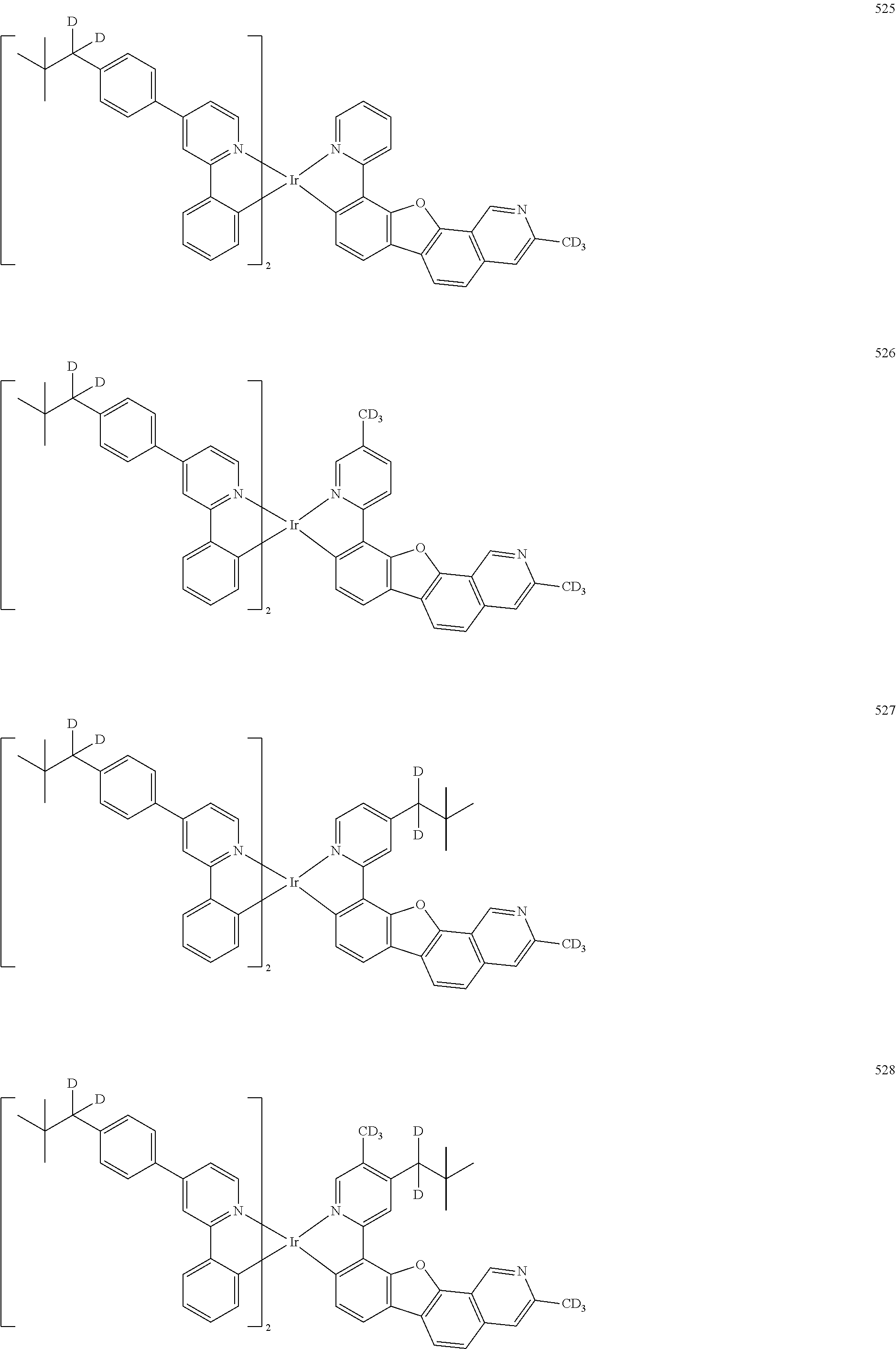

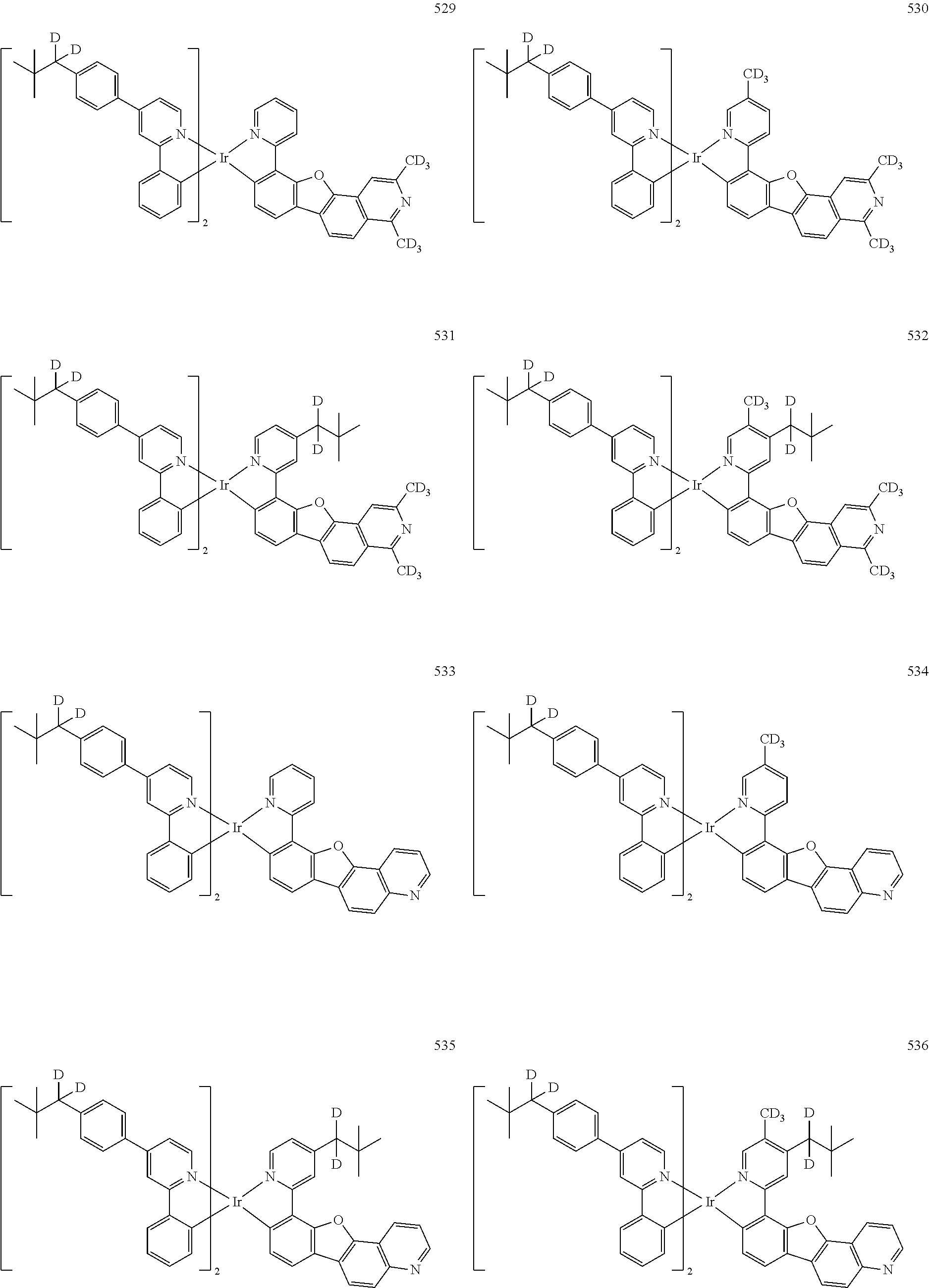

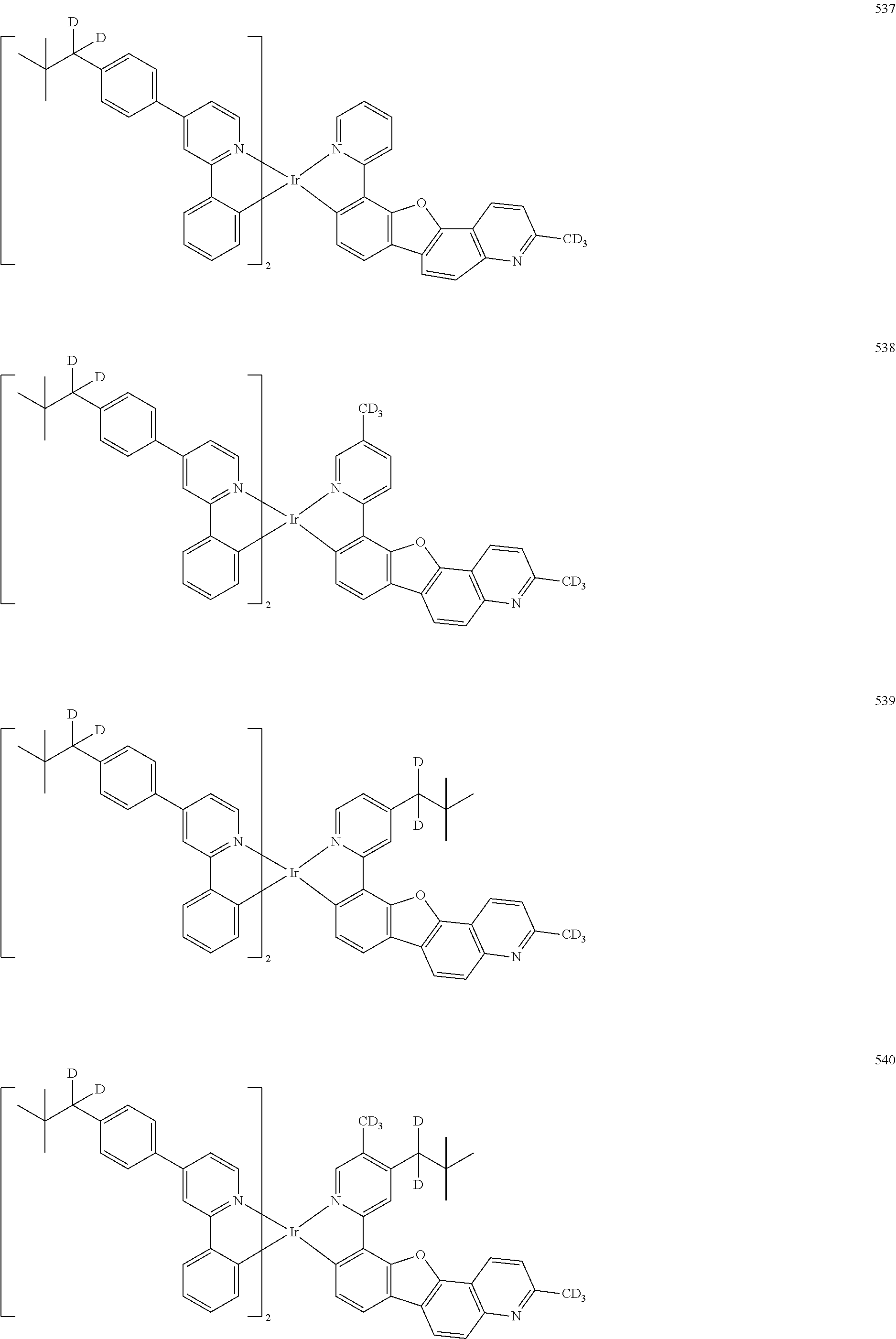

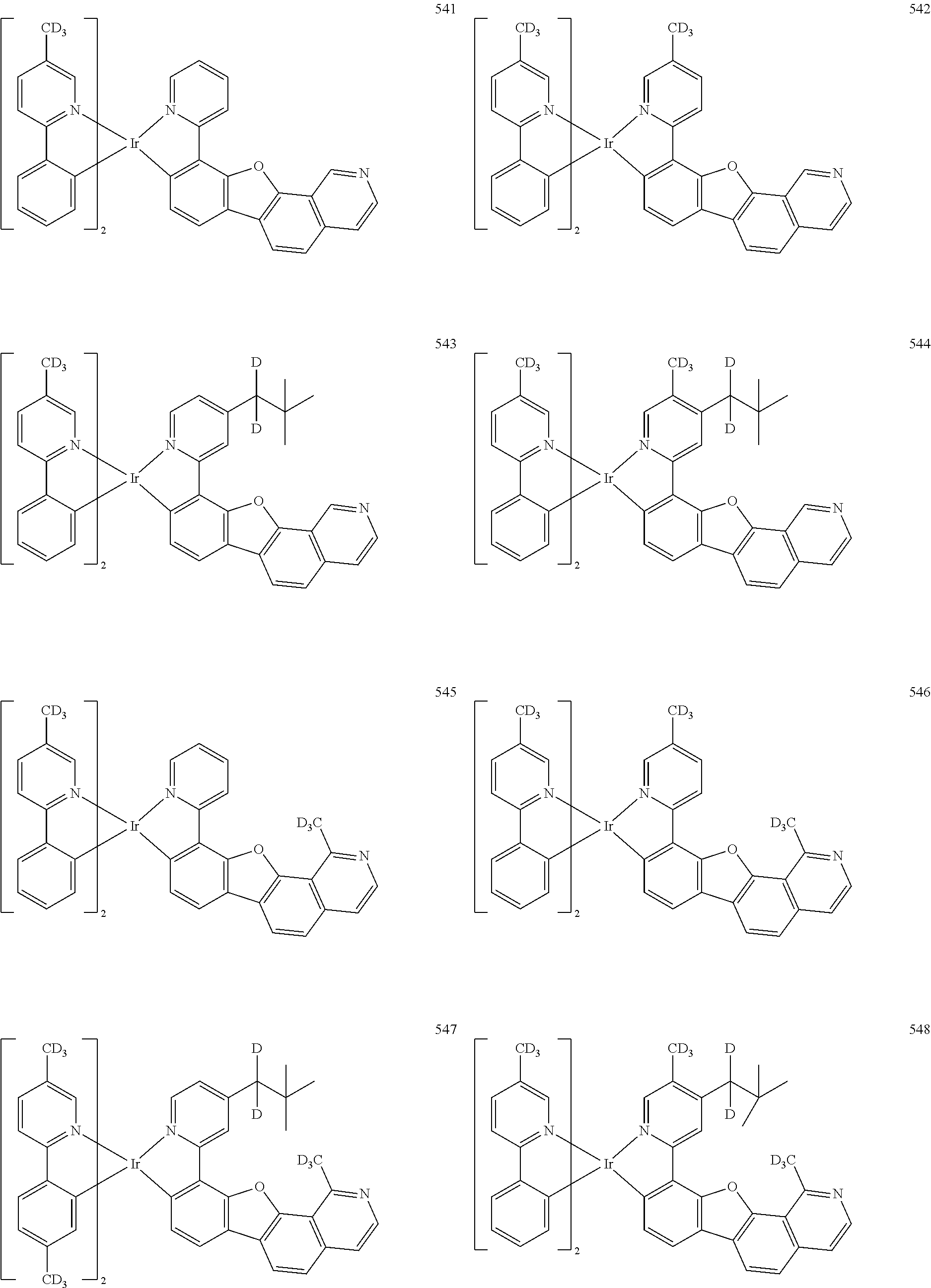

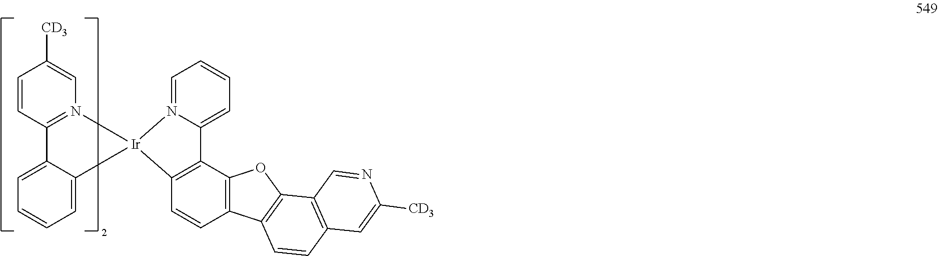

10. The organometallic compound of claim 1, wherein the compound represented by Chemical Formula 1 is a green phosphorescent material.

11. An organic light-emitting diode comprising:
a first electrode;
a second electrode facing the first electrode; and
an organic layer disposed between the first electrode and the second electrode, the organic layer including a light-emitting layer that includes a dopant material including the organometallic compound according to claim 1.

12. The organic light-emitting diode of claim 11, wherein the light-emitting layer is a green phosphorescent light-emitting layer.

13. The organic light-emitting diode of claim 11, wherein the organic layer further includes at least one selected from the group consisting of a hole injection layer, a hole transport layer, an electron transport layer, and an electron injection layer.

14. An organic light-emitting diode comprising:
a first electrode;
a second electrode facing the first electrode;
a first light-emitting stack; and
a second light-emitting stack,
wherein the first light-emitting stack and the second light-emitting stack are positioned between the first electrode and the second electrode,
wherein each of the first light-emitting stack and the second light-emitting stack includes at least one light-emitting layer, and
wherein at least one of the light-emitting layers includes a green phosphorescent light-emitting layer that includes a dopant material including the organometallic compound according to claim 1.

15. An organic light-emitting diode comprising:
a first electrode;
a second electrode facing the first electrode;
a first light-emitting stack;
a second light-emitting stack; and
a third light-emitting stack,
wherein the first light-emitting stack, the second light-emitting stack, and the third light-emitting stack are positioned between the first electrode and the second electrode,
wherein each of the first light-emitting stack, the second light-emitting stack and the third light-emitting stack includes at least one light-emitting layer, and
wherein at least one of the light-emitting layers includes a green phosphorescent light-emitting layer that includes a dopant material including the organometallic compound according to claim 1.

16. An organic light-emitting display device comprising:
a substrate;
a driving element positioned on the substrate; and
an organic light-emitting element disposed on the substrate and connected to the driving element, the organic light-emitting element including the organic light-emitting diode according to claim 11.

17. An organometallic compound represented by Chemical Formula 1:
Ir(L_{A})ₘ(L_{B})ₙ Chemical Formula 1
in Chemical Formula 1,
Ir represents iridium,
m is an integer from 1 to 3, n is an integer from 0 to 2, and a sum of m and n is 3,
L_{A} is represented by Chemical Formula, and L_{B} is represented by Chemical Formula 5: 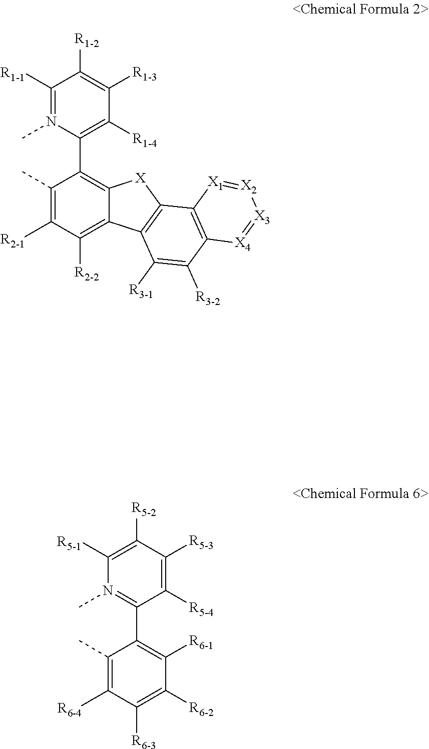
in Chemical Formula 2,
X is one selected from C(Rx)₂, NRx, oxygen (O), sulfur (S), and selenium (Se),
X₁, X₂, X₃, and X₄ each independently represents one selected from C(Rx) and N; at least one of X₁, X₂, X₃, and X₄ is N; each Rx independently represents one selected from hydrogen, C1 to C20 linear alkyl, and C3 to C20 branched alkyl; and optionally, C1 to C20 linear alkyl, and C3 to C20 branched alkyl is each independently substituted with at least one substituent selected from deuterium and halogen,
R₁₋, R₁₋₂, R₁₋₃, R₁₋₄, R₂₋₁, R₂₋₂, R₃₋₁, and R₃₋₂ each independently represents one selected from the group consisting of hydrogen, deuterium, halogen, C1 to C20 linear alkyl, C3 to C20 branched alkyl, C3 to C20 cycloalkyl, C3 to C20 heteroalkyl, C7 to C30 arylalkyl, C1 to C10 alkoxy, C6 to C20 aryloxy, amino, silyl, C2 to C20 alkenyl, C3 to C20 cycloalkenyl, C2 to C20 heteroalkenyl, C2 to C20 alkynyl, C6 to C30 aryl, C2 to C30 heteroaryl, and acyl, and optionally, C1 to C20 linear alkyl, C3 to C20 branched alkyl, C3 to C20 cycloalkyl, C3 to C20 heteroalkyl, C7 to C30 arylalkyl, C1 to C10 alkoxy, C6 to C20 aryloxy, amino, silyl, C2 to C20 alkenyl, C3 to C20 cycloalkenyl, C2 to C20 heteroalkenyl, C2 to C20 alkynyl, C6 to C30 aryl, C2 to C30 heteroaryl, and acyl are each independently substituted with at least one substituent selected from deuterium and halogen, and
optionally, two adjacent groups among R₁₋₁, R₁₋₂, R₁₋₃, and R₁₋₄ bind to each other to form a ring structure; optionally, R₂₋₁ and R₂₋₂ bind to each other to form a ring structure; and optionally, R₃₋₁ and R₃₋₂ bind to each other to form a ring structure; and
in Chemical Formula 6, R₅₋₁, R₅₋₂, R₅₋₃, R₅₋₄, R₆₋₁, R₆₋₂, R₆₋₃, and R₆₋₄ each independently represents one selected from the group consisting of hydrogen, deuterium, C1 to C5 linear alkyl, C3 to C5 branched alkyl, C6 to C10 aryl, and C7 to C30 arylalkyl, and optionally, C1 to C5 linear alkyl, C3 to C5 branched alkyl, and C7 to C30 arylalkyl is each independently substituted with at least one substituent selected from deuterium and halogen, and
optionally, two adjacent groups among R₅₋₁, R₅₋₂, R₅₋₃, and R₅₋₄ bind to each other to form a ring structure; and optionally, two adjacent groups among R₆₋₁, R₆₋₂, R₆₋₃, and R₆₋₄ bind to each other to form a ring structure.

18. The organometallic compound of claim 17, wherein R₅₋₂, R₅₋₃, and R₆₋₃ in Chemical Formula 6 are each independently an unsubstituted or deuterium-substituted methyl group.

19. The organometallic compound of claim 18, wherein X is O.

20. The organometallic compound of claim 19, wherein the organometallic compound represented by Chemical Formula 1 includes one selected from compounds 97, 101, 109, 121, 145, 157, 169, 137, 185, and 329: 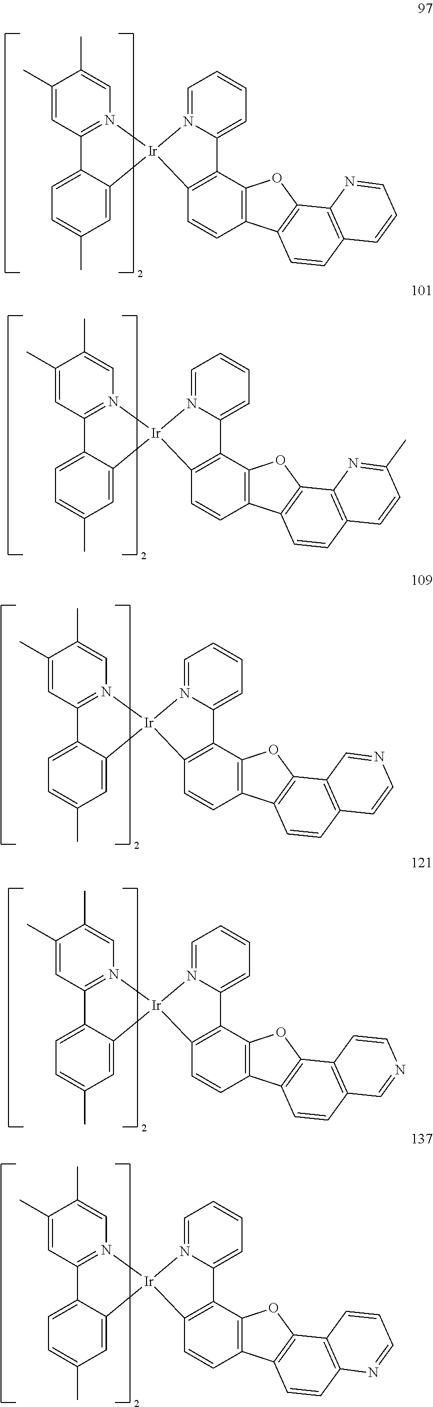 [chemical structure]
